(19) United States
(12) Patent Application Publication
(10) Pub. No.: US 2026/0096214 A1
(43) Pub. Date: Apr. 2, 2026

(54) SEMICONDUCTOR DEVICE

(71) Applicant: Semiconductor Energy Laboratory Co., Ltd., Atsugi-shi, Kanagawa-ken (JP)

(72) Inventors: Yutaka OKAZAKI, Isehara (JP); Motoki NAKASHIMA, Atsugi (JP)

(21) Appl. No.: 19/141,621

(22) PCT Filed: Jan. 12, 2024
(86) PCT No.: PCT/IB2024/050314

§ 371 Date: Jun. 20, 2025

(30) Foreign Application Priority Data
Jan. 19, 2023 (JP) 2023-006377
Mar. 24, 2023 (JP) 2023-047594

(51) Int. Cl. H10D 86/40; H10D 30/01; H10D 30/67; H10D 86/01

(52) U.S. Cl. CPC H10D 86/471; H10D 30/6706; H10D 30/6734; H10D 30/6736; H10D 86/431; H10D 30/0312; H10D 86/0221

(57) ABSTRACT

A semiconductor device that can be reduced in size or highly integrated is provided. The semiconductor device includes first and second transistors and first to third conductors. The first transistor includes first and second gate electrodes between which a semiconductor layer of the first transistor is positioned. The second gate electrode is provided over the semiconductor layer of the first transistor to overlap the first gate electrode. The second transistor includes a third gate electrode over a semiconductor layer of the second transistor. The second transistor is stacked over the first transistor. The third gate electrode overlaps the second gate electrode. The first conductor electrically connects a source electrode of the first transistor and a source electrode of the second transistor. The second conductor electrically connects a drain electrode of the first transistor and a drain electrode of the second transistor. The third conductor electrically connects the first gate electrode, the second gate electrode, and the third gate electrode.

### TECHNICAL FIELD

One embodiment of the present invention relates to a semiconductor device and a method for manufacturing a semiconductor device. Another embodiment of the present invention relates to a transistor and a method for manufacturing a transistor. Another embodiment of the present invention relates to an electronic appliance.

Note that one embodiment of the present invention is not limited to the above technical field. Examples of the technical field of one embodiment of the present invention include a semiconductor device, a display device, a light-emitting device, a power storage device, a memory device, a lighting device, an input device (e.g., a touch sensor), an input/output device (e.g., a touch panel), an electronic appliance including any of them, a method for driving any of them, and a method for manufacturing any of them.

Note that in this specification and the like, a semiconductor device refers to a general device that can function by utilizing semiconductor characteristics. A semiconductor element such as a transistor, a semiconductor circuit, an arithmetic device, and a memory device are each an embodiment of a semiconductor device. It can be sometimes said that a display device (e.g., a liquid crystal display device and a light-emitting display device), a projection device, a lighting device, an electro-optical device, a power storage device, a memory device, a semiconductor circuit, an imaging device, an electronic appliance, and the like include a semiconductor device.

### BACKGROUND ART

In recent years, the development of semiconductor devices has progressed, and semiconductor devices are used in LSIs, CPUs, memories, and the like. A CPU is an aggregation of semiconductor elements; the CPU includes a semiconductor integrated circuit (including at least a transistor and a capacitor) formed into a chip by processing a semiconductor wafer, and is provided with an electrode that is a connection terminal.

An integrated circuit (IC chip) of an LSI, a CPU, a memory, or the like is mounted on a circuit board, for example, a printed wiring board, to be used as one of components of a variety of electronic appliances.

In recent years, demand for an integrated circuit with higher density has risen with reductions in size and weight of electronic appliances. In addition, the productivity of a semiconductor device including an integrated circuit is desired to be increased. To achieve an integrated circuit with higher density, transistors included in an integrated circuit need to be scaled down. A well-known example of a minute transistor structure is a Fin-type structure. As a minute structure to replace a Fin-type structure, Non-Patent Document 1 discloses a GAA (Gate All Around) nanosheet structure in which silicon layers formed into nanosheet shapes are stacked and their peripheries are surrounded by a gate electrode.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a material of a semiconductor thin film applicable to the transistor, and an oxide semiconductor has been attracting attention as another material.

It is known that a transistor using an oxide semiconductor has an extremely low leakage current in the off state. For example, Patent Document 1 discloses a low-power-consumption CPU utilizing a feature of a low leakage current of the transistor using an oxide semiconductor. Furthermore, for example, Patent Document 2 discloses a memory device that can retain stored contents for a long time by utilizing a feature of a low leakage current of the transistor using an oxide semiconductor.

Patent Document 3 discloses a transistor having a minute structure in which a source electrode layer and a drain electrode layer are provided in contact with the top surface of an oxide semiconductor layer.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2016/125052

### Non-Patent Document

[Non-Patent Document 1] 2017 Symposium on VLSI Technology Digest of Technical Papers, T230

### SUMMARY OF THE INVENTION

### Problems to Be Solved by the Invention

An example of a method for achieving a semiconductor device with a high on-state current is employing a structure in which the number of transistors included in the semiconductor device is increased and the transistors are connected in parallel and provided adjacent to each other over one substrate. However, with this method, the area occupied by one semiconductor device in a substrate plane is increased; thus, it is difficult to manufacture a minute semiconductor device with a high degree of integration.

An example of a disclosed structure of a semiconductor device that obtains a high on-state current without increasing the area occupied in a substrate plane includes the above-described GAA nanosheet structure (see Non-Patent Document 1). However, this structure is based on the assumption that silicon is used for a semiconductor layer where a channel of a transistor is formed; hence, it is sometimes difficult to use a material other than silicon for the structure in terms of a manufacturing method or the like.

In view of the above, an object of one embodiment of the present invention is to provide a semiconductor device that can be reduced in size or highly integrated. Another object of one embodiment of the present invention is to provide a semiconductor device that operates at high speed. Another object of one embodiment of the present invention is to provide a semiconductor device with favorable electrical characteristics. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device with a high on-state current. Another object of one embodiment of the present invention is to provide a semiconductor device with low power consumption. Another object of one embodiment of the present invention is to provide a novel semiconductor device. Another object of one embodiment of the present invention is to provide a method for manufacturing a semiconductor device with high productivity. Another object of one embodiment of the present invention is to provide a method for manufacturing a novel semiconductor device.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a semiconductor device including a first transistor, a second transistor, a first insulator, a first conductor, a second conductor, and a third conductor. The first transistor includes a first gate electrode, a first gate insulator, a first semiconductor layer, a first source electrode, a first drain electrode, a second gate insulator, and a second gate electrode. The second transistor includes a second semiconductor layer, a second source electrode, a second drain electrode, a third gate insulator, and a third gate electrode. The first gate insulator is provided over the first gate electrode. The first semiconductor layer is provided over the first gate insulator to include a region overlapping the first gate electrode. The second gate insulator is provided over the first semiconductor layer. The second gate electrode is provided over the second gate insulator to include a region overlapping the first gate electrode. The first source electrode and the first drain electrode are provided over the first semiconductor layer so that the second gate electrode is positioned between the first source electrode and the first drain electrode in a planar view. The first insulator is provided over the second gate electrode. The second semiconductor layer is provided over the first insulator to include a region overlapping the first semiconductor layer. The third gate insulator is provided over the second semiconductor layer. The third gate electrode is provided over the third gate insulator to include a region overlapping the second gate electrode. The second source electrode and the second drain electrode are provided over the second semiconductor layer so that the third gate electrode is positioned between the second source electrode and the second drain electrode in the planar view. The first conductor is provided to penetrate the second source electrode and the second semiconductor layer and include a region in contact with the first source electrode. The second conductor is provided to penetrate the second drain electrode and the second semiconductor layer and include a region in contact with the first drain electrode. The third conductor is provided to include a region in contact with the first gate electrode, the second gate electrode, and the third gate electrode.

In the above, it is preferable that the first transistor and the second transistor each include a metal oxide in the semiconductor layer.

In the above, it is preferable that a second insulator covering the first transistor and a third insulator covering the second transistor be included; the third insulator, the second source electrode, the second semiconductor layer, and the second insulator include a first opening reaching the first source electrode; the third insulator, the second drain electrode, the second semiconductor layer, and the second insulator include a second opening reaching the first drain electrode; the second conductor be provided in contact with a sidewall and a bottom surface of the first opening; and the third conductor be provided in contact with a sidewall and a bottom surface of the second opening.

In the above, the length of the third gate electrode in the channel width direction is preferably smaller than the length of the second gate electrode in the channel width direction.

In the above, it is preferable that the width between the first source electrode and the first drain electrode and the width between the second source electrode and the second drain electrode be each less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm.

In the above, it is preferable that a second insulator covering the first transistor and a third insulator covering the second transistor be included; between the first source electrode and the first drain electrode, the second insulator include a first opening reaching the first semiconductor layer, between the second source electrode and the second drain electrode, the third insulator include a second opening reaching the second semiconductor layer, the second gate insulator be provided in contact with a sidewall and a bottom surface of the first opening, the second gate electrode be provided over the second gate insulator to fill the first opening, the third gate insulator be provided in contact with a sidewall and a bottom surface of the second opening, the third gate electrode be provided over the third gate insulator to fill the second opening, an uppermost surface of the second gate insulator be substantially level with a top surface of the second gate electrode; and an uppermost surface of the third gate insulator be substantially level with a top surface of the third gate electrode.

In the above, it is preferable that a side surface of each of the first source electrode and the first drain electrode not facing the second gate electrode be substantially aligned with a side surface of the first semiconductor layer, and a side surface of each of the second source electrode and the second drain electrode not facing the third gate electrode be substantially aligned with a side surface of the second semiconductor layer.

Another embodiment of the present invention is a semiconductor device including a first transistor, a second transistor, a first insulator, a first conductor, a second conductor, and a third conductor. The first transistor includes a first gate electrode, a first gate insulator, a first semiconductor layer, a first source electrode, a first drain electrode, a second gate insulator, and a second gate electrode. The second transistor includes a second semiconductor layer, a second source electrode, a second drain electrode, a third gate insulator, and a third gate electrode. The first gate insulator is provided over the first gate electrode. The first semiconductor layer is provided over the first gate insulator to include a region overlapping the first gate electrode. The second gate insulator is provided over the first semiconductor layer. The second gate electrode is provided over the second gate insulator to include a region overlapping the first gate electrode. The first source electrode and the first drain electrode are provided over the first semiconductor layer so that the second gate electrode is positioned between the first source electrode and the first drain electrode in a planar view. The first insulator is provided over the second gate electrode. The second semiconductor layer is provided over the first insulator to include a region overlapping the first semiconductor layer. The third gate insulator is provided over the second semiconductor layer. The third gate electrode is provided over the third gate insulator to include a region overlapping the second gate electrode. The second source electrode and the second drain electrode are provided over the second semiconductor layer so that the third gate electrode is positioned between the second source electrode and the second drain electrode in the planar view. The first conductor is provided in contact with a side surface of the first semiconductor layer, a side surface of the first source electrode, a side surface of the second semiconductor layer, and a side surface of the second source electrode. The second conductor is provided in contact with the side surface of the first semiconductor layer, a side surface of the first drain electrode, the side surface of the second semiconductor layer, and a side surface of the second drain electrode. The third conductor is provided to include a region in contact with a top surface of the first gate electrode, a top surface of the second gate electrode, and a top surface of the third gate electrode.

Another embodiment of the present invention is a semiconductor device including a first transistor, a second transistor, a first insulator, a first conductor, and a second conductor. The first transistor includes a first gate electrode, a first gate insulator, a first semiconductor layer, a first source electrode, a first drain electrode, a second gate insulator, and a second gate electrode. The second transistor includes a second semiconductor layer, a second source electrode, a second drain electrode, a third gate insulator, and a third gate electrode. The first gate insulator is provided over the first gate electrode. The first semiconductor layer is provided over the first gate insulator to include a region overlapping the first gate electrode. The second gate insulator is provided over the first semiconductor layer. The second gate electrode is provided over the second gate insulator to include a region overlapping the first gate electrode, and includes a region in contact with a top surface of the first gate electrode through an opening provided in the first gate insulator and the second gate insulator. The first source electrode and the first drain electrode are provided over the first semiconductor layer so that the second gate electrode is positioned between the first source electrode and the first drain electrode in a planar view. The first insulator is provided over the second gate electrode. The second semiconductor layer is provided over the first insulator to include a region overlapping the first semiconductor layer. The third gate insulator is provided over the second semiconductor layer. The third gate electrode is provided over the third gate insulator to include a region overlapping the second gate electrode, and includes a region in contact with a top surface of the second gate electrode through an opening provided in the first insulator and the third gate insulator. The second source electrode and the second drain electrode are provided over the second semiconductor layer so that the third gate electrode is positioned between the second source electrode and the second drain electrode in the planar view. The first conductor is provided to penetrate the second source electrode and the second semiconductor layer and include a region in contact with the first source electrode. The second conductor is provided to penetrate the second drain electrode and the second semiconductor layer and include a region in contact with the first drain electrode.

In the above, it is preferable that an end portion of the second gate electrode and an end portion of the third gate electrode be substantially aligned with each other in the planar view.

Another embodiment of the present invention is a semiconductor device including a first conductor; a first insulator over the first conductor; a first oxide over the first insulator; a second insulator, a second conductor, and a third conductor over the first oxide; a fourth conductor over the second insulator; a third insulator over the second insulator and the fourth conductor; a second oxide over the third insulator; a fourth insulator, a fifth conductor, and a sixth conductor over the second oxide; a seventh conductor over the fourth insulator; an eighth conductor that penetrates the fifth conductor and the second oxide and is in contact with the second conductor; a ninth conductor that penetrates the sixth conductor and the second oxide and is in contact with the third conductor; and a tenth conductor in contact with a top surface of the first conductor, a top surface of the fourth conductor, and a top surface of the seventh conductor. The first conductor is overlapped by the fourth conductor with the first oxide therebetween. The fourth conductor is overlapped by the seventh conductor with the second oxide therebetween. The second conductor and the fifth conductor are electrically connected to each other. The third conductor and the sixth conductor are electrically connected to each other. The first conductor, the fourth conductor, and the seventh conductor are electrically connected to each other. The third insulator includes a region in contact with a top surface of the second insulator and the top surface of the fourth conductor.

In the above, it is preferable that an uppermost surface of the second insulator and the top surface of the fourth conductor be substantially level with each other, and an uppermost surface of the fourth insulator and the top surface of the seventh conductor be substantially level with each other.

In the above, it is preferable that a side surface of each of the second conductor and the third conductor not facing the fourth conductor be substantially aligned with a side surface of the first oxide, and a side surface of each of the fifth conductor and the sixth conductor not facing the seventh conductor be substantially aligned with a side surface of the second oxide.

### Effect of the Invention

One embodiment of the present invention can provide a semiconductor device that can be reduced in size or highly integrated. Another embodiment of the present invention can provide a semiconductor device that operates at high speed. Another embodiment of the present invention can provide a semiconductor device with favorable electrical characteristics. Another embodiment of the present invention can provide a semiconductor device with a small variation in electrical characteristics of transistors. Another embodiment of the present invention can provide a highly reliable semiconductor device. Another embodiment of the present invention can provide a semiconductor device with a high on-state current. Another embodiment of the present invention can provide a semiconductor device with low power consumption. Another embodiment of the present invention can provide a novel semiconductor device. Another embodiment of the present invention can provide a method for manufacturing a semiconductor device with high productivity. Another embodiment of the present invention can provide a method for manufacturing a novel semiconductor device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a semiconductor device. FIG. 1B is a cross-sectional view illustrating an example of the semiconductor device.

FIG. 2 is a cross-sectional view illustrating an example of a semiconductor device.

FIG. 3A and FIG. 3B are plan views illustrating examples of a semiconductor device.

FIG. 4A and FIG. 4B are cross-sectional views illustrating examples of a semiconductor device.

FIG. 5A and FIG. 5B are cross-sectional views illustrating examples of a semiconductor device.

FIG. 6 is a cross-sectional view illustrating an example of a semiconductor device.

FIG. 7 is a cross-sectional view illustrating an example of a semiconductor device.

FIG. 8A and FIG. 8B are cross-sectional views illustrating examples of a semiconductor device.

FIG. 9A and FIG. 9B are cross-sectional views illustrating examples of a semiconductor device.

FIG. 10A is a plan view illustrating an example of a semiconductor device. FIG. 10B is a cross-sectional view illustrating an example of the semiconductor device.

FIG. 11A and FIG. 11B are plan views illustrating examples of a semiconductor device.

FIG. 12 is a cross-sectional view illustrating an example of a semiconductor device.

FIG. 13A is a plan view illustrating an example of a semiconductor device. FIG. 13B is a cross-sectional view illustrating an example of the semiconductor device.

FIG. 14A is a plan view illustrating an example of a semiconductor device. FIG. 14B is a cross-sectional view illustrating an example of the semiconductor device.

FIG. 15 is a plan view illustrating an example of a semiconductor device.

FIG. 16 is a cross-sectional view illustrating an example of a semiconductor device.

FIG. 17 is a cross-sectional view illustrating an example of a semiconductor device.

FIG. 18 is a plan view illustrating an example of a semiconductor device.

FIG. 19 is a cross-sectional view illustrating an example of a semiconductor device.

FIG. 20 is a plan view illustrating an example of a semiconductor device.

FIG. 21 is a cross-sectional view illustrating an example of a semiconductor device.

FIG. 22 is a plan view illustrating an example of a semiconductor device.

FIG. 23 is a cross-sectional view illustrating an example of a semiconductor device.

FIG. 24 is a cross-sectional view illustrating an example of a semiconductor device.

FIG. 25 is a cross-sectional view illustrating an example of a semiconductor device.

FIG. 26 is a plan view illustrating an example of a semiconductor device.

FIG. 27 is a cross-sectional view illustrating an example of a semiconductor device.

FIG. 28A and FIG. 28B are cross-sectional views illustrating an example of a method for manufacturing a semiconductor device.

FIG. 29A and FIG. 29B are cross-sectional views illustrating an example of a method for manufacturing a semiconductor device.

FIG. 30A and FIG. 30B are cross-sectional views illustrating an example of a method for manufacturing a semiconductor device.

FIG. 31A and FIG. 31B are cross-sectional views illustrating an example of a method for manufacturing a semiconductor device.

FIG. 32A and FIG. 32B are cross-sectional views illustrating an example of a method for manufacturing a semiconductor device.

FIG. 33A and FIG. 33B are cross-sectional views illustrating an example of a method for manufacturing a semiconductor device.

FIG. 34A and FIG. 34B are cross-sectional views illustrating an example of a method for manufacturing a semiconductor device.

FIG. 35A and FIG. 35B are cross-sectional views illustrating an example of a method for manufacturing a semiconductor device.

FIG. 36A and FIG. 36B are cross-sectional views illustrating an example of a method for manufacturing a semiconductor device.

FIG. 37A and FIG. 37B are cross-sectional views illustrating an example of a method for manufacturing a semiconductor device.

FIG. 38A and FIG. 38B are cross-sectional views illustrating an example of a method for manufacturing a semiconductor device.

FIG. 39A and FIG. 39B are cross-sectional views illustrating an example of a method for manufacturing a semiconductor device.

FIG. 40A and FIG. 40B are cross-sectional views illustrating an example of a method for manufacturing a semiconductor device.

FIG. 41A and FIG. 41B are cross-sectional views illustrating an example of a method for manufacturing a semiconductor device.

FIG. 42A and FIG. 42B are cross-sectional views illustrating an example of a method for manufacturing a semiconductor device.

FIG. 43A and FIG. 43B are cross-sectional views illustrating an example of a method for manufacturing a semiconductor device.

FIG. 44A and FIG. 44B are cross-sectional views illustrating an example of a method for manufacturing a semiconductor device.

FIG. 45A and FIG. 45B are cross-sectional views illustrating an example of a method for manufacturing a semiconductor device.

FIG. 46A and FIG. 46B are cross-sectional views illustrating an example of a method for manufacturing a semiconductor device.

FIG. 47A and FIG. 47B are cross-sectional views illustrating an example of a method for manufacturing a semiconductor device.

FIG. 48A and FIG. 48B are cross-sectional views illustrating an example of a method for manufacturing a semiconductor device.

FIG. 49A and FIG. 49B are cross-sectional views illustrating an example of a method for manufacturing a semiconductor device.

FIG. 50A and FIG. 50B are cross-sectional views illustrating an example of a method for manufacturing a semiconductor device.

FIG. 51A and FIG. 51B are cross-sectional views illustrating an example of a method for manufacturing a semiconductor device.

FIG. 52A and FIG. 52B are cross-sectional views illustrating an example of a method for manufacturing a semiconductor device.

FIG. 53A and FIG. 53B are cross-sectional views illustrating an example of a method for manufacturing a semiconductor device.

FIG. 54A and FIG. 54B are cross-sectional views illustrating an example of a method for manufacturing a semiconductor device.

FIG. 55A and FIG. 55B are cross-sectional views illustrating an example of a method for manufacturing a semiconductor device.

FIG. 56A and FIG. 56B are cross-sectional views illustrating an example of a method for manufacturing a semiconductor device.

FIG. 57A to FIG. 57C are cross-sectional views illustrating an example of a method for manufacturing a semiconductor device.

FIG. 58A and FIG. 58B are cross-sectional views illustrating an example of a method for manufacturing a semiconductor device.

FIG. 59A and FIG. 59B are cross-sectional views illustrating an example of a method for manufacturing a semiconductor device.

FIG. 60A and FIG. 60B are cross-sectional views illustrating an example of a method for manufacturing a semiconductor device.

FIG. 61A and FIG. 61B are cross-sectional views illustrating an example of a method for manufacturing a semiconductor device.

FIG. 62A and FIG. 62B are cross-sectional views illustrating an example of a method for manufacturing a semiconductor device.

FIG. 63A and FIG. 63B are cross-sectional views illustrating an example of a method for manufacturing a semiconductor device.

FIG. 64A and FIG. 64B are cross-sectional views illustrating an example of a method for manufacturing a semiconductor device.

FIG. 65A and FIG. 65B are cross-sectional views illustrating an example of a method for manufacturing a semiconductor device.

FIG. 66A and FIG. 66B are cross-sectional views illustrating an example of a method for manufacturing a semiconductor device.

FIG. 67A and FIG. 67B are cross-sectional views illustrating an example of a method for manufacturing a semiconductor device.

FIG. 68A and FIG. 68B are cross-sectional views illustrating an example of a method for manufacturing a semiconductor device.

FIG. 69A and FIG. 69B are cross-sectional views illustrating an example of a method for manufacturing a semiconductor device.

FIG. 70A and FIG. 70B are cross-sectional views illustrating an example of a method for manufacturing a semiconductor device.

FIG. 71A and FIG. 71B are cross-sectional views illustrating an example of a method for manufacturing a semiconductor device.

FIG. 72A and FIG. 72B are cross-sectional views illustrating an example of a method for manufacturing a semiconductor device.

FIG. 73A and FIG. 73B are cross-sectional views illustrating an example of a method for manufacturing a semiconductor device.

FIG. 74A and FIG. 74B are cross-sectional views illustrating an example of a method for manufacturing a semiconductor device.

FIG. 75A and FIG. 75B are cross-sectional views illustrating an example of a method for manufacturing a semiconductor device.

FIG. 76A and FIG. 76B are cross-sectional views illustrating an example of a method for manufacturing a semiconductor device.

FIG. 77A and FIG. 77B are cross-sectional views illustrating an example of a method for manufacturing a semiconductor device.

FIG. 78A and FIG. 78B are cross-sectional views illustrating an example of a method for manufacturing a semiconductor device.

FIG. 79A and FIG. 79B are cross-sectional views illustrating an example of a method for manufacturing a semiconductor device.

FIG. 80A and FIG. 80B are cross-sectional views illustrating an example of a method for manufacturing a semiconductor device.

FIG. 81A and FIG. 81B are cross-sectional views illustrating an example of a method for manufacturing a semiconductor device.

FIG. 82A and FIG. 82B are cross-sectional views illustrating an example of a method for manufacturing a semiconductor device.

FIG. 83A and FIG. 83B are cross-sectional views illustrating an example of a method for manufacturing a semiconductor device.

FIG. 84A and FIG. 84B are cross-sectional views illustrating an example of a method for manufacturing a semiconductor device.

FIG. 85A and FIG. 85B are cross-sectional views illustrating an example of a method for manufacturing a semiconductor device.

FIG. 86A and FIG. 86B are cross-sectional views illustrating an example of a method for manufacturing a semiconductor device.

FIG. 87A and FIG. 87B are cross-sectional views illustrating an example of a method for manufacturing a semiconductor device.

FIG. 88A and FIG. 88B are cross-sectional views illustrating an example of a method for manufacturing a semiconductor device.

FIG. 89A and FIG. 89B are cross-sectional views illustrating an example of a method for manufacturing a semiconductor device.

FIG. 90A and FIG. 90B are cross-sectional views illustrating an example of a method for manufacturing a semiconductor device.

FIG. 91A and FIG. 91B are cross-sectional views illustrating an example of a method for manufacturing a semiconductor device.

FIG. 92A and FIG. 92B are cross-sectional views illustrating an example of a method for manufacturing a semiconductor device.

FIG. 93A and FIG. 93B are cross-sectional views illustrating an example of a method for manufacturing a semiconductor device.

FIG. 94A and FIG. 94B are cross-sectional views illustrating an example of a method for manufacturing a semiconductor device.

FIG. 95A and FIG. 95B are cross-sectional views illustrating an example of a method for manufacturing a semiconductor device.

FIG. 96A and FIG. 96B are cross-sectional views illustrating an example of a method for manufacturing a semiconductor device.

FIG. 97A and FIG. 97B are cross-sectional views illustrating an example of a method for manufacturing a semiconductor device.

FIG. 98A and FIG. 98B are cross-sectional views illustrating an example of a method for manufacturing a semiconductor device.

FIG. 99A and FIG. 99B are cross-sectional views illustrating an example of a method for manufacturing a semiconductor device.

FIG. 100A and FIG. 100B are cross-sectional views illustrating an example of a method for manufacturing a semiconductor device.

FIG. 101A and FIG. 101B are cross-sectional views illustrating an example of a method for manufacturing a semiconductor device.

FIG. 102A and FIG. 102B are cross-sectional views illustrating an example of a method for manufacturing a semiconductor device.

FIG. 103A and FIG. 103B are cross-sectional views illustrating an example of a method for manufacturing a semiconductor device.

FIG. 104A and FIG. 104B are cross-sectional views illustrating an example of a method for manufacturing a semiconductor device.

FIG. 105A and FIG. 105B are cross-sectional views illustrating an example of a method for manufacturing a semiconductor device.

FIG. 106A is a plan view illustrating an example of a semiconductor device. FIG. 106B is a cross-sectional view illustrating an example of the semiconductor device.

FIG. 107A is a cross-sectional view illustrating an example of a semiconductor device. FIG. 107B is a circuit diagram illustrating the semiconductor device.

FIG. 108A and FIG. 108B are diagrams illustrating an example of a semiconductor device.

FIG. 109A to FIG. 109J are diagrams illustrating examples of electronic appliances.

FIG. 110A to FIG. 110E are diagrams illustrating examples of electronic appliances.

FIG. 111A to FIG. 111C are diagrams illustrating an example of an electronic appliance.

FIG. 112 is a diagram illustrating an example of space equipment.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or claims.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”. The term “conductor” can be interchanged with the term “conductive layer” or the term “conductive film” depending on the case or the circumstances. The term “insulator” can be interchanged with the term “insulating layer” or the term “insulating film” depending on the case or the circumstances.

The term “opening” includes a groove and a slit, for example. A region where an opening is formed is referred to as an opening portion in some cases.

In the drawings used in embodiments, a sidewall of an insulator in an opening portion in the insulator is illustrated as being substantially perpendicular to a substrate surface or a formation surface, but the sidewall may have a tapered shape. Note that in this specification and the like, “perpendicular” indicates a state where two straight lines are placed at an angle greater than or equal to 80° and less than or equal to 100°. Thus, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a tapered shape refers to such a shape that at least part of a side surface of a component is inclined with respect to a substrate surface or a formation surface. For example, the tapered shape refers to a shape where the angle formed by the inclined side surface and the substrate surface or the formation surface (hereinafter, such an angle is also referred to as a taper angle in some cases) is less than 90°. Note that the side surface of the component and the substrate surface are not necessarily completely flat and may be substantially flat with a slight curvature or substantially flat with slight unevenness.

In this specification and the like, the term “island shape” refers to a state where two or more layers formed using the same material in the same step are physically separated from each other.

In this specification and the like, the expression “substantially level” indicates a structure in which levels from a reference surface (e.g., a flat surface such as a substrate surface) are substantially the same in a cross-sectional view. In this specification and the like, the expression “substantially aligned”includes both “perfectly aligned”and “substantially aligned”.

In this specification and the like, the term “source” refers to part or the whole of a source region, a source electrode, and a source wiring. A source region refers to a region with resistivity lower than or equal to a given value in a semiconductor layer. A source electrode refers to a conductive layer including a portion connected to a source region. A source wiring refers to a wiring for electrically connecting a source electrode of at least one transistor to another electrode or another wiring.

In this specification and the like, the term “drain” refers to part or the whole of a drain region, a drain electrode, and a drain wiring. A drain region refers to a region with resistivity lower than or equal to a given value in a semiconductor layer. A drain electrode refers to a conductive layer including a portion connected to a drain region. A drain wiring refers to a wiring for electrically connecting a drain electrode of at least one transistor to another electrode or another wiring.

### Embodiment 1

One embodiment of the present invention is a semiconductor device that includes a transistor. A transistor according to one embodiment of the present invention includes n (n is an integer greater than or equal to 2) island-shaped semiconductor layers in each of which a channel is formed. That is, the n semiconductor layers each function as the channel of the transistor. The n semiconductor layers are provided to be stacked. Note that the semiconductor layer in a first layer is referred to as a first semiconductor layer, and the semiconductor layer in a second layer is referred to as a second semiconductor layer. The semiconductor layer in an i-th layer (i is an integer greater than or equal to 1 and less than or equal to n) is referred to as an i-th semiconductor layer, and the semiconductor layer in an n-th layer is referred to as an n-th semiconductor layer.

Each of the n semiconductor layers includes a source and a drain. In the n semiconductor layers, the sources are electrically connected to each other, and the drains are electrically connected to each other.

A first conductor is provided below the first semiconductor layer. The first conductor includes a region overlapped by the first semiconductor layer. A second conductor is provided above the first semiconductor layer and below the second semiconductor layer. The second conductor includes a region that overlaps the first semiconductor layer and is overlapped by the second semiconductor layer. In other words, the second semiconductor layer includes a region overlapping the first semiconductor layer with the second conductor therebetween. The second conductor includes a region overlapping the first conductor with the first semiconductor layer therebetween and a region overlapping the first conductor without the first semiconductor layer therebetween. An i+1-th conductor is provided above the i-th semiconductor layer and below the i+1-th semiconductor layer. The i+1-th conductor includes a region that overlaps the i-th semiconductor layer and is overlapped by the i+1-th semiconductor layer. In other words, the i+1-th semiconductor layer includes a region overlapping the i-th semiconductor layer with the i+1-th conductor therebetween. The i+1-th conductor includes a region overlapping the i-th conductor with the i-th semiconductor layer therebetween and a region overlapping the i-th conductor without the i-th semiconductor layer therebetween. An n+1-th conductor is provided above the n-th semiconductor layer. The n+1-th conductor includes a region overlapping the n-th semiconductor layer. The first to n+1-th conductors are electrically connected to each other. The first to n+1-th conductors each function as a gate electrode of the transistor.

That is, the transistor according to one embodiment of the present invention includes the n semiconductor layers and the (n+1) conductors. The conductors functioning as gate electrodes are provided above and below each semiconductor layer, whereby the channel width of the transistor can be increased and the on-state current of the transistor can be increased. Furthermore, stacking the n semiconductor layers can achieve a transistor having a high on-state current without an increase in the area occupied in a substrate plane. That is, the transistor can have a small size and a high degree of integration and also have a high on-state current.

Note that each of the semiconductor layers includes a channel, a source, and a drain. The conductors functioning as the gate electrodes are provided above and below each semiconductor layer. That is, a transistor can be regarded as being formed for each of the semiconductor layers. Accordingly, the semiconductor device of one embodiment of the present invention, which includes the n semiconductor layers, is regarded as being composed of n transistors. The n transistors are provided to be stacked. In the n transistors, the sources are electrically connected to each other, the drains are electrically connected to each other, and the gate electrodes are electrically connected to each other. That is, the semiconductor device of one embodiment of the present invention is composed of the n transistors that are stacked and connected in parallel. With this structure, the semiconductor device can have a high on-state current without an increase in the area occupied in the substrate plane. That is, the semiconductor device can have a small size and a high degree of integration and also have a high on-state current.

An example of a means for increasing the on-state current of a semiconductor device is a method in which the number of transistors included in the semiconductor device is increased and the transistors are connected in parallel to enhance the current generating capability of the semiconductor device as a whole. For example, by parallel-connecting m (m is an integer greater than or equal to 1) transistors that have the same size and are formed using the same material (all of which have the same current generating capability per transistor), the semiconductor device as a whole can output an on-state current m times as high as that in the case of one transistor.

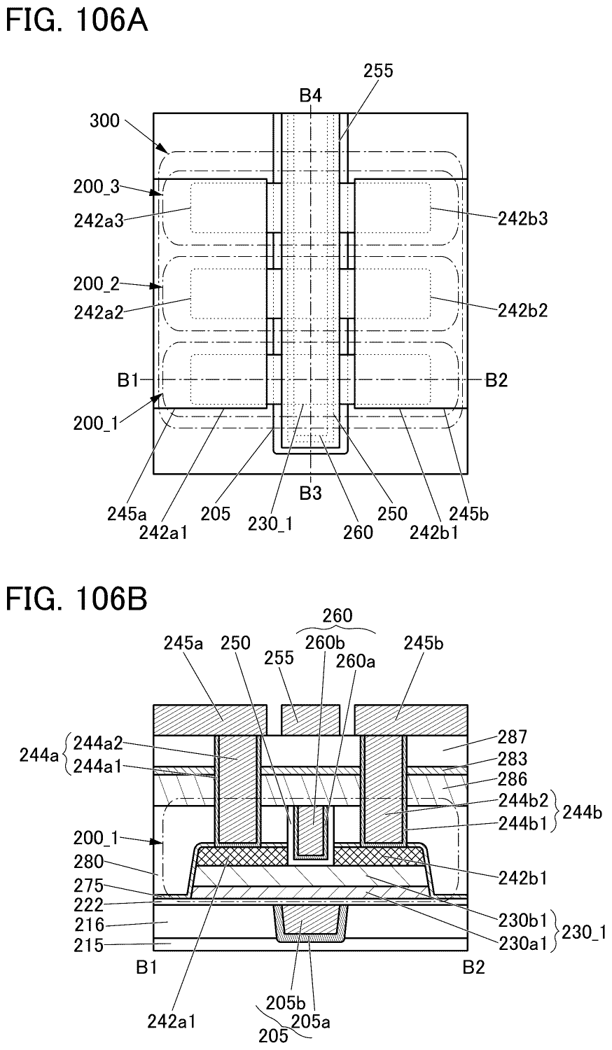

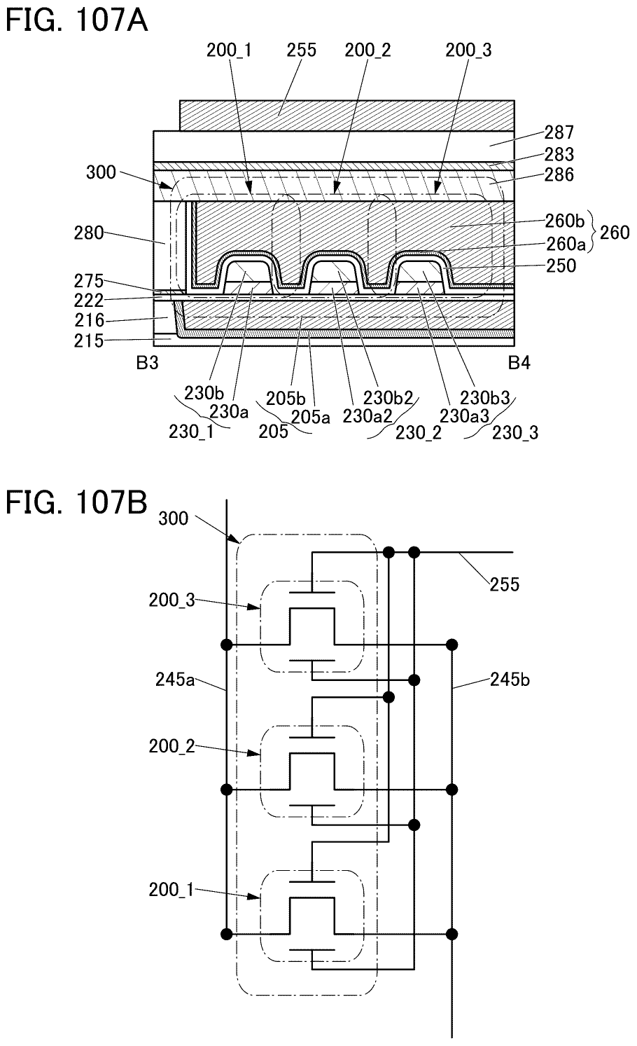

FIG. 106A to FIG. 107B illustrate a structure example of a semiconductor device 300 in which three transistors that have the same size and are formed using the same material are connected in parallel. FIG. 106A is a plan view of the semiconductor device 300. FIG. 106B is a cross-sectional view of the semiconductor device 300 along the dashed-dotted line B1-B2 in FIG. 106A. FIG. 107A is a cross-sectional view of the semiconductor device 300 along the dashed-dotted line B3-B4 in FIG. 106A. FIG. 107B is a circuit diagram illustrating the structure of the semiconductor device 300. Note that in this specification and the like, a plan view refers to a diagram showing an object in a planar view.

As illustrated in FIG. 106A, FIG. 107A, and FIG. 107B, the semiconductor device 300 includes a transistor 200_1, a transistor 200_2, and a transistor 200_3. As illustrated in FIG. 106A, the transistor 200_1, the transistor 200_2, and the transistor 200_3 are provided to be adjacent to each other along the dashed-dotted line B3-B4. The transistor 200_1, the transistor 200_2, and the transistor 200_3 have the same channel length, the same channel width, and the same current generating capability.

As illustrated in FIG. 106B, the transistor 200_1 is provided to include a region overlapping a conductor 205 (a conductor 205a and a conductor 205b) with an insulator 222 therebetween.

The conductor 205 is provided to be embedded in an insulator 215 over a substrate (not illustrated) and an insulator 216 over the insulator 215. The conductor 205 includes the conductor 205a and the conductor 205b over the conductor 205a. An opening reaching the insulator 215 is provided in the insulator 216, and the conductor 205a is provided in contact with a side surface of the insulator 216 and the top surface of the insulator 215 in the opening. The conductor 205b is provided over the conductor 205a to fill the opening.

The conductor 205a is formed using a conductive material having a function of inhibiting diffusion of oxygen. The conductor 205b is formed using a material having higher conductivity than that for the conductor 205a.

The uppermost surface of the conductor 205a (the surface in contact with the insulator 222), the top surface of the conductor 205b, and the top surface of the insulator 216 are substantially level with each other. The insulator 222 is provided in contact with the uppermost surface of the conductor 205a, the top surface of the conductor 205b, and the top surface of the insulator 216.

The transistor 200_1 includes an oxide 230_1 (an oxide 230a1 and an oxide 230b1), a conductor 242a1, a conductor 242b1, an insulator 250, and a conductor 260 (a conductor 260a and a conductor 260b).

In the transistor 200_1, the oxide 230_1 functions as a semiconductor layer where a channel is formed. The conductor 242a1 functions as one of a source electrode and a drain electrode. The conductor 242b1 functions as the other of the source electrode and the drain electrode. The insulator 250 functions as a first gate insulator. The conductor 260 functions as a first gate electrode (also referred to as a top gate electrode). Thus, FIG. 106B can also be regarded as a cross-sectional view of the transistor 200_1 in the channel length direction. FIG. 107A can also be regarded as a cross-sectional view of the transistor 200_1 in the channel width direction.

Note that the conductor 205 can function as a second gate electrode (also referred to as a bottom gate electrode or a back gate electrode) of the transistor 200_1. In this case, the insulator 222 functions as a second gate insulator of the transistor 200_1. For example, in the case where the conductor 260 and the conductor 205 that are provided to sandwich the oxide 230_1 from above and below are electrically connected to each other, a gate electric field can be applied from above and below the oxide 230_1. At this time, when the insulator 250 and the insulator 222 have substantially the same thickness, a gate electric field with uniform intensity can be applied from above and below the oxide 230.

Here, as illustrated in FIG. 106A and FIG. 107A, the conductor 205 is provided to extend in the channel width direction of the transistor 200_1, the transistor 200_2, and the transistor 200_3. Thus, the conductor 205 can function not only as the second gate electrode of the transistor 200_1 but also as second gate electrodes of the transistor 200_2 and the transistor 200_3. Similarly, the insulator 222 is provided in a plane shape across the transistor 200_1, the transistor 200_2, and the transistor 200_3. Thus, the insulator 222 can function not only as the second gate insulator of the transistor 200_1 but also as second gate insulators of the transistor 200_2 and the transistor 200_3.

The oxide 230_1 includes the oxide 230a1 and the oxide 230b1 over the oxide 230a1. The oxide 230_1 is provided in an island shape over the insulator 222 to include a region overlapping the conductor 205.

The conductor 260 is provided over the oxide 230b1 with the insulator 250 therebetween. The conductor 260 includes a region overlapping the conductor 205 with the oxide 230_1 therebetween. The conductor 260 includes the conductor 260a and the conductor 260b over the conductor 260a. The conductor 260a is formed using a conductive material having a function of inhibiting diffusion of oxygen. The conductor 260b is formed using a material having higher conductivity than that for the conductor 260a.

Over the oxide 230b1, the conductor 242a1 and the conductor 242b1 are provided such that the insulator 250 and the conductor 260 are positioned therebetween in a planar view. As illustrated in FIG. 106B, side surfaces of the conductor 242a1 and the conductor 242b1 that do not face the conductor 260 are formed to be substantially aligned with side surfaces of the oxide 230a1 and the oxide 230b1.

An insulator 275 is provided in contact with the top surface of the conductor 242a1; the top surface of the conductor 242b1; the side surfaces of the oxide 230a1, the oxide 230b1, and the conductor 242a1 that are formed to be substantially aligned with each other; the side surfaces of the oxide 230a1, the oxide 230b1, and the conductor 242b1 that are formed to be substantially aligned with each other; and the top surface of the insulator 222. The insulator 275 has a function of inhibiting diffusion of impurities into the oxide 230_1 from above the transistor 200_1.

An insulator 280 is provided over the transistor 200_1 and the insulator 275. The top surface of the insulator 280 is planarized. An opening is formed in the insulator 280 and the insulator 275 in a region overlapping the conductor 205, and the insulator 250 is provided in contact with a side surface of the insulator 280, a side surface of the insulator 275, a side surface of the conductor 242a1, a side surface of the conductor 242b1, and the top surface of the oxide 230b1 in the opening. The conductor 260a is provided over the insulator 250, and the conductor 260b is provided over the conductor 260a to fill the opening.

As illustrated in FIG. 106A and FIG. 107A, the insulator 250 and the conductor 260 are provided to cover side surfaces and the top surfaces of the oxides (the oxide 230_1 to an oxide 230_3) included in the transistor 200_1 to the transistor 200_3 in the channel width direction of the transistor 200_1 to the transistor 200_3. Thus, the insulator 250 can function not only as the first gate insulator of the transistor 200_1 but also as first gate insulators of the transistor 200_2 and the transistor 200_3. Similarly, the conductor 260 can function not only as the first gate electrode of the transistor 200_1 but also as first gate electrodes of the transistor 200_2 and the transistor 200_3.

The conductor 205 is provided below the transistor 200_1 to the transistor 200_3 with the insulator 222 therebetween in the channel width direction of the transistor 200_1 to the transistor 200_3. Thus, the oxides (the oxide 230_1 to the oxide 230_3) included in the transistor 200_1 to the transistor 200_3 can be surrounded by the electric field from the conductor 260 and the electric field from the conductor 205.

The uppermost surface of the insulator 250 (the surface in contact with an insulator 286), the uppermost surface of the conductor 260a (the surface in contact with the insulator 286), the top surface of the conductor 260b, and the top surface of the insulator 280 are substantially level with each other. The insulator 286 is provided in contact with the uppermost surface of the insulator 250, the uppermost surface of the conductor 260a, the top surface of the conductor 260b, and the top surface of the insulator 280. In the case where the insulator 286 contains a large amount of oxygen, oxygen contained in the insulator 286 can be supplied to the insulator 280 during the deposition of the insulator 286 or in later heat treatment, for example.

An insulator 283 is provided over the insulator 286, and an insulator 287 is provided over the insulator 283. The insulator 283 has a function of inhibiting diffusion of impurities into the transistor 200_1 from above the insulator 286. Note that in the case where the insulator 215 has a function similar to that of the insulator 283, both the top and bottom of the transistor 200_1 can be covered with the insulators having a function of inhibiting diffusion of impurities. The top surface of the insulator 287 has planarity.

An opening reaching the conductor 242a1 is provided in the insulator 287, the insulator 283, the insulator 286, the insulator 280, and the insulator 275, and a conductor 244a (a conductor 244a1 and a conductor 244a2) is provided in the opening. The conductor 244a includes the conductor 244a1 and the conductor 244a2 over the conductor 244a1. The conductor 244a1 is provided in contact with the sidewall of the opening and the top surface of the conductor 242a1, and the conductor 244a2 is provided to fill the opening.

An opening reaching the conductor 242b1 is provided in the insulator 287, the insulator 283, the insulator 286, the insulator 280, and the insulator 275, and a conductor 244b (a conductor 244b1 and a conductor 244b2) is provided in the opening. The conductor 244b includes the conductor 244b1 and the conductor 244b2 over the conductor 244b1. The conductor 244b1 is provided in contact with the sidewall of the opening and the top surface of the conductor 242b1, and the conductor 244b2 is provided to fill the opening.

The conductor 244a1 and the conductor 244b1 are formed using a conductive material having a function of inhibiting diffusion of oxygen. The conductor 244a2 is formed using a material having higher conductivity than that for the conductor 244a1. The conductor 244b2 is formed using a material having higher conductivity than that for the conductor 244b1.

The uppermost surface of the conductor 244a1 (the surface in contact with a conductor 245a), the top surface of the conductor 244a2, the uppermost surface of the conductor 244b1 (the surface in contact with a conductor 245b), the top surface of the conductor 244b2, and the top surface of the insulator 287 are substantially level with each other. The conductor 245a is provided in contact with the uppermost surface of the conductor 244a1, the top surface of the conductor 244a2, and the top surface of the insulator 287. The conductor 245b is provided in contact with the uppermost surface of the conductor 244b1, the top surface of the conductor 244b2, and the top surface of the insulator 287. The conductor 245a and the conductor 245b each function as a wiring. The conductor 244a functions as a plug that connects the conductor 242a1 and the conductor 245a. The conductor 244b functions as a plug that connects the conductor 242b1 and the conductor 245b.

Between the conductor 245a and the conductor 245b, a conductor 255 is provided in contact with the top surface of the insulator 287. The conductor 255 is provided to include a region overlapping the conductor 205 and the conductor 260. As illustrated in FIG. 106A and FIG. 107A, the conductor 255 is provided to extend in the channel width direction of the transistor 200_1, the transistor 200_2, and the transistor 200_3. Although not illustrated in FIG. 106A and FIG. 107A, the conductor 205 extending to the B4 side, the conductor 260, and the conductor 255 are electrically connected to each other. Thus, the conductor 255 functions as a wiring connected to the conductor 260 serving as the first gate electrode and the conductor 205 serving as the second gate electrode.

The above components have mainly been described for the transistor 200_1 illustrated in FIG. 106B; similar description can be applied to the transistor 200_2 and the transistor 200_3 by changing the number at the end of the reference numerals (the number after “_”).

FIG. 107B is a circuit diagram illustrating the connection relation between the transistor 200_1 to the transistor 200_3 included in the semiconductor device 300 illustrated in FIG. 106A to FIG. 107A. As illustrated in FIG. 107B, either the sources or the drains of the transistor 200_1 to the transistor 200_3 are electrically connected to each other through the conductor 245a. The others of the sources and the drains of the transistor 200_1 to the transistor 200_3 are electrically connected to each other through the conductor 245b. The gates of the transistor 200_1 to the transistor 200_3 are electrically connected to each other. That is, the transistor 200_1 to the transistor 200_3 are connected in parallel.

With the transistor 200_1 to the transistor 200_3 connected in parallel, the semiconductor device 300 (when the transistor 200_1 to the transistor 200_3 have the same current generating capability) can output an on-state current three times as high as that in the case of including only one transistor.

However, in the structure illustrated in FIG. 106A to FIG. 107B, the transistor 200_1 to the transistor 200_3 are placed adjacent to each other over one substrate. Therefore, although the structure illustrated in FIG. 106A to FIG. 107B is effective as a semiconductor device structure for obtaining a high on-state current, there is still room for improvement in the structure in order to achieve a minute semiconductor device with a high degree of integration.

An example of a disclosed structure of a semiconductor device that obtains a high on-state current without increasing the area occupied in the substrate plane is the above-described GAA nanosheet structure (see Non-Patent Document 1). However, silicon is assumed to be used for the semiconductor layer where the channel of the transistor is formed; thus, it is difficult to use the oxide of one embodiment of the present invention, for example, instead of silicon for the structure in terms of the manufacturing method or the like.

In view of these problems, in the semiconductor device of one embodiment of the present invention, a plurality of transistors are not placed adjacent to each other over one substrate but overlap each other to have a stacked-layer structure with layers corresponding to the number of transistors. With this structure, the semiconductor device of one embodiment of the present invention can output a high on-state current without an increase in the area occupied in the substrate plane. Moreover, the range of choices for materials that can be used for the semiconductor layer where the channel of the transistor is formed can be widened.

Structure examples of the semiconductor device of one embodiment of the present invention will be described below with reference to drawings. Note that the description of portions overlapping the foregoing description is omitted below in some cases.

### Structure Example 1 of Semiconductor Device

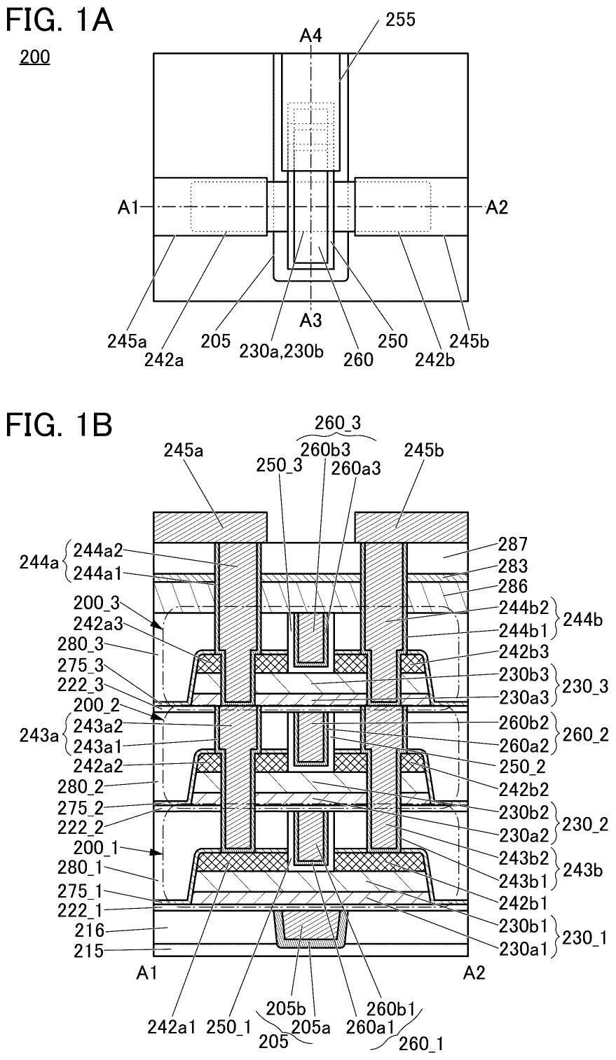

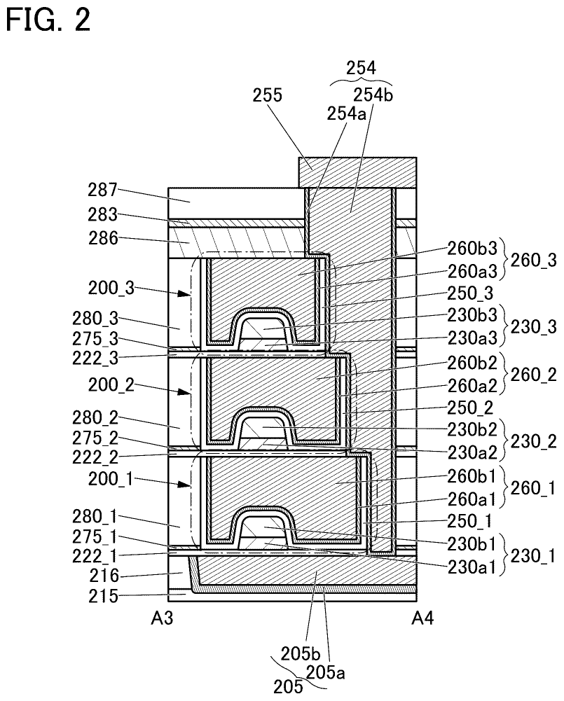

FIG. 1A, FIG. 1B, and FIG. 2 illustrate a structure example of a semiconductor device 200 of one embodiment of the present invention. FIG. 1A is a plan view of the semiconductor device 200. FIG. 1B is a cross-sectional view of the semiconductor device 200 along the dashed-dotted line A1-A2 in FIG. 1A. FIG. 2 is a cross-sectional view of the semiconductor device 200 along the dashed-dotted line A3-A4 in FIG. 1A.

The semiconductor device 200 of one embodiment of the present invention includes the conductor 205 (the conductor 205a and the conductor 205b), the transistor 200_1, the transistor 200_2, the transistor 200_3, a conductor 243a (a conductor 243a1 and a conductor 243a2), the conductor 244a (the conductor 244a1 and the conductor 244a2), a conductor 243b (a conductor 243b1 and a conductor 243b2), the conductor 244b (the conductor 244b1 and the conductor 244b2), and a conductor 254 (a conductor 254a and a conductor 254b). Although FIG. 1B and FIG. 2 illustrate the structure in which the semiconductor device 200 includes three transistors, one embodiment of the present invention is not limited thereto. The semiconductor device 200 includes at least two transistors. Accordingly, the semiconductor device 200 may include two transistors or four or more transistors.

The transistor 200_1 is provided over an insulator 222_1 to include a region overlapping the conductor 205.

The transistor 200_2 is stacked over the transistor 200_1 to overlap the transistor 200_1.

The transistor 200_3 is stacked over the transistor 200_2 to overlap the transistor 200_2.

Thus, FIG. 1B can also be regarded as a cross-sectional view of the transistor 200_1, the transistor 200_2, and the transistor 200_3 in the channel length direction. FIG. 2 can also be regarded as a cross-sectional view of the transistor 200_1, the transistor 200_2, and the transistor 200_3 in the channel width direction.

Although some portions overlap the description referring to FIG. 106A to FIG. 107A, the structures of the transistor 200_1 to the transistor 200_3 included in the semiconductor device 200 of one embodiment of the present invention will be described below.

As illustrated in FIG. 1B, the transistor 200_1 is provided to include a region overlapping the conductor 205 (the conductor 205a and the conductor 205b) with the insulator 222_1 therebetween.

The conductor 205 is provided to be embedded in the insulator 215 over a substrate (not illustrated) and the insulator 216 over the insulator 215. The conductor 205 includes the conductor 205a and the conductor 205b over the conductor 205a. An opening reaching the insulator 215 is provided in the insulator 216, and the conductor 205a is provided in contact with a side surface of the insulator 216 and the top surface of the insulator 215 in the opening. The conductor 205b is provided over the conductor 205a to fill the opening.

The conductor 205a is preferably formed using a conductive material having a function of inhibiting diffusion of oxygen. The use of such a conductive material can inhibit a reduction in conductivity of the conductor 205b due to oxidation. The conductor 205b is preferably formed using a material having higher conductivity than that for the conductor 205a.

The uppermost surface of the conductor 205a (the surface in contact with the insulator 222_1), the top surface of the conductor 205b, and the top surface of the insulator 216 are substantially level with each other. The insulator 222_1 is provided in contact with the uppermost surface of the conductor 205a, the top surface of the conductor 205b, and the top surface of the insulator 216.

The transistor 200_1 includes the oxide 230_1 (the oxide 230a1 and the oxide 230b1), the conductor 242a1, the conductor 242b1, an insulator 250_1, and a conductor 260_1 (a conductor 260a1 and a conductor 260b1).

In the transistor 200_1, the oxide 230_1 functions as the semiconductor layer where the channel is formed. The conductor 242a1 functions as one of the source electrode and the drain electrode. The conductor 242b1 functions as the other of the source electrode and the drain electrode. The insulator 250_1 functions as the first gate insulator. The conductor 260_1 functions as the first gate electrode.

Note that the conductor 205 can function as the second gate electrode of the transistor 200_1. In this case, the insulator 222_1 functions as the second gate insulator of the transistor 200_1.

In the semiconductor device 200 of one embodiment of the present invention, the conductor 260_1 and the conductor 205 are electrically connected to each other through the conductor 254 as illustrated in FIG. 2. Thus, a gate electric field can be applied from above and below the oxide 230_1. Here, the thickness of the insulator 222_1 is preferably substantially equal to the thickness of the insulator 250_1. In that case, a gate electric field with uniform intensity can be applied from above and below the oxide 230_1.

The oxide 230_1 includes the oxide 230a1 and the oxide 230b1 over the oxide 230a1. The oxide 230_1 is provided in an island shape over the insulator 222_1 to include a region overlapping the conductor 205.

The conductor 260_1 is provided over the oxide 230b1 with the insulator 250_1 therebetween. The conductor 260_1 includes a region overlapping the conductor 205 with the oxide 230_1 therebetween. The conductor 260_1 includes the conductor 260a1 and the conductor 260b1 over the conductor 260a1. The conductor 260a1 is preferably formed using a conductive material having a function of inhibiting diffusion of oxygen. The use of such a conductive material can inhibit a reduction in conductivity of the conductor 260b1 due to oxidation. The conductor 260b1 is preferably formed using a material having higher conductivity than that for the conductor 260a1.

Over the oxide 230b1, the conductor 242a1 and the conductor 242b1 are provided such that the insulator 250_1 and the conductor 260_1 are positioned therebetween in a planar view. As illustrated in FIG. 1B, side surfaces of the conductor 242a1 and the conductor 242b1 that do not face the conductor 260_1 are formed to be substantially aligned with side surfaces of the oxide 230a1 and the oxide 230b1.

Although side surfaces of the oxide 230a1, the oxide 230b1, and the conductor 242a1 that are formed to be substantially aligned with each other and side surfaces of the oxide 230a1, the oxide 230b1, and the conductor 242b1 that are formed to be substantially aligned with each other are tapered in FIG. 1B and the like, one embodiment of the present invention is not limited thereto. The side surfaces may be formed substantially perpendicular to the substrate surface. In the case where the side surfaces are tapered, coverage of the side surfaces with a layer formed over the transistor 200_1 can be improved. Meanwhile, in the case where the side surfaces are formed substantially perpendicular to the substrate surface, the size of the transistor 200_1 can be further reduced.

An insulator 275_1 is provided in contact with the top surface of the conductor 242a1; the top surface of the conductor 242b1; the side surfaces of the oxide 230a1, the oxide 230b1, and the conductor 242a1 that are formed to be substantially aligned with each other; the side surfaces of the oxide 230a1, the oxide 230b1, and the conductor 242b1 that are formed to be substantially aligned with each other; and the top surface of the insulator 222_1. The insulator 275_1 has a function of inhibiting diffusion of impurities into the oxide 230_1 from above the transistor 200 1.

An insulator 280_1 is provided over the transistor 200_1 and the insulator 275_1. The top surface of the insulator 280_1 is preferably planarized. An opening is formed in the insulator 280_1 and the insulator 275_1 in a region overlapping the conductor 205, and the insulator 250_1 is provided in contact with a side surface of the insulator 280_1, a side surface of the insulator 275_1, a side surface of the conductor 242a1, a side surface of the conductor 242b1, and the top surface of the oxide 230b1 in the opening. The conductor 260a1 is provided over the insulator 250_1, and the conductor 260b1 is provided over the conductor 260a1 to fill the opening.

An insulator 222_2 is provided over the transistor 200_1 and the insulator 280_1. The uppermost surface of the insulator 250_1 (the surface in contact with the insulator 222_2), the uppermost surface of the conductor 260a1 (the surface in contact with the insulator 222_2), the top surface of the conductor 260b1, and the top surface of the insulator 280_1 are substantially level with each other.

The transistor 200_2 is provided over the transistor 200_1 with the insulator 222 2 therebetween. The transistor 200_2 includes an oxide 230_2 (an oxide 230a2 and an oxide 230b2), a conductor 242a2, a conductor 242b2, an insulator 250_2, and a conductor 260_2 (a conductor 260a2 and a conductor 260b2). An insulator 275_2 is provided to cover the transistor 200_2, and an insulator 280_2 is provided over the insulator 275_2. An insulator 222_3 is provided over the insulator 280_2 and the transistor 200_2.

The transistor 200_3 is provided over the transistor 200_2 with the insulator 222_3 therebetween. The transistor 200_3 includes an oxide 230_3 (an oxide 230a3 and an oxide 230b3), a conductor 242a3, a conductor 242b3, an insulator 250_3, and a conductor 260_3 (a conductor 260a3 and a conductor 260b3). An insulator 275_3 is provided to cover the transistor 200_3, and an insulator 280_3 is provided over the insulator 275_3.

As for the structures of the insulator 222_2, the transistor 200_2, the insulator 275_2, and the insulator 280_2 and the structures of the insulator 222_3, the transistor 200_3, the insulator 275_3, and the insulator 280_3, the description similar to that of the insulator 222_1, the transistor 200_1, the insulator 275_1, and the insulator 280_1 can be applied by changing the number at the end of the reference numerals (the number after “_”).

As illustrated in FIG. 2, in the semiconductor device 200 of one embodiment of the present invention, channel formation regions of the transistor 200_1 to the transistor 200_3 are surrounded by the respective first gate electrodes (the conductor 260_1 to the conductor 260_3). In this specification and the like, a transistor structure in which a channel formation region is electrically surrounded by at least the electric field of the first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect does not easily occur can be provided.

When the transistor 200_1 to the transistor 200_3 have the above-described S-channel structure, the channel formation regions can be electrically surrounded. Since the S-channel structure is a structure with the electrically surrounded channel formation region, the S-channel structure can be regarded as being substantially equivalent to the GAA structure or a LGAA (Lateral GAA) structure. When the transistor 200_1 to the transistor 200_3 have the S-channel structure, the GAA structure, or the LGAA structure, the channel formation regions that are formed at the interfaces between the oxide 230_1 to the oxide 230_3 and the gate insulators (the insulators 250 and the insulators 222) or in the vicinities of the interfaces can correspond to the entire bulks of the oxide 230_1 to the oxide 230_3. Accordingly, the density of current flowing through the transistors can be increased, which should increase the on-state current of the transistors or increase the field-effect mobility of the transistors.

In the semiconductor device 200 of one embodiment of the present invention, all the transistor 200_1 to the transistor 200_3 are provided to overlap each other in a planar view, as illustrated in FIG. 1A. Thus, the area occupied by the semiconductor device in the substrate plane can be significantly reduced. Moreover, the number of transistors can be increased while an increase in the occupied area is inhibited.

The semiconductor device 200 of one embodiment of the present invention is different from the above-described semiconductor device 300 in that the conductor 205 can function as the second gate electrode of only the transistor 200_1 as illustrated in FIG. 2.

Another difference is that, while the second gate insulator (the insulator 222) is shared by all the transistors in the semiconductor device 300, the transistors include the respective second gate insulators (the insulator 222_1 to the insulator 222_3) in the semiconductor device 200 of one embodiment of the present invention.

Another difference is that, while the first gate insulator (the insulator 250) is shared by all the transistors in the semiconductor device 300, the transistors include the respective first gate insulators (the insulator 250_1 to the insulator 250_3) in the semiconductor device 200 of one embodiment of the present invention.

Another difference is that, while the first gate electrode (the conductor 260) is shared by all the transistors in the semiconductor device 300, the transistors include the respective first gate electrodes (the conductor 260_1 to the conductor 260_3) in the semiconductor device 200 of one embodiment of the present invention.

Note that in this specification and the like, the lower oxides (the oxide 230a1 to the oxide 230a3) included in the transistor 200_1 to the transistor 200_3 may be collectively referred to as an oxide 230a. The upper oxides (the oxide 230b1 to the oxide 230b3) included in the transistor 200_1 to the transistor 200_3 may be collectively referred to as an oxide 230b. The oxide 230a and the oxide 230b may be collectively referred to as the oxide 230. Either the source electrodes or the drain electrodes (the conductor 242a1 to the conductor 242a3) included in the transistor 200_1 to the transistor 200_3 may be collectively referred to as a conductor 242a. The others of the source electrodes and the drain electrodes (the conductor 242b1 to the conductor 242b3) included in the transistor 200_1 to the transistor 200_3 may be collectively referred to as a conductor 242b. The first gate insulators (the insulator 250_1 to the insulator 250_3) included in the transistor 200_1 to the transistor 200_3 may be collectively referred to as the insulator 250. The gate electrodes (the conductor 260_1 to the conductor 260_3) included in the transistor 200_1 to the transistor 200_3 may be collectively referred to as the conductor 260.

In the semiconductor device 200, the transistor 200_1 to the transistor 200_3 that are stacked to overlap each other are connected in parallel. That is, as illustrated in FIG. 107B, the sources of the transistor 200_1 to the transistor 200_3 are electrically connected to each other. The drains of the transistor 200_1 to the transistor 200_3 are electrically connected to each other. The gates of the transistor 200_1 to the transistor 200_3 are electrically connected to each other.

As illustrated in FIG. 1B, in the semiconductor device 200 of one embodiment of the present invention, the conductor 242a1 functioning as the one of the source electrode and the drain electrode of the transistor 200_1 is electrically connected to the conductor 242a2 functioning as the one of the source electrode and the drain electrode of the transistor 200_2 through the conductor 243a (the conductor 243a1 and the conductor 243a2). The conductor 243a is provided to penetrate the conductor 242a2 and the oxide 230_2. The conductor 242b1 functioning as the other of the source electrode and the drain electrode of the transistor 200_1 is electrically connected to the conductor 242b2 functioning as the other of the source electrode and the drain electrode of the transistor 200_2 through the conductor 243b (the conductor 243b1 and the conductor 243b2). The conductor 243b is provided to penetrate the conductor 242b2 and the oxide 230_2.

The conductor 242a2 functioning as the one of the source electrode and the drain electrode of the transistor 200_2 is electrically connected to the conductor 242a3 functioning as the one of the source electrode and the drain electrode of the transistor 200_3 through the conductor 243a (the conductor 243a1 and the conductor 243a2) and the conductor 244a (the conductor 244a1 and the conductor 244a2). The conductor 244a is provided to penetrate the conductor 242a3 and the oxide 230_3. The conductor 242b2 functioning as the other of the source electrode and the drain electrode of the transistor 200_2 is electrically connected to the conductor 242b3 functioning as the other of the source electrode and the drain electrode of the transistor 200_3 through the conductor 243b (the conductor 243b1 and the conductor 243b2) and the conductor 244b (the conductor 244b1 and the conductor 244b2). The conductor 244b is provided to penetrate the conductor 242b3 and the oxide 230_3.

The conductor 243a has a function of a plug that electrically connects the one of the source electrode and the drain electrode (the conductor 242a1) of the transistor 200_1 and the one of the source electrode and the drain electrode (the conductor 242a2) of the transistor 200_2. The conductor 243b has a function of a plug that electrically connects the other of the source electrode and the drain electrode (the conductor 242b1) of the transistor 200_1 and the other of the source electrode and the drain electrode (the conductor 242b2) of the transistor 200_2.

The conductor 243a includes the conductor 243a1 and the conductor 243a2 over the conductor 243a1. The conductor 243b includes the conductor 243b1 and the conductor 243b2 over the conductor 243b1.

As described above, the insulator 275_1 is provided to cover the transistor 200_1, and the insulator 280_1 is provided over the insulator 275_1. The insulator 222_2 is provided over the insulator 280_1 and the transistor 200_1, and the transistor 200_2 is provided over the insulator 222_2.

The insulator 275_2 is provided to cover the transistor 200_2, and the insulator 280_2 is provided over the insulator 275_2. The top surface of the insulator 280_2, the uppermost surface of the insulator 250_2 (the surface in contact with the insulator 222_3), the uppermost surface of the conductor 260a2 (the surface in contact with the insulator 222_3), and the top surface of the conductor 260b2 are substantially level with each other. The insulator 222_3 is provided in contact with the top surface of the insulator 280_2, the uppermost surface of the insulator 250_2, the uppermost surface of the conductor 260a2, and the top surface of the conductor 260b2.

A first opening reaching the top surface of the conductor 242a1 is provided in the insulator 222_3, the insulator 280_2, the insulator 275_2, the conductor 242a2, the oxide 230_2, the insulator 222_2, the insulator 280_1, and the insulator 275_1. Similarly, a second opening reaching the top surface of the conductor 242b1 is provided in the insulator 222_3, the insulator 280_2, the insulator 275_2, the conductor 242b2, the oxide 230_2, the insulator 222_2, the insulator 280_1, and the insulator 275_1. The first opening and the second opening are preferably provided at the positions to be line-symmetric with respect to the conductor 260 in a planar view.

The conductor 243a1 is provided in contact with the sidewall of the first opening and the top surface of the conductor 242a1, and the conductor 243a2 is provided over the conductor 243a1 to fill the first opening. Similarly, the conductor 243b1 is provided in contact with the sidewall of the second opening and the top surface of the conductor 242b1, and the conductor 243b2 is provided over the conductor 243b1 to fill the second opening.

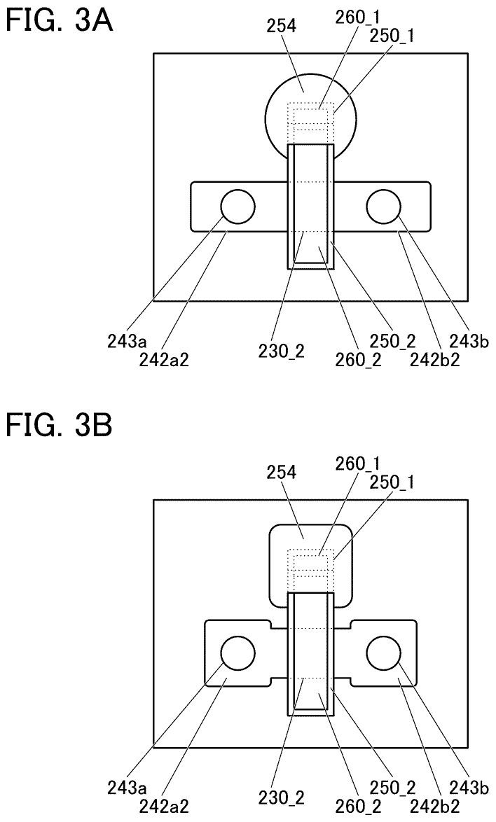

FIG. 3A is a plan view of the semiconductor device 200. FIG. 3A illustrates a region including the transistor 200_2 and its vicinity. For clarity of the drawing, some components are not illustrated in the plan view of FIG. 3A.

As illustrated in FIG. 3A, the conductor 243a is provided inside the opening formed in the conductor 242a2. The conductor 243b is provided inside the opening formed in the conductor 242b2. Although FIG. 3A illustrates the structure in which the top-view shapes of the opening formed in the conductor 242a2 and the opening formed in the conductor 242b2 are circular, one embodiment of the present invention is not limited thereto. For example, the top-view shapes of these openings may be an oval shape, a polygonal shape, or a polygonal shape with rounded corners.

Although the top-view shape of the conductor 242a2 is a quadrangular shape with rounded corners in FIG. 3A, one embodiment of the present invention is not limited thereto. The top-view shape of the conductor 242a2 may be, for example, a shape obtained by combining a plurality of polygons or a shape obtained by combining a plurality of polygons with rounded corners. For example, as illustrated in FIG. 3B, the length in the channel width direction of a region including the opening provided with the conductor 243a may be larger than the length in the channel width direction of a side surface of the conductor 242a2 that faces the conductor 260_2. With such a structure, the area of the conductor 242a2 in a planar view can be increased, lowering the required level of alignment accuracy for the opening. Thus, the degree of difficulty in forming a minute memory cell can be reduced. The same applies to the top-view shape of the conductor 242b2.

The conductor 243a1 and the conductor 243b1 are preferably formed using a conductive material having a function of inhibiting diffusion of oxygen. The use of such a conductive material can inhibit a reduction in conductivity of the conductor 243a2 and the conductor 243b2 due to oxidation. The conductor 243a2 is preferably formed using a material having higher conductivity than that for the conductor 243a1. The conductor 243b2 is preferably formed using a material having higher conductivity than that for the conductor 243b1.

The uppermost surface of the conductor 243a1 (the surface in contact with the oxide 230a3), the top surface of the conductor 243a2, the uppermost surface of the conductor 243b1 (the surface in contact with the oxide 230a3), the top surface of the conductor 243b2, and the top surface of the insulator 222_3 are substantially level with each other.

The conductor 244a has a function of a plug that electrically connects the conductor 243a and the one of the source electrode and the drain electrode (the conductor 242a3) of the transistor 200_3. The conductor 244b has a function of a plug that electrically connects the conductor 243b and the other of the source electrode and the drain electrode (the conductor 242b3) of the transistor 200_3.

The conductor 244a includes the conductor 244a1 and the conductor 244a2 over the conductor 244a1. The conductor 244b includes the conductor 244b1 and the conductor 244b2 over the conductor 244b1.

As described above, the transistor 200_3 is provided over the insulator 222_3. The insulator 275_3 is provided to cover the transistor 200_3, and the insulator 280_3 is provided over the insulator 275_3. The top surface of the insulator 280_3, the uppermost surface of the insulator 250_3 (the surface in contact with the insulator 286), the uppermost surface of the conductor 260a3 (the surface in contact with the insulator 286), and the top surface of the conductor 260b3 are substantially level with each other.

The insulator 286 is provided in contact with the top surface of the insulator 280_3, the uppermost surface of the insulator 250_3, the uppermost surface of the conductor 260a3, and the top surface of the conductor 260b3. The insulator 286 preferably contains a large amount of oxygen. Providing the insulator 286 allows oxygen contained in the insulator 286 to be supplied to the insulator 280_3 during the deposition of the insulator 286 or in later heat treatment, for example.

The insulator 283 is provided over the insulator 286, and the insulator 287 is provided over the insulator 283. The insulator 283 has a function of inhibiting diffusion of impurities into the transistor 200_1 to the transistor 200_3 from above the insulator 286. Note that the above-described insulator 215 preferably has a function similar to that of the insulator 283, in which case both the top and bottom of the transistor 200_1 to the transistor 200_3 can be covered with the insulators having a function of inhibiting diffusion of impurities. The top surface of the insulator 287 preferably has planarity.

A third opening reaching the top surface of the conductor 243a is provided in the insulator 287, the insulator 283, the insulator 286, the insulator 280_3, the insulator 275_3, the conductor 242a3, and the oxide 230_3. Similarly, a fourth opening reaching the top surface of the conductor 243b is provided in the insulator 287, the insulator 283, the insulator 286, the insulator 280_3, the insulator 275_3, the conductor 242b3, and the oxide 230_3.

The conductor 244a1 is provided in contact with the sidewall of the third opening and the top surface of the conductor 243a, and the conductor 244a2 is provided over the conductor 244a1 to fill the third opening. Similarly, the conductor 244b1 is provided in contact with the sidewall of the fourth opening and the top surface of the conductor 243b, and the conductor 244b2 is provided over the conductor 244b1 to fill the fourth opening.

As in the semiconductor device 300 described above, the conductor 244a1 and the conductor 244b1 in the semiconductor device 200 illustrated in FIG. 1A to FIG. 2 are preferably formed using a conductive material having a function of inhibiting diffusion of oxygen. The use of the conductive material can inhibit a reduction in conductivity of the conductor 244a2 and the conductor 244b2 due to oxidation. The conductor 244a2 is preferably formed using a material having higher conductivity than that for the conductor 244a1. The conductor 244b2 is preferably formed using a material having higher conductivity than that for the conductor 244b1.

The uppermost surface of the conductor 244a1 (the surface in contact with the conductor 245a), the top surface of the conductor 244a2, the uppermost surface of the conductor 244b1 (the surface in contact with the conductor 245b), the top surface of the conductor 244b2, and the top surface of the insulator 287 are substantially level with each other. The conductor 245a is provided in contact with the uppermost surface of the conductor 244a1, the top surface of the conductor 244a2, and the top surface of the insulator 287. The conductor 245b is provided in contact with the uppermost surface of the conductor 244b1, the top surface of the conductor 244b2, and the top surface of the insulator 287. The conductor 245a and the conductor 245b each function as a wiring.

The conductor 244a electrically connects the conductor 243a and the conductor 245a. The conductor 244b electrically connects the conductor 243b and the conductor 245b. Thus, it can be said that either the source electrodes or the drain electrodes (the conductor 242a1 to the conductor 242a3) of the transistor 200_1 to the transistor 200_3 are electrically connected to the conductor 245a functioning as a wiring through the conductor 243a and the conductor 244a functioning as plugs. It can be said that the others of the source electrodes and the drain electrodes (the conductor 242b1 to the conductor 242b3) of the transistor 200_1 to the transistor 200_3 are electrically connected to the conductor 245b functioning as a wiring through the conductor 243b and the conductor 244b functioning as plugs.

As illustrated in FIG. 2, the conductors functioning as the gate electrodes (the conductor 260_1 to the conductor 260_3) of the transistor 200_1 to the transistor 200_3 have different lengths in the channel width direction of the transistors (hereinafter also referred to as gate widths). Specifically, the gate width of the transistor 200_1 is the largest, the gate width of the transistor 200_2 is the second largest, and the gate width of the transistor 200_3 is the smallest. That is, among the plurality of transistors stacked in the semiconductor device 200, the gate width of the transistor positioned in the lowest layer is the largest, and the gate width of the transistor positioned in a higher layer is smaller.

End portions on the A3 side of the conductors functioning as the gate electrodes (the conductor 260_1 to the conductor 260_3) of the transistor 200_1 to the transistor 200_3 are substantially aligned with each other as illustrated in FIG. 1A and FIG. 2. Meanwhile, their end portions on the A4 side are not aligned among the transistor 200_1 to the transistor 200_3, and the end portion of the gate electrode of the transistor positioned in a lower layer is closer to the A4 side. That is, in the semiconductor device 200 of one embodiment of the present invention, the gate electrodes of the transistors are regarded as having a step-like shape in a cross-sectional view in the channel width direction of the transistors (see FIG. 2).

The height of the oxide 230 (denoted as H) is preferably greater than or equal to the channel width of the oxide 230 (which is the length in the A3-A4 direction and denoted as W). For example, the ratio of the height of the oxide 230 to the channel width of the oxide 230 (H/W) is preferably greater than or equal to 1, further preferably greater than or equal to 2, still further preferably greater than or equal to 5. With such a structure, the channel formation region can be enlarged without an increase in the area occupied by the transistor. Even in the case where the thickness of the insulator 250 is large, a region to which the gate electric field of the conductor 260 is applied can be enlarged. Accordingly, the on-state current or field-effect mobility of the transistor can be increased. Thus, the transistor can have improved electrical characteristics.

Although there is no particular limitation on the upper limit of H/W, H/W is preferably such that the oxide 230 does not collapse during the manufacturing process of the semiconductor device. For example, H/W is preferably less than or equal to 100, less than or equal to 50, less than or equal to 20, or less than or equal to 10. Thus, H/W is preferably greater than or equal to 1 and less than or equal to 100, greater than or equal to 1 and less than or equal to 50, greater than or equal to 2 and less than or equal to 50, greater than or equal to 2 and less than or equal to 20, or greater than or equal to 5 and less than or equal to 20.

As illustrated in FIG. 2, in the semiconductor device 200 of one embodiment of the present invention, the conductors functioning as the gate electrodes (the conductor 260_1 to the conductor 260_3) of the transistor 200_1 to the transistor 200_3 are electrically connected to each other through the conductor 254 (the conductor 254a and the conductor 254b). The conductor 254 is also electrically connected to the conductor 205. That is, the conductor 205 and the conductor 260 are electrically connected to each other. The conductor 254 includes the conductor 254a and the conductor 254b over the conductor 254a.

As illustrated in FIG. 2, in the semiconductor device 200 of one embodiment of the present invention, a fifth opening reaching the top surface of the conductor 205 is provided in the insulator 287, the insulator 283, the insulator 286, the insulator 280_3, the insulator 275_3, the insulator 222_3, the insulator 280_2, the insulator 275_2, the insulator 222_2, the insulator 280_1, the insulator 275_1, and the insulator 222_1.

The conductor 254a is provided in contact with the sidewall of the fifth opening and the top surface of the conductor 205, and the conductor 254b is provided over the conductor 254a to fill the fifth opening. The conductor 254a includes a region in contact with the top surface of the conductor 260_3, a region in contact with the top surface of the conductor 260_2, and a region in contact with the top surface of the conductor 260_1. The conductor 254a is preferably formed using a conductive material having a function of inhibiting diffusion of oxygen. The use of such a conductive material can inhibit a reduction in conductivity of the conductor 254b due to oxidation. The conductor 254b is preferably formed using a material having higher conductivity than that for the conductor 254a.

FIG. 3A illustrates a state where the conductor 254 is in contact with the top surface of the conductor 260_2 and the top surface of the conductor 260_1. Note that the top-view shape of the opening that is provided with the conductor 254 and formed in the insulator 287 may be a circular shape, an oval shape, a polygonal shape, or a polygonal shape with rounded corners. In FIG. 3A, the top-view shape of the opening is a circular shape with a notch. The conductor 260_3 and the insulator 250_3 are positioned above the notch, whereby the top-view shape of the opening is the shape illustrated in FIG. 3A. In FIG. 3B, the top-view shape of the opening is a polygonal shape with a notch and rounded corners.

The conductor 254 has a function of a plug that electrically connects the conductor 255 functioning as a wiring to the conductor 260_1 to the conductor 260_3 functioning as the gate electrodes (first gate electrodes) of the transistor 200_1 to the transistor 200_3 and the conductor 205 that can function as the second gate electrode of the transistor 200_1. In the transistor 200_3, the conductor 260_3 functions as the first gate electrode and the conductor 260_2 functions as the second gate electrode. In the transistor 200_2, the conductor 260_2 functions as the first gate electrode and the conductor 260_1 functions as the second gate electrode. In the transistor 200_1, the conductor 260_1 functions as the first gate electrode and the conductor 205 functions as the second gate electrode.

The uppermost surface of the conductor 254a (the surface in contact with the conductor 255), the top surface of the conductor 254b, and the top surface of the insulator 287 are substantially level with each other. The conductor 255 is provided in contact with the uppermost surface of the conductor 254a, the top surface of the conductor 254b, and the top surface of the insulator 287. The conductor 255 functions as a wiring.

With the above-described structure, the semiconductor device 200 of one embodiment of the present invention can output a high on-state current without an increase in the area occupied in the substrate plane.

In the semiconductor device 200 of one embodiment of the present invention, the oxide 230 (the oxide 230_1 to the oxide 230_3) preferably includes the oxide 230a (the oxide 230a1 to the oxide 230a3) and the oxide 230b (the oxide 230b1 to the oxide 230b3) over the oxide 230a. Including the oxide 230a under the oxide 230b makes it possible to inhibit diffusion of impurities into the oxide 230b from components formed below the oxide 230a.

Although an example in which the oxide 230 has a two-layer structure of the oxide 230a and the oxide 230b is described in this embodiment, one embodiment of the present invention is not limited thereto. The oxide 230 may have a single-layer structure of the oxide 230b or a stacked-layer structure of three or more layers, for example.

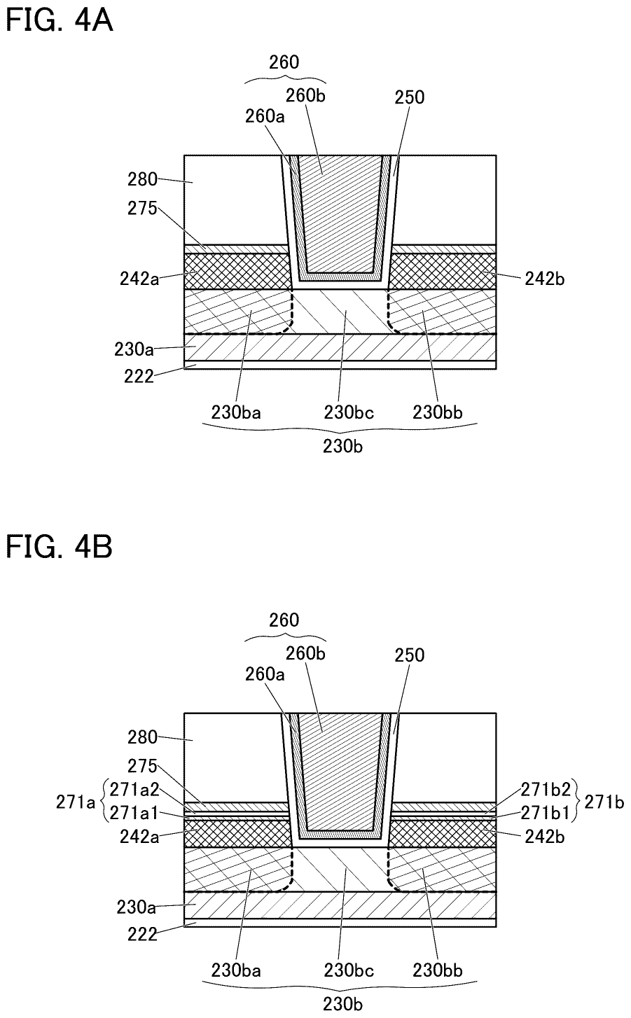

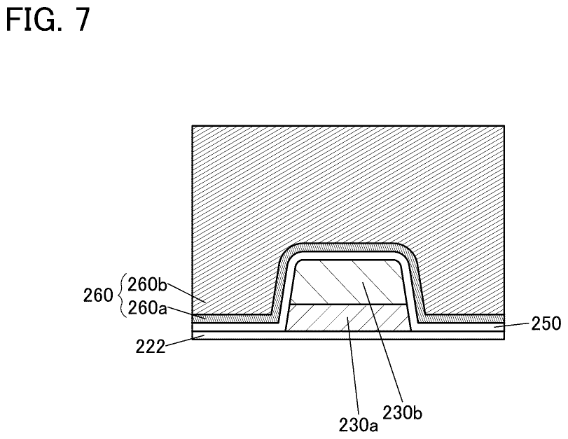

FIG. 4A is an enlarged cross-sectional view in the channel length direction of a transistor (the transistor 200_1 to the transistor 200_3) included in the semiconductor device 200 of one embodiment of the present invention, and FIG. 7 is an enlarged cross-sectional view in the channel width direction of the transistor.

FIG. 4A is different from FIG. 1B and the like in illustrating an example where the sidewall of an opening portion provided with the insulator 250 functioning as the gate insulator and the conductor 260 (the conductor 260a and the conductor 260b) functioning as the gate electrode of the transistor is tapered. Accordingly, the sidewall of the opening portion in the semiconductor device 200 of one embodiment of the present invention may be tapered or may be substantially perpendicular to the substrate surface. In the case where the sidewall of the opening portion is tapered, coverage with the insulator 250 and the conductor 260 provided in the opening portion can be improved. In the case where the sidewall of the opening portion is substantially perpendicular to the substrate surface, a further reduction in size of the transistor can be achieved.

As illustrated in FIG. 4A, the oxide 230b includes a region 230bc, and a region 230ba and a region 230bb provided such that the region 230bc is positioned therebetween. Here, the region 230bc functions as a channel formation region of the transistor. The region 230ba functions as one of a source region and a drain region of the transistor, and the region 230bb functions as the other of the source region and the drain region of the transistor. At least part of the region 230bc is overlapped by the conductor 260. The region 230ba is overlapped by the conductor 242a, and the region 230bb is overlapped by the conductor 242b.

The region 230bc has a smaller amount of oxygen vacancies or a lower impurity concentration than the region 230ba and the region 230bb, and thus is a high-resistance region with a low carrier concentration. Thus, the region 230bc can be regarded as being i-type (intrinsic) or substantially i-type.

The region 230ba and the region 230bb have a large amount of oxygen vacancies or a high concentration of impurities such as hydrogen, nitrogen, and a metal element, and thus are low-resistance regions with a high carrier concentration. In other words, the region 230ba and the region 230bb are each an n-type region (a low-resistance region) having a higher carrier concentration than the region 230bc.

Note that the carrier concentration of the region 230bc is preferably lower than or equal to 1×10¹⁸ cm⁻³, lower than 1×10¹⁷ cm⁻³, lower than 1 ×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the region 230bc is not particularly limited and can be, for example, 1×10⁻⁹ cm⁻³.

In order to reduce the carrier concentration of the oxide 230b, the impurity concentration of the oxide 230b is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration may be referred to as a highly purified intrinsic or substantially highly purified intrinsic oxide semiconductor (or metal oxide).

In order to obtain stable electrical characteristics of the transistor, reducing the impurity concentration in the oxide 230b is effective. In order to reduce the impurity concentration in the oxide 230b, it is preferable that the impurity concentration in an adjacent film be also reduced. Examples of impurities include hydrogen, nitrogen, an alkali metal, an alkaline earth metal, iron, nickel, and silicon. Note that an impurity in the oxide 230b refers to, for example, an element other than the main components of the oxide 230b. For example, an element with a concentration lower than 0.1 atomic % can be regarded as an impurity.

Note that the region 230bc, the region 230ba, and the region 230bb may each be formed not only in the oxide 230b but also in the oxide 230a.

In the oxide 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, a region closer to the region 230bc may have lower concentrations of impurity elements such as hydrogen and nitrogen.

A metal oxide functioning as a semiconductor (hereinafter also referred to as an oxide semiconductor) is preferably used for the oxide 230 (the oxide 230a and the oxide 230b).

The metal oxide functioning as a semiconductor preferably has a band gap larger than or equal to 2 eV, further preferably larger than or equal to 2.5 eV. With the use of a metal oxide having a larger band gap, the off-state current of the transistor can be reduced. Such a transistor including a metal oxide in a channel formation region is referred to as an OS transistor. The off-state current of the OS transistor is low, so that power consumption of the semiconductor device can be adequately reduced. The OS transistor has excellent frequency characteristics, which enables the semiconductor device to operate at high speed.

The oxide 230 preferably includes a metal oxide (an oxide semiconductor). Examples of the metal oxide that can be used for the oxide 230 include indium oxide, gallium oxide, and zinc oxide. The metal oxide preferably contains at least indium (In) or zinc (Zn). The metal oxide preferably contains two or three selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element”, and a “metal element” described in this specification and the like may refer to a metalloid element.

For the oxide 230, it is possible to use, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO). Alternatively, it is possible to use indium tin oxide containing silicon, gallium tin oxide (Ga—Sn oxide), aluminum tin oxide (Al—Sn oxide), or the like.

By increasing the proportion of the number of indium atoms in the total number of atoms of all the metal elements contained in the metal oxide, the field-effect mobility of the transistor can be increased.

Note that the metal oxide may contain, instead of or in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor containing the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed, and the reliability of the transistor can be increased.

By increasing the proportion of the number of element M atoms in the total number of atoms of all the metal elements included in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor is suppressed, and the reliability of the transistor can be increased.

As described above, the electrical characteristics and reliability of the transistor vary depending on the composition of the metal oxide used for the oxide 230. Thus, by varying the composition of the metal oxide in accordance with the electrical characteristics and reliability required for the transistor, the semiconductor device can have both excellent electrical characteristics and high reliability.

The oxide 230 preferably has a stacked-layer structure of a plurality of oxide layers with different chemical compositions. For example, the atomic ratio of the element M to a metal element that is a main component in the metal oxide used for the oxide 230a is preferably greater than the atomic ratio of the element M to a metal element that is a main component in the metal oxide used for the oxide 230b. Moreover, the atomic ratio of the element M to In in the metal oxide used for the oxide 230a is preferably greater than the atomic ratio of the element M to In in the metal oxide used for the oxide 230b. With this structure, impurities and oxygen can be inhibited from diffusing into the oxide 230b from the components formed below the oxide 230a.

Furthermore, the atomic ratio of In to the element M in the metal oxide used for the oxide 230b is preferably greater than the atomic ratio of In to the element M in the metal oxide used for the oxide 230a. With this structure, the transistor can have a high on-state current and excellent frequency characteristics.

When the oxide 230a and the oxide 230b contain a common element as the main component besides oxygen, the density of defect states at the interface between the oxide 230a and the oxide 230b can be reduced. Thus, the influence of interface scattering on carrier conduction is small, and the transistor can have a high on-state current and excellent frequency characteristics.

Specifically, as the oxide 230a, a metal oxide with a composition of In:M:Zn=1:3:2 [atomic ratio] or in the neighborhood thereof, a composition of In:M:Zn=1:3:4 [atomic ratio] or in the neighborhood thereof, or a composition of In:M:Zn=1:1:0.5 [atomic ratio] or in the neighborhood thereof can be used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of ±30% of an intended atomic ratio. Gallium is preferably used as the element M. In the case where a single layer of the oxide 230b is provided as the oxide 230, a metal oxide that can be used for the oxide 230a may be used for the oxide 230b. The compositions of the metal oxides that can be used for the oxide 230a and the oxide 230b are not limited to the above. For example, the composition of the metal oxide that can be used for the oxide 230a may be applied to the oxide 230b. Similarly, the composition of the metal oxide that can be used for the oxide 230b may be applied to the oxide 230a.

When the metal oxide is deposited by a sputtering method, the above atomic ratio is not limited to the atomic ratio of the deposited of the metal oxide and may be the atomic ratio of a sputtering target used for depositing the metal oxide.

The oxide 230b preferably has crystallinity. It is particularly preferable to use a CAAC-OS (C-Axis Aligned Crystalline Oxide Semiconductor) for the oxide 230b.

The CAAC-OS is a metal oxide having a dense structure with high crystallinity and small amounts of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear grain boundary is difficult to observe in a CAAC-OS; thus, it can be said that a reduction in electron mobility due to the grain boundary is less likely to occur. Thus, a metal oxide including a CAAC-OS is physically stable. Accordingly, a metal oxide including a CAAC-OS is resistant to heat and has high reliability.

When an oxide having crystallinity, such as a CAAC-OS, is used for the oxide 230b, oxygen extraction from the oxide 230b by the source electrode or the drain electrode can be inhibited. This can reduce oxygen extraction from the oxide 230b even when heat treatment is performed; thus, the transistor is stable with respect to high temperatures in the manufacturing process (what is called thermal budget).

A transistor using an oxide semiconductor is likely to have its electrical characteristics changed by impurities and oxygen vacancies in a region where a channel is formed in the oxide semiconductor, which might reduce the reliability. In some cases, hydrogen in the vicinity of an oxygen vacancy forms a defect where hydrogen enters the oxygen vacancy (hereinafter, such defect is sometimes referred to as V_{O}H), which generates an electron serving as a carrier. Therefore, if the region 230bc where a channel is formed in the oxide semiconductor includes oxygen vacancies, the transistor is likely to have normally-on characteristics (characteristics with which, even when no voltage is applied to the gate electrode, the channel exists and current flows through the transistor). Thus, impurities, oxygen vacancies, and V_{O}H are preferably reduced as much as possible in the region 230bc in the oxide semiconductor. In other words, it is preferable that the region 230bc in the oxide semiconductor have a reduced carrier concentration and be i-type (intrinsic) or substantially i-type.

As a countermeasure to the above, an insulator containing oxygen to be released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the region 230ba or the region 230bb might cause a decrease in the on-state current or field-effect mobility of the transistor. Furthermore, a variation of the amount of oxygen supplied to the region 230ba or the region 230bb in the substrate plane leads to a variation in characteristics of semiconductor devices including the transistors. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the region 230bc is preferably an i-type or substantially i-type region with a reduced carrier concentration, whereas the region 230ba and the region 230bb are preferably n-type regions with a high carrier concentration. That is, the amounts of oxygen vacancies and V_{O}H in the region 230bc of the oxide semiconductor are preferably reduced. Furthermore, it is preferable that the region 230ba and the region 230bb not be supplied with an excess amount of oxygen and the amount of V_{O}H in the region 230ba and the region 230bb not be excessively reduced. In addition, a reduction in conductivity of the conductor 260, the conductor 242a, the conductor 242b, and the like is preferably inhibited. For example, oxidation of the conductor 260, the conductor 242a, the conductor 242b, and the like is preferably inhibited. Note that hydrogen in an oxide semiconductor can form V_{O}H; thus, the hydrogen concentration needs to be reduced in order to reduce the amount of V_{O}H.

In view of the above, in this embodiment, the semiconductor device has a structure in which the hydrogen concentration of the region 230bc is reduced, oxidation of the conductor 242a, the conductor 242b, and the conductor 260 is inhibited, and a reduction in hydrogen concentration of the region 230ba and the region 230bb is inhibited.

FIG. 4B is an enlarged cross-sectional view in the channel length direction of a transistor having a structure different from that of the transistor illustrated in FIG. 4A. Note that FIG. 7 can be referred to for an enlarged cross-sectional view in the channel width direction of the transistor illustrated in FIG. 4B.

The transistor illustrated in FIG. 4B includes an insulator 271a over the conductor 242a and an insulator 271b over the conductor 242b. The insulator 271a includes an insulator 271a1 and an insulator 271a2 over the insulator 271a1. The insulator 271b includes an insulator 271b1 and an insulator 271b2 over the insulator 271b1.

The insulator 271a is provided over the conductor 242a and the insulator 271b is provided over the conductor 242b, whereby end portions of the conductor 242a and the conductor 242b can be prevented from being excessively etched when an oxide film to be the oxide 230 and a conductive film to be the conductor 242a and the conductor 242b are collectively processed into an island shape. That is, the insulator 271a and the insulator 271b have a function of an etching stopper that protects the conductor 242a and the conductor 242b at the time of processing the conductive film into an island shape. As the insulator 271a and the insulator 271b, an inorganic insulator that is less likely to oxidize the conductor 242a and the conductor 242b is preferably used. For example, a nitride insulator or an oxide insulator is preferably used. When the insulators having a function of the etching stopper are provided over the conductor 242a and the conductor 242b, a minute transistor can be processed with high accuracy. Although the insulator 271a and the insulator 271b each have a two-layer stacked structure in FIG. 4B, each of them may have a single-layer structure or a stacked-layer structure of three or more layers.

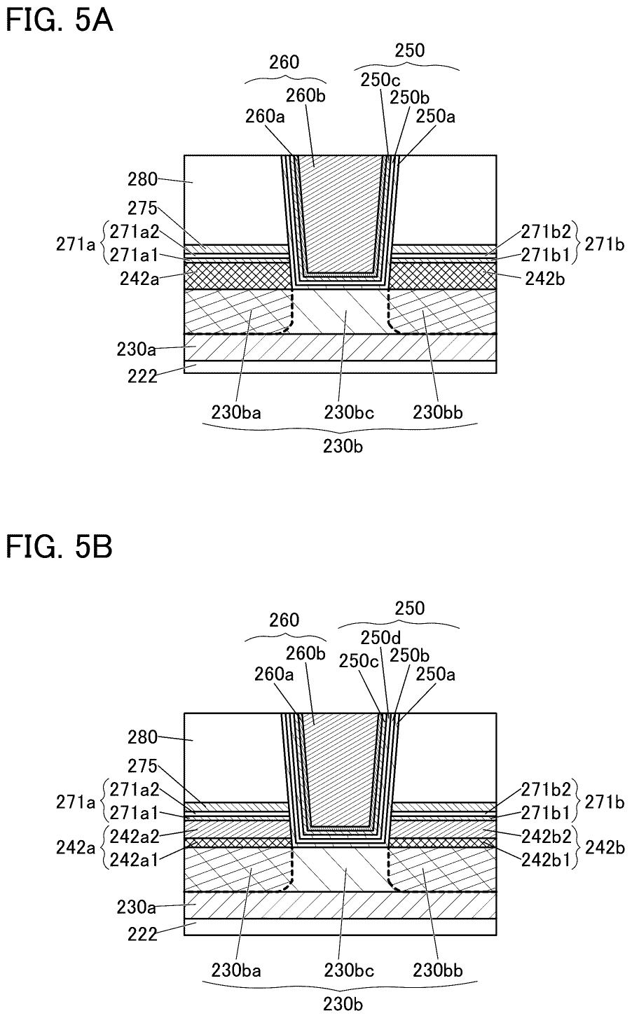

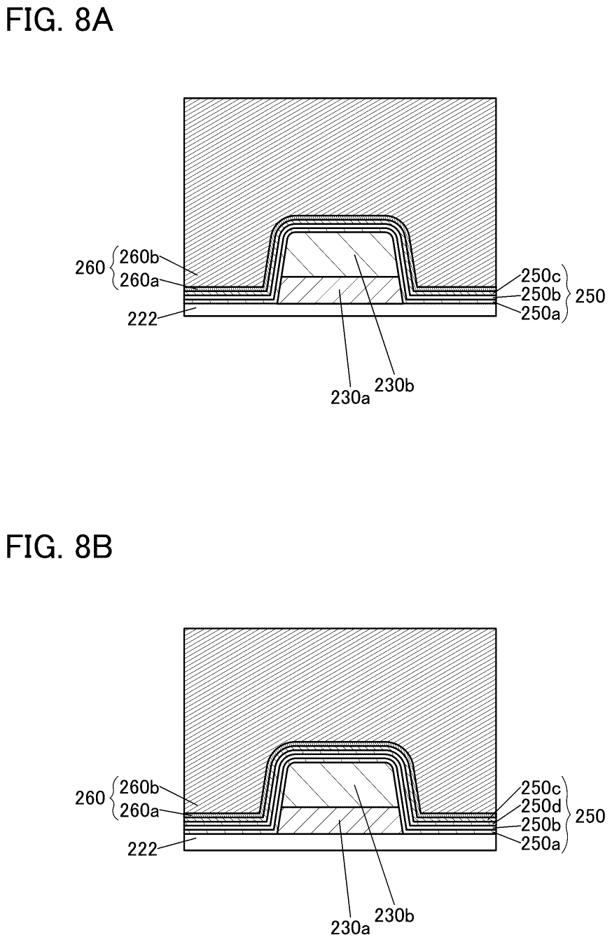

FIG. 5A is an enlarged cross-sectional view in the channel length direction of a transistor having a structure different from that of the transistor illustrated in FIG. 4B. Note that FIG. 8A can be referred to for an enlarged cross-sectional view in the channel width direction of the transistor illustrated in FIG. 5A.

The transistor illustrated in FIG. 5A is different from the transistor illustrated in FIG. 4B in that the insulator 250 has a three-layer stacked structure of an insulator 250a, an insulator 250b over the insulator 250a, and an insulator 250c over the insulator 250b.

In the transistor illustrated in FIG. 5A, the insulator 250a in contact with the region 230bc of the oxide 230b preferably has a function of capturing and fixing hydrogen. In that case, the hydrogen concentration in the region 230bc of the oxide 230b can be reduced. Accordingly, V_{O}H in the region 230bc can be reduced, so that the region 230bc can be an i-type or substantially i-type region.

Examples of an insulator having a function of capturing and fixing hydrogen include a metal oxide having an amorphous structure. For the insulator 250a, a metal oxide such as magnesium oxide or an oxide containing one or both of aluminum and hafnium is preferably used, for example. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

A high-permittivity (high-k) material is preferably used for the insulator 250a. An example of the high-k material is an oxide containing one or both of aluminum and hafnium. With the use of the high-k material for the insulator 250a, a gate potential applied during the operation of the transistor can be reduced while the physical thickness of the gate insulator is maintained. In addition, the equivalent oxide thickness (EOT) of the insulator functioning as the gate insulator can be reduced.

As described above, for the insulator 250a, an oxide containing one or both of aluminum and hafnium is preferably used, an oxide that has an amorphous structure and contains one or both of aluminum and hafnium is further preferably used, and aluminum oxide having an amorphous structure is still further preferably used.

An insulator having a thermally stable structure, such as silicon oxide or silicon oxynitride, is preferably used for the insulator 250b. Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

As the insulator 250c, an insulator that functions as a barrier insulator against oxygen is preferably used. The insulator 250c is in contact with the conductor 260. Thus, when an insulator functioning as a barrier insulator against oxygen is used as the insulator 250c, oxygen contained in the insulator 250b can be inhibited from diffusing to the conductor 260 side through the insulator 250c and oxidizing the conductor 260.

Note that in this specification and the like, a barrier insulator refers to an insulator having a barrier property. A barrier property in this specification and the like means a function of inhibiting diffusion of a target substance (also referred to as having low permeability). In addition, a barrier property in this specification and the like means a function of capturing and fixing (also referred to as gettering) a targeted substance.

As illustrated in FIG. 5B and FIG. 8B, an insulator 250d may be provided over the insulator 250b. In this case, as the insulator 250d, an insulator that can be used for the insulator 250a can be provided. For the insulator 250d, hafnium oxide can be used, for example. Here, when the insulator 250d is provided between the insulator 250b and the insulator 250c, hydrogen contained in the insulator 250b and the like can be captured and fixed more effectively.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator 250a, the insulator 250c, the insulator 250d, and the insulator 275 are provided in the vicinities of the conductor 242a, the conductor 242b, and the conductor 260.

Examples of the barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 250a, the insulator 250c, and the insulator 275 preferably has a single-layer structure or a stacked-layer structure of the barrier insulator against oxygen.

The insulator 250a preferably has a barrier property against oxygen. It is preferable that oxygen be less likely to pass through the insulator 250a than at least through the insulator 280. The insulator 250a includes a region in contact with the side surface of the conductor 242a and a region in contact with the side surface of the conductor 242b. When the insulator 250a has a barrier property against oxygen, oxidation of the side surfaces of the conductor 242a and the conductor 242b and formation of oxide films on the side surfaces can be inhibited. Accordingly, a reduction in the on-state current or field-effect mobility of the transistor can be inhibited.

As illustrated in FIG. 8A and FIG. 8B, the insulator 250a is provided in contact with the top surface and the side surface of the oxide 230b, the side surface of the oxide 230a, and the top surface of the insulator 222. When the insulator 250a has a barrier property against oxygen, release of oxygen from the region 230bc of the oxide 230b at the time of performing heat treatment or the like can be inhibited. This can inhibit formation of oxygen vacancies in the oxide 230a and the oxide 230b.

By providing the insulator 250a, even when the insulator 280 contains an excess amount of oxygen, excessive supply of oxygen to the oxide 230a and the oxide 230b can be inhibited and an appropriate amount of oxygen can be supplied to the oxide 230a and the oxide 230b. Accordingly, the region 230ba and the region 230bb are inhibited from being excessively oxidized, and thus a reduction in the on-state current or field-effect mobility of the transistor can be inhibited.

The oxide containing one or both of aluminum and hafnium has a barrier property against oxygen and thus can be suitably used for the insulator 250a.

As described above, the insulator 250c preferably has a barrier property against oxygen. As illustrated in FIG. 5A and FIG. 5B, the insulator 250c is provided between the region 230bc of the oxide 230 and the conductor 260 and between the insulator 280 and the conductor 260. This structure can inhibit oxygen contained in the region 230bc of the oxide 230 from diffusing into the conductor 260 and thus can inhibit formation of oxygen vacancies in the region 230bc of the oxide 230. In addition, oxygen contained in the oxide 230 and oxygen contained in the insulator 280 can be inhibited from diffusing into the conductor 260 and oxidizing the conductor 260. It is preferable that oxygen be less likely to pass through the insulator 250c than at least through the insulator 280. For example, silicon nitride is preferably used for the insulator 250c. In this case, the insulator 250c contains at least nitrogen and silicon.

The insulator 250c preferably has a barrier property against hydrogen. In that case, diffusion of impurities contained in the conductor 260, such as hydrogen, into the oxide 230b can be prevented.

The insulator 275 preferably has a barrier property against oxygen. The insulator 275 is provided between the insulator 280 and the conductor 242a and between the insulator 280 and the conductor 242b. This structure can inhibit diffusion of oxygen contained in the insulator 280 into the conductor 242a and the conductor 242b. Accordingly, oxidation of the conductor 242a and the conductor 242b by oxygen contained in the insulator 280 can be inhibited, so that an increase in resistivity and a reduction in on-state current can be inhibited. It is preferable that oxygen be less likely to pass through the insulator 275 than at least through the insulator 280. For example, silicon nitride is preferably used for the insulator 275. In this case, the insulator 275 contains at least nitrogen and silicon.

In order to inhibit a reduction in the hydrogen concentration of the region 230ba and the region 230bb in the oxide 230, a barrier insulator against hydrogen is preferably provided in the vicinity of each of the region 230ba and the region 230bb. In the semiconductor device described in this embodiment, the insulator 275 is provided in the vicinities of the region 230ba and the region 230bb.

Examples of the barrier insulator against hydrogen include oxides such as aluminum oxide, hafnium oxide, and tantalum oxide and nitrides such as silicon nitride. For example, the insulator 275 preferably has a single-layer structure or a stacked-layer structure of the barrier insulator against hydrogen.

The insulator 275 preferably has a barrier property against hydrogen. When the insulator 275 has a barrier property against hydrogen, the insulator 250 can be inhibited from capturing and fixing hydrogen in the region 230ba and the region 230bb. Accordingly, the region 230ba and the region 230bb can be n-type regions.

With the above structure, the region 230bc can be an i-type or substantially i-type region, and the region 230ba and the region 230bb can be n-type regions; thus, a transistor with favorable electrical characteristics can be provided. The transistor with the above structure can have excellent electrical characteristics even when scaled down or highly integrated. Scaling down of the transistor can improve the high-frequency characteristics. Specifically, the cutoff frequency can be improved.

The insulator 250a to the insulator 250d function as part of the gate insulator. The insulator 250a to the insulator 250d are provided in the opening formed in the insulator 280 and the like, together with the conductor 260. The thicknesses of the insulator 250a to the insulator 250d are preferably small for scaling down of the transistor. The thickness of each of the insulator 250a to the insulator 250d is preferably larger than or equal to 0.1 nm and smaller than or equal to 10 nm, further preferably larger than or equal to 0.1 nm and smaller than or equal to 5.0 nm, still further preferably larger than or equal to 0.5 nm and smaller than or equal to 5.0 nm, yet further preferably larger than or equal to 1.0 nm and smaller than 5.0 nm, yet still further preferably larger than or equal to 1.0 nm and smaller than or equal to 3.0 nm. Note that at least part of each of the insulator 250a to the insulator 250d includes a region having the above-described thickness.

To form the insulator 250a to the insulator 250d having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables film formation at a lower temperature.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. Therefore, the insulator 250 can be deposited on the side surface of the opening portion formed in the insulator 280 and the like, the side end portions of the conductor 242a and the conductor 242b, and the like, with a small thickness like the above-described thickness and favorable coverage.

Note that some precursors used in an ALD method contain carbon or the like. Thus, in some cases, a film provided by an ALD method includes impurities such as carbon in a larger amount than a film provided by another film formation method. Note that impurities can be quantified by secondary ion mass spectrometry (SIMS), X-ray photoelectron spectroscopy (XPS), or auger electron spectroscopy (AES).

Although the case where the insulator 250 has a three-layer structure of the insulator 250a to the insulator 250c or a four-layer structure of the insulator 250a to the insulator 250d is described above, the present invention is not limited thereto. The insulator 250 can have a structure including at least one of the insulator 250a to the insulator 250d. When the insulator 250 is formed of one, two, or three layer(s) of the insulator 250a to the insulator 250d, the manufacturing process of the semiconductor device can be simplified and the productivity can be increased.

In addition to the above structure, the semiconductor device of this embodiment preferably has a structure in which hydrogen is inhibited from entering the transistor. For example, an insulator having a function of inhibiting diffusion of hydrogen is preferably provided to cover one or both of the top and bottom of the transistor. In the semiconductor device described in this embodiment, the insulator corresponds to the insulator 215 and the insulator 283, for example. The insulator 215 and the insulator 283 may have similar structures.

The insulator 283 preferably functions as a barrier insulator that inhibits diffusion of impurities such as water and hydrogen from above the semiconductor device 200 into the transistor included in the semiconductor device. Thus, the insulator 283 preferably includes an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material that does not easily transmit the impurities). Alternatively, the insulator 283 preferably includes an insulating material having a function of inhibiting diffusion of oxygen (e.g., at least one of an oxygen atom, an oxygen molecule, and the like) (an insulating material that does not easily transmit the oxygen).

The insulator 283 preferably includes an insulator having a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used.

Although the insulator 283 has a single-layer structure in FIG. 1B and the like, one embodiment of the present invention is not limited thereto. The insulator 283 may have a stacked-layer structure of two or more layers. For example, in the case where the insulator 283 has a two-layer stacked structure, silicon nitride or the like having a higher hydrogen barrier property is preferably used for the second insulator in the insulator 283. The first insulator in the insulator 283 preferably includes aluminum oxide, magnesium oxide, or the like, which has a function of capturing and fixing hydrogen well. Thus, impurities such as water and hydrogen can be inhibited from diffusing into the transistor from an interlayer insulating film and the like that are provided above the insulator 283. Alternatively, oxygen contained in the insulator 280 and the like can be inhibited from diffusing into the components above the transistor through the insulator 283.

When the insulator 215 has a structure similar to that of the insulator 283, it is possible to inhibit diffusion of impurities such as water and hydrogen into the transistor from the substrate side through the insulator 215.

In this manner, it is preferable that the transistor be surrounded by the insulators having a function of inhibiting diffusion of oxygen and impurities such as water and hydrogen.

The conductor 205 is placed to be overlapped by the oxide 230_1 and the conductor 260_1. Thus, the conductor 205 can function as the second gate electrode of the transistor 200_1. Here, the conductor 205 is preferably provided to be embedded in an opening portion formed in the insulator 216. Moreover, the conductor 205 is preferably provided to extend in the channel width direction as illustrated in FIG. 1A and FIG. 2. With such a structure, the conductor 205 can function as a wiring when a plurality of transistors are provided in one substrate plane.

The conductor 205 may have a single-layer structure or a stacked-layer structure. FIG. 1B and the like illustrate an example in which the conductor 205 has a two-layer stacked structure of the conductor 205a and the conductor 205b. The conductor 205a is provided in contact with the sidewall of the opening portion and the top surface of the insulator 215. The conductor 205b is provided to fill a concave portion that is defined by the conductor 205a and formed along the opening portion. Here, the top surface of the conductor 205 is substantially level with the top surface of the insulator 216.

Here, the conductor 205a preferably contains a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductor 205a preferably contains a conductive material having a function of inhibiting diffusion of oxygen (e.g., at least one of an oxygen atom, an oxygen molecule, and the like).

When the conductor 205a is formed using a conductive material having a function of inhibiting diffusion of hydrogen, impurities such as hydrogen contained in the conductor 205b can be prevented from diffusing into the oxide 230_1 through the insulator 216 and the like. When the conductor 205a is formed using a conductive material having a function of inhibiting diffusion of oxygen, a reduction in conductivity of the conductor 205b due to oxidation by oxygen diffused from the insulator 216 can be inhibited. Examples of the conductive material having a function of inhibiting diffusion of oxygen include titanium, titanium nitride, tantalum, tantalum nitride, ruthenium, and ruthenium oxide. The conductor 205a can have a single-layer structure or a stacked-layer structure of the above conductive material. For example, the conductor 205a preferably contains titanium nitride.

A conductive material containing tungsten, copper, or aluminum as its main component is preferably used for the conductor 205b. For example, the conductor 205b preferably contains tungsten.

Note that the electrical resistivity of the conductor 205 is designed in consideration of the potential applied to the conductor 205, and the thickness of the conductor 205 is set in accordance with the electrical resistivity. The thickness of the insulator 216 is substantially equal to that of the conductor 205. Here, the conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, inhibiting diffusion of the impurities into the oxide 230_1.

The insulator 222 (the insulator 222_1 to the insulator 222_3) functions as an interlayer film positioned between the transistors included in the semiconductor device 200. Moreover, the insulator 222_1 to the insulator 222_3 function as the second gate insulators of the transistor 200_1 to the transistor 200_3. Thus, the material and thickness of the insulator 222 are preferably the same as those of the insulator 250. In particular, in the case where the insulator 250 has a stacked-layer structure, the insulator 222 preferably has a stacked-layer structure and the stacking order of the layers in the insulator 222 is preferably reversed from that in the insulator 250. For example, in the case where the insulator 250 has a stacked-layer structure of a first insulator and a second insulator over the first insulator, the insulator 222 preferably has a stacked-layer structure of a second insulator and a first insulator over the second insulator. With such a structure, the oxide 230 can be surrounded by insulators having the same function (e.g., the first insulators). Although the material and thickness of the insulator 222 may be different from those of the insulator 250, the insulator 222 and the insulator 250 preferably have substantially the same EOT. In that case, the electric field from the conductor 260_1 and the electric field from the conductor 205, which are applied to the oxide 230_1, can have substantially the same intensity. The electric field from the conductor 260_2 and the electric field from the conductor 260_1, which are applied to the oxide 230_2, can have substantially the same intensity. The electric field from the conductor 260_3 and the electric field from the conductor 260_2, which are applied to the oxide 230_3, can have substantially the same intensity.

Substantially the same EOT of the insulator 222 and the insulator 250 is preferable, in which case the gate electric field can be applied to the oxides 230 in the transistor 200_1 to the transistor 200_3 substantially uniformly from all directions.

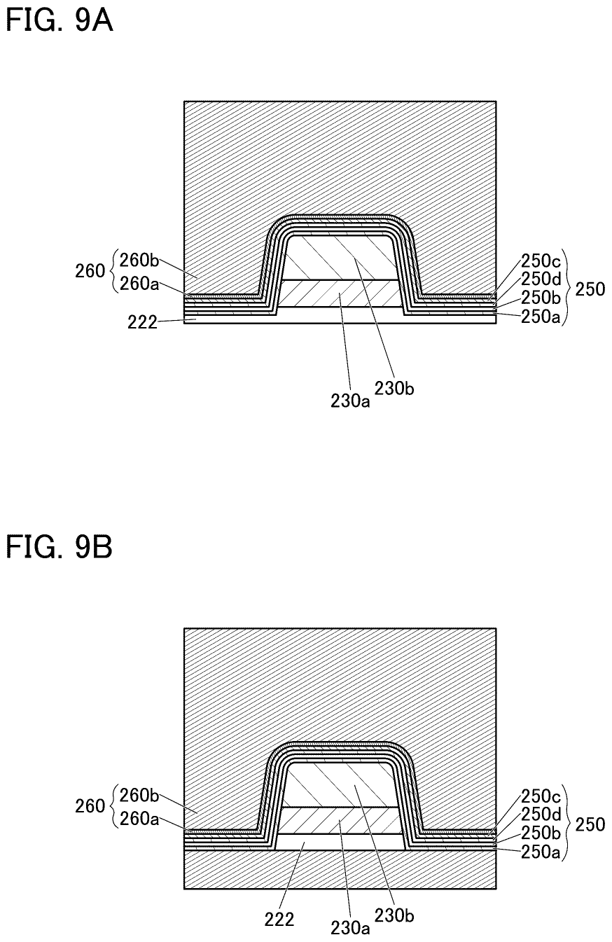

Note that part or the whole of the insulator 222 in a region that is not overlapped by the oxide 230 may be removed. For example, the semiconductor device 200 may have a structure in which part of the insulator 222 in a region that is not overlapped by the oxide 230 is removed as illustrated in FIG. 9A. In this case, the insulator 222 can be regarded as having a projecting portion in a region overlapped by the oxide 230. The semiconductor device 200 may have a structure in which the insulator 222 in a region that is not overlapped by the oxide 230 is removed as illustrated in FIG. 9B. In this case, the insulator 222 has an island shape. The insulator 250 is in contact with the top surface of the second gate electrode in a region not overlapping the oxide 230.

With either of the above structures, the bottom surface of the conductor 260 in a region not overlapping the oxide 230 can be made lower in level (made closer to the substrate side). This is preferable because the electric field from the conductor 260 functioning as the gate electrode can affect the entire channel formation region and thus the transistor will operate favorably.

For each of the conductor 242a (the conductor 242a1 to the conductor 242a3), the conductor 242b (the conductor 242b1 to the conductor 242b3), and the conductor 260 (the conductor 260_1 to the conductor 260_3), a conductive material that is less likely to be oxidized or a conductive material having a function of inhibiting diffusion of oxygen is preferably used. Examples of such a conductive material include a conductive material containing nitrogen and a conductive material containing oxygen. Thus, a decrease in conductivity of the conductor 242a, the conductor 242b, and the conductor 260 can be inhibited. In the case where a conductive material containing metal and nitrogen is used for the conductor 242a, the conductor 242b, and the conductor 260, the conductor 242a, the conductor 242b, and the conductor 260 contain at least metal and nitrogen.

Each of the conductor 242a and the conductor 242b may have a single-layer structure or a stacked-layer structure. The conductor 260 may have a single-layer structure or a stacked-layer structure.

For the conductor 242a and the conductor 242b, a metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that hydrogen contained in the oxide 230 or the like diffuses into the conductor 242a or the conductor 242b in some cases. In particular, when a nitride containing tantalum is used for the conductor 242a and the conductor 242b, hydrogen contained in the oxide 230 or the like is likely to diffuse into the conductor 242a or the conductor 242b, and the hydrogen that has diffused is bonded to nitrogen contained in the conductor 242a and the conductor 242b in some cases. That is, hydrogen contained in the oxide 230 or the like is absorbed by the conductor 242a and the conductor 242b in some cases.

As illustrated in FIG. 5B, the conductor 242a and the conductor 242b may each have a two-layer structure. In that case, the conductor 242a is a stacked film of the conductor 242a1 and the conductor 242a2 over the conductor 242a1, and the conductor 242b is a stacked film of the conductor 242b1 and the conductor 242b2 over the conductor 242b1. At this time, the above-described conductive material that is less likely to be oxidized or the above-described conductive material having a function of inhibiting diffusion of oxygen is preferably used for the layers (the conductor 242a1 and the conductor 242b1) in contact with the oxide 230b. Thus, a decrease in conductivity of the conductor 242a and the conductor 242b can be inhibited.

The conductor 242a2 and the conductor 242b2 preferably have higher conductivity than the conductor 242a1 and the conductor 242b1. For example, the thicknesses of the conductor 242a2 and the conductor 242b2 are preferably larger than the thicknesses of the conductor 242a1 and the conductor 242b1. For the conductor 242a2 and the conductor 242b2, a conductor that can be used for the conductor 205b can be used. The above structure can reduce the resistances of the conductor 242a2 and the conductor 242b2. This can increase the operating speed of the transistor.

For example, tantalum nitride or titanium nitride can be used for the conductor 242a1 and the conductor 242b1, and tungsten can be used for the conductor 242a2 and the conductor 242b2.

To inhibit a reduction in conductivity of the conductor 242a and the conductor 242b, an oxide having crystallinity, such as a CAAC-OS, is preferably used for the oxide 230b. Specifically, a metal oxide containing indium, zinc, and one or more selected from gallium, aluminum, and tin is preferably used. When a CAAC-OS is used, oxygen extraction from the oxide 230b by the conductor 242a or the conductor 242b can be inhibited. Furthermore, a reduction in conductivity of the conductor 242a and the conductor 242b can be inhibited.

As illustrated in FIG. 7 and the like, the oxide 230b may have a curved surface between the side surface of the oxide 230b and the top surface of the oxide 230b in a cross-sectional view in the channel width direction. In other words, an end portion of the side surface and an end portion of the top surface may be curved (hereinafter also referred to as rounded).

The radius of curvature of the curved surface is preferably greater than 0 nm and less than the thickness of the oxide 230b in a region overlapped by the conductor 242a or the conductor 242b or less than half of the length of a region not having the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 250 and the conductor 260 in the channel width direction of the transistor.

In FIG. 1B and the like, the conductor 260 (the conductor 260_1 to the conductor 260_3) has a two-layer structure. Here, the conductor 260 preferably includes the conductor 260a and the conductor 260b placed over the conductor 260a. For example, the conductor 260a is preferably placed to cover the bottom surface and the side surface of the conductor 260b. In this case, a conductive material that is less likely to be oxidized or a conductive material having a function of inhibiting diffusion of oxygen is preferably used for the conductor 260a.

For the conductor 260a (the conductor 260a1 to the conductor 260a3), a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used. Alternatively, it is preferable to use a conductive material having a function of inhibiting diffusion of oxygen (e.g., at least one of an oxygen atom, an oxygen molecule, and the like).

When the conductor 260a has a function of inhibiting diffusion of oxygen, the conductivity of the conductor 260b can be inhibited from being lowered because of oxidation due to oxygen contained in the insulator 280 or the like. As the conductive material having a function of inhibiting diffusion of oxygen, for example, titanium, titanium nitride, tantalum, tantalum nitride, ruthenium, or ruthenium oxide is preferably used.

For the conductor 260b (the conductor 260b1 to the conductor 260b3), a conductor having high conductivity is preferably used. For example, a conductive material containing tungsten, copper, or aluminum as its main component can be used for the conductor 260b. The conductor 260b may have a stacked-layer structure; for example, a stacked-layer structure of titanium or titanium nitride and the above conductive material may be employed.

As illustrated in FIG. 1B and the like, the conductor 260 is formed in a self-aligned manner to fill the opening formed in the insulator 280 and the like. The formation of the conductor 260 in this manner allows the conductor 260 to be placed properly in a region between the conductor 242a and the conductor 242b without alignment.

The insulator 216 and the insulator 280 each preferably have a lower permittivity than the insulator 283. When a material with a low permittivity is used for an interlayer film, parasitic capacitance generated between wirings can be reduced.

For example, the insulator 216 and the insulator 280 each preferably contain one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. A material such as silicon oxide, silicon oxynitride, or porous silicon oxide is particularly preferably used, in which case a region including oxygen that is released by heating can be easily formed.

The top surfaces of the insulator 216 and the insulator 280 may be planarized.

The concentration of impurities such as water and hydrogen in the insulator 280 is preferably reduced. For example, the insulator 280 preferably contains an oxide containing silicon, such as silicon oxide or silicon oxynitride.

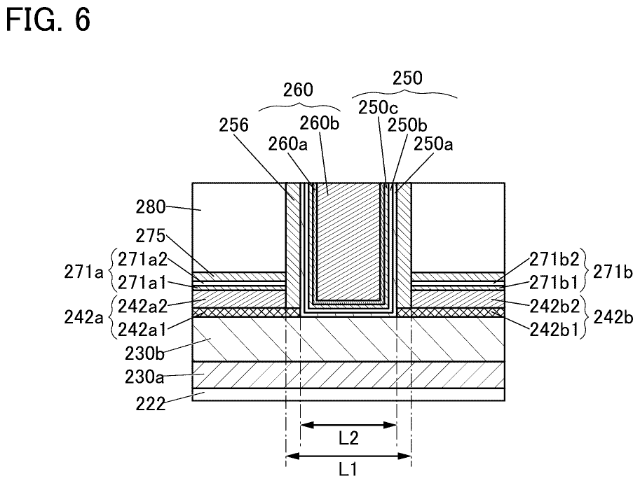

FIG. 6 is an enlarged cross-sectional view in the channel length direction of a transistor having a structure different from that of the transistor illustrated in FIG. 5A. Note that FIG. 8A can be referred to for an enlarged cross-sectional view in the channel width direction of the transistor illustrated in FIG. 6.

The transistor illustrated in FIG. 6 is different from the transistor illustrated in FIG. 5A in that an insulator 256 is provided between the insulator 250 and the insulator 280 and the like in the opening formed in the insulator 280 and the like.

The insulator 256 is provided in contact with sidewalls of the opening formed in the insulator 280 and the like. As illustrated in FIG. 6, on one sidewall side of the opening, the insulator 256 includes a region in contact with the side surface of the insulator 280, the side surface of the insulator 275, the side surface of the insulator 271a (the insulator 271a1 and the insulator 271a2), the side surface of the conductor 242a2, and the top surface of the conductor 242a1. On the other sidewall side of the opening, the insulator 256 includes a region in contact with the side surface of the insulator 280, the side surface of the insulator 275, the side surface of the insulator 271b (the insulator 271b1 and the insulator 271b2), the side surface of the conductor 242b2, and the top surface of the conductor 242b1.

As illustrated in FIG. 6, a distance L2 between the conductor 242a1 and the conductor 242b1 is smaller than a distance L1 between the conductor 242a2 and the conductor 242b2 in a cross-sectional view of the transistor in the channel length direction. Specifically, the difference between the distance L1 and the distance L2 is equal or substantially equal to twice the thickness of the insulator 256. Here, the thickness of the insulator 256 refers to the thickness of at least part of the insulator 256 in the channel length direction of the transistor. With such a structure, the distance between the source electrode and the drain electrode is shortened, and the channel length of the transistor can be shortened accordingly. Thus, the frequency characteristics of the transistor can be improved. Shortening the channel length of the transistor in this manner enables the semiconductor device to have a higher operating speed.

The opening provided in the insulator 280 and the like overlaps a region between the conductor 242a2 and the conductor 242b2. In a planar view, the side surface of the opening in the insulator 280 is aligned or substantially aligned with the side surface of the conductor 242a2 and the side surface of the conductor 242b2. The conductor 242a1 and the conductor 242b1 are formed to partly extend toward the inside of the opening. Here, part of the top surface of the conductor 242a1 is in contact with the conductor 242a2, and part of the top surface of the conductor 242b1 is in contact with the conductor 242b2. Thus, in the opening, the insulator 256 is in contact with another part of the top surface of the conductor 242a1, another part of the top surface of the conductor 242b1, the side surface of the conductor 242a2, and the side surface of the conductor 242b2. The insulator 250 is in contact with the top surface of the oxide 230, the side surface of the conductor 242a1, the side surface of the conductor 242b1, and the side surface of the insulator 256.

The insulator 256 is preferably an insulator that is not easily oxidized, such as nitride. The insulator 256 is formed in the shape of a side wall (also referred to as a sidewall insulating layer, a sidewall protective layer, or the like) by anisotropic etching to be in contact with the sidewall of the opening provided in the insulator 280 and the like. The insulator 256 is formed in contact with the side surface of the conductor 242a2 and the side surface of the conductor 242b2 and has a function of protecting the conductor 242a2 and the conductor 242b2. The insulator 256 formed in contact with the side surface of the conductor 242a2 and the side surface of the conductor 242b2 can prevent excessive oxidation of the conductor 242a2 and the conductor 242b2.

### Structure Example 2 of Semiconductor Device

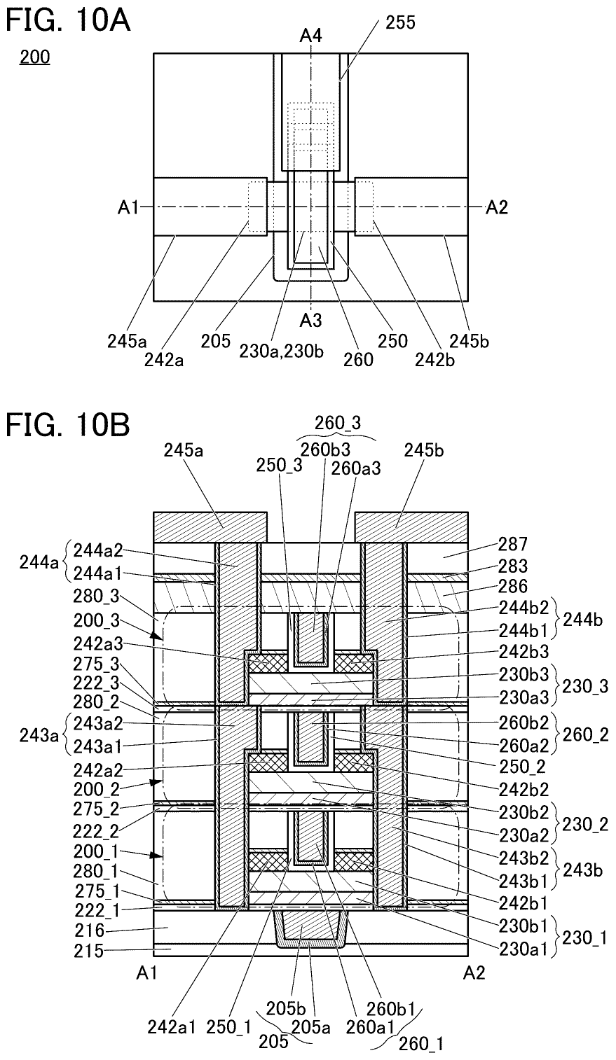

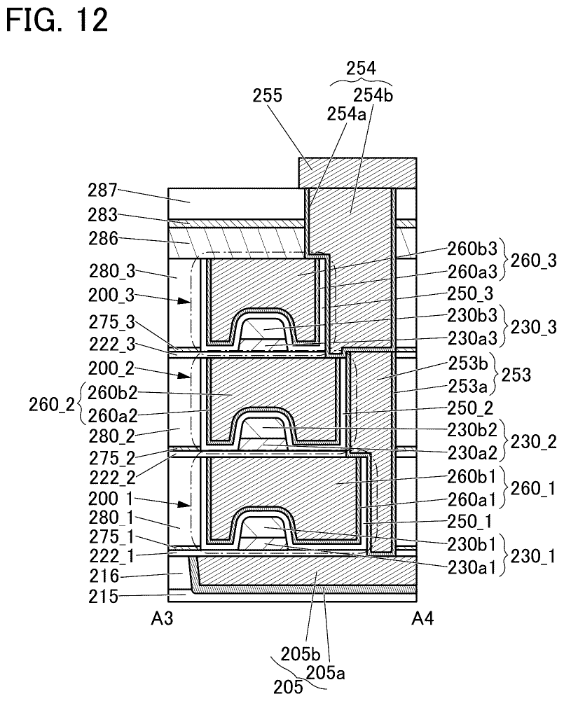

FIG. 10A and FIG. 10B illustrate a structure example of the semiconductor device 200 different from that shown in <Structure example 1 of semiconductor device>. FIG. 10A is a plan view of the semiconductor device 200. FIG. 10B is a cross-sectional view of the semiconductor device 200 along the dashed-dotted line A1-A2 in FIG. 10A. Note that FIG. 2 or FIG. 12 can be referred to for a cross-sectional view of the semiconductor device 200 along the dashed-dotted line A3-A4 in FIG. 10A.

The semiconductor device 200 illustrated in FIG. 10A and FIG. 10B is different from the semiconductor device 200 in <Structure example 1 of semiconductor device> in that the conductor 243a is in contact with the side surface of the oxide 230_1, the side surface of the conductor 242a1, the side surface of the oxide 230_2, the side surface of the conductor 242a2, and the top surface of the conductor 242a2, and the conductor 243b is in contact with the side surface of the oxide 230_1, the side surface of the conductor 242b1, the side surface of the oxide 230_2, the side surface of the conductor 242b2, and the top surface of the conductor 242b2. Other differences from the semiconductor device 200 in <Structure example 1 of semiconductor device> are that the conductor 244a is in contact with the side surface of the oxide 230_3, the side surface of the conductor 242a3, and the top surface of the conductor 242a3, and that the conductor 244b is in contact with the side surface of the oxide 230_3, the side surface of the conductor 242b3, and the top surface of the conductor 242b3.

In the semiconductor device 200 illustrated in FIG. 10A and FIG. 10B, the length in the channel length direction of the oxide 230 (the oxide 230_1 to the oxide 230_3) included in the transistor 200_1 to the transistor 200_3 is smaller than that in the semiconductor device 200 in <Structure example 1 of semiconductor device>.

In the semiconductor device 200 illustrated in FIG. 10A and FIG. 10B, the conductor 243a includes a region in contact with the top surface of the insulator 216, one of the side surfaces of the oxide 230_1, one of the side surfaces of the conductor 242a1, one of the side surfaces of the oxide 230_2, and one of the side surfaces of the conductor 242a2 in a cross-sectional view in the channel length direction of the transistors. The conductor 243b includes a region in contact with the top surface of the insulator 216, the other of the side surfaces of the oxide 230_1, one of the side surfaces of the conductor 242b1, the other of the side surfaces of the oxide 230_2, and one of the side surfaces of the conductor 242b2. For the conductor 243a and the conductor 243b other than the above points, the description of the conductor 243a and the conductor 243b included in the semiconductor device 200 in <Structure example 1 of semiconductor device> can be referred to.

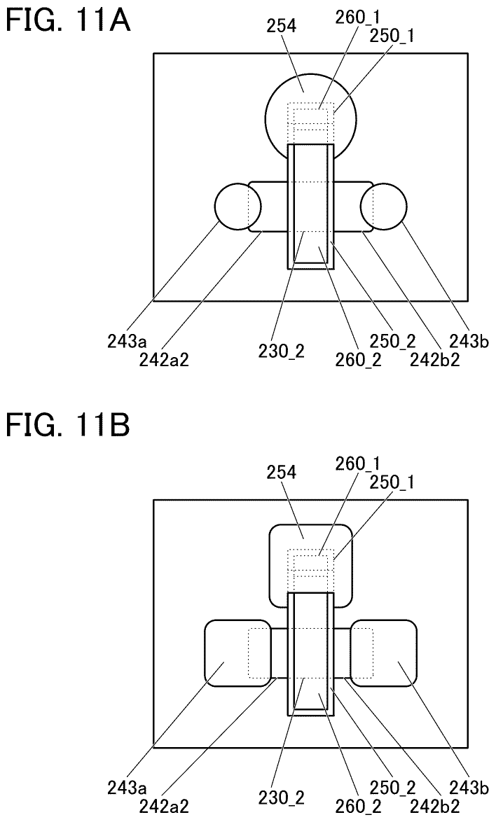

FIG. 11A is a plan view of the semiconductor device 200. FIG. 11A illustrates a region including the transistor 200_2 and its vicinity. For clarity of the drawing, some components are not illustrated in the plan view of FIG. 11A.

As illustrated in FIG. 11A, the conductor 243a includes a region in contact with the top surface of the conductor 242a2, and the conductor 243b includes a region in contact with the top surface of the conductor 242b2. Although FIG. 11A illustrates the structure in which the top-view shapes of the conductor 243a and the conductor 243b are circular, one embodiment of the present invention is not limited thereto. For example, the top-view shapes of the conductor 243a and the conductor 243b may be an oval shape, a polygonal shape, or a polygonal shape with rounded corners.

In FIG. 11B, the top-view shape of the conductor 243a is a polygonal shape with rounded corners. Note that the conductor 243a is preferably in contact with the side surface in the channel width direction as well as the one of the side surfaces in the channel length direction, as illustrated in FIG. 11B. Such a structure can enlarge the contact area between the conductor 243a and the conductor 242a2; hence, the on-state current, field-effect mobility, and frequency characteristics of the transistor 200_2 can be improved. The same applies to the conductor 243b.

In the semiconductor device 200 illustrated in FIG. 10A and FIG. 10B, the conductor 244a includes a region in contact with the top surface of the conductor 243a, one of the side surfaces of the oxide 230_3, and one of the side surfaces of the conductor 242a3 in a cross-sectional view in the channel length direction of the transistors. The conductor 244b includes a region in contact with the top surface of the conductor 243b, the other of the side surfaces of the oxide 230_3, and one of the side surfaces of the conductor 242b3. For the conductor 244a and the conductor 244b other than the above points, the description of the conductor 244a and the conductor 244b included in the semiconductor device 200 in <Structure example 1 of semiconductor device> can be referred to.

For the semiconductor device 200 illustrated in FIG. 10A and FIG. 10B other than the above, the description of the semiconductor device 200 in <Structure example 1 of semiconductor device> can be referred to.

The semiconductor device 200 illustrated in FIG. 10A and FIG. 10B, which has the above-described structure, can have a smaller size and a higher degree of integration than the semiconductor device 200 in <Structure example 1 of semiconductor device>.

### Structure Example 3 of Semiconductor Device

FIG. 12 illustrates a structure example of the semiconductor device 200 different from that shown in <Structure example 1 of semiconductor device>. FIG. 12 shows a variation example of the cross-sectional view of the semiconductor device 200 in <Structure example 1 of semiconductor device> along the dashed-dotted line A3-A4 (the cross-sectional view of the semiconductor device 200 corresponding to the channel width direction of the transistors). Note that FIG. 1A or FIG. 10A can be referred to for a plan view of the semiconductor device 200. FIG. 1B or FIG. 10B can be referred to for a cross-sectional view of the semiconductor device 200 corresponding to the channel length direction of the transistors.

The semiconductor device 200 illustrated in FIG. 12 is different from the semiconductor device 200 in <Structure example 1 of semiconductor device> in that the conductor functioning as the plug that electrically connects the gate electrodes of the transistors is composed of a conductor 253 (a conductor 253a and a conductor 253b) and the conductor 254 (the conductor 254a and the conductor 254b).

The conductor 253 includes the conductor 253a and the conductor 253b over the conductor 253a. The conductor 253a is provided in contact with the sidewall of an opening provided in the insulator 222_1, the insulator 275_1, the insulator 280_1, the insulator 222_2, the insulator 275_2, the insulator 280_2, and the insulator 222_3 and the top surface of the conductor 205. The conductor 253a includes a region in contact with the top surface of the conductor 260_1. The conductor 253b is provided to fill the opening.

The conductor 254 includes the conductor 254a and the conductor 254b over the conductor 254a. The conductor 254a is provided in contact with the sidewall of an opening provided in the insulator 222_3, the insulator 275_3, the insulator 280_3, the insulator 286, the insulator 283, and the insulator 287. The conductor 254a includes a region in contact with the top surface of the conductor 253, the top surface of the conductor 260_2, and the top surface of the conductor 260_3. The conductor 254b is provided to fill the opening. For the conductor 254 other than the above points, the description of the conductor 254 included in the semiconductor device 200 in <Structure example 1 of semiconductor device> can be referred to.

The conductor 253a can be formed using the same material as the conductor 254a. The conductor 253b can be formed using the same material as the conductor 254b. That is, the conductor 253a is preferably formed using a conductive material having a function of inhibiting diffusion of oxygen. The conductor 253b is preferably formed using a material having higher conductivity than that for the conductor 253a.

The conductor composed of the conductor 253 and the conductor 254 is electrically connected to the conductor 205, the conductor 260_1, the conductor 260_2, and the conductor 260_3. Thus, the conductor composed of the conductor 253 and the conductor 254 has a function of a plug that electrically connects the conductor 255 functioning as a wiring to the conductor 260_1 to the conductor 260_3 functioning as the gate electrodes (first gate electrodes) of the transistor 200_1 to the transistor 200_3 and the conductor 205 that can function as the second gate electrode of the transistor 200_1.

For the semiconductor device 200 illustrated in FIG. 12 other than the above, the description of the semiconductor device 200 in <Structure example 1 of semiconductor device> can be referred to.

In the semiconductor device 200 illustrated in FIG. 12, which has the above-described structure, the plug that electrically connects the source electrodes of the transistors, the plug that electrically connects the drain electrodes thereof, and the plug that connects the gate electrodes of the transistors can be formed at the same time.

For example, in the case where FIG. 12 is a cross-sectional view along the dashed-dotted line A3-A4 of the semiconductor device 200 illustrated in FIG. 10A and FIG. 10B, the conductor 243a, the conductor 243b, and the conductor 253 can be formed in the same step. Moreover, the conductor 244a, the conductor 244b, and the conductor 254 can be formed in the same step. Thus, the number of steps can be smaller in the semiconductor device 200 illustrated in FIG. 12 than in the semiconductor device 200 in <Structure example 1 of semiconductor device>.

### Structure Example 4 of Semiconductor Device

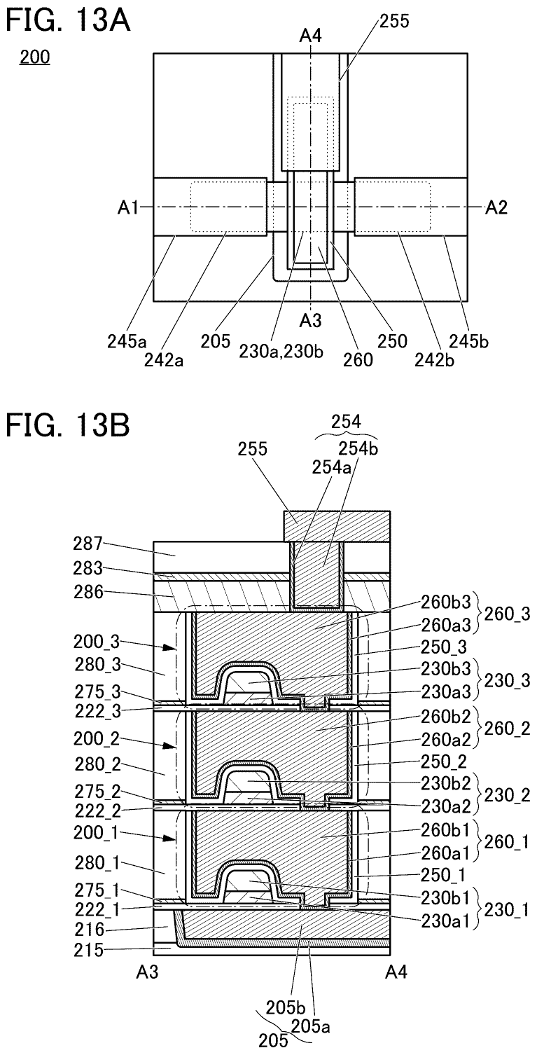

FIG. 13A and FIG. 13B illustrate a structure example of the semiconductor device 200 different from that shown in <Structure example 1 of semiconductor device>. FIG. 13A is a plan view of the semiconductor device 200. FIG. 13B is a cross-sectional view of the semiconductor device 200 along the dashed-dotted line A3-A4 in FIG. 13A. Note that FIG. 1B or FIG. 10B can be referred to for a cross-sectional view of the semiconductor device 200 along the dashed-dotted line A1-A2 in FIG. 13A.

The semiconductor device 200 illustrated in FIG. 13A and FIG. 13B is different from the semiconductor device 200 in <Structure example 1 of semiconductor device> in that the conductors functioning as the gate electrodes (the conductor 260_1 to the conductor 260_3) of the transistor 200_1 to the transistor 200_3 have the same size and the same shape in the channel width direction. That is, end portions of the conductor 260_1 to the conductor 260_3 are substantially aligned with each other in a planar view. Another difference from the semiconductor device 200 in <Structure example 1 of semiconductor device> is that a conductor functioning as a plug that connects the gate electrodes of the transistors is not provided and two gate electrodes of transistors are directly connected to each other.

As illustrated in FIG. 13B, the conductor 260_1 (the conductor 260a1 and the conductor 260b1) functioning as the gate electrode of the transistor 200_1 includes a region in contact with the top surface of the conductor 205 through an opening provided in the insulator 222_1 and the insulator 250_1.

The conductor 260_2 (the conductor 260a2 and the conductor 260b2) functioning as the gate electrode of the transistor 200_2 includes a region in contact with the top surface of the conductor 260_1 through an opening provided in the insulator 222_2 and the insulator 250_2.

The conductor 260_3 (the conductor 260a3 and the conductor 260b3) functioning as the gate electrode of the transistor 200_3 includes a region in contact with the top surface of the conductor 260_2 through an opening provided in the insulator 222_3 and the insulator 250_3.

The conductor 254 (the conductor 254a and the conductor 254b) is provided in contact with the sidewall of an opening provided in the insulator 286, the insulator 283, and the insulator 287. The conductor 254a includes a region in contact with the top surface of the conductor 260_3. The conductor 254b is provided over the conductor 254a to fill the opening. For the conductor 254 other than the above points, the description of the conductor 254 included in the semiconductor device 200 in <Structure example 1 of semiconductor device>can be referred to.

As illustrated in FIG. 13A and FIG. 13B, the end portions of the conductors functioning as the gate electrodes (the conductor 260_1 to the conductor 260_3) of the transistors are substantially aligned with each other in the channel width direction. That is, these conductors have the same size and the same shape.

In the semiconductor device 200 illustrated in FIG. 13A and FIG. 13B, the top surface of the gate electrode of one transistor is in contact with the bottom surface of the gate electrode of a transistor positioned in a layer immediately above the one transistor. Thus, a plug for connecting the gate electrodes of the transistors, such as one in the semiconductor device 200 in <Structure example 1 of semiconductor device>, is not needed.

Accordingly, the size of the semiconductor device in the channel width direction can be reduced by the area of the omitted plug.

Since the gate electrodes of the transistors included in the semiconductor device 200 have the same size and the same shape, the gate electrodes do not need to be formed using different masks for the transistors provided in different layers. In other words, the gate electrodes of all the transistors can be formed using only one mask. Thus, the manufacturing cost can be lower than that of the semiconductor device 200 in <Structure example 1 of semiconductor device>.

Even when the end portions of the conductor 260_1 to the conductor 260_3 are not aligned with each other in the channel width direction, the conductor 260_1 and the conductor 260_2 can be surely connected to each other through the opening provided in the insulator 222_2 and the insulator 250_2. Moreover, the conductor 260_2 and the conductor 260_3 can be surely connected to each other through the opening provided in the insulator 222_3 and the insulator 250_3. Accordingly, the required level of alignment accuracy for the opening to be provided with the conductor 260 and the insulator 250 is lowered, so that the degree of difficulty in forming a minute memory cell can be reduced.

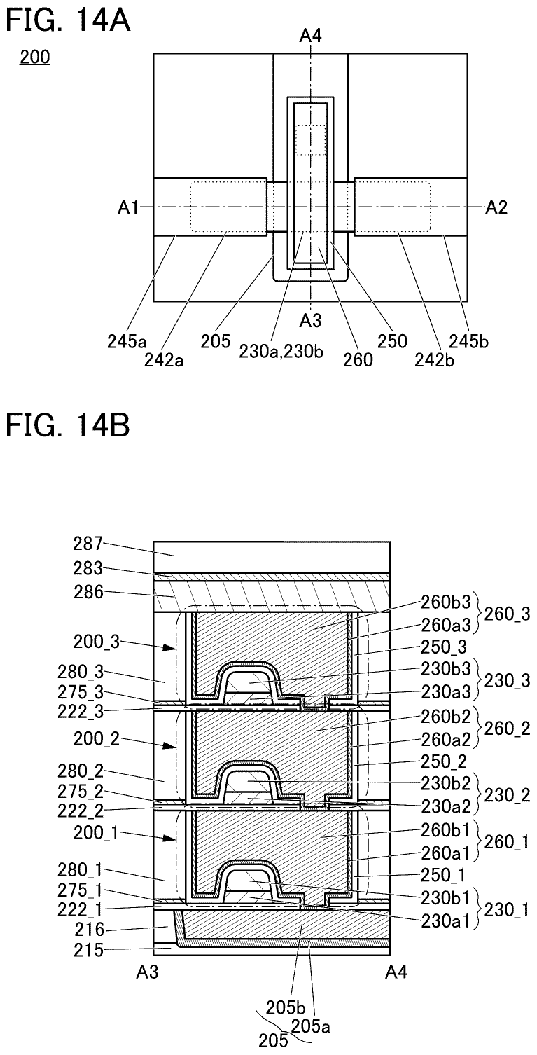

Note that in the case where the conductor 205 functions also as a wiring, the conductor 255 and the conductor 254 may be omitted as illustrated in FIG. 14A and FIG. 14B. In this case, it is possible to achieve a smaller number of steps and lower manufacturing cost than those of the semiconductor device 200 illustrated in FIG. 13A and FIG. 13B because the steps for forming the conductor 255 and the conductor 254 are not needed.

For the semiconductor device 200 illustrated in FIG. 13A and FIG. 13B other than the above, the description of the semiconductor device 200 in <Structure example 1 of semiconductor device> can be referred to.

### Structure Example 5 of Semiconductor Device

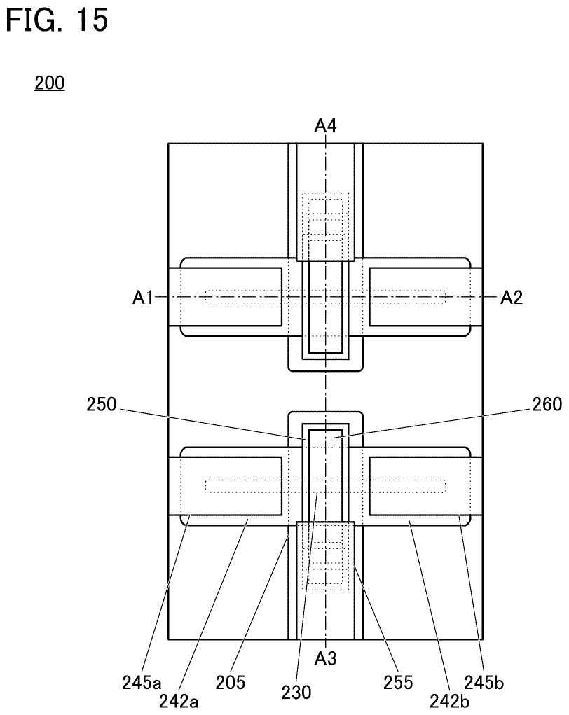

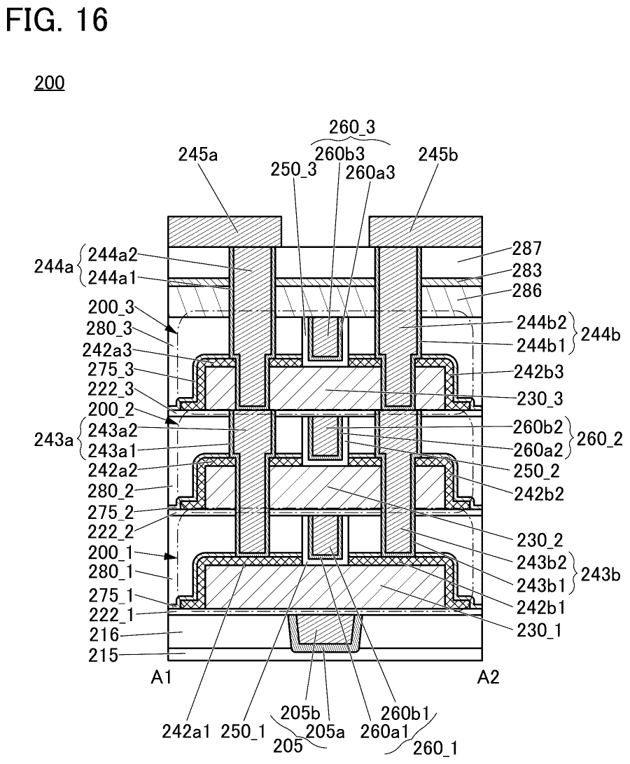

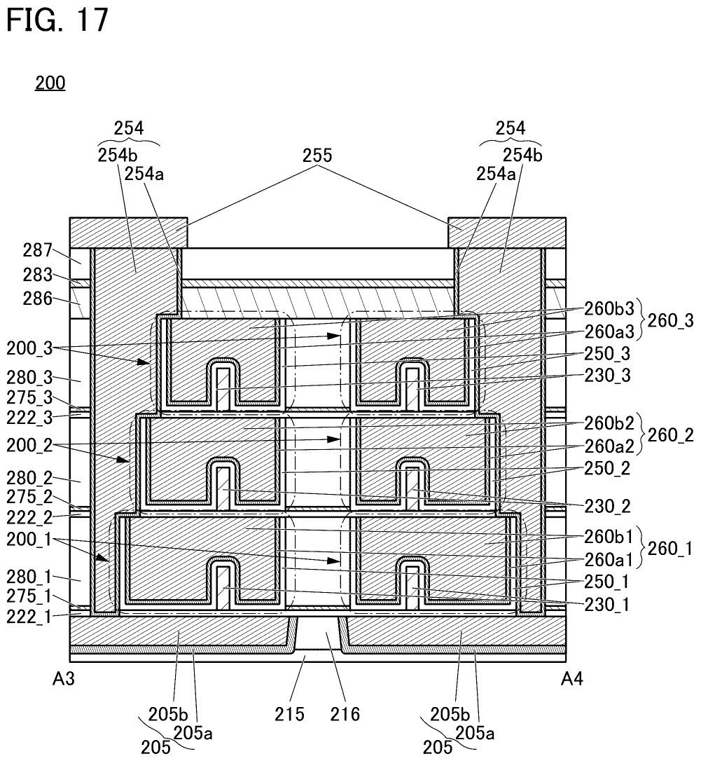

FIG. 15 to FIG. 17 illustrate a structure example of the semiconductor device 200 different from that shown in <Structure example 1 of semiconductor device>. FIG. 15 is a plan view of the semiconductor device 200. FIG. 16 is a cross-sectional view of the semiconductor device 200 along the dashed-dotted line A1-A2 in FIG. 15. FIG. 17 is a cross-sectional view of the semiconductor device 200 along the dashed-dotted line A3-A4 in FIG. 15.

The semiconductor device 200 illustrated in FIG. 15 to FIG. 17 is different from the semiconductor device 200 in <Structure example 1 of semiconductor device> in that the oxide 230_1 to the oxide 230_3 functioning as the semiconductor layers where the channels are formed in the transistor 200_1 to the transistor 200_3 each have a single-layer structure. Another difference from the semiconductor device 200 in <Structure example 1 of semiconductor device> is that, as illustrated in FIG. 16, the conductor 242a1 to the conductor 242a3 functioning either the source electrodes or the drain electrodes of the transistor 200_1 to the transistor 200_3 and the conductor 242b1 to the conductor 242b3 functioning as the others of the source electrodes and the drain electrodes of the transistor 200_1 to the transistor 200_3 cover the side surfaces and top surfaces of the transistor 200_1 to the transistor 200_3 in the channel length direction (the direction of the dashed-dotted line A1-A2 in FIG. 15).

Another difference from the semiconductor device 200 in <Structure example 1 of semiconductor device> is that, as illustrated in FIG. 17, a set of the transistor 200_1 to the transistor 200_3, the conductor 205, the conductor 254, and the conductor 255 is provided on the A3 side and another set thereof is provided on the A4 side such that the sets face each other in the channel width direction (the direction of the dashed-dotted line A3-A4 in FIG. 15).

That is, the semiconductor device 200 illustrated in FIG. 15 to FIG. 17 can be regarded as having a structure in which two transistors 200_1, two transistors 200_2, two transistors 200_3, two conductors 205, two conductors 254, and two conductors 255 are provided.

As described later, in the semiconductor device 200 illustrated in FIG. 15 to FIG. 17, the two transistors 200_1 can be formed at the same time. The two transistors 200_2 can be formed at the same time. The two transistors 200_3 can be formed at the same time.

Unlike in the transistor 200_1 included in the semiconductor device 200 in <Structure example 1 of semiconductor device>, the oxide 230_1 has a single-layer structure in the transistor 200_1 included in the semiconductor device 200 illustrated in FIG. 15 to FIG. 17. For the oxide 230_1 of the transistor 200_1 included in the semiconductor device 200 illustrated in FIG. 15 to FIG. 17, it is possible to use the same material as one of the oxide 230a1 or the oxide 230b1 in the oxide 230_1 of the transistor 200_1 included in the semiconductor device 200 in <Structure example 1 of semiconductor device>.

Unlike in the transistor 200_1 included in the semiconductor device 200 in <Structure example 1 of semiconductor device>, in the transistor 200_1 included in the semiconductor device 200 illustrated in FIG. 15 to FIG. 17, the conductor 242a1 and the conductor 242b1 are provided to extend beyond side surfaces of the oxide 230_1 that do not face the conductor 260_1. Thus, in the transistor 200_1 included in the semiconductor device 200 illustrated in FIG. 15 to FIG. 17, the conductor 242a1 is in contact with the top surface and the side surface on one side (the A1 side) of the oxide 230_1 and the top surface on one side (the A1 side) of the insulator 222_1, with the conductor 260_1 as the axis. The conductor 242b1 is in contact with the top surface and the side surface on the other side (the A2 side) of the oxide 230_1 and the top surface on the other side (the A2 side) of the insulator 222_1, with the conductor 260_1 as the axis. With such a structure, the area where the oxide 230_1 and the conductor 242a1 are in contact with each other is enlarged, so that the contact resistance between the oxide 230_1 and the conductor 242a1 can be reduced. Furthermore, the area where the oxide 230_1 and the conductor 242b1 are in contact with each other is enlarged, so that the contact resistance between the oxide 230_1 and the conductor 242b1 can be reduced. Consequently, the transistor 200_1 can have a high on-state current.

Over the oxide 230_1, the conductor 242a1 and the conductor 242b1 are provided such that the insulator 250_1 and the conductor 260_1 are positioned therebetween in a planar view. As illustrated in FIG. 16, side surfaces of the conductor 242a1 and the conductor 242b1 that do not face the conductor 260_1 extend beyond the side surfaces of the oxide 230_1.

The insulator 275_1 is provided in contact with the top surface of the conductor 242a1, the side surface of the conductor 242a1 that does not face the conductor 260_1, the top surface of the conductor 242b1, the side surface of the conductor 242b1 that does not face the conductor 260_1, and the top surface of the insulator 222_1.

The above description of the transistor 200_1 can be applied to the transistor 200_2 and the transistor 200_3 by changing the number at the end of the reference numerals (the number after “_”) of the oxide 230_1, the conductor 242a1, the conductor 242b1, the insulator 250_1, the conductor 260_1, the insulator 222_1, and the insulator 275_1 in the transistor 200_1.

In the conductors functioning as the gate electrodes (the conductor 260_1 to the conductor 260_3) of the transistor 200_1 to the transistor 200_3, end portions on the side where the two transistors 200_1, the two transistors 200_2, and the two transistors 200_3 face each other are substantially aligned with each other as illustrated in FIG. 15 to FIG. 17. Meanwhile, end portions on the side where the two transistors 200_1, the two transistors 200_2, and the two transistors 200_3 do not face each other are not aligned among the transistors 200_1 to the transistors 200_3, and the end portion of the gate electrode of the transistor positioned in the lower layer is positioned more outward. That is, in the semiconductor device 200 of one embodiment of the present invention, the gate electrodes of the transistors are regarded as forming two opposite step-like shapes in a cross-sectional view in the channel width direction of the transistors (see FIG. 17).

As described above, the semiconductor device 200 illustrated in FIG. 15 to FIG. 17 includes the two transistors 200_1, the two transistors 200_2, and the two transistors 200_3. Accordingly, it can obtain a higher on-state current than the semiconductor device 200 in <Structure example 1 of semiconductor device>.

For the semiconductor device 200 illustrated in FIG. 15 to FIG. 17 other than the above, the description of the semiconductor device 200 in <Structure example 1 of semiconductor device> can be referred to.

### Structure Example 6 of Semiconductor Device

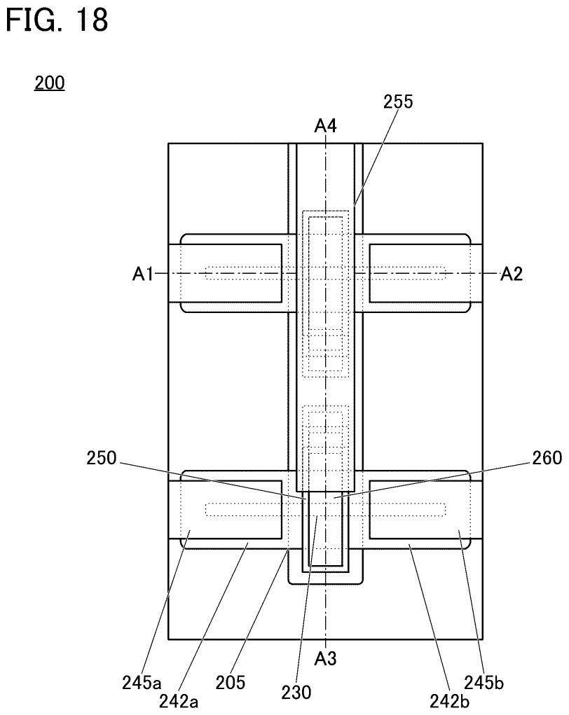

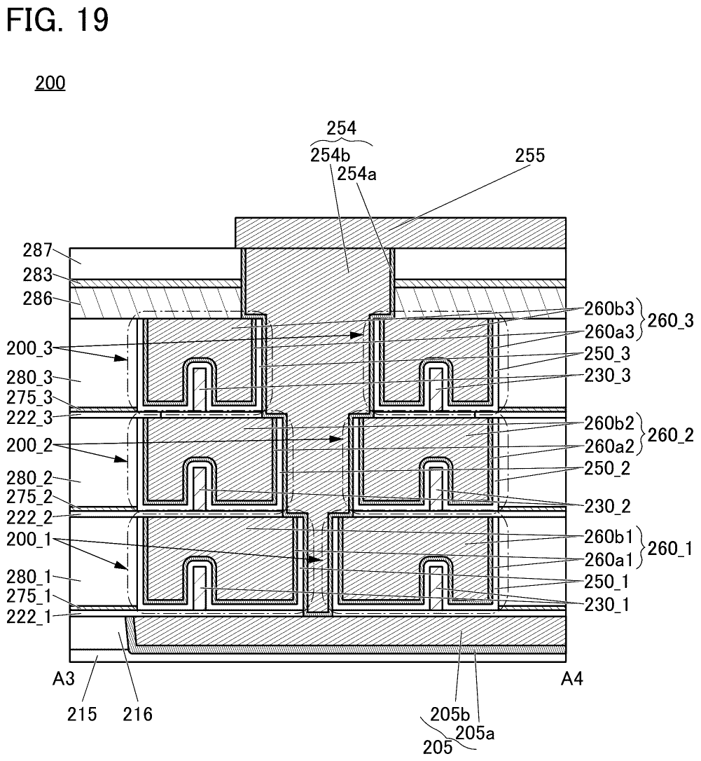

FIG. 18 and FIG. 19 illustrate a structure example of the semiconductor device 200 different from that shown in <Structure example 5 of semiconductor device>. FIG. 18 is a plan view of the semiconductor device 200. FIG. 19 is a cross-sectional view of the semiconductor device 200 along the dashed-dotted line A3-A4 in FIG. 18 (a cross-sectional view of the semiconductor device 200 corresponding to the channel width direction of the transistors). Note that FIG. 16 can be referred to for a cross-sectional view of the semiconductor device 200 along the dashed-dotted line A1-A2 in FIG. 18 (a cross-sectional view of the semiconductor device 200 corresponding to the channel length direction of the transistors).

The semiconductor device 200 illustrated in FIG. 18 and FIG. 19 is different from the semiconductor device 200 in <Structure example 5 of semiconductor device> in including only one conductor 254 functioning as a plug that electrically connects the gate electrodes (the conductors 260 and the conductors 205) of the transistors and only one conductor 255 functioning as a wiring. FIG. 18 and FIG. 19 illustrate an example in which the conductor 254 and the conductor 255 are provided between the two transistors 200_1, between the two transistors 200_2, and between the two transistors 200_3, where these transistors are provided in the channel width direction of the transistors 200_1 to the transistors 200_3. In the illustrated example, the conductor 205 and the conductor 255 extend to the A4 side.

Another difference from the semiconductor device 200 in <Structure example 5 of semiconductor device> is that the conductor 205 is shared by two oxides 230_1 provided in the channel width direction of the transistors 200_1.

For the semiconductor device 200 illustrated in FIG. 18 and FIG. 19 other than the above points, the description of the semiconductor device 200 in <Structure example 5 of semiconductor device> can be referred to.

In the semiconductor device 200 illustrated in FIG. 18 and FIG. 19, which has the above-described structure, a gate electric field can be applied to all the oxides 230 of the transistors included in the semiconductor device 200 only by one plug (the conductor 254) and one wiring (the conductor 255).

The number of conductors 254 and conductors 255 included in the semiconductor device 200 illustrated in FIG. 18 and FIG. 19 is reduced to half of the number of conductors 254 and conductors 255 included in the semiconductor device 200 in <Structure example 5 of semiconductor device>, whereby the area occupied by the semiconductor device 200 in the substrate plane can be reduced.

### Structure Example 7 of Semiconductor Device

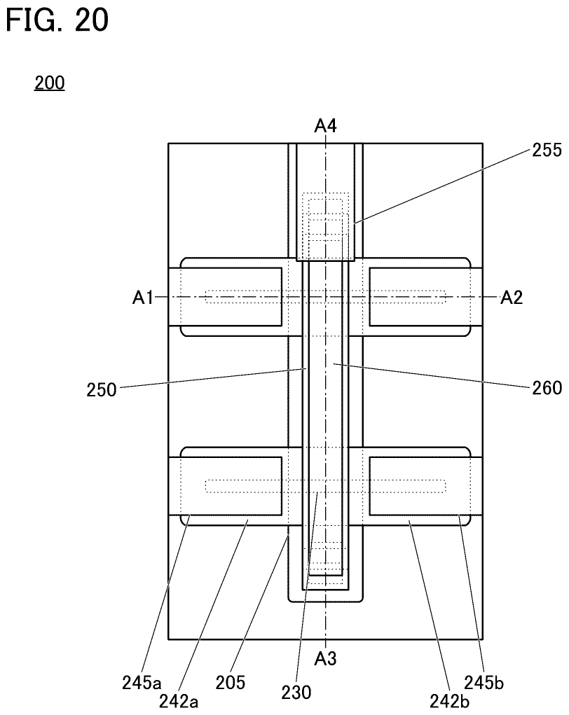

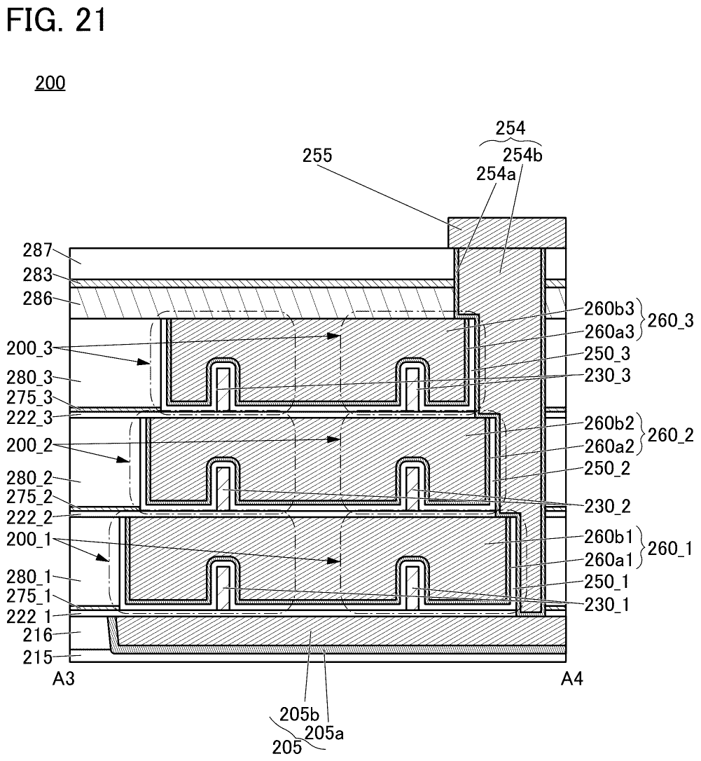

FIG. 20 and FIG. 21 illustrate a structure example of the semiconductor device 200 different from that shown in <Structure example 5 of semiconductor device>. FIG. 20 is a plan view of the semiconductor device 200. FIG. 21 is a cross-sectional view of the semiconductor device 200 along the dashed-dotted line A3-A4 in FIG. 20 (a cross-sectional view of the semiconductor device 200 corresponding to the channel width direction of the transistors). Note that FIG. 16 can be referred to for a cross-sectional view of the semiconductor device 200 along the dashed-dotted line A1-A2 in FIG. 20 (a cross-sectional view of the semiconductor device 200 corresponding to the channel length direction of the transistors).

The semiconductor device 200 illustrated in FIG. 20 and FIG. 21 is different from the semiconductor device 200 in <Structure example 5 of semiconductor device> in that one insulator 250 functioning as the first gate insulator of each transistor and one conductor 260 functioning as the first gate electrode of each transistor are shared by the two oxides 230 provided in the channel width direction of the transistors. Another difference from the semiconductor device 200 in <Structure example 5 of semiconductor device> is that one conductor 205 functioning as the second gate electrode of the transistor 200_1 is shared by the two oxides 230_1 provided in the channel width direction of the transistors 200_1.

Another difference from the semiconductor device 200 in <Structure example 5 of semiconductor device> is in including only one conductor 254 functioning as a plug that electrically connects the gate electrodes (the conductors 260 and the conductors 205) of the transistors and only one conductor 255 functioning as a wiring. FIG. 20 and FIG. 21 illustrate an example in which the conductor 254 and the conductor 255 are provided only on the A4 side in the channel width direction of the transistors and are not provided on the A3 side. In the illustrated example, the conductor 205 extends to the A4 side.

For the semiconductor device 200 illustrated in FIG. 20 and FIG. 21 other than the above points, the description of the semiconductor device 200 in <Structure example 5 of semiconductor device> can be referred to.

In the semiconductor device 200 illustrated in FIG. 20 and FIG. 21, which has the above-described structure, a gate electric field can be applied to all the oxides 230 of the transistors included in the semiconductor device 200 only by one plug (the conductor 254) and one wiring (the conductor 255).

The number of conductors 254 and conductors 255 included in the semiconductor device 200 illustrated in FIG. 20 and FIG. 21 is reduced to half of the number of conductors 254 and conductors 255 included in the semiconductor device 200 in <Structure example 5 of semiconductor device>, whereby the area occupied by the semiconductor device 200 in the substrate plane can be reduced.

In the semiconductor device 200 illustrated in FIG. 20 and FIG. 21, the insulator 280 does not need to remain between the two oxides 230 adjacent in the channel width direction. Thus, the distance between the two oxides 230 adjacent in the channel width direction can be shortened, so that the area occupied by the semiconductor device 200 in the substrate plane can be reduced.

### Structure Example 8 of Semiconductor Device

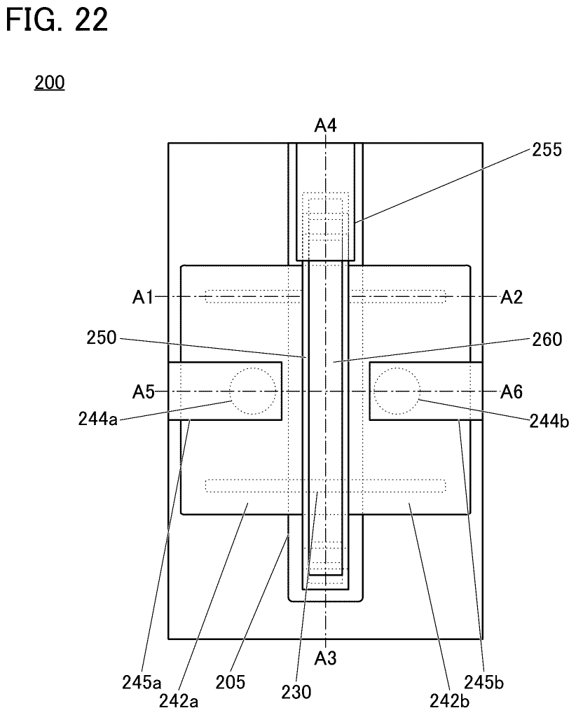

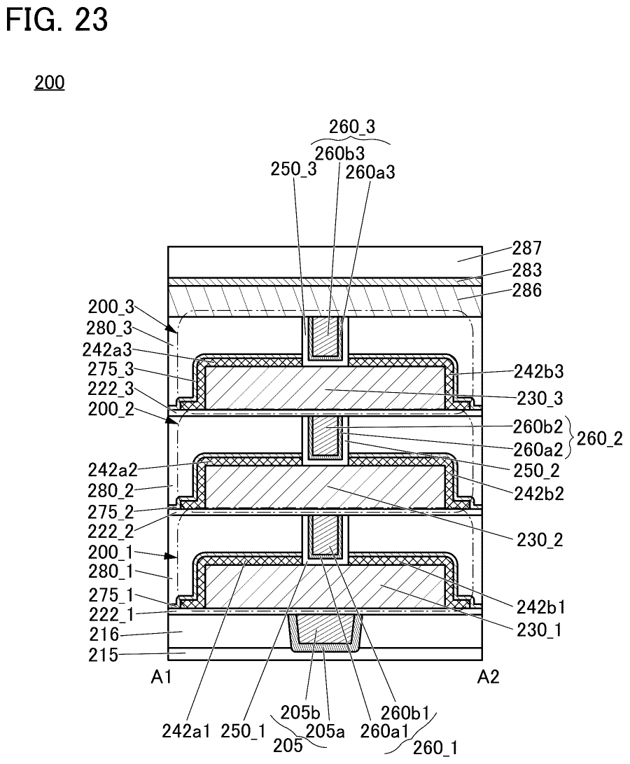

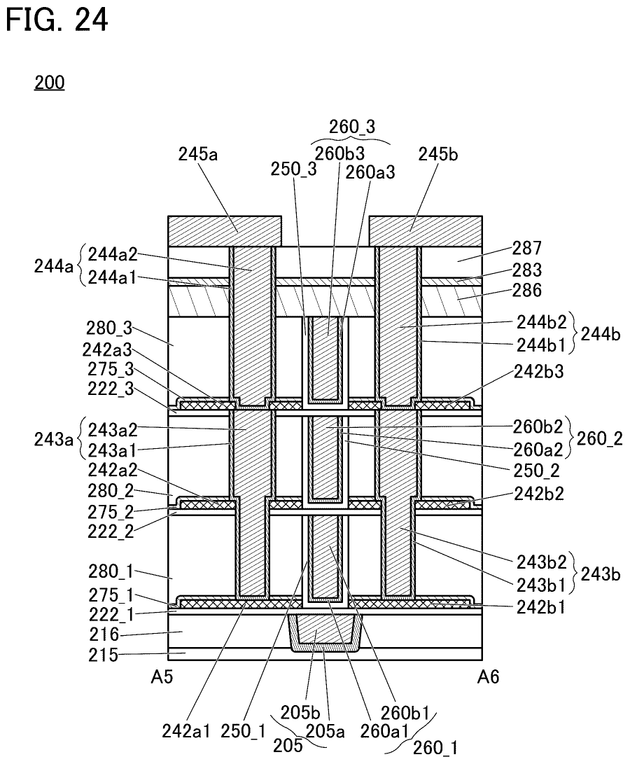

FIG. 22 to FIG. 24 illustrate a structure example of the semiconductor device 200 different from that shown in <Structure example 5 of semiconductor device>. FIG. 22 is a plan view of the semiconductor device 200. FIG. 23 is a cross-sectional view of the semiconductor device 200 along the dashed-dotted line A1-A2 in FIG. 22 (a cross-sectional view of the semiconductor device 200 corresponding to the channel length direction of the transistors). FIG. 24 is a cross-sectional view of the semiconductor device 200 along the dashed-dotted line A5-A6 in FIG. 22. Note that FIG. 21 can be referred to for a cross-sectional view of the semiconductor device 200 along the dashed-dotted line A3-A4 in FIG. 22 (a cross-sectional view of the semiconductor device 200 corresponding to the channel width direction of the transistors).

The semiconductor device 200 illustrated in FIG. 22 to FIG. 24 is different from the semiconductor device 200 in <Structure example 5 of semiconductor device> in that the conductor 242a included in one transistor 200_1 is positioned on part of the top surface and part of the side surface of the oxide 230 included in another transistor 200_1 provided in the channel width direction of the one transistor 200_1. That is, the difference from the semiconductor device 200 in <Structure example 5 of semiconductor device> is that the conductor 242a is shared by the two oxides 230_1 provided in the channel width direction of the transistors 200_1. Similarly, unlike in the semiconductor device 200 in <Structure example 5 of semiconductor device>, the conductor 242b included in one transistor 200_1 is positioned on part of the top surface and part of the side surface of the oxide 230 included in another transistor 200_1 provided in the channel width direction of the one transistor 200_1. That is, the difference from the semiconductor device 200 in <Structure example 5 of semiconductor device> is that the conductor 242b is shared by the two oxides 230_1 provided in the channel width direction of the transistors 200_1.

Unlike in the semiconductor device 200 in <Structure example 5 of semiconductor device>, the conductor 243a is in contact with a region of the conductor 242a1 that does not overlap the oxide 230_1 and a region of the conductor 242a2 that does not overlap the oxide 230_2. Similarly, unlike in the semiconductor device 200 in <Structure example 5 of semiconductor device>, the conductor 243b is in contact with a region of the conductor 242b1 that does not overlap the oxide 230_1 and a region of the conductor 242b2 that does not overlap the oxide 230_2.

Unlike in the semiconductor device 200 in <Structure example 5 of semiconductor device>, the conductor 244a is in contact with a region of the conductor 242a3 that does not overlap the oxide 230_3. Similarly, unlike in the semiconductor device 200 in <Structure example 5 of semiconductor device>, the conductor 244b is in contact with a region of the conductor 242b3 that does not overlap the oxide 230_3.

With the above structure, the transistor 200_1 to the transistor 200_3 can be connected in parallel to other transistors 200_1 to 200_3 provided in the channel width direction of the transistors 200_1 to 200_3. Thus, the semiconductor device 200 illustrated in FIG. 22 to FIG. 24 (when the transistor 200_1 to the transistor 200_3 have the same current generating capability) can output an on-state current six times as high as that in the case of including only one of the transistor 200_1 to the transistor 200_3.

FIG. 24 illustrates an example of a structure in which the conductor 244a and the conductor 243a are in contact with each other and the conductor 244b and the conductor 243b are in contact with each other, and the conductor 243a and the conductor 242a1 are in contact with each other and the conductor 243b and the conductor 242b1 are in contact with each other. Specifically, the conductor 244a is positioned in an opening formed in the insulator 287, the insulator 283, the insulator 286, the insulator 280_3, the insulator 275_3, and the conductor 242a3, and the conductor 243a is positioned in an opening formed in the insulator 222_3, the insulator 280_2, the insulator 275_2, the conductor 242a2, the insulator 222_2, the insulator 280_1, and the insulator 275_1. The conductor 244b is positioned in an opening formed in the insulator 287, the insulator 283, the insulator 286, the insulator 280_3, the insulator 275_3, and the conductor 242b3, and the conductor 243b is positioned in an opening formed in the insulator 222_3, the insulator 280_2, the insulator 275_2, the conductor 242b2, the insulator 222_2, the insulator 280_1, and the insulator 275_1.

Note that the present invention is not limited to the above structure. The conductor 244a and the conductor 243a may be electrically connected to each other through the conductor 242a3, and the conductor 244b and the conductor 243b may be electrically connected to each other through the conductor 242b3. The conductor 243a and the conductor 242a1 may be electrically connected to each other through a conductor provided between the transistor 200_1 and the transistor 200_2, and the conductor 243b and the conductor 242b1 may be electrically connected to each other through a conductor provided between the transistor 200_1 and the transistor 200_2.

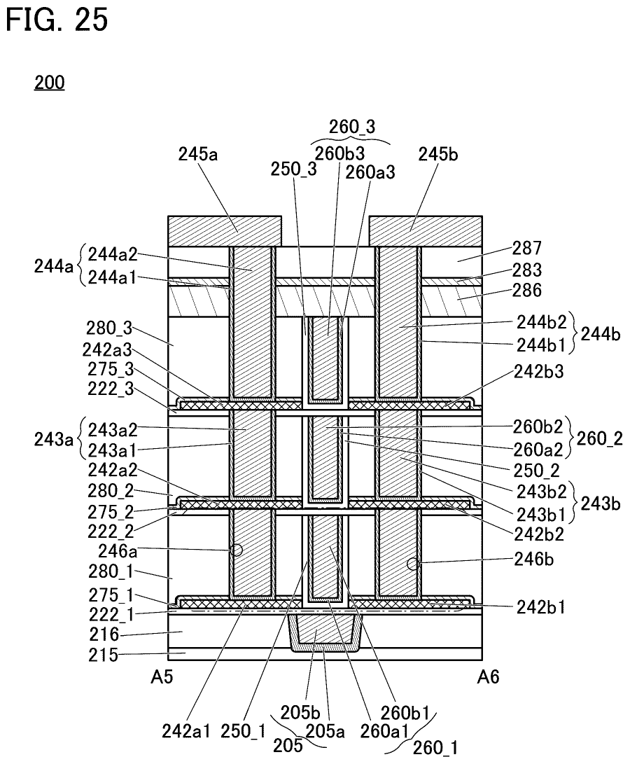

For example, as illustrated in FIG. 25, it is preferable that the conductor 244a be provided in an opening formed in the insulator 287, the insulator 283, the insulator 286, the insulator 280_3, and the insulator 275_3, the conductor 243a be provided in an opening formed in the insulator 222_3, the insulator 280_2, and the insulator 275_2, and the conductor 246a be provided in an opening formed in the insulator 222_2, the insulator 280_1, and the insulator 275_1. Similarly, it is preferable that the conductor 244b be provided in an opening formed in the insulator 287, the insulator 283, the insulator 286, the insulator 280_3, and the insulator 275_3, the conductor 243b be provided in an opening formed in the insulator 222_3, the insulator 280_2, and the insulator 275_2, and the conductor 246b be provided in an opening formed in the insulator 222_2, the insulator 280_1, and the insulator 275_1. Accordingly, the conductor 242a1 to the conductor 242a3 can be electrically connected to the conductor 245a. Similarly, the conductor 242b1 to the conductor 242b3 can be electrically connected to the conductor 245b.

With the above structure, an opening does not need to be formed in the conductor 242a2, the conductor 242b2, the conductor 242a3, and the conductor 242b3. Thus, the distance between the two transistors 200_1 provided in the channel width direction of the transistors 200_1 can be shortened, so that the area occupied by the semiconductor device 200 in the substrate plane can be reduced.

Note that FIG. 22 illustrates an example of a structure in which separate oxides 230_1 are provided in the transistors 200_1 that share the conductor 242a and the conductor 242b. Note that the present invention is not limited thereto. The oxide 230 may be provided as a continuous layer in the transistors 200_1 that share the conductor 242a and the conductor 242b.

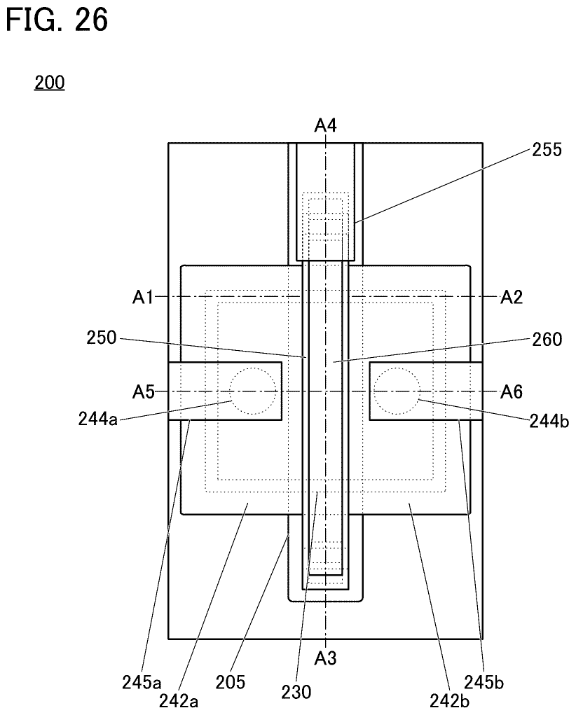

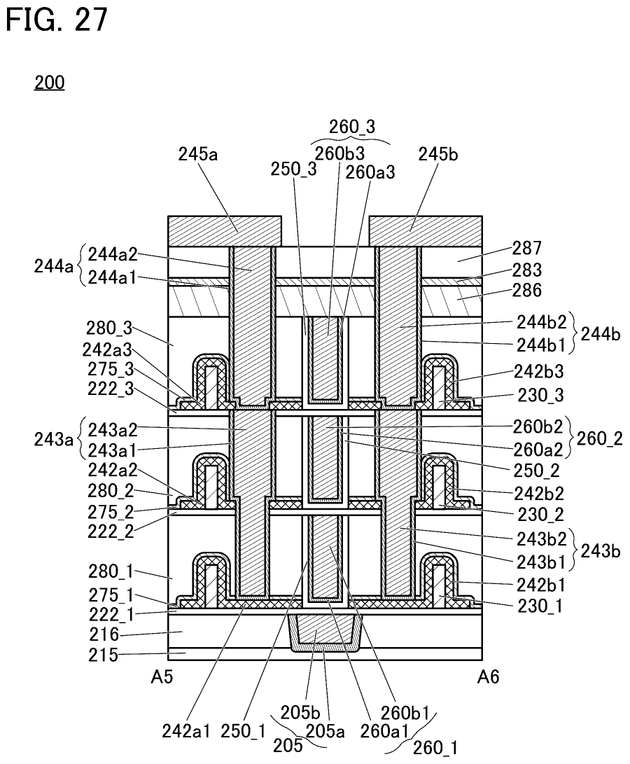

For example, as illustrated in FIG. 26, the top-view shape of the oxide 230_1 may be a quadrangular shape. Such a structure eliminates the need for a step of dividing the oxide 230_1 between the transistors 200_1 that share the conductor 242a and the conductor 242b. Thus, the total number of steps can be reduced, so that an inexpensive semiconductor device can be achieved. Note that FIG. 27 is a cross-sectional view of the semiconductor device 200 along the dashed-dotted line A5-A6 in FIG. 26.

### Constituent Materials for Semiconductor Device

Constituent materials that can be used for the semiconductor device 200 of one embodiment of the present invention will be described below. Note that each layer included in the semiconductor device 200 may have a single-layer structure or a stacked-layer structure.

### Substrate

As a substrate where the transistor included in the semiconductor device 200 is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is the above-described semiconductor substrate including an insulator region, e.g., an SOI (Silicon On Insulator) substrate. Examples of the conductor substrate include a graphite substrate, a metal substrate, an alloy substrate, and a conductive resin substrate. Other examples of substrates include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, these substrates provided with one or more kinds of elements may be used. Examples of the element provided for the substrate include a capacitor, a resistor, a switching element, a light-emitting element, and a memory element.

### Insulator

Examples of the insulator include an insulating oxide, an insulating nitride, an insulating oxynitride, an insulating nitride oxide, an insulating metal oxide, an insulating metal oxynitride, and an insulating metal nitride oxide.

As scaling down and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In contrast, when a material with a low relative permittivity is used for the insulator functioning as an interlayer film, parasitic capacitance generated between wirings can be reduced. Thus, a material is preferably selected in accordance with the function of the insulator.

Examples of the insulator with a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used. Specific examples of the insulator having a function of inhibiting passage of oxygen and impurities such as hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide and metal nitrides such as aluminum nitride, silicon nitride oxide, and silicon nitride.

The insulator functioning as a gate insulator is preferably an insulator including a region containing oxygen to be released by heating. For example, when a structure is employed in which silicon oxide or silicon oxynitride including a region containing oxygen released by heating is in contact with the oxide 230, oxygen vacancies included in the oxide 230 can be filled.

### Conductor

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. Examples of the conductor include tantalum nitride, titanium nitride, tungsten, a nitride containing titanium and aluminum, a nitride containing tantalum and aluminum, ruthenium oxide, ruthenium nitride, an oxide containing strontium and ruthenium, and an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. A semiconductor having high electrical conductivity, typified by polycrystalline silicon containing an impurity element such as phosphorus, or silicide such as nickel silicide may be used.

In the case of using a conductor having a stacked-layer structure, for example, a stacked-layer structure combining a material containing the above metal element and a conductive material containing oxygen, a stacked-layer structure combining a material containing the above metal element and a conductive material containing nitrogen, or a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### Metal Oxide

For the oxide 230, a metal oxide functioning as a semiconductor (an oxide semiconductor) is preferably used. A metal oxide that can be used for the oxide 230 of one embodiment of the present invention will be described below.

The metal oxide preferably contains at least indium or zinc. In particular, indium and zinc are preferably contained. Moreover, aluminum, gallium, yttrium, tin, antimony, or the like is preferably included in addition to them. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, the element M, and zinc is considered. The element M is aluminum, gallium, yttrium, tin, or antimony. Examples of other elements that can be used as the element M include boron, titanium, iron, nickel, germanium, zirconium, molybdenum, lanthanum, cerium, neodymium, hafnium, tantalum, tungsten, magnesium, and cobalt. Note that a combination of two or more of the above elements may be used as the element M. In particular, the element M is preferably one or more kinds selected from gallium, aluminum, yttrium, and tin.

Note that in this specification and the like, a metal oxide containing nitrogen is also collectively referred to as a metal oxide in some cases. A metal oxide containing nitrogen may be referred to as a metal oxynitride.

Hereinafter, an In—Ga—Zn oxide is described as an example of the metal oxide.

Examples of crystal structures of an oxide semiconductor include amorphous (including completely amorphous), CAAC, CAC (Cloud-Aligned Composite), single crystal, and polycrystal structures.

Note that oxide semiconductors might be classified in a manner different from the above-described one when classified in terms of the structure. For example, oxide semiconductors are classified into a single crystal oxide semiconductor and a non-single-crystal oxide semiconductor. Examples of the non-single-crystal oxide semiconductor include the above-described CAAC-OS and an nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### CAAC-OS

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of minute crystals, the maximum diameter of the crystal region may be approximately several tens of nanometers.

The CAAC-OS is an oxide semiconductor with high crystallinity in which no clear grain boundary is observed. Thus, in the CAAC-OS, a reduction in electron mobility due to the grain boundary is less likely to occur. Moreover, since the crystallinity of an oxide semiconductor might be decreased by entry of impurities, formation of defects, or the like, the CAAC-OS can also be regarded as an oxide semiconductor that has small amounts of impurities and defects (e.g., oxygen vacancies). Thus, an oxide semiconductor including the CAAC-OS is physically stable. Accordingly, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for an OS transistor can extend the degree of freedom of the manufacturing process.

nc-OS

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

a-Like OS

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

Next, the above-described CAC-OS is described in detail. Note that the CAC-OS relates to the material composition.

### CAC-OS

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size are mixed in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

In a material composition of a CAC-OS in an In—Ga—Zn oxide that contains In, Ga, Zn, and O, there are regions containing In as a main component (first regions) in part of the CAC-OS and regions containing Ga as a main component (second regions) in another part of the CAC-OS. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. In addition, in the case of forming the CAC-OS by a sputtering method, one or more selected from an inert gas (typically, argon), an oxygen gas, and a nitrogen gas can be used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

Here, the first region is a region having higher conductivity than the second region. That is, when carriers flow through the first region, the conductivity of a metal oxide is exhibited. Accordingly, when the first regions are distributed in a metal oxide like a cloud, high field-effect mobility (μ) can be achieved.

On the other hand, the second region is a region having a higher insulating property than the first region. That is, when the second regions are distributed in a metal oxide, a leakage current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Iₒₙ), high field-effect mobility (μ), and favorable switching operation can be achieved.

A transistor using the CAC-OS has high reliability. Thus, the CAC-OS is most suitably used for a variety of semiconductor devices such as display devices.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### Other Semiconductor Materials

A semiconductor material that can be used for a semiconductor layer of a transistor is not limited to the above metal oxides. A semiconductor material that has a band gap (a semiconductor material that is not a zero-gap semiconductor) may be used for the semiconductor. For example, a single-element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon atoms, nitrogen atoms, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For the semiconductor layer of the transistor, transition metal chalcogenide functioning as a semiconductor is preferably used, for example. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer of the transistor can provide a semiconductor device with a high on-state current.

### Example 1 of Method for Manufacturing Semiconductor Device

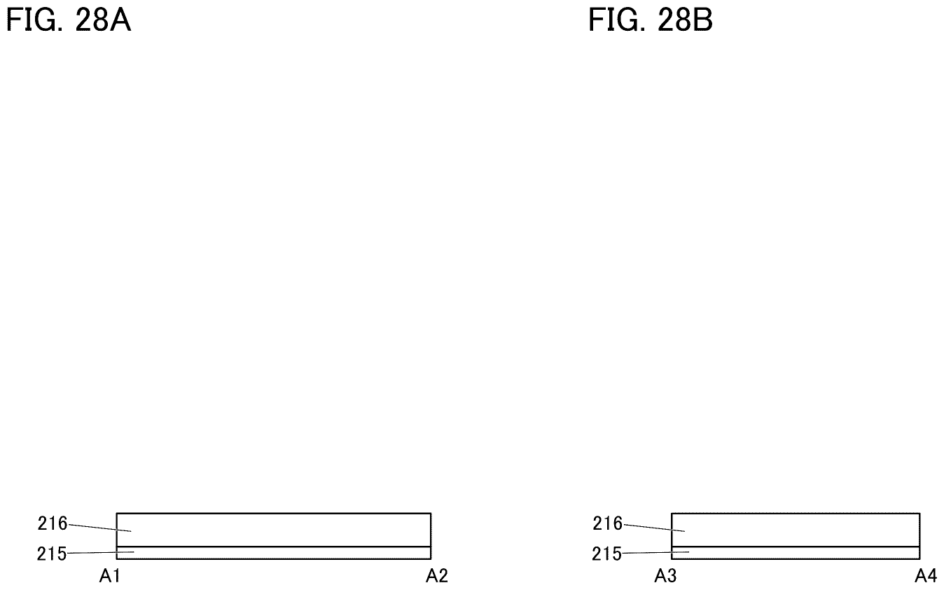

An example of a method for manufacturing the semiconductor device 200 of one embodiment of the present invention will be described with reference to FIG. 28A to FIG. 56B. Here, the case of manufacturing the semiconductor device 200 illustrated in FIG. 1A to FIG. 2 is described as an example.

In FIG. 28 to FIG. 56, A of each drawing is a cross-sectional view along the dashed-dotted line A1-A2 in FIG. 1A, and is also a cross-sectional view in the channel length direction of the transistors included in the semiconductor device 200. Moreover, B of each drawing is a cross-sectional view along the dashed-dotted line A3-A4 in FIG. 1A, and is also a cross-sectional view in the channel width direction of the transistors included in the semiconductor device 200.

Hereinafter, an insulating material for forming an insulator, a conductive material for forming a conductor, or a semiconductor material for forming a semiconductor can be deposited by a sputtering method, a chemical vapor deposition (CVD) method, a molecular beam epitaxy (MBE) method, a pulsed laser deposition (PLD) method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is formed, and a DC sputtering method is mainly used in the case where a metal conductive film is formed. A pulsed DC sputtering method is mainly used in the case where a film of a compound such as an oxide, a nitride, or a carbide is formed by a reactive sputtering method.

Note that CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object on which a film is to be formed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, a thermal CVD method, which does not use plasma, does not cause such plasma damage and thus can increase the yield of the semiconductor device. Furthermore, a film with few defects can be obtained by a thermal CVD method, which does not cause plasma damage during film formation.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, a CVD method and an ALD method are film formation methods that enable good step coverage almost regardless of the shape of an object on which a film is to be formed. In particular, an ALD method enables excellent step coverage and excellent thickness uniformity and thus is suitable for covering a surface of an opening portion with a high aspect ratio, for example. On the other hand, an ALD method has a relatively low deposition rate, and thus is preferably used in combination with another film formation method with a high deposition rate, such as a CVD method, in some cases.

By a CVD method, a film with a certain composition can be formed depending on the flow rate ratio of the source gases. For example, when the flow rate ratio of the source gases is changed during the film formation by a CVD method, a film having a continuously changed composition can be formed. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By an ALD method, a film with a certain composition can be formed by concurrently introducing different kinds of precursors. In the case where different kinds of precursors are introduced, a film with a certain composition can be formed by controlling the number of cycles for each of the precursors.

First, a substrate (not illustrated) is prepared, and the insulator 215 is deposited over the substrate. For the insulator 215, it is preferable to use the above-described insulator having a function of inhibiting passage of oxygen and impurities such as hydrogen. As the deposition method for the insulator 215, a sputtering method, a CVD method, an MBE method, a PLD method, or an ALD method can be used, for example. It is preferable to use a sputtering method that does not need to use a molecule including hydrogen as a deposition gas, in which case the hydrogen concentration in the insulator 215 can be reduced.

Next, the insulator 216 is deposited over the insulator 215 (FIG. 28A and FIG. 28B). The insulator 216 is preferably deposited by a sputtering method. By using a sputtering method, which does not need to use a molecule containing hydrogen as a deposition gas, the hydrogen concentration in the insulator 216 can be reduced. Meanwhile, without limitation to a sputtering method, the insulator 216 may be deposited by a CVD method, an MBE method, a PLD method, an ALD method, or the like as appropriate.

For example, as the insulator 216, silicon oxide is deposited by a pulsed DC sputtering method using a silicon target in an atmosphere containing an oxygen gas. The use of a pulsed DC sputtering method can achieve more uniform film thickness and improve the sputtering rate and film quality.

The insulator 215 and the insulator 216 are preferably deposited successively without exposure to the air. For example, a multi-chamber film formation apparatus is used. As a result, the amounts of hydrogen in the deposited insulator 215 and insulator 216 can be reduced, and furthermore, entry of hydrogen into the films in intervals between film formation steps can be inhibited.

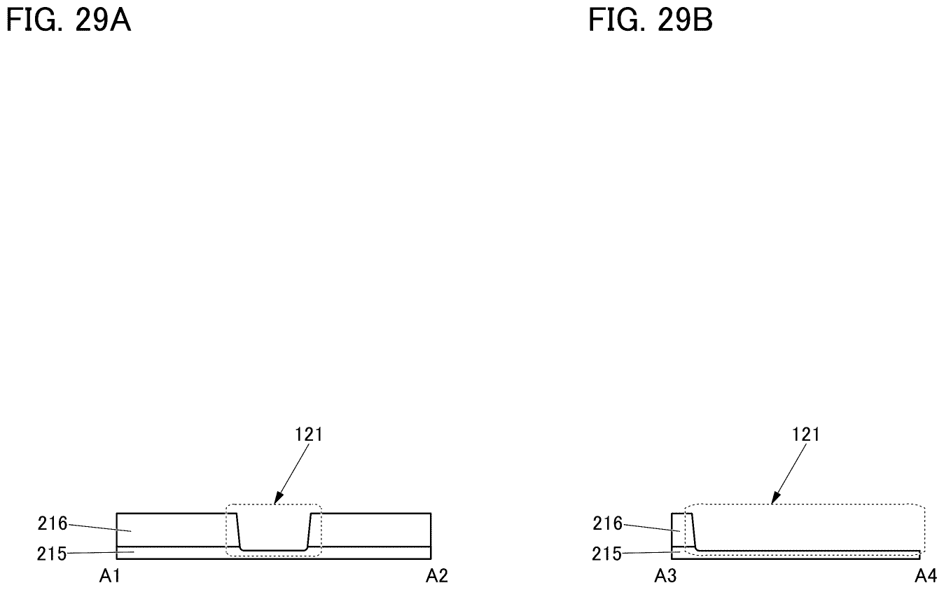

Then, an opening 121 reaching the insulator 215 is formed in the insulator 216 (FIG. 29A and FIG. 29B). A wet etching method may be used for the formation of the opening 121; however, a dry etching method is preferably used for microfabrication. As the insulator 215, it is preferable to select an insulator that functions as an etching stopper film at the time of forming a groove by etching the insulator 216. For example, in the case where silicon oxide or silicon oxynitride is used for the insulator 216 in which the groove is to be formed, silicon nitride, aluminum oxide, or hafnium oxide is preferably used for the insulator 215.

Note that at the time of forming the opening 121, the thickness of the insulator 215 in a region overlapped by the opening 121 may become smaller than the thickness of the insulator 215 in a region not overlapped by the opening 121.

After the formation of the opening 121, a conductive film to be the conductor 205a is formed. The conductive film preferably includes a conductor having a function of inhibiting passage of oxygen. For example, tantalum nitride, tungsten nitride, or titanium nitride can be used. Alternatively, a stacked film of the conductor having a function of inhibiting passage of oxygen and tantalum, tungsten, titanium, molybdenum, aluminum, copper, or a molybdenum-tungsten alloy can be used. The conductive film can be formed by a sputtering method, a CVD method, an MBE method, a PLD method, an ALD method, or the like.

For example, titanium nitride is deposited as the conductive film to be the conductor 205a. When such a metal nitride is used for the layer under the conductor 205b, oxidation of the conductor 205b by the insulator 216 or the like can be inhibited. Furthermore, even when a metal that is likely to diffuse, such as copper, is used for the conductor 205b, the metal can be prevented from diffusing to the outside through the conductor 205a.

Next, a conductive film to be the conductor 205b is formed. Tantalum, tungsten, titanium, molybdenum, aluminum, copper, a molybdenum-tungsten alloy, or the like can be used for the conductive film. The conductive film can be formed by a plating method, a sputtering method, a CVD method, an MBE method, a PLD method, an ALD method, or the like. For example, tungsten is deposited as the conductive film.

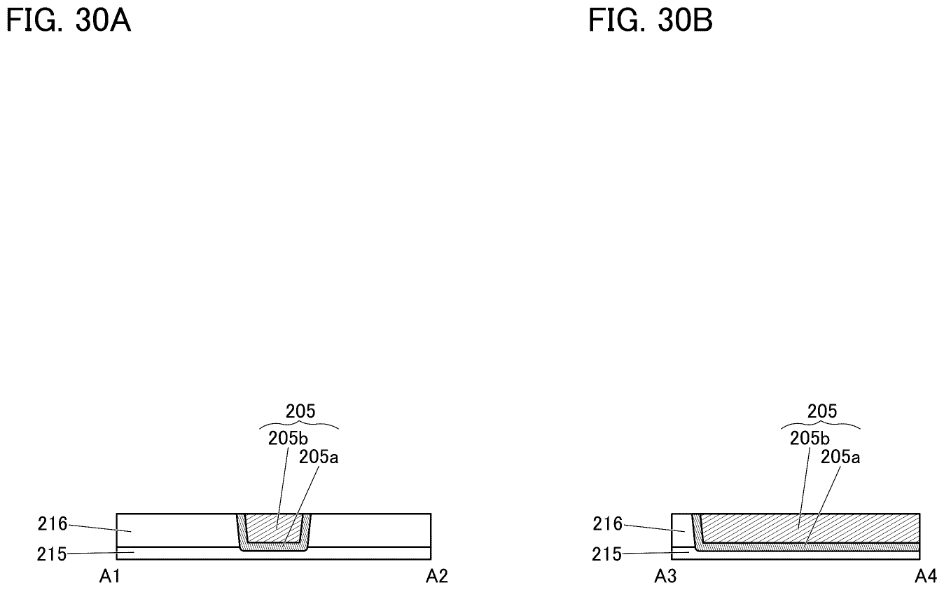

Then, chemical mechanical polishing (CMP) treatment is performed, thereby removing part of the conductive film to be the conductor 205a and part of the conductive film to be the conductor 205b and exposing the top surface of the insulator 216 (FIG. 30A and FIG. 30B). As a result, the conductor 205a and the conductor 205b remain only in the opening 121. Note that the insulator 216 is partly removed by the CMP treatment in some cases.

Subsequently, the insulator 222_1 is deposited over the insulator 216 and the conductor 205 (the conductor 205a and the conductor 205b). An insulator containing an oxide of one or both of aluminum and hafnium is preferably deposited as the insulator 222_1. Note that as the insulator containing an oxide of one or both of aluminum and hafnium, aluminum oxide, hafnium oxide, or an oxide containing aluminum and hafnium (hafnium aluminate) is preferably used, for example. Alternatively, hafnium-zirconium oxide is preferably used. The insulator containing an oxide of one or both of aluminum and hafnium has a barrier property against oxygen, hydrogen, and water. When the insulator 222_1 has a barrier property against hydrogen and water, hydrogen and water contained in components provided around the transistor are inhibited from diffusing into the transistor through the insulator 222_1, and generation of oxygen vacancies in the oxide 230 can be inhibited.

Alternatively, the insulator 222_1 can be a stacked film of an insulator containing an oxide of one or both of aluminum and hafnium and silicon oxide, silicon oxynitride, silicon nitride, or silicon nitride oxide.

The insulator 222_1 can be deposited by, for example, a sputtering method, a CVD method, an MBE method, a PLD method, or an ALD method. For example, as the insulator 222_1, hafnium oxide is deposited by an ALD method. For another example, the insulator 222_1 may have a stacked-layer structure of silicon nitride deposited by a PEALD method and hafnium oxide deposited by an ALD method.

Next, an oxide film 230A1 is formed over the insulator 222_1, and an oxide film 230B1 is formed over the oxide film 230A1. A metal oxide applicable to the oxide 230a is used for the oxide film 230A1, and a metal oxide applicable to the oxide 230b is used for the oxide film 230B1. Note that the oxide film 230A1 and the oxide film 230B1 are preferably formed successively without being exposed to an atmospheric environment. By the deposition without exposure to the air, impurities or moisture from the atmospheric environment can be prevented from being attached onto the oxide film 230A1 and the oxide film 230B1, so that the vicinity of the interface between the oxide film 230A1 and the oxide film 230B1 can be kept clean.

The oxide film 230A1 and the oxide film 230B1 can each be formed by, for example, a sputtering method, a CVD method, an MBE method, a PLD method, or an ALD method. For example, the oxide film 230A1 and the oxide film 230B1 are formed by a sputtering method.

For example, in the case where the oxide film 230A1 and the oxide film 230B1 are formed by a sputtering method, oxygen or a mixed gas of oxygen and a noble gas is used as a sputtering gas. Increasing the proportion of oxygen included in the sputtering gas can increase the amount of excess oxygen in the formed oxide films. In the case where the oxide films are formed by a sputtering method, an In-M-Zn oxide target or the like can be used.

In particular, when the oxide film 230A1 is formed, part of oxygen contained in the sputtering gas is supplied to the insulator 222_1 in some cases. Thus, the proportion of oxygen contained in the sputtering gas is preferably higher than or equal to 70%, further preferably higher than or equal to 80%, still further preferably 100%.

In the case where the oxide film 230B1 is formed by a sputtering method and the proportion of oxygen contained in the sputtering gas is higher than 30% and lower than or equal to 100%, preferably higher than or equal to 70% and lower than or equal to 100%, an oxygen-excess oxide semiconductor is formed. A transistor including an oxygen-excess oxide semiconductor in its channel formation region can have relatively high reliability. Note that one embodiment of the present invention is not limited thereto. In the case where the oxide film 230B1 is formed by a sputtering method and the proportion of oxygen contained in the sputtering gas is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in its channel formation region can have relatively high field-effect mobility. Furthermore, when the deposition is performed while the substrate is being heated, the crystallinity of the oxide film can be improved.

For example, the oxide film 230A1 is formed by a sputtering method using an oxide target with In:Ga:Zn=1:3:2 [atomic ratio] or an oxide target with In:Ga:Zn=1:3:4 [atomic ratio]. In addition, the oxide film 230B1 is formed by a sputtering method using an oxide target with In:Ga:Zn=1:1:1 [atomic ratio], an oxide target with In:Ga:Zn=1:1:1.2 [atomic ratio], an oxide target with In:Ga:Zn=4:2:4.1 [atomic ratio], or an oxide target with In:Ga:Zn=1:1:2 [atomic ratio]. Note that each of the oxide films is preferably formed so as to have characteristics required for the oxide 230a and the oxide 230b by selecting the deposition conditions and the atomic ratios as appropriate.

Note that the oxide film 230A1 and the oxide film 230B1 are preferably formed by a sputtering method without exposure to the air. For example, a multi-chamber film formation apparatus is preferably used. Thus, entry of hydrogen into the oxide film 230A1 and the oxide film 230B1 in intervals between the film formation steps can be inhibited.

When an ALD method is used as the method for forming the oxide film 230A1 and the oxide film 230B1, employing one or both of a deposition condition with a high substrate temperature and impurity removal treatment makes it possible to form films with smaller amounts of carbon and chlorine than the case of using an ALD method without employing the condition and the treatment. l

For example, impurity removal treatment is preferably performed intermittently in an oxygen-containing atmosphere during the formation of the oxide film 230A1 and the oxide film 230B1. Furthermore, impurity removal treatment is preferably performed in an oxygen-containing atmosphere after the formation of the oxide film 230A1 and the oxide film 230B1. Impurities in the films can be removed by performing impurity removal treatment during and/or after the formation of the oxide film 230A1 and the oxide film 230B1. This can inhibit impurities (e.g., hydrogen, carbon, and nitrogen) contained in a raw material such as a precursor from remaining in the oxide film 230A1 and the oxide film 230B1. Thus, the impurity concentrations in the oxide film 230A1 and the oxide film 230B1 can be reduced. Moreover, the crystallinity of the oxide film 230A1 and the oxide film 230B1 can be increased.

Examples of the impurity removal treatment include plasma treatment, microwave treatment, and heat treatment.

When plasma treatment or microwave treatment is performed, the substrate temperature is preferably higher than or equal to room temperature (e.g., 25° C.) and lower than or equal to 500° C., higher than or equal to 100° C. and lower than or equal to 500° C., higher than or equal to 200° C. and lower than or equal to 500° C., higher than or equal to 300° C. and lower than or equal to 500° C., higher than or equal to 400° C. and lower than or equal to 500° C., or higher than or equal to 400° C. and lower than or equal to 450° C., for example. The temperature of heat treatment is preferably higher than or equal to 100° C. and lower than or equal to 500° C., higher than or equal to 200 ° C. and lower than or equal to 500° C., higher than or equal to 300° C. and lower than or equal to 500° C., higher than or equal to 400° C. and lower than or equal to 500° C., or higher than or equal to 400° C. and lower than or equal to 450° C., for example.

The temperature at the time of the impurity removal treatment is particularly preferably set lower than or equal to the maximum temperature in the manufacturing process of the transistor or the semiconductor device, in which case the impurity content in the metal oxide can be reduced without a decrease in productivity. For example, when the maximum temperature in manufacturing the semiconductor device of one embodiment of the present invention is lower than or equal to 500° C., preferably lower than or equal to 450° C., the productivity of the semiconductor device can be increased.

Here, microwave treatment refers to, for example, treatment using an apparatus including a power source that generates high-density plasma with the use of a microwave. In this specification and the like, the microwave refers to an electromagnetic wave having a frequency greater than or equal to 300 MHz and less than or equal to 300 GHz. The microwave treatment can also be referred to as microwave-excited high-density plasma treatment.

Next, heat treatment is preferably performed. The heat treatment is performed in a temperature range where the oxide film 230A1 and the oxide film 230B1 do not become polycrystals. The temperature of the heat treatment is preferably higher than or equal to 100° C. and lower than or equal to 650° C., higher than or equal to 250° C. and lower than or equal to 600° C., or higher than or equal to 350° C. and lower than or equal to 550° C., for example.

Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, heat treatment may be performed in a nitrogen gas or inert gas atmosphere, and then another heat treatment may be performed in an atmosphere containing an oxidizing gas at 10 ppm or more, 1% or more, or 10% or more in order to compensate for released oxygen.

The gas used in the above heat treatment is preferably highly purified. For example, the amount of moisture contained in the gas used in the above heat treatment is preferably lower than or equal to 1 ppb, further preferably lower than or equal to 0.1 ppb, still further preferably lower than or equal to 0.05 ppb. The heat treatment using a highly purified gas can prevent entry of moisture or the like into the oxide film 230A1, the oxide film 230B1, and the like as much as possible.

For example, the heat treatment is performed at 450° C. for one hour with the flow rate ratio of a nitrogen gas to an oxygen gas being 4:1. By the heat treatment using the oxygen gas, impurities such as carbon, water, and hydrogen in the oxide film 230A1 and the oxide film 230B1 can be reduced. The reduction of impurities in the films improves the crystallinity of the oxide film 230B1, thereby offering a dense structure with higher density. Thus, crystal regions in the oxide film 230A1 and the oxide film 230B1 are expanded, so that in-plane variations of the crystal regions in the oxide film 230A1 and the oxide film 230B1 can be reduced. Accordingly, in-plane variations of electrical characteristics of the transistors can be reduced.

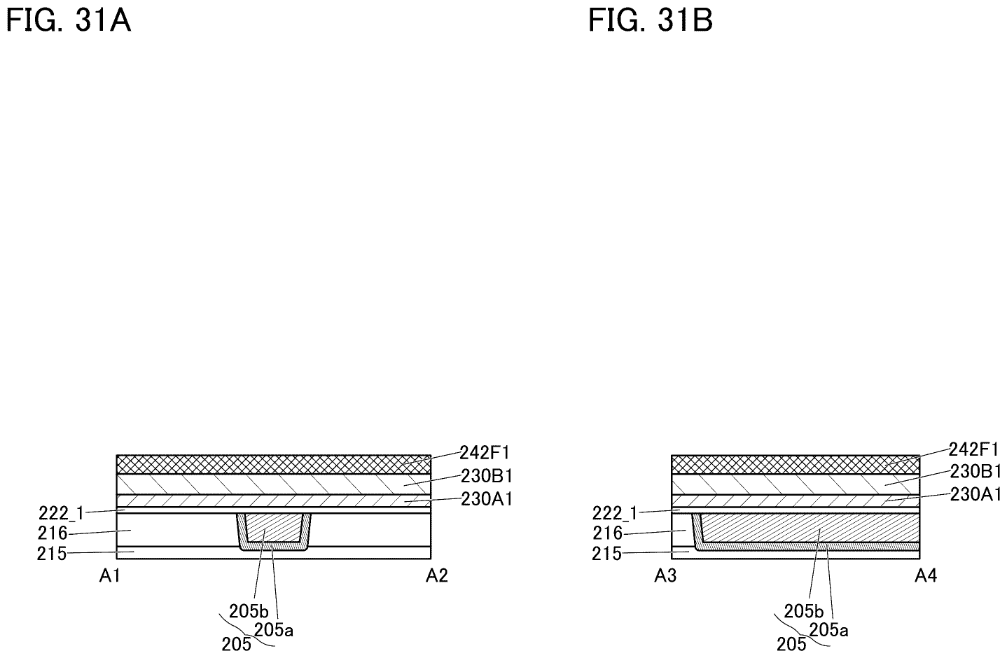

Subsequently, a conductive film 242F1 is formed over the oxide film 230B1 (FIG. 31A and FIG. 31B). For the conductive film 242F1, a conductor corresponding to the conductor 242a and the conductor 242b is used. After the formation of the oxide film 230B1, the conductive film 242F1 is formed over and in contact with the oxide film 230B1 without inserting an etching step or the like, so that the top surface of the oxide film 230B1 can be protected by the conductive film 242F1. Thus, diffusion of impurities into the oxide 230 included in the transistor can be reduced, whereby the electrical characteristics and reliability of the semiconductor device can be improved.

The conductive film 242F1 can be formed by a sputtering method, a CVD method, an MBE method, a PLD method, a plating method, or an ALD method. For example, for the conductive film 242F1, tantalum nitride is deposited by a sputtering method. Note that heat treatment may be performed before the formation of the conductive film 242F1. This heat treatment may be performed under reduced pressure, and the conductive film 242F1 may be successively formed without exposure to the air. Such treatment can remove moisture and hydrogen adsorbed onto the surface of the oxide film 230B1, and further can reduce the moisture concentrations and the hydrogen concentrations in the oxide film 230A1 and the oxide film 230B1. The temperature of the heat treatment is preferably higher than or equal to 100° C. and lower than or equal to 400° C. For example, the temperature of the heat treatment is 250° C.

Note that the conductive film 242F1 may be a stacked film. For example, in the case where a stacked-layer structure of the conductor 242a1 and the conductor 242a2 and a stacked-layer structure of the conductor 242b1 and the conductor 242b2 are employed as illustrated in FIG. 5B and the like, tantalum nitride is deposited by a sputtering method and tungsten is deposited thereover by a sputtering method as the conductive film 242F1.

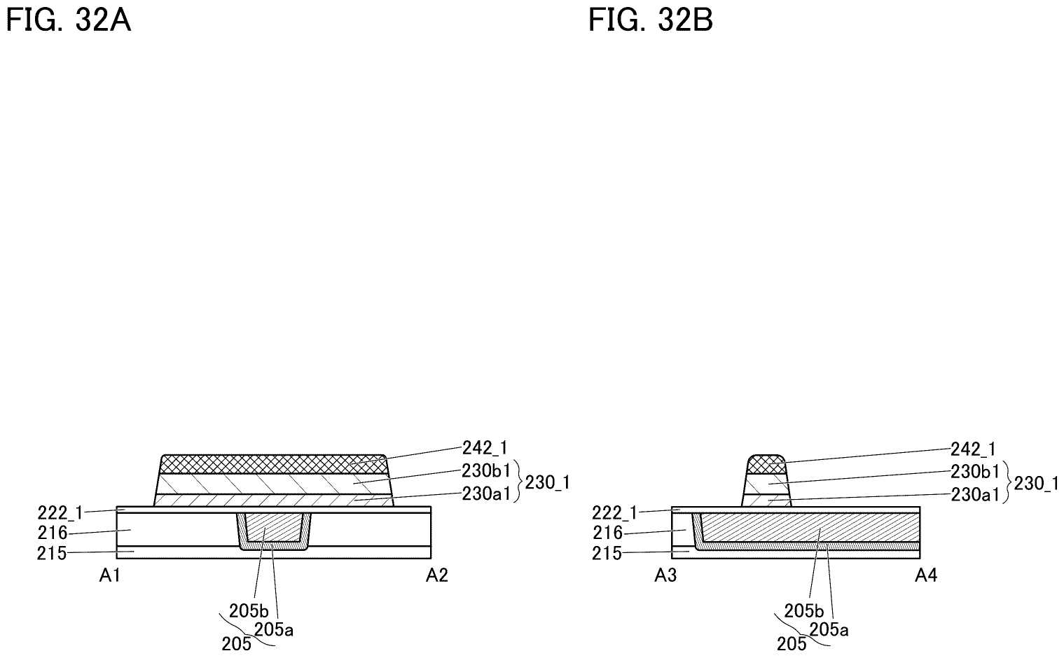

Next, the oxide film 230A1, the oxide film 230B1, and the conductive film 242F1 are processed into an island shape by a lithography method, thereby forming the oxide 230a1, the oxide 230b1, and a conductor 242_1 (FIG. 32A and FIG. 32B).

Preferably, the oxide 230a1, the oxide 230b1, and the conductor 242_1 are collectively processed into an island shape. In this case, it is preferable that the side end portion of the conductor 242_1 be substantially aligned with the side end portion of the oxide 230a1 and the side end portion of the oxide 230b1 in a planar view. With such a structure, the number of steps for the semiconductor device of one embodiment of the present invention can be reduced. Thus, a method for manufacturing a semiconductor device with high productivity can be provided.

The oxide 230a1, the oxide 230b1, and the conductor 242_1 are formed to at least partly overlap the conductor 205. The insulator 222_1 is exposed in a region not overlapped by the oxide 230a1, the oxide 230b1, and the conductor 242_1.

Although FIG. 32A and FIG. 32B illustrate the structure in which the side surfaces of the oxide 230a1, the oxide 230b1, and the conductor 242_1 are tapered, one embodiment of the present invention is not limited thereto. The side surfaces of the oxide 230a1, the oxide 230b1, and the conductor 242_1 may be substantially perpendicular to the top surface of the insulator 222_1. In the case where a plurality of transistors are provided in the substrate plane, such a structure achieves a small area and high density of the transistors.

Note that in the case where the side surfaces of the oxide 230a1, the oxide 230b1, and the conductor 242_1 are tapered, their taper angles are preferably greater than or equal to 60° and less than 90°, for example. When the side surfaces of the oxide 230a1, the oxide 230b1, and the conductor 242_1 are tapered in this manner, the coverage of these side surfaces with the insulator 275 and the like can be improved in a later step, so that generation of defects such as voids in the insulator 275 can be suppressed.

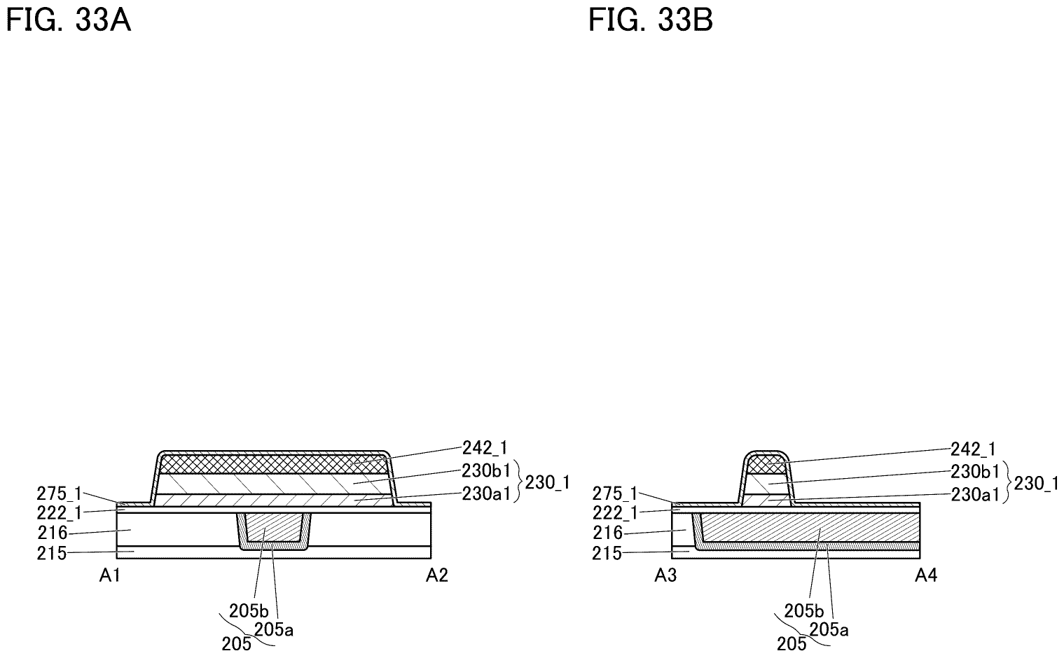

Then, the insulator 275_1 is deposited to cover the oxide 230a1, the oxide 230b1, and the conductor 242_1 (FIG. 33A and FIG. 33B). The insulator 275_1 is preferably in contact with the top surface of the insulator 222_1.

The insulator 275_1 can be deposited by, for example, a sputtering method, a CVD method, an MBE method, a PLD method, or an ALD method. For the insulator 275_1, the above-described insulator having a function of inhibiting passage of oxygen is preferably used. For example, for the insulator 275_1, silicon nitride is preferably deposited by a PEALD method. Alternatively, for the insulator 275_1, it is preferable that aluminum oxide be deposited by a sputtering method and silicon nitride be deposited thereover by a PEALD method. When the insulator 275_1 has the above-described structure, the function of inhibiting diffusion of oxygen and impurities such as water and hydrogen can be improved.

In this manner, the oxide 230a1, the oxide 230b1, and the conductor 242_1 are covered with the insulator 275_1 having a function of inhibiting diffusion of oxygen, thereby suppressing direct diffusion of oxygen into the oxide 230a1, the oxide 230b1, and the conductor 242_1 from the insulator 280 and the like in a later step.

Subsequently, the insulator 280_1 is deposited over the insulator 275_1. The insulator 280_1 can be deposited by, for example, a sputtering method, a CVD method, an MBE method, a PLD method, or an ALD method. The above-described insulators can be used for the insulator 280_1.

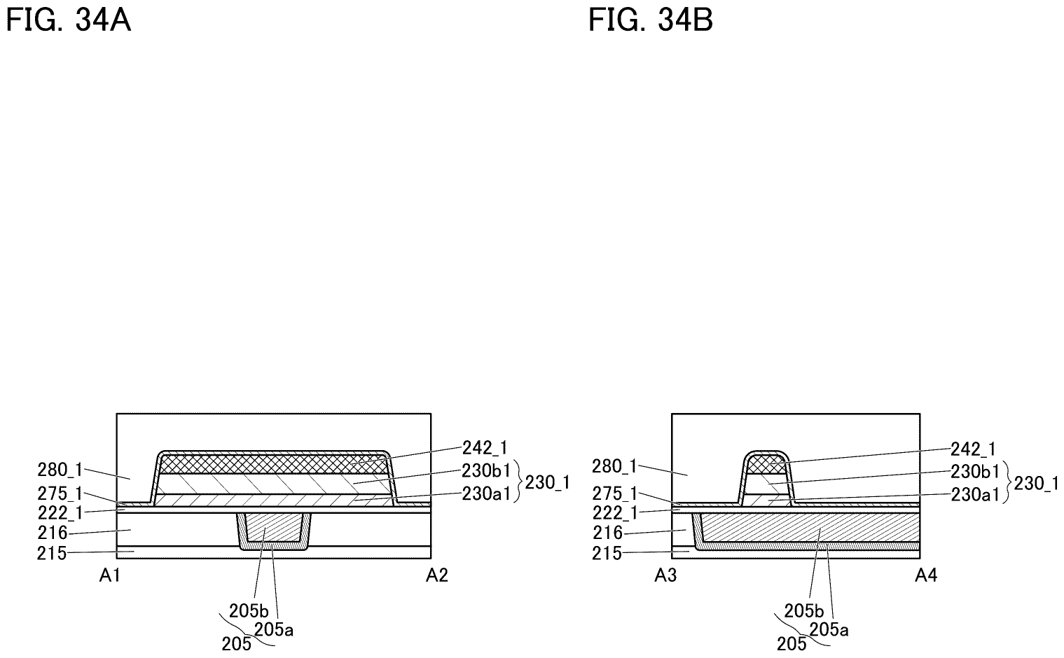

The top surface of the insulator 280_1 is preferably planarized by being subjected to CMP treatment after the deposition (FIG. 34A and FIG. 34B). Note that, for example, silicon nitride may be deposited over the insulator 280_1 by a sputtering method and CMP treatment may be performed on the silicon nitride until the insulator 280_1 is reached.

For the insulator 280_1, silicon oxide is preferably deposited by a sputtering method. When the insulator 280_1 is deposited by a sputtering method in an oxygen-containing atmosphere, the insulator 280_1 containing excess oxygen can be formed. By using a sputtering method, which does not need to use a molecule containing hydrogen as a deposition gas, the hydrogen concentration in the insulator 280_1 can be reduced. Note that heat treatment may be performed before the formation of the insulator 280_1. The heat treatment may be performed under reduced pressure, and the insulator 280_1 may be successively deposited without exposure to the air. Such treatment can remove moisture and hydrogen adsorbed onto the surface of the insulator 275_1 and the like, and further can reduce the moisture concentrations and the hydrogen concentrations in the oxide 230a1 and the oxide 230b1. Note that the temperature of the heat treatment is preferably higher than or equal to 100° C. and lower than or equal to 400° C. For example, the temperature of the heat treatment is 250° C.

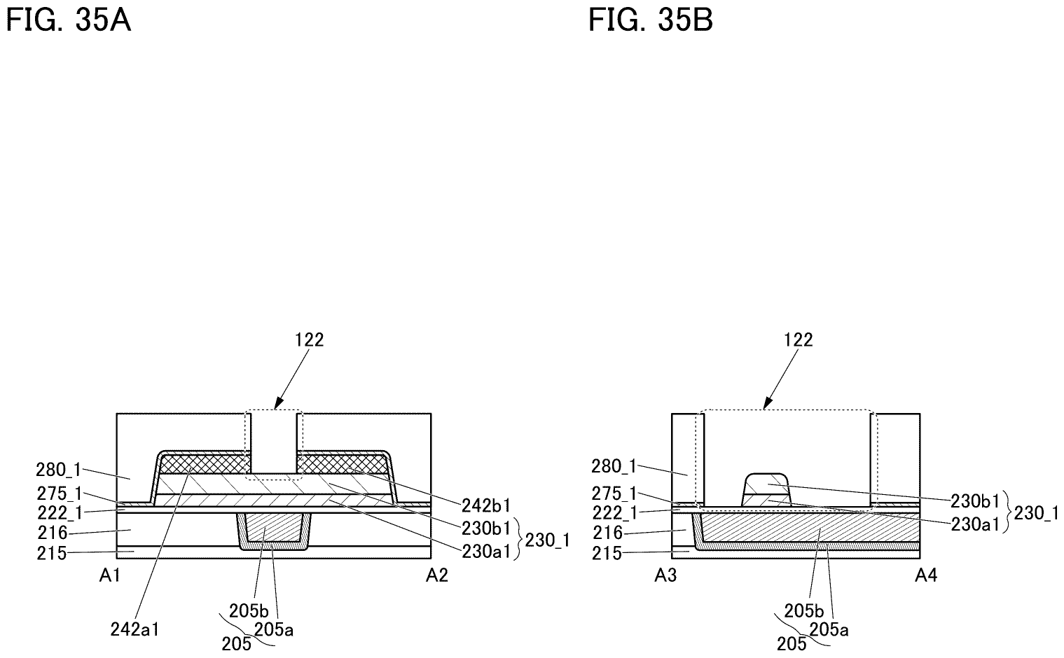

Next, the conductor 242_1, the insulator 275_1, and the insulator 280_1 are processed by a lithography method, thereby forming an opening 122 reaching the oxide 230b1 (FIG. 35A and FIG. 35B). The opening 122 reaching the oxide 230b1 is provided in a region where the oxide 230b1 and the conductor 205 overlap each other.

A dry etching method or a wet etching method can be employed for the processing. Processing by a dry etching method is suitable for microfabrication. The conductor 242_1, the insulator 275_1, and the insulator 280_1 may be processed under different conditions. In particular, in the case where a dry etching method is used for processing the conductor 242_1, an ICP etching apparatus is preferably used. In this case, the etching treatment is preferably performed by applying bias power to increase the etching rate with respect to the conductor 242_1.

By this processing, the conductor 242_1 is divided into the conductor 242a1 and the conductor 242b1 each having an island shape.

The width of the opening 122 (the width in the channel length direction of the transistor 200_1), which affects the channel length of the transistor 200_1, is preferably extremely small. For example, the width of the opening 122 is preferably greater than or equal to 1 nm and less than or equal to 60 nm, greater than or equal to 5 nm and greater than or equal to 50 nm, greater than or equal to 5 nm and less than or equal to 40 nm, greater than or equal to 5 nm and less than or equal to 30 nm, greater than or equal to 5 nm and less than or equal to 20 nm, or greater than or equal to 5 nm and less than or equal to 10 nm. When the ratio of the channel width to the channel length increases owing to an extremely small channel length of the transistor, the resistance of the channel formation region (also referred to as channel resistance) decreases, which contributes to an increase in on-state current; meanwhile, when the channel resistance decreases and the contact resistance between the semiconductor layer of the transistor and the source electrode or between the semiconductor layer of the transistor and the drain electrode exceeds the channel resistance, the contact resistance becomes a bottleneck, and a further reduction in the channel length does not result in a higher on-state current. In one embodiment of the present invention, forming the opening 122 to have a width within the above range allows the channel resistance to be kept higher than the above contact resistance; thus, the transistor 200_1 can have a high on-state current and a small size. In order to process the opening minutely as described above, a lithography method using an electron beam or short-wavelength light such as EUV light is preferably employed.

By the above etching treatment, impurities might be attached to the side surface of the oxide 230a1, the top surface and the side surface of the oxide 230b1, the side surfaces of the conductor 242a1 and the conductor 242b1, the side surface of the insulator 275_1, the side surface of the insulator 280_1, and the like or the impurities might diffuse thereinto. A step of removing the impurities may be performed. In addition, a damaged region might be formed on the surface of the oxide 230b1 by the above dry etching. Such a damaged region may be removed. The impurities come from components contained in the insulator 280_1, the insulator 275_1, the conductor 242a1, and the conductor 242b1; components contained in a member of an apparatus used to form the opening 122; and components contained in a gas or a liquid used for etching, for instance. Examples of the impurities include hafnium, aluminum, silicon, tantalum, fluorine, and chlorine.

In particular, impurities such as aluminum and silicon might reduce the crystallinity of the oxide 230b1. Thus, it is preferable that impurities such as aluminum and silicon be removed from the surface of the oxide 230b1 and the vicinity thereof. The concentration of the impurities is preferably reduced. For example, the concentration of aluminum atoms at the surface of the oxide 230b1 and the vicinity thereof is preferably lower than or equal to 5.0 atomic %, further preferably lower than or equal to 2.0 atomic %, still further preferably lower than or equal to 1.5 atomic %, yet further preferably lower than or equal to 1.0 atomic %, yet still further preferably lower than 0.3 atomic %.

Note that since the density of a crystal structure is reduced in a low-crystallinity region of the oxide 230b1 due to impurities such as aluminum and silicon, a large amount of V_{O}H is formed; thus, the transistor 200_1 is likely to have normally-on characteristics. Hence, the low-crystallinity region of the oxide 230b1 is preferably reduced or removed.

The oxide 230b1 preferably has a layered CAAC structure. In particular, the CAAC structure preferably reaches a lower end portion of the drain in the oxide 230b1. Here, in the transistor 200_1, the conductor 242a1 or the conductor 242b1 preferably functions as the drain electrode. That is, the oxide 230b1 in the vicinity of the lower end portion of the conductor 242a1 or the conductor 242b1 preferably has a CAAC structure. In this manner, the low-crystallinity region of the oxide 230b1 is removed and the CAAC structure is formed also in the end portion of the drain, which significantly affects the drain breakdown voltage; thus, a variation in electrical characteristics of the transistor 200_1 can be further suppressed. In addition, the reliability of the transistor 200_1 can be increased.

In order to remove impurities and the like attached to the surface of the oxide 230b1 in the above etching step, cleaning treatment is performed. Examples of the cleaning method include wet cleaning using a cleaning solution or the like (which can also be referred to as wet etching process) and plasma treatment using plasma, and any of these cleanings may be performed in combination as appropriate. Note that the cleaning treatment sometimes makes the opening 122 deeper.

The wet cleaning may be performed using an aqueous solution in which one or more of ammonia water, oxalic acid, phosphoric acid, and hydrofluoric acid is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

For the ultrasonic cleaning, a frequency higher than or equal to 200 kHz is preferably used, and a frequency higher than or equal to 900 kHz is further preferably used. Damage to the oxide 230b1 and the like can be reduced with such a frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the above cleaning treatment, wet cleaning using diluted ammonia water is performed, for example. The cleaning treatment can remove impurities that are attached onto the surfaces of the oxide 230a1, the oxide 230b1, and the like or diffused into the oxide 230a1, the oxide 230b1, and the like. Furthermore, the low-crystallinity portion of the oxide 230b1 can be removed to increase the crystallinity of the whole oxide 230b1.

After the etching or the cleaning, heat treatment may be performed. The heat treatment temperature is preferably higher than or equal to 100° C. and lower than or equal to 650° C., higher than or equal to 250° C. and lower than or equal to 600° C., higher than or equal to 350° C. and lower than or equal to 550° C., or higher than or equal to 350° C. and lower than or equal to 400° C., for example. Note that the heat treatment is performed in a nitrogen gas or inert gas atmosphere, or an atmosphere containing an oxidizing gas at 10 ppm or more, 1% or more, or 10% or more. For example, the heat treatment is preferably performed at 350° C. for one hour at a flow rate ratio of a nitrogen gas to an oxygen gas of 4:1. Accordingly, oxygen can be supplied to the oxide 230a1 and the oxide 230b1 to reduce oxygen vacancies. In addition, such heat treatment can improve the crystallinity of the oxide 230b1. Furthermore, hydrogen remaining in the oxide 230a1 and the oxide 230b1 reacts with supplied oxygen, so that the hydrogen can be removed in the form of H₂O (dehydration can be caused). This can inhibit recombination of hydrogen remaining in the oxide 230a1 and the oxide 230b1 with oxygen vacancies and formation of V_{O}H. The heat treatment may be performed under reduced pressure. Alternatively, heat treatment may be performed in an oxygen atmosphere, and then heat treatment may be successively performed in a nitrogen atmosphere without exposure to the air.

In the case where heat treatment is performed in the state where the conductor 242a1 and the conductor 242b1 are in contact with the oxide 230b1, the sheet resistance of the oxide 230b1 in a region overlapped by the conductor 242a1 and a region overlapped by the conductor 242b1 decreases in some cases. Furthermore, the carrier concentration sometimes increases. Thus, the resistance of the oxide 230b1 in the region overlapped by the conductor 242a1 and the region overlapped by the conductor 242b1 can be lowered in a self-aligned manner.

Note that the above heat treatment may be omitted. For example, in the case where the conductor 242a and the conductor 242b each have a stacked-layer structure as illustrated in FIG. 5B and the like and a tungsten film or the like, which is relatively easily oxidized, is used for the conductor 242a2 and the conductor 242b2, the heat treatment may be omitted. Thus, the conductor 242a2 and the conductor 242b2 can be prevented from being excessively oxidized by the heat treatment.

Next, an insulating film to be the insulator 250_1 is formed over the oxide 230b1 and the insulator 280_1. The insulating film is formed to be in contact with the sidewall and the bottom surface of the opening 122. The insulating film can be formed by a sputtering method, a CVD method, an MBE method, a PLD method, or an ALD method, for example. The insulating film is preferably formed by an ALD method. The insulating film is preferably formed to have a small thickness and needs to have a small variation in thickness. Since an ALD method is a film formation method in which a precursor and a reactant (e.g., an oxidizer) are alternately introduced and can adjust the thickness with the number of repetition times of the cycle, accurate control of the thickness is possible. Furthermore, the insulating film needs to be formed to favorably cover the bottom surface and the side surface of the opening 122. By an ALD method, atomic layers can be deposited one by one along the bottom surface and the side surface of the opening 122, whereby the insulating film can be formed in the opening 122 with favorable coverage.

In the case where the insulating film is formed by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffused into the oxide 230b1 can be reduced.

The insulating film to be the insulator 250_1 can have a stacked-layer structure as illustrated in FIG. 5A and FIG. 8A, and FIG. 5B and FIG. 8B. In the case of the structure illustrated in FIG. 5A and FIG. 8A, aluminum oxide can be deposited by a thermal ALD method as the insulating film to be the insulator 250a, silicon oxide can be deposited by a PEALD method as the insulating film to be the insulator 250b, and silicon nitride can be deposited by a PEALD method as the insulating film to be the insulator 250c. In the case of the structure illustrated in FIG. 5B and FIG. 8B, hafnium oxide can be deposited by a thermal ALD method as the insulating film to be the insulator 250d.

Then, it is preferable to perform microwave treatment in an oxygen-containing atmosphere. Note that in the case where the insulator 250_1 has a stacked-layer structure, the microwave treatment is not necessarily performed after all the insulating films to be the insulator 250_1 are formed. For example, in the case of the structure illustrated in FIG. 5A and FIG. 8A, microwave treatment may be performed after the insulating film to be the insulator 250a and the insulating film to be the insulator 250b are formed, and then the insulating film to be the insulator 250c may be formed. For example, in the case of the structure illustrated in FIG. 5B and FIG. 8B, the steps may be performed in the following order: formation of the insulating film to be the insulator 250a and the insulating film to be the insulator 250b, microwave treatment, formation of the insulating film to be the insulator 250d, microwave treatment, and formation of the insulating film to be the insulator 250c. In the above manner, microwave treatment in an oxygen-containing atmosphere may be performed a plurality of times (at least two or more times).

The microwave treatment is preferably performed with a microwave treatment apparatus including a power source for generating high-density plasma using microwaves, for example. Here, the frequency of the microwave treatment apparatus is preferably higher than or equal to 300 MHz and lower than or equal to 300 GHz, further preferably higher than or equal to 2.4 GHz and lower than or equal to 2.5 GHz, and can be set to 2.45 GHz, for example. Oxygen radicals at a high density can be generated with high-density plasma. The electric power of the power source that applies microwaves of the microwave treatment apparatus is preferably higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 230b1 efficiently.

The microwave treatment is preferably performed under reduced pressure, and the pressure is preferably higher than or equal to 10 Pa and lower than or equal to 1000 Pa, further preferably higher than or equal to 300 Pa and lower than or equal to 700 Pa. The treatment temperature is preferably lower than or equal to 750° C., further preferably lower than or equal to 500° C., and can be set to approximately 250° C., for example. The oxygen plasma treatment may be followed successively by heat treatment without exposure to the external air. The temperature of the heat treatment is preferably higher than or equal to 100° C. and lower than or equal to 750° C., further preferably higher than or equal to 300° C. and lower than or equal to 500 ° C., for example.

The microwave treatment can be performed using an oxygen gas and an argon gas, for example. Here, the oxygen flow rate ratio (O₂/(O₂+Ar)) is higher than 0% and lower than or equal to 100%, preferably higher than 0% and lower than or equal to 50%, further preferably higher than or equal to 10% and lower than or equal to 40%, still further preferably higher than or equal to 10% and lower than or equal to 30%. The carrier concentration in the oxide 230b1 can be reduced by thus performing the microwave treatment in an oxygen-containing atmosphere. In addition, the carrier concentrations in the oxide 230b1 can be prevented from being excessively reduced by preventing an excess amount of oxygen from being introduced into the chamber in the microwave treatment.

The microwave treatment in an oxygen-containing atmosphere can convert an oxygen gas into plasma using a high-frequency wave such as a microwave or RF, and apply the oxygen plasma to a region of the oxide 230b1 that is between the conductor 242a1 and the conductor 242b1. By the effect of the plasma, the microwave, or the like, V_{O}H in the region can be separated into an oxygen vacancy and hydrogen, and hydrogen can be removed from the region. Here, in the case of employing the structure illustrated in FIG. 5A and FIG. 8A or FIG. 5B and FIG. 8B, an insulating film having a function of capturing and fixing hydrogen (e.g., aluminum oxide) is preferably used as the insulating film to be the insulator 250a. With such a structure, hydrogen generated by the microwave treatment can be captured or fixed in the insulator 250a. Accordingly, V_{O}H included in the channel formation region can be reduced. In the above manner, oxygen vacancies and V_{O}H in the channel formation region can be reduced to lower the carrier concentration. In addition, oxygen radicals generated by the oxygen plasma can be supplied to oxygen vacancies formed in the channel formation region, thereby further reducing oxygen vacancies in the channel formation region and lowering the carrier concentration.

The oxygen implanted into the channel formation region has any of a variety of forms such as an oxygen atom, an oxygen molecule, an oxygen ion, and an oxygen radical (also referred to as O radical, which is an atom, a molecule, or an ion having an unpaired electron). Note that the oxygen implanted into the channel formation region has any one or more of the above forms, and is particularly preferably an oxygen radical. The film quality of the insulator 250_1 can be improved, leading to higher reliability of the transistor 200_1.

Meanwhile, the oxide 230b1 includes a region overlapped by the conductor 242a1 or the conductor 242b1. The region can function as a source region or a drain region. Here, the conductor 242a1 and the conductor 242b1 preferably function as blocking films preventing the effect caused by the high-frequency wave such as a microwave or RF, the oxygen plasma, or the like in the microwave treatment in an oxygen-containing atmosphere. Therefore, the conductor 242a1 and the conductor 242b1 preferably have a function of blocking an electromagnetic wave of greater than or equal to 300 MHz and less than or equal to 300 GHz, for example, greater than or equal to 2.4 GHz and less than or equal to 2.5 GHz.

The effect of the high-frequency wave such as a microwave or RF, the oxygen plasma, or the like is blocked by the conductor 242a1 and the conductor 242b1 and thus does not affect the region of the oxide 230b1 overlapped by the conductor 242a1 or the conductor 242b1. This prevents a reduction in V_{O}H and supply of an excess amount of oxygen in the source region and the drain region by the microwave treatment, so that the carrier concentration can be prevented from being lowered.

The insulating film to be the insulator 250_1 having a barrier property against oxygen is provided in contact with the side surfaces of the conductor 242a1 and the conductor 242b1. This can inhibit formation of oxide films on the side surfaces of the conductor 242a1 and the conductor 242b1 by the microwave treatment.

The film quality of the insulating film to be the insulator 250_1 can be improved, leading to higher reliability of the transistor 200_1.

In the above manner, oxygen vacancies and V_{O}H can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited, and the conductivity (the state of the low-resistance regions) before the microwave treatment is performed can be maintained. As a result, change in the electrical characteristics of the transistor 200_1 can be inhibited, and thus variations in the electrical characteristics of the transistors 200_1 in the substrate plane can be inhibited.

In the microwave treatment, thermal energy is directly transmitted to the oxide 230b1 in some cases owing to an electromagnetic interaction between the microwave and a molecule in the oxide 230b1. The oxide 230b1 may be heated by this thermal energy. Such heat treatment is sometimes referred to as microwave annealing. When microwave treatment is performed in an oxygen-containing atmosphere, an effect equivalent to that of oxygen annealing is sometimes obtained. In the case where hydrogen is contained in the oxide 230b1, it is probable that the thermal energy is transmitted to the hydrogen in the oxide 230b1 and the hydrogen activated by the energy is released from the oxide 230b1.

Note that microwave treatment may be performed before the formation of the insulating film to be the insulator 250_1, without the microwave treatment performed after the formation of the insulating film.

After the microwave treatment following the formation of the insulating film to be the insulator 250_1, heat treatment may be performed with the reduced pressure being maintained. Such treatment enables hydrogen in the insulating film, the oxide 230b1, and the oxide 230a1 to be removed efficiently. Part of hydrogen is gettered by the conductor 242a1 and the conductor 242b1 in some cases. Alternatively, the step of performing microwave treatment and then performing heat treatment with the reduced pressure being maintained may be repeated a plurality of cycles. The repetition of the heat treatment enables hydrogen in the insulating film, the oxide 230b1, and the oxide 230a1 to be removed more efficiently. Note that the temperature of the heat treatment is preferably higher than or equal to 300° C. and lower than or equal to 500° C. The microwave treatment, i.e., the microwave annealing, may also serve as the heat treatment. The heat treatment is not necessarily performed in the case where the oxide 230b1 and the like are adequately heated by the microwave annealing.

The microwave treatment improves the film quality of the insulating film to be the insulator 250_1, thereby inhibiting diffusion of hydrogen, water, impurities, and the like. Accordingly, hydrogen, water, impurities, and the like can be inhibited from diffusing into the oxide 230b1, the oxide 230a1, and the like through the insulator 250_1 in a later step such as formation of a conductive film to be the conductor 260_1 or later treatment such as heat treatment.

Next, a conductive film to be the conductor 260a1 and a conductive film to be the conductor 260b1 are formed in this order. The conductive film to be the conductor 260a1 and the conductive film to be the conductor 260b1 can each be formed by a sputtering method, a CVD method, an MBE method, a PLD method, a plating method, or an ALD method, for example. For instance, titanium nitride is deposited by an ALD method as the conductive film to be the conductor 260a1, and tungsten is deposited by a CVD method as the conductive film to be the conductor 260b1.

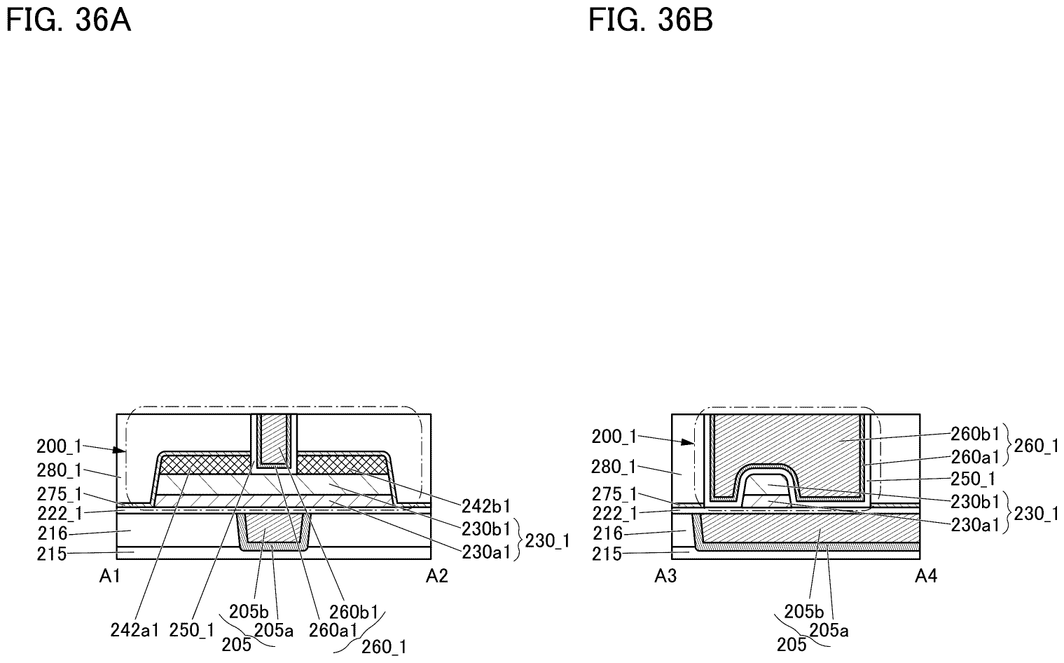

Then, the insulating film to be the insulator 250_1, the conductive film to be the conductor 260a1, and the conductive film to be the conductor 260b1 are polished by CMP treatment until the insulator 280_1 is exposed. That is, portions of the insulating film to be the insulator 250_1, the conductive film to be the conductor 260a1, and the conductive film to be the conductor 260b1 that are exposed from the opening 122 are removed. Thus, the insulator 250_1 and the conductor 260_1 (the conductor 260a1 and the conductor 260b1) are formed in the opening 122 overlapping the conductor 205 (FIG. 36A and FIG. 36B).

Accordingly, the insulator 250_1 is provided in contact with the sidewall and the bottom surface of the opening 122. The conductor 260_1 is positioned to fill the opening 122 with the insulator 250_1 therebetween. In this manner, the transistor 200_1 is formed.

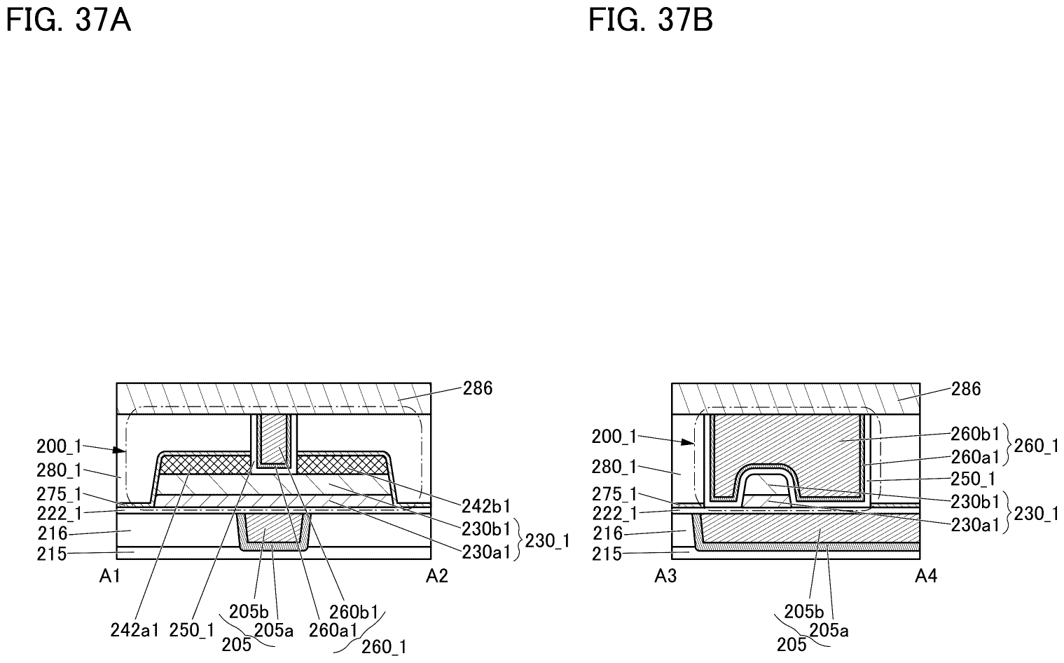

Next, the insulator 286 is formed over the insulator 250_1, the conductor 260_1, and the insulator 280_1 (FIG. 37A and FIG. 37B). The insulator 286 can be deposited by, for example, a sputtering method, a CVD method, an MBE method, a PLD method, or an ALD method. The insulator 286 is preferably deposited by a sputtering method. By using a sputtering method, which does not need to use a molecule containing hydrogen as a deposition gas, the hydrogen concentration in the insulator 286 can be reduced.

As described above, the insulator 286 preferably contains a large amount of oxygen. In that case, oxygen contained in the insulator 286 can be supplied to the insulator 280_1 during the deposition of the insulator 286 and by heat treatment after the deposition, for example. When oxygen supplied to the insulator 280_1 is supplied to the oxide 230_1, oxygen vacancies in the oxide 230_1 can be reduced. As a result, the transistor 200_1 can have favorable electrical characteristics and reliability.

For example, as the insulator 286, aluminum oxide is deposited by a pulsed DC sputtering method using an aluminum target in an atmosphere containing an oxygen gas. The use of a pulsed DC sputtering method can achieve more uniform film thickness and improve the sputtering rate and film quality. The RF power applied to the substrate is lower than or equal to 1.86 W/cm². The RF power is preferably higher than or equal to 0 W/cm² and lower than or equal to 0.62 W/cm². Note that the RF power of 0 W/cm² means no application of RF power to the substrate. The amount of oxygen implanted into a layer below the insulator 286 can be controlled depending on the amount of RF power applied to the substrate. For example, the amount of oxygen implanted into the layer below the insulator 286 decreases as the RF power decreases, and the amount of oxygen is easily saturated even when the insulator 286 has a small thickness. Moreover, the amount of oxygen implanted into the layer below the insulator 286 increases as the RF power increases. With low RF power, the amount of oxygen implanted to the insulator 280_1 can be reduced. Alternatively, the insulator 286 may have a stacked-layer structure of two layers. In this case, for example, the lower layer of the insulator 286 is formed with an RF power of 0 W/cm² applied to the substrate, and the upper layer of the insulator 286 is formed with an RF power of 0.62 W/cm² applied to the substrate.

The RF frequency is preferably 10 MHz or higher. The typical frequency is 13.56 MHz. The higher the RF frequency is, the less damage the substrate gets.

The insulator 286 is deposited by a sputtering method in an oxygen-containing atmosphere, whereby oxygen can be added to the insulator 280_1 during the deposition. Thus, excess oxygen can be contained in the insulator 280_1. At this time, the insulator 286 is preferably deposited while the substrate is being heated.

Note that heat treatment may be performed before the deposition of the insulator 286. The heat treatment may be performed under reduced pressure, and the insulator 286 may be successively deposited without exposure to the air. Such treatment can remove moisture and hydrogen adsorbed onto the surface of the insulator 280_1, and further can reduce the moisture concentration and the hydrogen concentration in the insulator 280_1. The temperature of the heat treatment is preferably higher than or equal to 100° C. and lower than or equal to 400° C. For example, the temperature of the heat treatment is 250° C.

Subsequently, the insulator 286 is removed. A dry etching method, a wet etching method, or CMP can be used to remove the insulator 286. By the removal, the top surface of the insulator 250_1, the top surface of the conductor 260_1, and the top surface of the insulator 280_1 are exposed.

Note that the insulator 286 may be used as the insulator 222_2 without being removed. Alternatively, the insulator 286 that is thinned by being partly removed may be used as the insulator 222_2 or part of the insulator 222_2.

Note that oxygen may be supplied to the insulator 280_1 by oxygen plasma treatment or the like. At this time, the insulator 286 is not necessarily formed in some cases.

Next, the insulator 222_2 is formed in contact with the top surface of the insulator 250_1, the top surface of the conductor 260_1, and the top surface of the insulator 280_1. The above description of the insulator 222_1 can be referred to for a material, a formation method, and the like that can be used for the insulator 222_2.

Then, an oxide film 230A2 is formed over the insulator 222_2, and an oxide film 230B2 is formed over the oxide film 230A2. The above description of the oxide film 230A1 can be referred to for a material, a formation method, and the like that can be used for the oxide film 230A2. The above description of the oxide film 230B1 can be referred to for a material, a formation method, and the like that can be used for the oxide film 230B2.

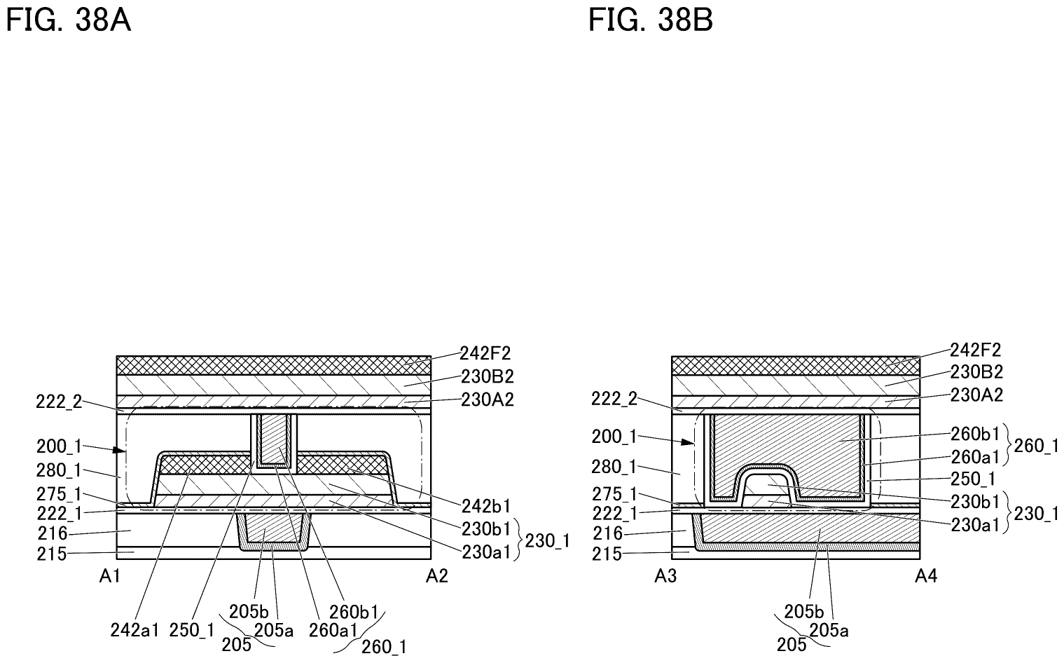

Next, a conductive film 242F2 is formed over the oxide film 230B2 (FIG. 38A and FIG. 38B). The above description of the conductive film 242F1 can be referred to for a material, a formation method, and the like that can be used for the conductive film 242F2.

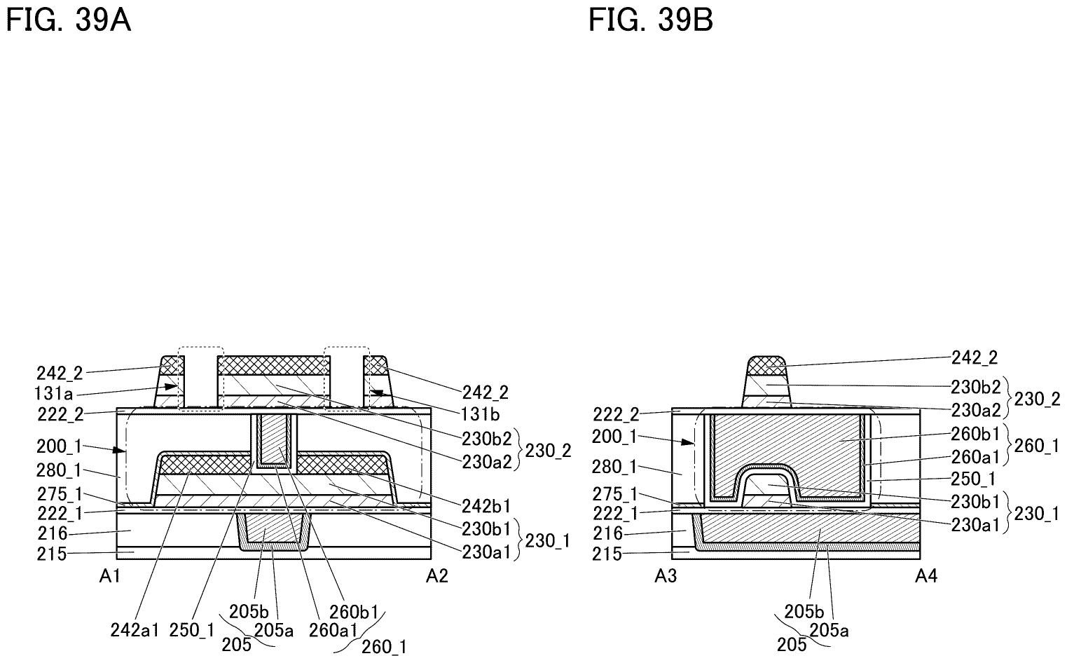

Subsequently, the oxide film 230A2, the oxide film 230B2, and the conductive film 242F2 are processed into an island shape by a lithography method, thereby forming the oxide 230a2, the oxide 230b2, and a conductor 242_2 (FIG. 39A and FIG. 39B). The oxide 230a2, the oxide 230b2, and the conductor 242_2 are formed to at least partly overlap the conductor 260_1. The above description of the processing method and the like for the oxide 230a1, the oxide 230b1, and the conductor 242_1 can be referred to for the processing method and the like for the oxide 230a2, the oxide 230b2, and the conductor 242_2. By the processing, an opening 131a is formed in a region overlapping the conductor 242a1 and an opening 131b is formed in a region overlapping the conductor 242b1. The insulator 222_2 is exposed in a region that is not overlapped by the oxide 230a2, the oxide 230b2, or the conductor 242_2 (e.g., a region overlapped by the opening 131a or the opening 131b).

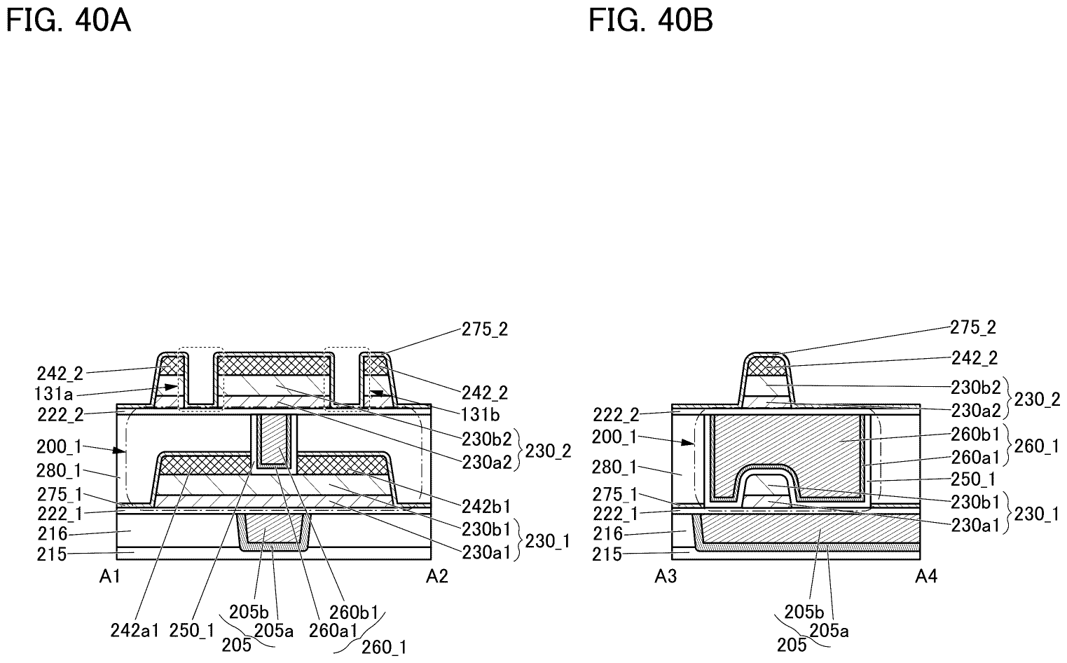

Then, the insulator 275_2 is deposited to cover the oxide 230a2, the oxide 230b2, and the conductor 242_2 (FIG. 40A and FIG. 40B). The insulator 275_2 is provided in contact with the sidewalls and the bottom surfaces of the opening 131a and the opening 131b. The insulator 275_2 includes a region in contact with the side surface of the oxide 230a2, the side surface of the oxide 230b2, the side surface and the top surface of the conductor 242_2, and the top surface of the insulator 222_2. Note that the above description of the insulator 275_1 can be referred to for a material, deposition conditions, and the like that can be used for the insulator 275_2.

Next, the insulator 280_2 is deposited over the insulator 275_2. The above description of the insulator 280_1 can be referred to for a material, deposition conditions, and the like that can be used for the insulator 280_2.

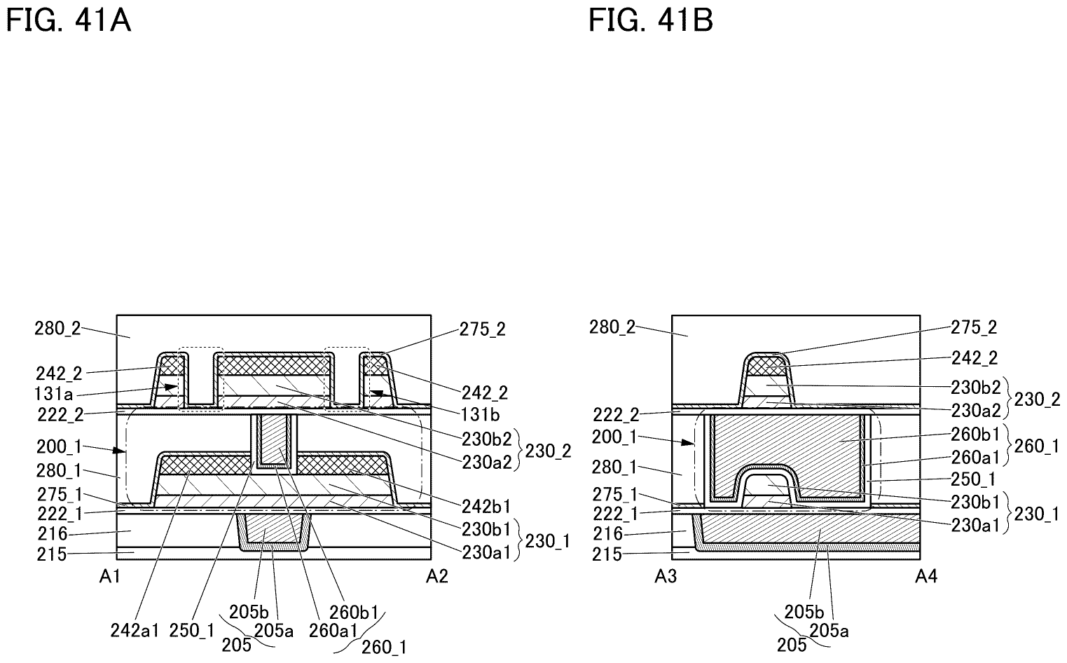

The top surface of the insulator 280_2 is preferably planarized by being subjected to CMP treatment after the deposition (FIG. 41A and FIG. 41B). Note that, for example, silicon nitride may be deposited over the insulator 280_2 by a sputtering method and CMP treatment may be performed on the silicon nitride until the insulator 280_2 is reached.

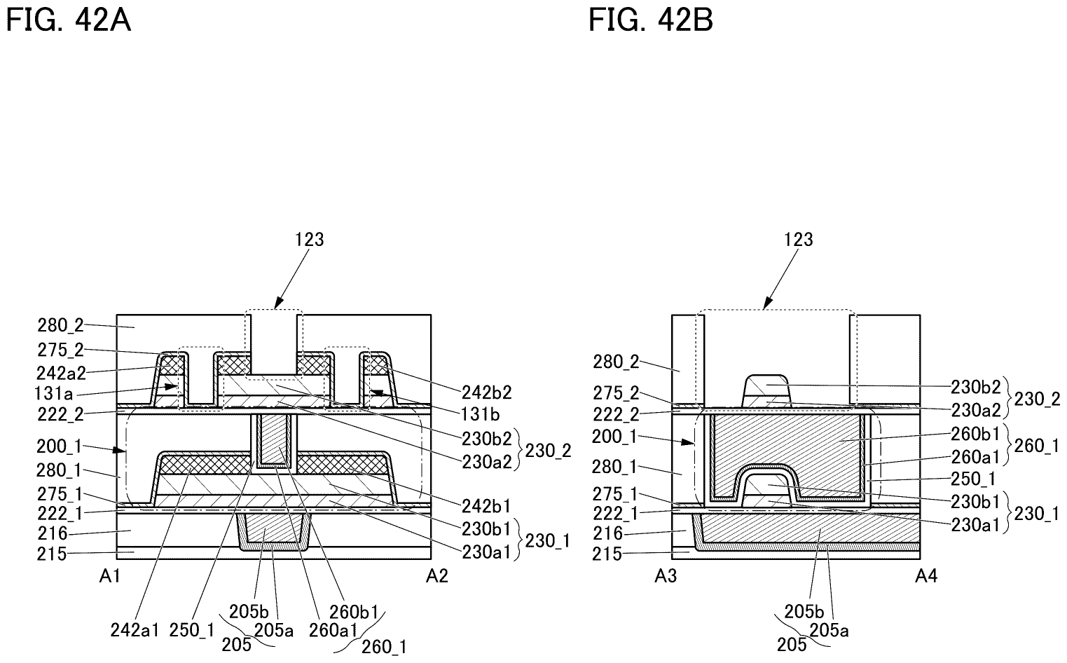

Then, the conductor 242_2, the insulator 275_2, and the insulator 280_2 are processed by a lithography method, thereby forming an opening 123 reaching the oxide 230b2 (FIG. 42A and FIG. 42B). The opening 123 is provided in a region where the oxide 230b2 and the conductor 260_1 overlap each other. The above description of the formation method and the like for the opening 122 can be referred to for the formation method and the like for the opening 123.

By this processing, the conductor 242_2 is divided into the conductor 242a2 and the conductor 242b2 each having an island shape.

The width of the opening 123 (the width in the channel length direction of the transistor 200_2), which affects the channel length of the transistor 200_2, is preferably extremely small. For example, the width of the opening 123 is preferably greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, greater than or equal to 1 nm and less than or equal to 10 nm, or greater than or equal to 5 nm and less than or equal to 10 nm. In order to process the opening minutely as described above, a lithography method using an electron beam or short-wavelength light such as EUV light is preferably employed.

Next, an insulating film to be the insulator 250_2 is formed over the oxide 230b2 and the insulator 280_2. The insulating film is formed to be in contact with the sidewall and the bottom surface of the opening 123. The above description of the material, the formation method, and the like that can be used for the insulating film to be the insulator 250_1 can be referred to for a material, a formation method, and the like that can be used for the insulating film to be the insulator 250_2.

Subsequently, a conductive film to be the conductor 260a2 and a conductive film to be the conductor 260b2 are formed in this order. The above description of the materials, the formation methods, and the like that can be used for the conductive film to be the conductor 260a1 and the conductive film to be the conductor 260b1 can be referred to for materials, formation methods, and the like that can be used for the conductive film to be the conductor 260a2 and the conductive film to be the conductor 260b2.

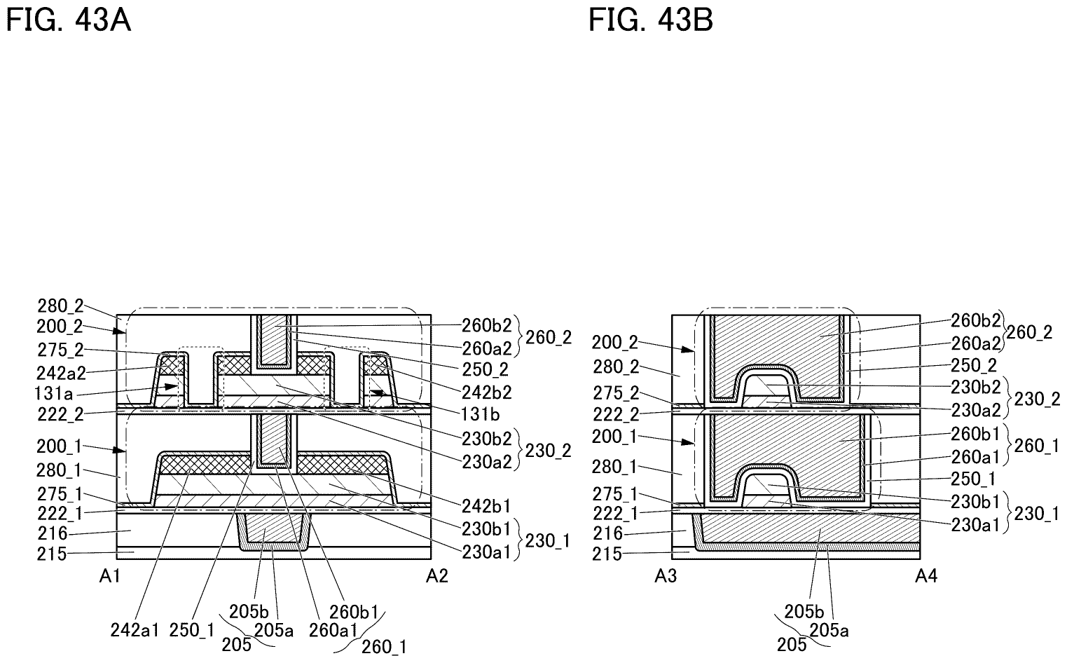

Then, the insulating film to be the insulator 250_2, the conductive film to be the conductor 260a2, and the conductive film to be the conductor 260b2 are polished by CMP treatment until the insulator 280_2 is exposed. That is, portions of the insulating film to be the insulator 250_2, the conductive film to be the conductor 260a2, and the conductive film to be the conductor 260b2 that are exposed from the opening 123 are removed. Thus, the insulator 250_2 and the conductor 260_2 (the conductor 260a2 and the conductor 260b2) are formed in the opening 123 overlapping the conductor 260_1 (FIG. 43A and FIG. 43B).

Accordingly, the insulator 250_2 is provided in contact with the sidewall and the bottom surface of the opening 123. The conductor 260_2 is positioned to fill the opening 123 with the insulator 250_2 therebetween. In this manner, the transistor 200_2 is formed.

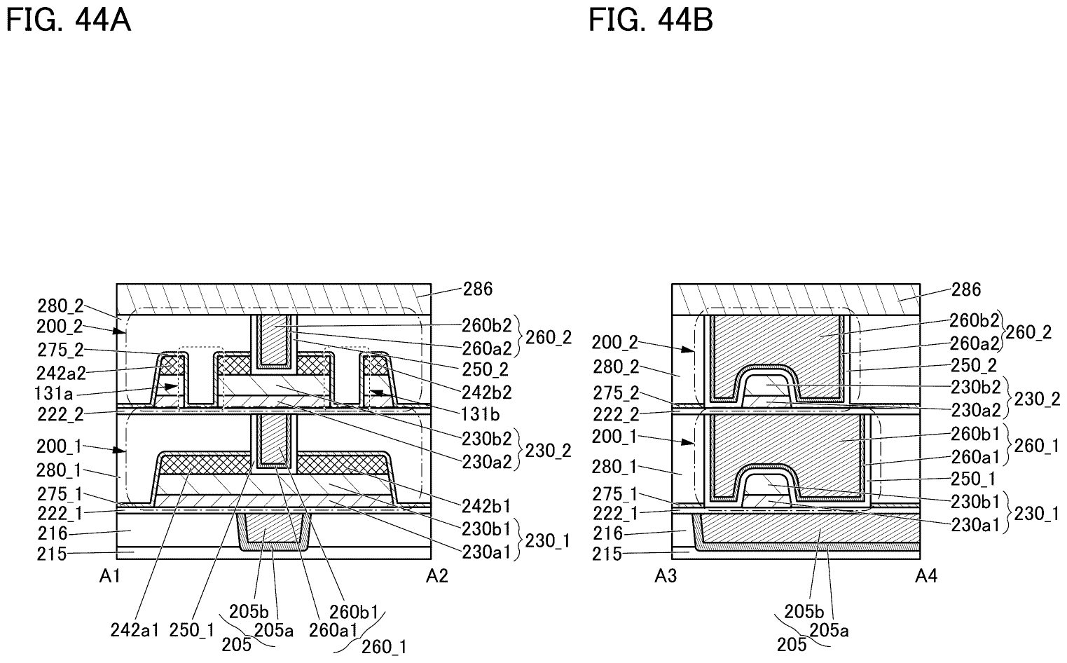

Next, the insulator 286 is formed over the insulator 250_2, the conductor 260_2, and the insulator 280_2 (FIG. 44A and FIG. 44B). The above description can be referred to for a material, a formation method, and the like that can be used for the insulator 286.

Then, the insulator 286 is removed. A dry etching method, a wet etching method, or CMP can be used to remove the insulator 286. By the removal, the top surface of the insulator 250_2, the top surface of the conductor 260_2, and the top surface of the insulator 280_2 are exposed.

Note that the insulator 286 may be used as the insulator 222_3 without being removed. Alternatively, the insulator 286 that is thinned by being partly removed may be used as the insulator 222_3 or part of the insulator 222_3.

Note that oxygen may be supplied to the insulator 280_2 by oxygen plasma treatment or the like. At this time, the insulator 286 is not necessarily formed in some cases.

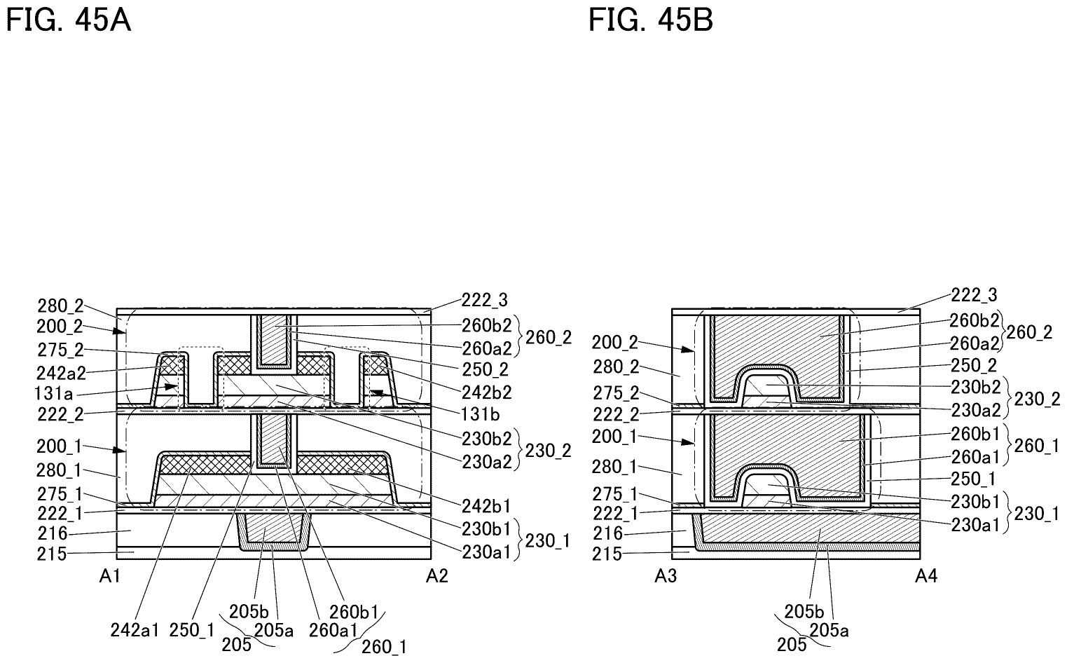

Next, the insulator 222_3 is formed in contact with the top surface of the insulator 250_2, the top surface of the conductor 260_2, and the top surface of the insulator 280_2 (FIG. 45A and FIG. 45B). The above description of the insulator 222_1 can be referred to for a material, a formation method, and the like that can be used for the insulator 222_3.

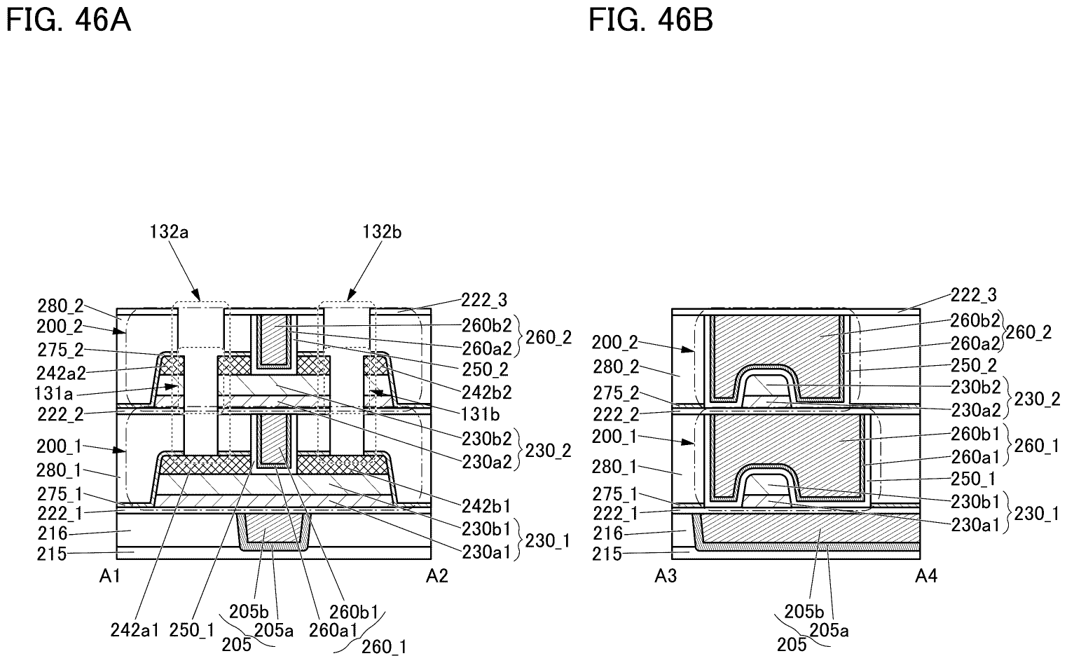

Subsequently, the insulator 222_3, the insulator 280_2, the insulator 275_2, the insulator 222_2, the insulator 280_1, and the insulator 275_1 are processed by a lithography method, whereby an opening 132a reaching the conductor 242a1 is formed in a region overlapping the opening 131a and an opening 132b reaching the conductor 242b1 is formed in a region overlapping the opening 131b (FIG. 46A and FIG. 46B). A dry etching method or a wet etching method can be used for the processing. By the processing, regions of the insulator 275_2 that are in contact with the sidewalls of the opening 131a and the opening 131b are removed.

As described above, the opening 132a is formed in the region overlapping the opening 131a. The opening 132b is formed in the region overlapping the opening 131b. Thus, the opening 131a can be regarded as being included in the opening 132a. The opening 131b can be regarded as being included in the opening 132b. Since the opening 131a and the opening 131b are formed in advance in the respective regions where the opening 132a or the opening 132b is to be formed, the opening 132a and the opening 132b that reach the conductor 242a1 and the conductor 242b1, respectively, can be easily processed.

In order to form the opening 132a to overlap the opening 131a, the maximum diameter of the opening 132a in a planar view is preferably larger than the maximum diameter of the opening 131a in a planar view. In order to form the opening 132b to overlap the opening 131b, the maximum diameter of the opening 132b in a planar view is preferably larger than the maximum diameter of the opening 131b in a planar view. Here, part of a region of the insulator 275_2 over the conductor 242a2 and part of a region thereof over the conductor 242b2 are removed.

Note that the opening 132a corresponds to the above-described first opening, and the opening 132b corresponds to the above-described second opening.

Then, a conductive film to be the conductor 243a1 and the conductor 243b1 is formed over the conductor 242a1, the conductor 242b1, and the insulator 222_3. The conductive film is formed to be in contact with the sidewalls and the bottom surfaces of the opening 132a and the opening 132b. The description of the material, the formation method, and the like that can be used for the conductive film to be the conductor 260a1, for example, can be referred to for a material, a formation method, and the like that can be used for the conductive film to be the conductor 243a1 and the conductor 243b1.

Next, a conductive film to be the conductor 243a2 and the conductor 243b2 is formed over the conductive film to be the conductor 243a1 and the conductor 243b1. The description of the material, the formation method, and the like that can be used for the conductive film to be the conductor 260b1, for example, can be referred to for a material, a formation method, and the like that can be used for the conductive film to be the conductor 243a2 and the conductor 243b2.

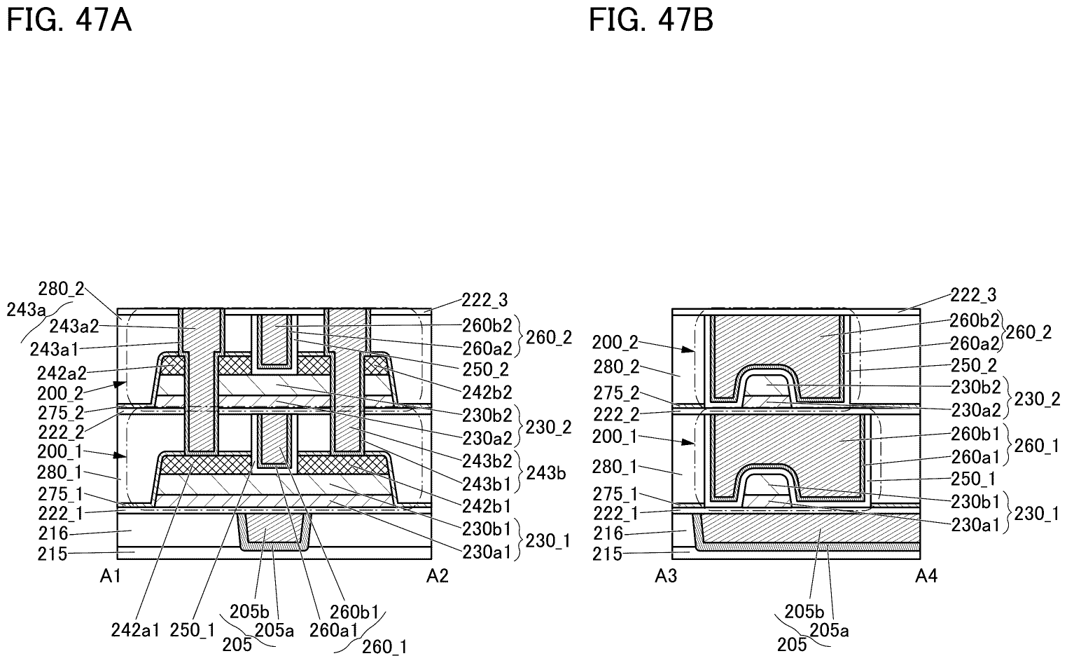

Subsequently, the conductive film to be the conductor 243a1 and the conductor 243b1 and the conductive film to be the conductor 243a2 and the conductor 243b2 are polished by CMP treatment until the insulator 222_3 is exposed. That is, portions of the conductive film to be the conductor 243a1 and the conductor 243b1 and the conductive film to be the conductor 243a2 and the conductor 243b2 that are exposed from the opening 132a and the opening 132b are removed. Thus, the conductor 243a (the conductor 243a1 and the conductor 243a2) is formed in the opening 132a. Moreover, the conductor 243b (the conductor 243b1 and the conductor 243b2) is formed in the opening 132b (FIG. 47A and FIG. 47B).

Accordingly, the conductor 242a1 and the conductor 242a2 are electrically connected to each other through the conductor 243a. The conductor 242b1 and the conductor 242b2 are electrically connected to each other through the conductor 243b.

Next, an oxide film 230A3 is formed over the conductor 243a, the conductor 243b, and the insulator 222_3, and an oxide film 230B3 is formed over the oxide film 230A3. The above description of the oxide film 230A1 can be referred to for a material, a formation method, and the like that can be used for the oxide film 230A3. The above description of the oxide film 230B1 can be referred to for a material, a formation method, and the like that can be used for the oxide film 230B3.

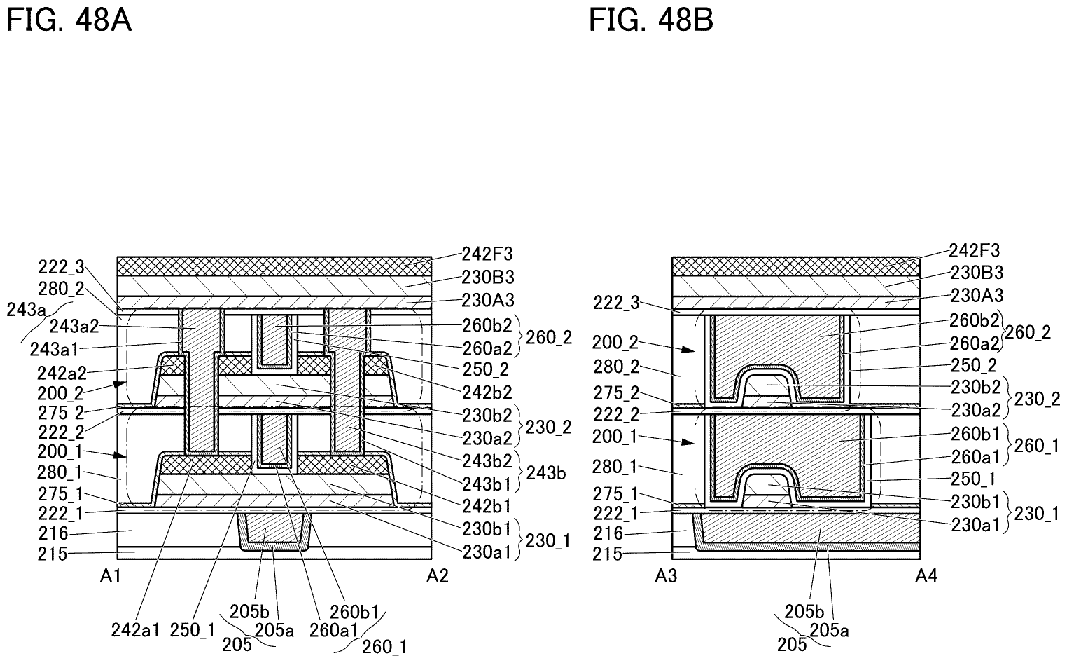

Then, a conductive film 242F3 is formed over the oxide film 230B3 (FIG. 48A and FIG. 48B). The above description of the conductive film 242F1 can be referred to for a material, a formation method, and the like that can be used for the conductive film 242F3.

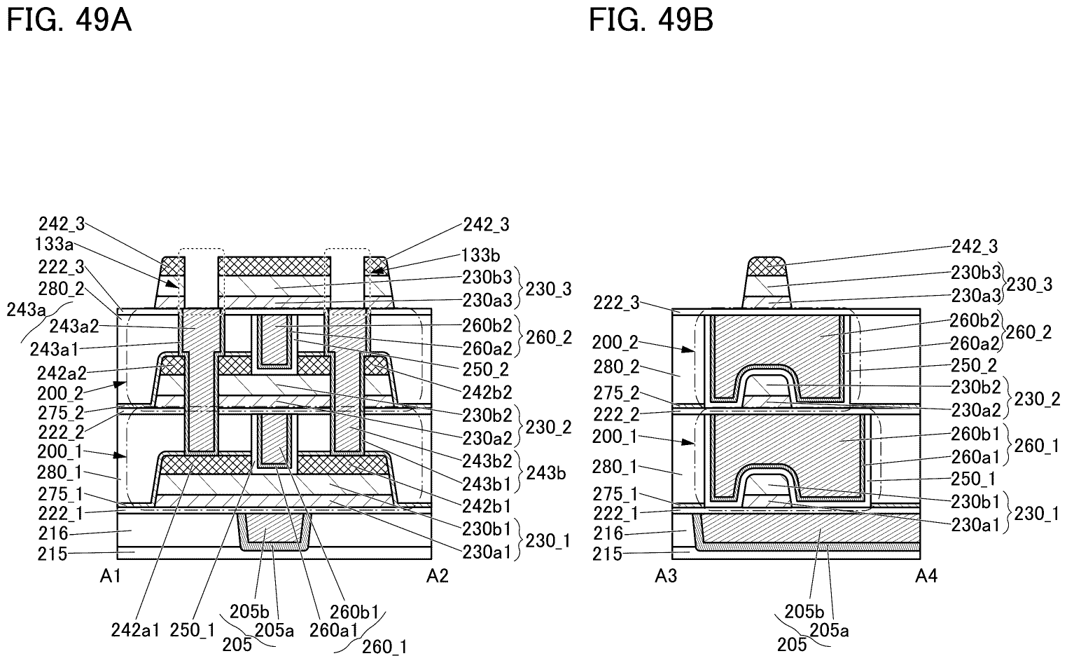

Next, the oxide film 230A3, the oxide film 230B3, and the conductive film 242F3 are processed into an island shape by a lithography method, thereby forming the oxide 230a3, the oxide 230b3, and a conductor 242_3 (FIG. 49A and FIG. 49B). The oxide 230a3, the oxide 230b3, and the conductor 242_3 are formed to at least partly overlap the conductor 260_2. The above description of the processing method and the like for the oxide 230a1, the oxide 230b1, and the conductor 242_1 can be referred to for the processing method and the like for the oxide 230a3, the oxide 230b3, and the conductor 242_3. By the processing, an opening 133a is formed in a region overlapping the conductor 243a and an opening 133b is formed in a region overlapping the conductor 243b. The conductor 243a, the conductor 243b, and the insulator 222_3 are exposed in a region that is not overlapped by the oxide 230a3, the oxide 230b3, or the conductor 242_3.

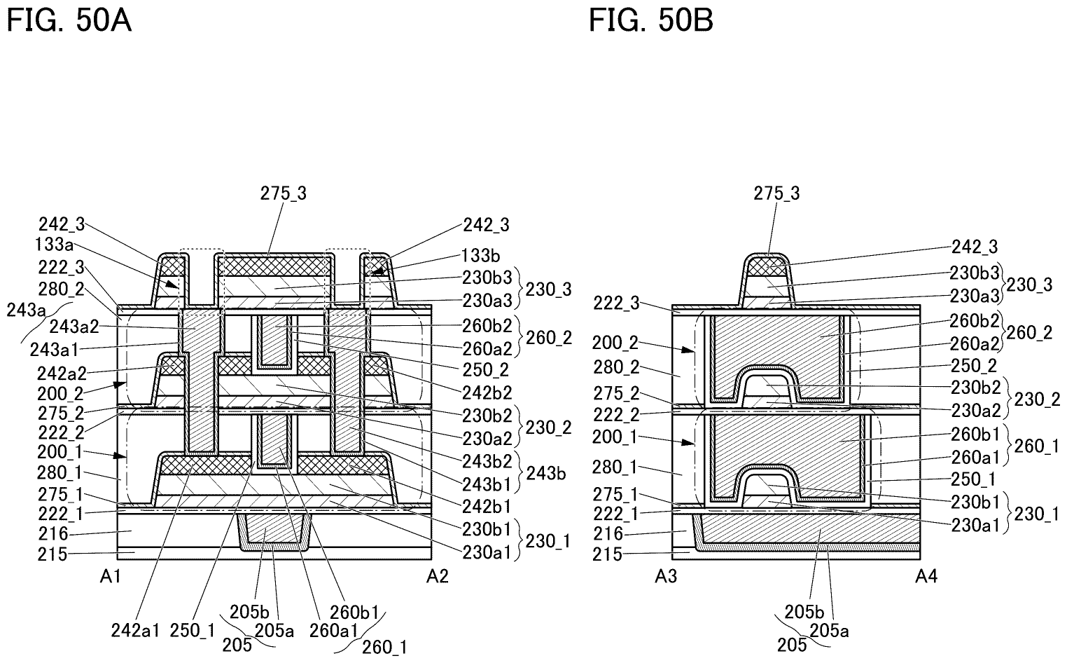

Then, the insulator 275_3 is deposited to cover the oxide 230a3, the oxide 230b3, and the conductor 242_3 (FIG. 50A and FIG. 50B). The insulator 275_3 is provided in contact with the sidewalls and the bottom surfaces of the opening 133a and the opening 133b. The insulator 275_3 includes a region in contact with the side surface of the oxide 230a3, the side surface of the oxide 230b3, the side surface and the top surface of the conductor 242_3, the top surface of the conductor 243a, the top surface of the conductor 243b, and the top surface of the insulator 222_3. Note that the above description of the insulator 275_1 can be referred to for a material, deposition conditions, and the like that can be used for the insulator 275_3.

Next, the insulator 280_3 is deposited over the insulator 275_3. The above description of the insulator 280_1 can be referred to for a material, deposition conditions, and the like that can be used for the insulator 280_3.

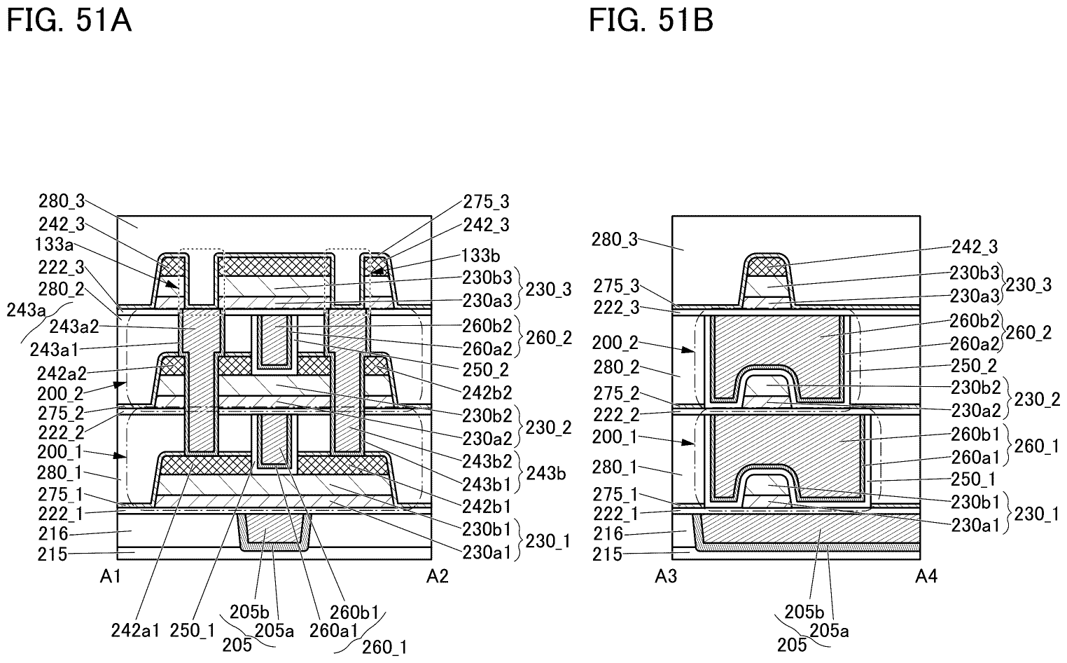

The top surface of the insulator 280_3 is preferably planarized by being subjected to CMP treatment after the deposition (FIG. 51A and FIG. 51B). Note that, for example, silicon nitride may be deposited over the insulator 280_3 by a sputtering method and CMP treatment may be performed on the silicon nitride until the insulator 280_3 is reached.

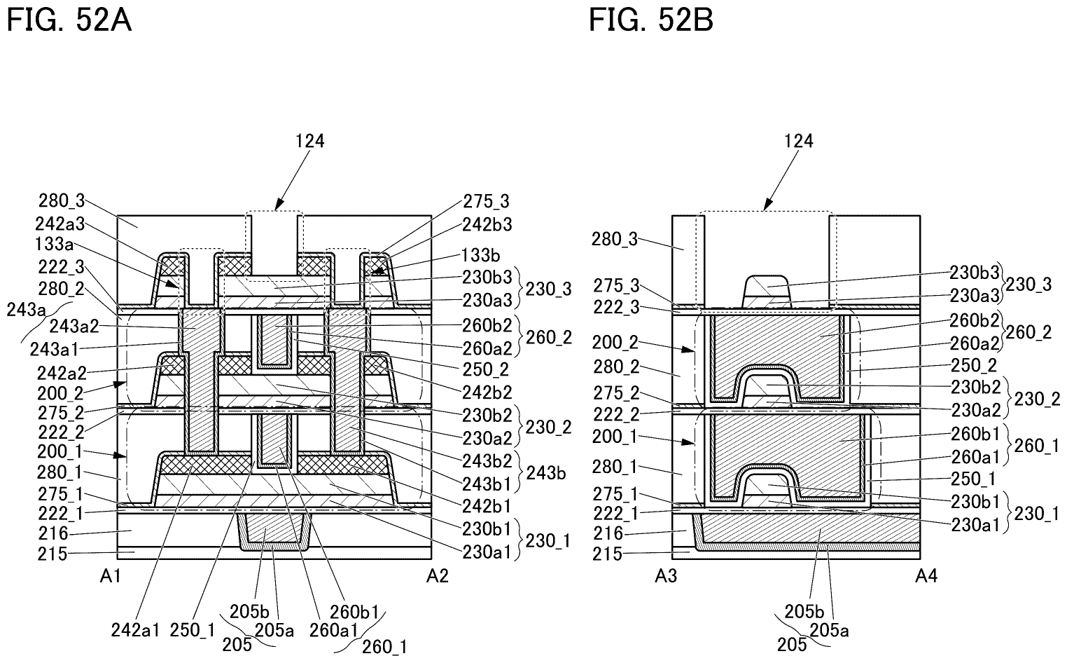

Next, the conductor 242_3, the insulator 275_3, and the insulator 280_3 are processed by a lithography method, thereby forming an opening 124 reaching the oxide 230b3 (FIG. 52A and FIG. 52B). The opening 124 is provided in a region where the oxide 230b3 and the conductor 260_2 overlap each other. The above description of the formation method and the like for the opening 122 can be referred to for the formation method and the like for the opening 124.

By this processing, the conductor 242_3 is divided into the conductor 242a3 and the conductor 242b3 each having an island shape.

The width of the opening 124 (the width in the channel length direction of the transistor 200_3), which affects the channel length of the transistor 200_3, is preferably extremely small. For example, the width of the opening 124 is preferably greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, greater than or equal to 1 nm and less than or equal to 10 nm, or greater than or equal to 5 nm and less than or equal to 10 nm. In order to process the opening minutely as described above, a lithography method using an electron beam or short-wavelength light such as EUV light is preferably employed.

The width of the opening 124, the width of the opening 123, and the width of the opening 122 are preferably the same. This structure allows the transistor 200_1 to the transistor 200_3 to have the same channel length and thus can reduce variations in electrical characteristics of the semiconductor device 200.

Then, an insulating film to be the insulator 250_3 is formed over the oxide 230b3 and the insulator 280_3. The insulating film is formed to be in contact with the sidewall and the bottom surface of the opening 124. The above description of the material, the formation method, and the like that can be used for the insulating film to be the insulator 250_1 can be referred to for a material, a formation method, and the like that can be used for the insulating film to be the insulator 250_3.

Next, a conductive film to be the conductor 260a3 and a conductive film to be the conductor 260b3 are formed in this order. The above description of the materials, the formation methods, and the like that can be used for the conductive film to be the conductor 260a1 and the conductive film to be the conductor 260b1 can be referred to for materials, formation methods, and the like that can be used for the conductive film to be the conductor 260a3 and the conductive film to be the conductor 260b3.

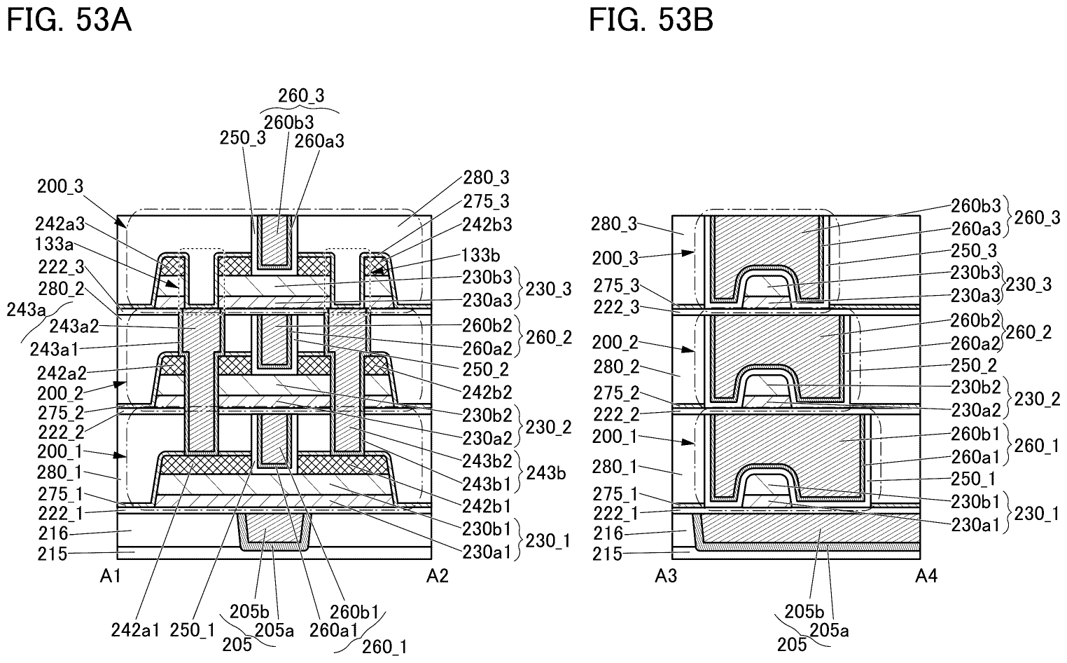

Then, the insulating film to be the insulator 250_3, the conductive film to be the conductor 260a3, and the conductive film to be the conductor 260b3 are polished by CMP treatment until the insulator 280_3 is exposed. That is, portions of the insulating film to be the insulator 250_3, the conductive film to be the conductor 260a3, and the conductive film to be the conductor 260b3 that are exposed from the opening 124 are removed. Thus, the insulator 250_3 and the conductor 260_3 (the conductor 260a3 and the conductor 260b3) are formed in the opening 124 overlapping the conductor 260_2 (FIG. 53A and FIG. 53B).

Accordingly, the insulator 250_3 is provided in contact with the sidewall and the bottom surface of the opening 124. The conductor 260_3 is positioned to fill the opening 124 with the insulator 250_3 therebetween. In this manner, the transistor 200_3 is formed.

Next, the insulator 286 is formed over the insulator 250_3, the conductor 260_3, and the insulator 280_3. The above description can be referred to for the material, the formation method, and the like that can be used for the insulator 286.

Subsequently the insulator 283 is formed over the insulator 286. The insulator 283 can be deposited by, for example, a sputtering method, a CVD method, an MBE method, a PLD method, or an ALD method. The insulator 283 is preferably deposited by a sputtering method. By employing a sputtering method, which does not need to use a molecule containing hydrogen as a deposition gas, the hydrogen concentration in the insulator 283 can be reduced. Any of the above-described materials can be used for the insulator 283. For example, silicon nitride is deposited by a sputtering method as the insulator 283.

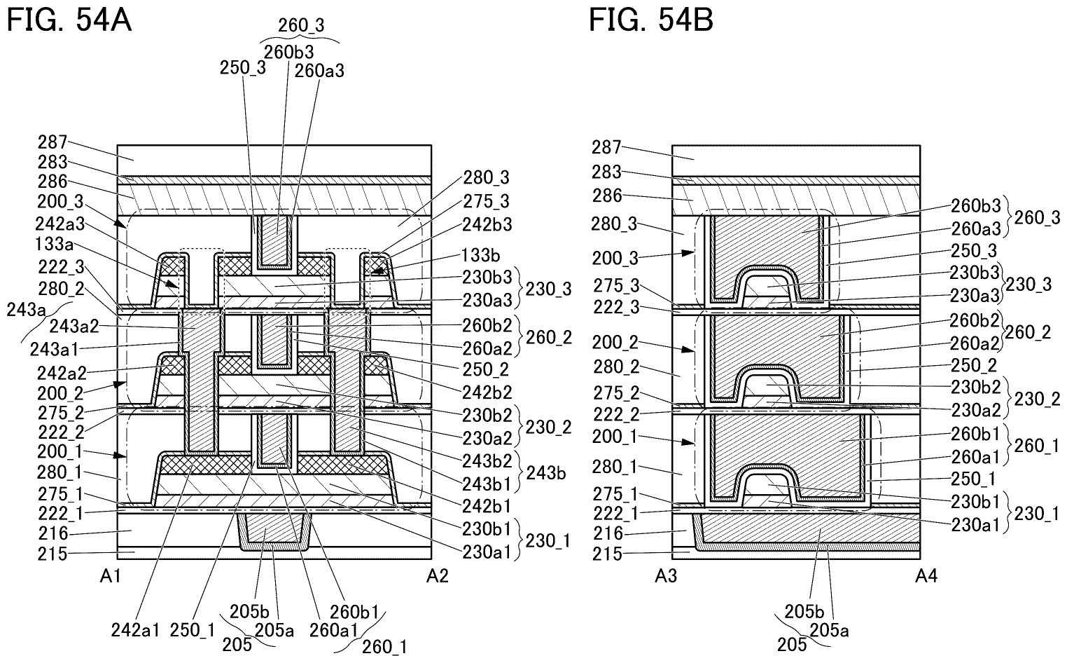

Next, the insulator 287 is formed over the insulator 283 (FIG. 54A and FIG. 54B). The insulator 287 can be deposited by, for example, a sputtering method, a CVD method, an MBE method, a PLD method, or an ALD method. For the insulator 287, a material with a low relative permittivity is preferably used. When a material with a low relative permittivity is used for the insulator 287, the parasitic capacitance between wirings that are provided to sandwich the insulator 287 can be reduced.

Here, it is preferable that the insulator 286, the insulator 283, and the insulator 287 be successively formed without being exposed to the atmospheric environment. By the deposition without exposure to the air, impurities or moisture from the atmospheric environment can be prevented from being attached onto the insulator 286, the insulator 283, and the insulator 287; hence, the vicinity of the interface between the insulator 286 and the insulator 283 and the vicinity of the interface between the insulator 283 and the insulator 287 can be kept clean.

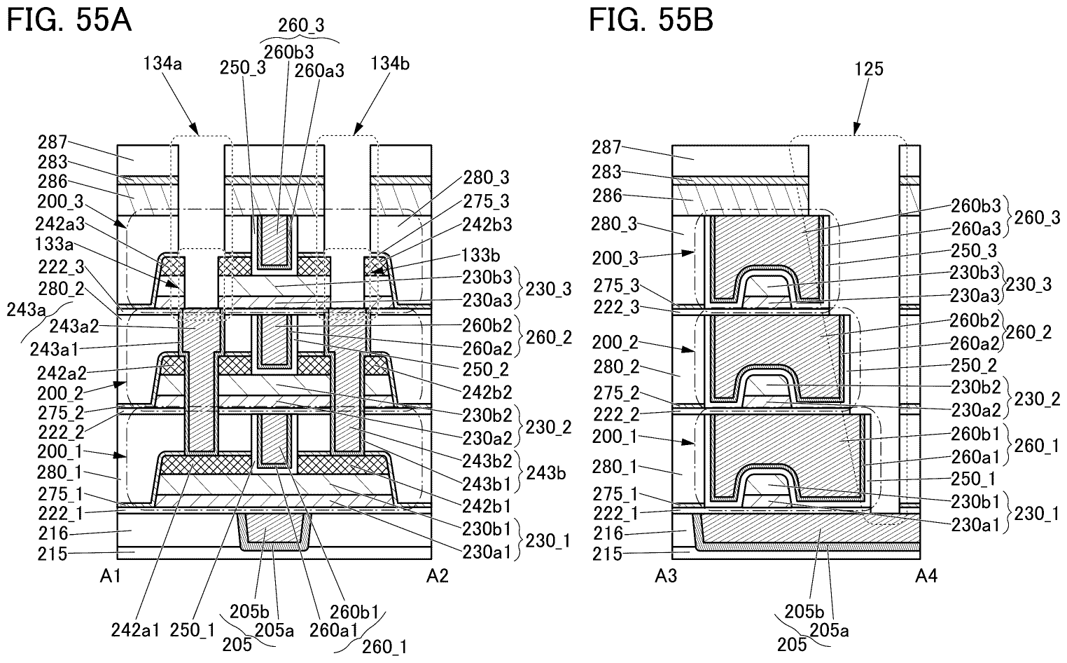

Subsequently, the insulator 287, the insulator 283, the insulator 286, the insulator 280_3, and the insulator 275_3 are processed by a lithography method, whereby an opening 134a reaching the conductor 243a is formed in a region overlapping the opening 133a and an opening 134b reaching the conductor 243b is formed in a region overlapping the opening 133b (FIG. 55A).

A dry etching method or a wet etching method can be used for the processing. By the processing, regions of the insulator 275_3 that are in contact with the sidewalls of the opening 133a and the opening 133b are removed.

As described above, the opening 134a is formed in the region overlapping the opening 133a. The opening 134b is formed in the region overlapping the opening 133b. Thus, the opening 133a can be regarded as being included in the opening 134a. The opening 133b can be regarded as being included in the opening 134b. Since the opening 133a and the opening 133b are formed in advance in the respective regions where the opening 134a or the opening 134b is to be formed, the opening 134a and the opening 134b that reach the conductor 243a and the conductor 243b, respectively, can be easily processed.

In order to form the opening 134a to overlap the opening 133a, the maximum diameter of the opening 134a in a planar view is preferably larger than the maximum diameter of the opening 133a in a planar view. In order to form the opening 134b to overlap the opening 133b, the maximum diameter of the opening 134b in a planar view is preferably larger than the maximum diameter of the opening 133b in a planar view. Here, part of a region of the insulator 275_3 over the conductor 242a3 and part of a region thereof over the conductor 242b3 are removed.

Note that the opening 134a corresponds to the above-described third opening, and the opening 134b corresponds to the above-described fourth opening.

Then, a conductive film to be the conductor 244a1 and the conductor 244b1 is formed over the conductor 243a, the conductor 243b, the conductor 242a3, the conductor 242b3, and the insulator 287. The conductive film is formed to be in contact with the sidewalls and the bottom surfaces of the opening 134a and the opening 134b. Thus, the conductor 244a1 is in contact with the top surface of the conductor 243a and the top surface of the conductor 242a3. The conductor 244b1 is in contact with the top surface of the conductor 243b and the top surface of the conductor 242b3. The description of the material, the formation method, and the like that can be used for the conductive film to be the conductor 260a1, for example, can be referred to for a material, a formation method, and the like that can be used for the conductive film to be the conductor 244a1 and the conductor 244b1.

Next, a conductive film to be the conductor 244a2 and the conductor 244b2 is formed over the conductive film to be the conductor 244a1 and the conductor 244b1. The description of the material, the formation method, and the like that can be used for the conductive film to be the conductor 260b1, for example, can be referred to for a material, a formation method, and the like that can be used for the conductive film to be the conductor 244a2 and the conductor 244b2.

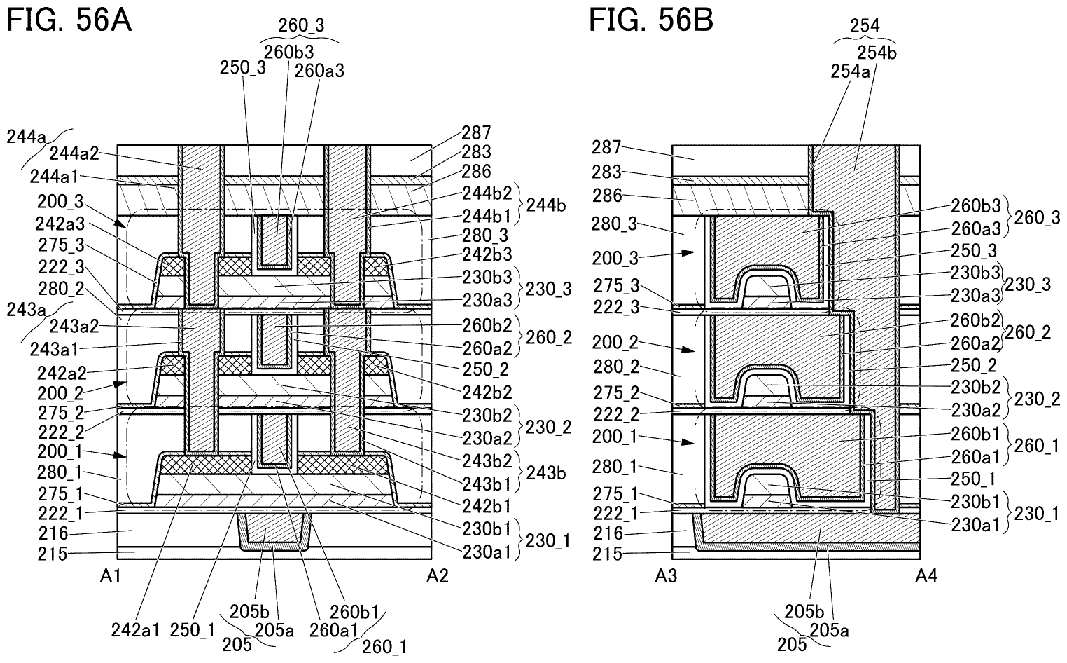

Subsequently, the conductive film to be the conductor 244a1 and the conductor 244b1 and the conductive film to be the conductor 244a2 and the conductor 244b2 are polished by CMP treatment until the insulator 287 is exposed. That is, portions of the conductive film to be the conductor 244a1 and the conductor 244b1 and the conductive film to be the conductor 244a2 and the conductor 244b2 that are exposed from the opening 134a and the opening 134b are removed. Thus, the conductor 244a (the conductor 244a1 and the conductor 244a2) is formed in the opening 134a reaching the conductor 243a. Moreover, the conductor 244b (the conductor 244b1 and the conductor 244b2) is formed in the opening 134b reaching the conductor 243b (FIG. 56A).

Accordingly, the conductor 244a electrically connects the conductor 242a3 and the conductor 243a. The conductor 244b electrically connects the conductor 242b3 and the conductor 243b. That is, the conductor 243a and the conductor 244a electrically connect the conductors functioning as either the source electrodes or the drain electrodes (the conductor 242a1 to the conductor 242a3) of the transistor 200_1 to the transistor 200_3. The conductor 243b and the conductor 244b electrically connect the conductors functioning as the others of the source electrodes and the drain electrodes (the conductor 242b1 to the conductor 242b3) of the transistor 200_1 to the transistor 200_3.

Then, the insulator 287, the insulator 283, the insulator 286, the insulator 280_3, the insulator 275_3, the insulator 222_3, the insulator 280_2, the insulator 275_2, the insulator 222_2, the insulator 280_1, the insulator 275_1, and the insulator 222_1 are processed by a lithography method, whereby an opening 125 reaching the conductor 205 is formed (FIG. 55B). The opening 125 includes a region overlapping the top surface of the conductor 205, the top surface of the conductor 260_1, the top surface of the conductor 260_2, and the top surface of the conductor 260_3 in a planar view.

A dry etching method or a wet etching method can be used for the processing. By the processing, part of the top surface of the conductor 205, part of the top surface of the conductor 260_1, part of the top surface of the conductor 260_2, and part of the top surface of the conductor 260_3 are exposed in the opening 125.

Note that the opening 125 corresponds to the above-described fifth opening.

Next, a conductive film to be the conductor 254a is formed over the conductor 205, the conductor 260_1, the conductor 260_2, the conductor 260_3, and the insulator 287. The conductive film is formed to be in contact with the sidewall and the bottom surface of the opening 125. Thus, the conductive film is in contact with the top surface of the conductor 205, the top surface of the conductor 260_1, the top surface of the conductor 260_2, and the top surface of the conductor 260_3. The description of the material, the formation method, and the like that can be used for the conductive film to be the conductor 260a1, for example, can be referred to for a material, a formation method, and the like that can be used for the conductive film to be the conductor 254a.

Subsequently, a conductive film to be the conductor 254b is formed over the conductive film to be the conductor 254a. The description of the material, the formation method, and the like that can be used for the conductive film to be the conductor 260b1, for example, can be referred to for a material, a formation method, and the like that can be used for the conductive film to be the conductor 254b.

Then, the conductive film to be the conductor 254a and the conductive film to be the conductor 254b are polished by CMP treatment until the insulator 287 is exposed. That is, portions of the conductive film to be the conductor 254a and the conductive film to be the conductor 254b that are exposed from the opening 125 are removed. Thus, the conductor 254 (the conductor 254a and the conductor 254b) is formed in the opening 125 reaching the conductor 205 (FIG. 56B).

Accordingly, the conductor 254 electrically connects the conductor 260_1 to the conductor 260_3 and the conductor 205. That is, the conductor 254 electrically connects the conductor 205 and the conductors functioning as the gate electrodes (the conductor 260_1 to the conductor 260_3) of the transistor 200_1 to the transistor 200_3.

Although an example of a method in which the conductors 244a and 244b and the conductor 254 are formed in different steps is described above, one embodiment of the present invention is not limited thereto. For example, the conductor 244a, the conductor 244b, and the conductor 254 may be formed at the same time in the following manner: the openings 134a and 134b and the opening 125 are formed at the same time, a first conductive film and a second conductive film are formed in this order, and CMP treatment is performed until the top surface of the insulator 287 is exposed.

Next, a conductive film to be the conductor 245a, the conductor 245b, and the conductor 255 is formed over the conductor 244a, the conductor 244b, the conductor 254, and the insulator 287. The description of the material, the formation method, and the like that can be used for the conductive film to be the conductor 260b1, for example, can be referred to for a material, a formation method, and the like that can be used for the conductive film.

Then, the conductor 245a, the conductor 245b, and the conductor 255 are formed by a lithography method to include a region overlapping the conductor 244a, a region overlapping the conductor 244b, and a region overlapping the conductor 254, respectively.

Through the above steps, the semiconductor device 200 illustrated in FIG. 1A to FIG. 2 can be manufactured.

### Example 2 of Method for Manufacturing Semiconductor Device

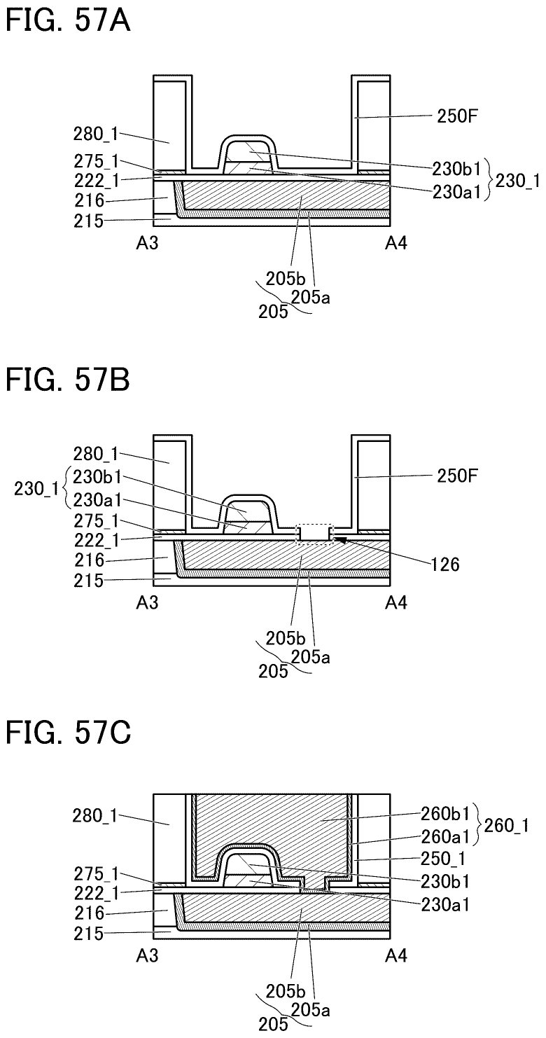

An example of a method for manufacturing the semiconductor device 200 illustrated in FIG. 13A and FIG. 13B will be described with reference to FIG. 57A to FIG. 57C.

Note that only part of the method for manufacturing the semiconductor device 200 illustrated in FIG. 13A and FIG. 13B is described below.

FIG. 57A to FIG. 57C are cross-sectional views along the dashed-dotted line A3-A4 in FIG. 13A.

First, the steps up to FIG. 35B described in <Example 1 of method for manufacturing semiconductor device> are performed.

Next, an insulating film 250F is formed in contact with the sidewall and the bottom surface of the opening 122 illustrated in FIG. 35B (FIG. 57A). The above description of the material, the formation method, and the like that can be used for the insulating film to be the insulator 250_1 can be referred to for a material, a formation method, and the like that can be used for the insulating film 250F.

Subsequently, by a lithography method, an opening 126 reaching the conductor 205 is formed in the insulating film 250F and the insulator 222_1 in a region that does not overlap the oxide 230_1 on the bottom surface of the opening 122 (FIG. 57B). A dry etching method or a wet etching method can be used to form the opening 126.

Next, a conductive film to be the conductor 260a1 is formed in contact with the top surface of the insulating film 250F, the sidewall of the opening 126, and the exposed top surface of the conductor 205, and a conductive film to be the conductor 260b1 is formed over the conductive film to be the conductor 260a1. The above description can be referred to for materials, formation methods, and the like that can be used for the conductive film to be the conductor 260a1 and the conductive film to be the conductor 260b1.

Then, the insulating film 250F, the conductive film to be the conductor 260a1, and the conductive film to be the conductor 260b1 are polished by CMP treatment until the insulator 280_1 is exposed. That is, portions of the insulating film 250F, the conductive film to be the conductor 260a1, and the conductive film to be the conductor 260b1 that are exposed from the opening 122 are removed. Thus, the insulator 250_1 and the conductor 260_1 (the conductor 260a1 and the conductor 260b1) are formed in the opening 126 reaching the conductor 205 and in the opening 122 (FIG. 57C).

Through the above steps, the conductor 205 and the conductor 260_1 can be electrically connected to each other.

Next, the steps described with reference to FIG. 37B to FIG. 42B are performed.

Then, by performing the steps described with reference to FIG. 57A to FIG. 57C, the conductor 260_2 is formed, and the conductor 260_2 and the conductor 260_1 can be electrically connected to each other.

By repeating the above steps, the steps up to the formation of the transistor 200_3 in the semiconductor device 200 illustrated in FIG. 13B can be performed.

### Example 3 of Method for Manufacturing Semiconductor Device

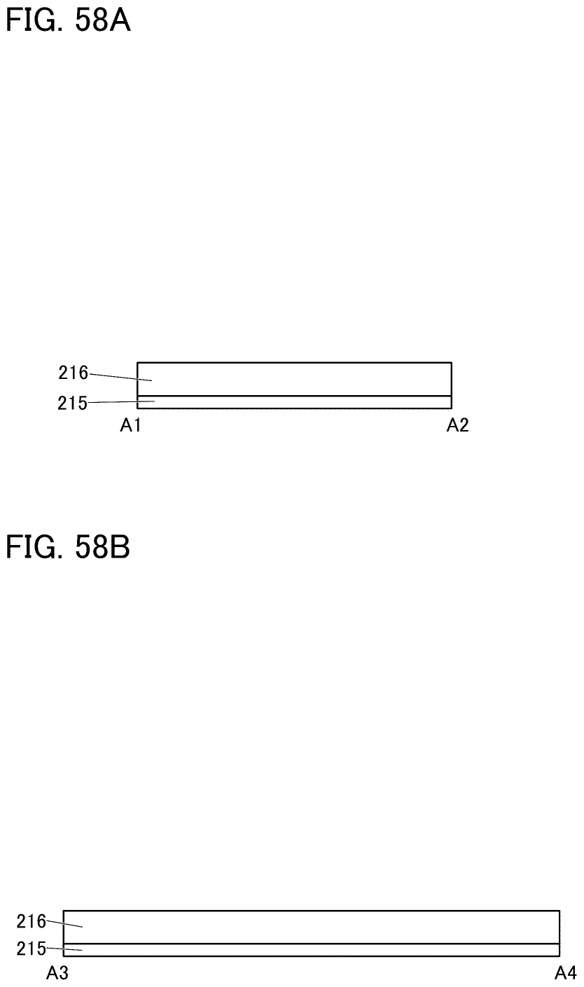

An example of the case of manufacturing the semiconductor device 200 illustrated in FIG. 15 to FIG. 17 will be described with reference to FIG. 58A to FIG. 104B.

In FIG. 58 to FIG. 104, A of each drawing is a cross-sectional view along the dashed-dotted line A1-A2 in FIG. 15, and is also a cross-sectional view in the channel length direction of the transistors included in the semiconductor device 200. Moreover, B of each drawing is a cross-sectional view along the dashed-dotted line A3-A4 in FIG. 15, and is also a cross-sectional view in the channel width direction of the transistors included in the semiconductor device 200.

First, a substrate (not illustrated) is prepared, and the insulator 215 is deposited over the substrate. The above description can be referred to for a material, a formation method, and the like that can be used for the insulator 215.

Next, the insulator 216 is deposited over the insulator 215 (FIG. 58A and FIG. 58B). The above description can be referred to for a material, a formation method, and the like that can be used for the insulator 216.

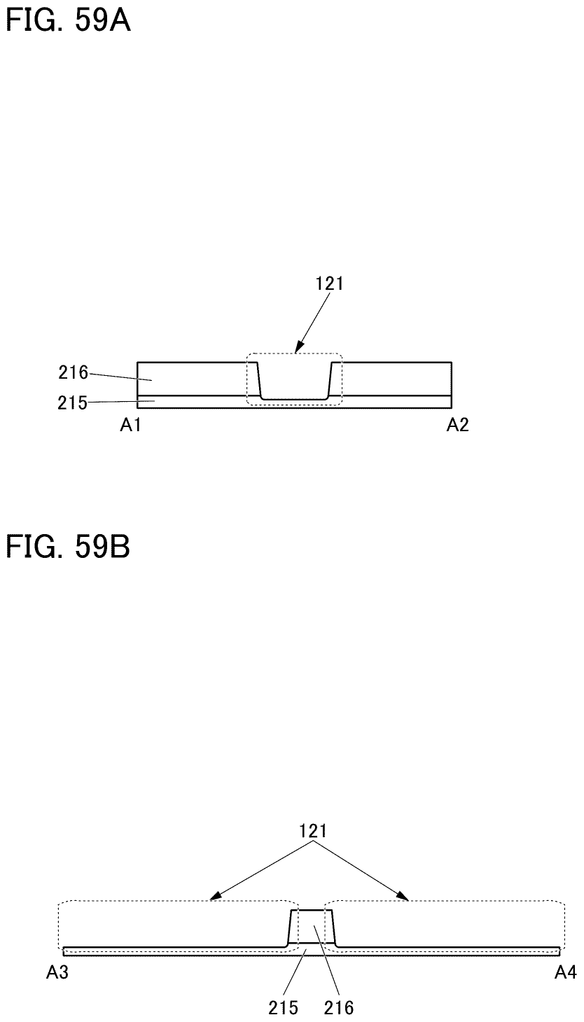

Then, two openings 121 reaching the insulator 215 are formed in the insulator 216 (FIG. 59A and FIG. 59B). The above description can be referred to for a method for forming the openings 121.

After the formation of the openings 121, a conductive film to be the conductor 205a is formed. The above description can be referred to for a material, a formation method, and the like that can be used for the conductive film to be the conductor 205a.

Next, a conductive film to be the conductor 205b is formed. The above description can be referred to for a material, a formation method, and the like that can be used for the conductive film to be the conductor 205b.

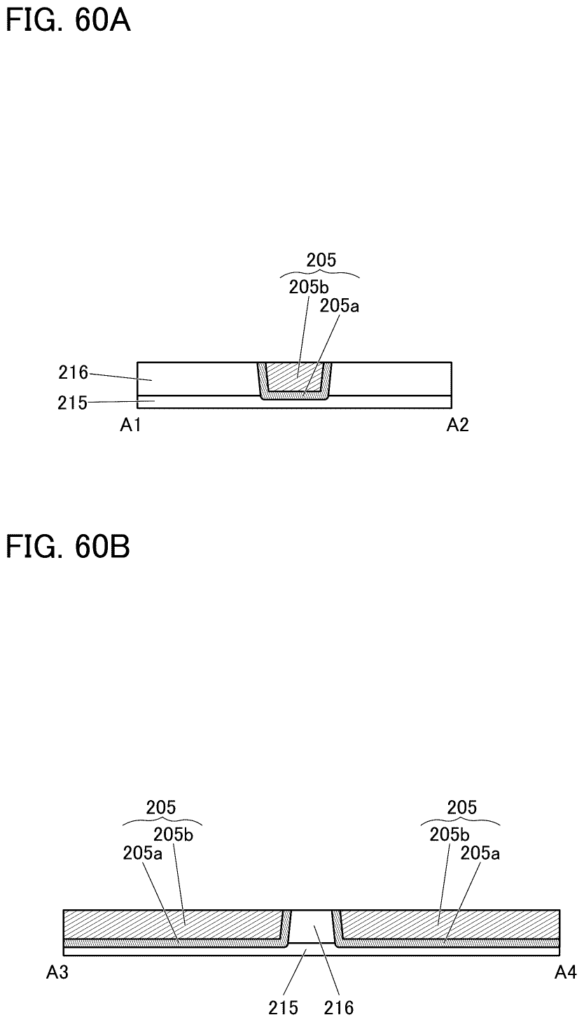

Then, CMP treatment is performed to partly remove the conductive film to be the conductor 205a and the conductive film to be the conductor 205b, so that the top surface of the insulator 216 is exposed (FIG. 60A and FIG. 60B). As a result, the conductors 205a and the conductors 205b remain only in the openings 121. Note that the insulator 216 is partly removed by the CMP treatment in some cases.

Subsequently, the insulator 222_1 is deposited over the insulator 216 and the conductors 205 (the conductors 205a and the conductors 205b). The above description can be referred to for a material, a formation method, and the like that can be used for the insulator 222_1.

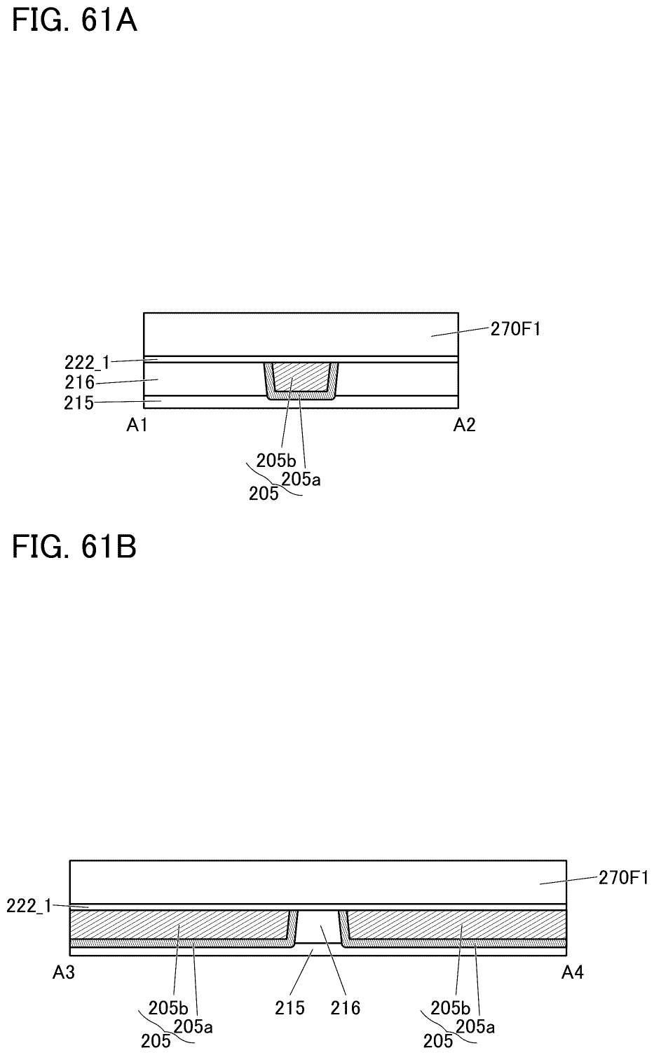

Next, an insulating film 270F1 is formed over the insulator 222_1 (FIG. 61A and FIG. 61B). The insulating film 270F1 can be formed by a sputtering method, a CVD method, an MBE method, a PLD method, or an ALD method, for example. For the insulating film 270F1, any of the above-described insulating materials that can be used for the insulator 280 can be used, for example.

For the insulating film 270F1, silicon oxide is preferably deposited by a sputtering method, for example. When the insulating film 270F1 is formed by a sputtering method in an oxygen-containing atmosphere, the insulating film 270F1 containing excess oxygen can be formed. By using a sputtering method, which does not need to use a molecule containing hydrogen as a deposition gas, the concentration of hydrogen in the insulating film 270F1 can be reduced. Thus, excess oxygen contained in the insulating film 270F1 can be supplied to the oxide 230_1 formed in a later step. Moreover, supply of hydrogen from the insulating film 270F1 to the oxide 230_1 can be inhibited.

Note that the insulating film 270F1 is not limited only to an insulating material in a strict sense. For example, a metal oxide with a relatively high insulating property can also be used. For example, a metal oxide that can be used for the oxide 230 may be used.

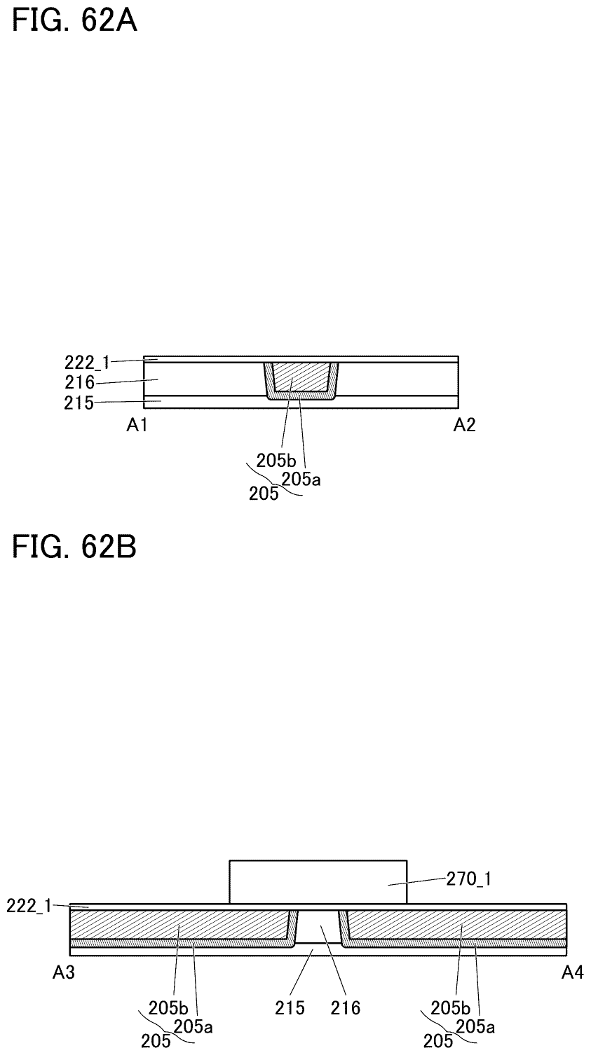

Then, the insulating film 270F1 is processed into an island shape by a lithography method, thereby forming an insulator 270_1 (FIG. 62A and FIG. 62B). The insulator 270_1 is formed to include regions overlapping the two opposite conductors 205 in the channel width direction of the transistors included in the semiconductor device 200. Note that in the channel length direction of the transistors, the insulator 270_1 may be provided for each transistor or may be provided to extend in the A1-A2 direction to be shared by the transistors. The insulator 270_1 is preferably formed such that its side surface is perpendicular or substantially perpendicular to the top surface of the insulator 222_1. Accordingly, when an oxide film 230F1 to be formed later over the insulator 270_1 is processed by anisotropic etching, the oxide 230_1 in contact with the side surface of the insulator 270_1 can be formed with high accuracy. Moreover, in the case where a plurality of transistors are provided in the substrate plane, a small area and high density of the transistors can be achieved. By the processing, the insulating film 270F1 in a region where the oxide 230_1 is to be provided later is removed.

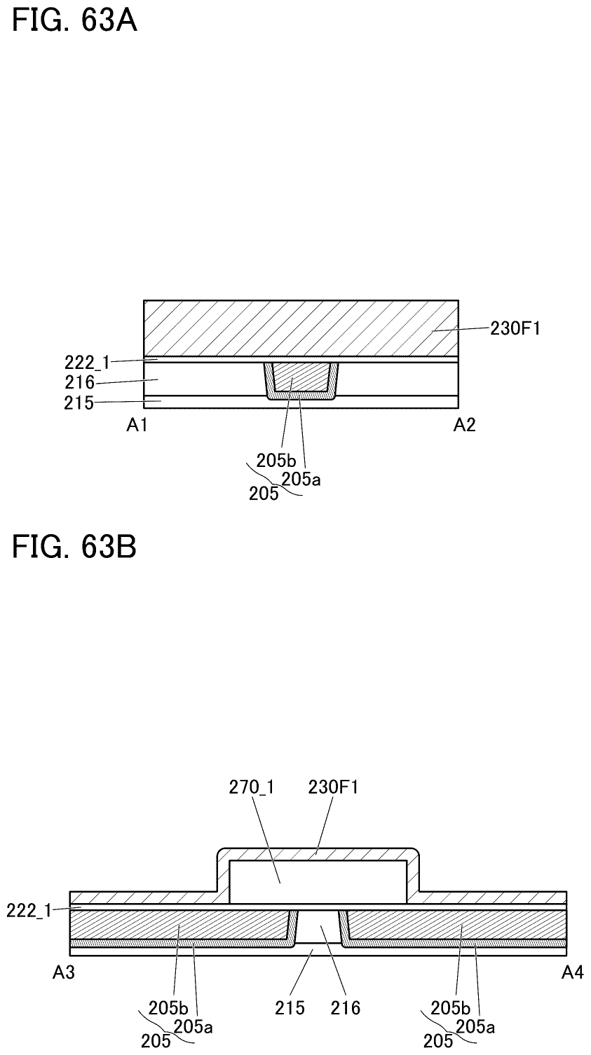

Subsequently, the oxide film 230F1 is formed over the insulator 270_1 and the insulator 222_1 (FIG. 63A and FIG. 63B). The oxide film 230F1 includes a region in contact with the top surface and the side surface of the insulator 270_1 and the top surface of the insulator 222_1. For the oxide film 230F1, a metal oxide applicable to the oxide 230 is used.

The above description of the formation method and the like for the oxide film 230A1 and the oxide film 230B1 can be referred to for a formation method and the like for the oxide film 230F1. The oxide film 230F1 is preferably formed by an ALD method, for example. When the oxide film 230F1 is formed by an ALD method, the oxide film 230F1 can be formed on the side surface of the insulator 270_1 with favorable coverage.

Next, heat treatment is preferably performed. The above description of the heat treatment that can be performed after the formation of the oxide film 230A1 and the oxide film 230B1 can be referred to for the conditions of the heat treatment.

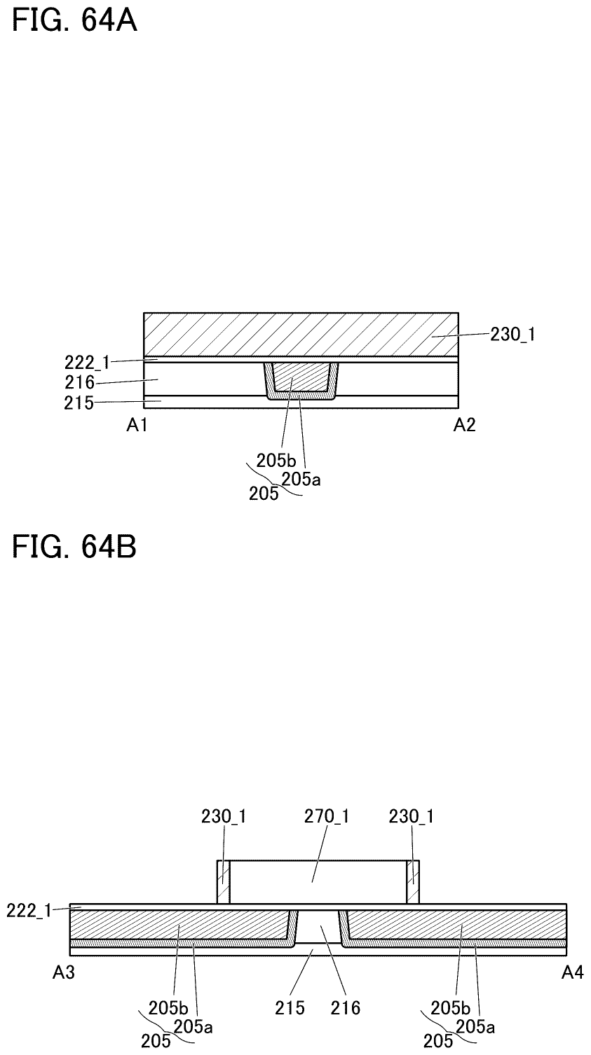

Then, the oxide film 230F1 is processed by anisotropic etching, thereby removing a region in contact with the top surface of the insulator 270_1 and a region in contact with the top surface of the insulator 222_1. Thus, the oxide 230_1 in contact with the side surface of the insulator 270_1 is formed (FIG. 64A and FIG. 64B).

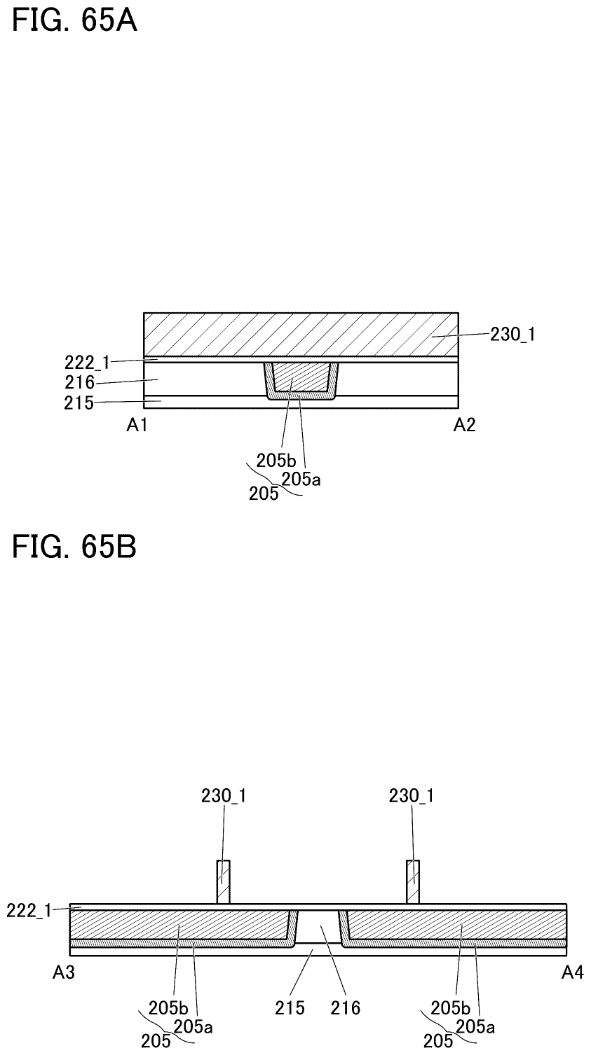

Next, the insulator 270_1 is removed (FIG. 65A and FIG. 65B). Thus, two island-shaped oxides 230_1 that face each other in the channel width direction of the transistors remain over the insulator 222_1 overlapping the conductor 205.

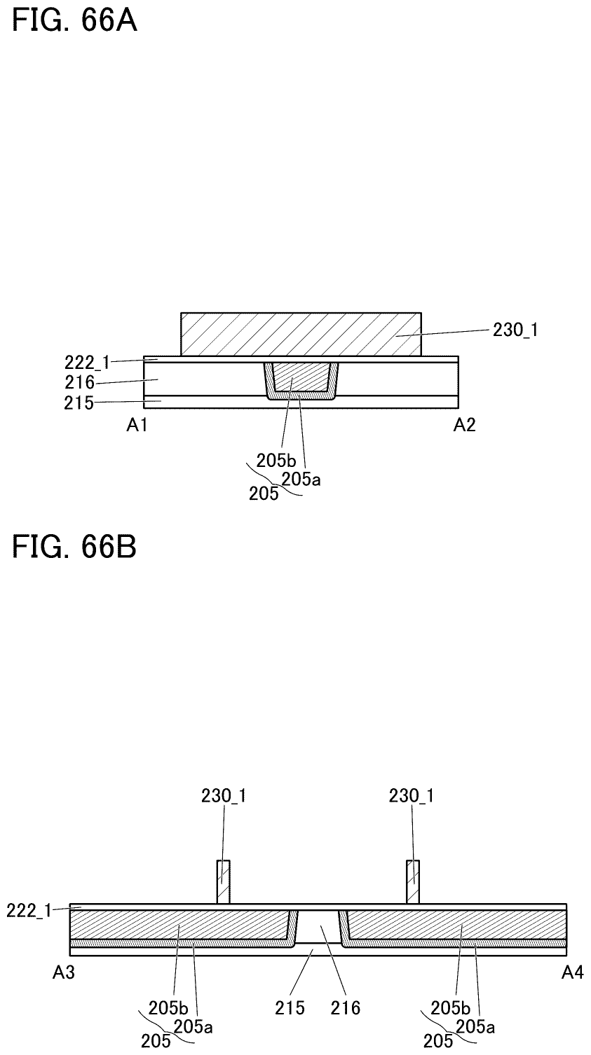

Subsequently, treatment is performed in which the oxide 230_1 illustrated in FIG. 65A is processed into an island shape by processing an end portion on the A1 side and an end portion on the A2 side of the oxide 230_1 by a lithography method (FIG. 66A and FIG. 66B). The processed oxide 230_1 also includes a region overlapping the conductor 205. Note that the treatment is unnecessary in the case where the oxide 230_1 having the shape illustrated in FIG. 26 is formed.

Although the treatment for processing the oxide 230_1 into an island shape (FIG. 66A and FIG. 66B) is performed after the treatment for removing the insulator 270_1 (FIG. 65A and FIG. 65B) in the above example, one embodiment of the present invention is not limited thereto. In one embodiment of the present invention, treatment for reducing the size of the oxide 230_1 (FIG. 66A and FIG. 66B) may be performed first, followed by the treatment for removing the insulator 270_1 (FIG. 65A and FIG. 65B).

In the case where the island-shaped oxide 230_1 is formed by a photolithography method, the channel width (W) of the oxide 230_1 is set by the light exposure limit of photolithography; meanwhile, in this embodiment, the channel width (W) of the oxide 230_1 can be set by the thickness of the oxide film 230F1. Thus, the channel width of the transistor 200_1 can be an extremely small value less than or equal to the light exposure limit of photolithography (e.g., greater than or equal to 0.1 nm and less than or equal to 60 nm, greater than or equal to 1 nm and less than or equal to 50 nm, greater than or equal to 5 nm and less than or equal to 40 nm, greater than or equal to 5 nm and less than or equal to 30 nm, greater than or equal to 5 nm and less than or equal to 20 nm, or greater than or equal to 5 nm and less than or equal to 10 nm). Accordingly, scaling down of the transistor can be achieved.

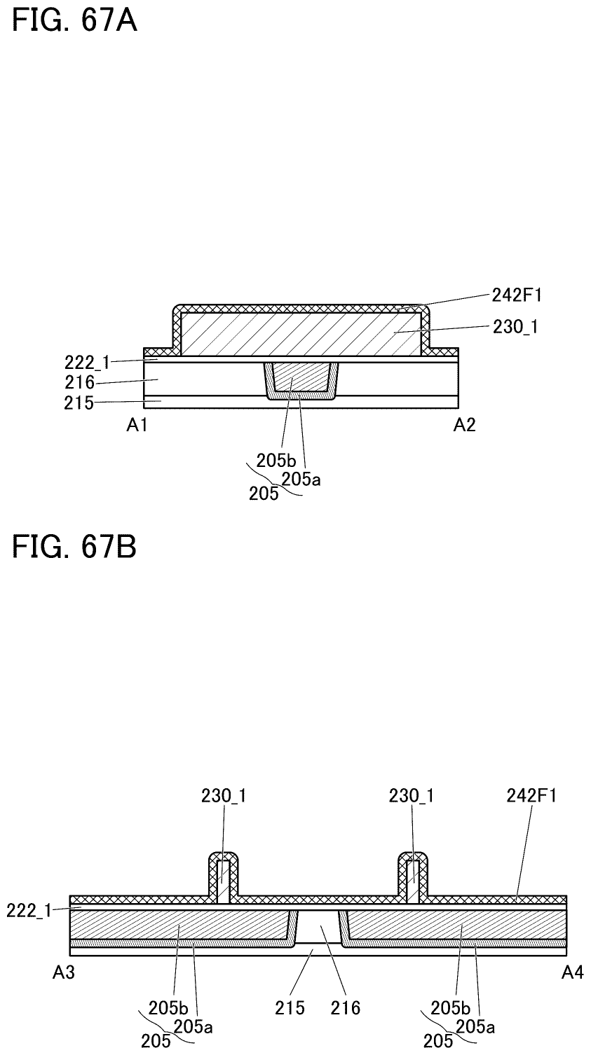

Next, the conductive film 242F1 is formed to cover the oxide 230_1 and the insulator 222_1 (FIG. 67A and FIG. 67B). The conductive film 242F1 includes a region in contact with the top surface and the side surface of the oxide 230_1 and the top surface of the insulator 222_1. For the conductive film 242F1, a conductor corresponding to the conductor 242a and the conductor 242b is used. The above description can be referred to for a material, a formation method, and the like that can be used for the conductive film 242F1.

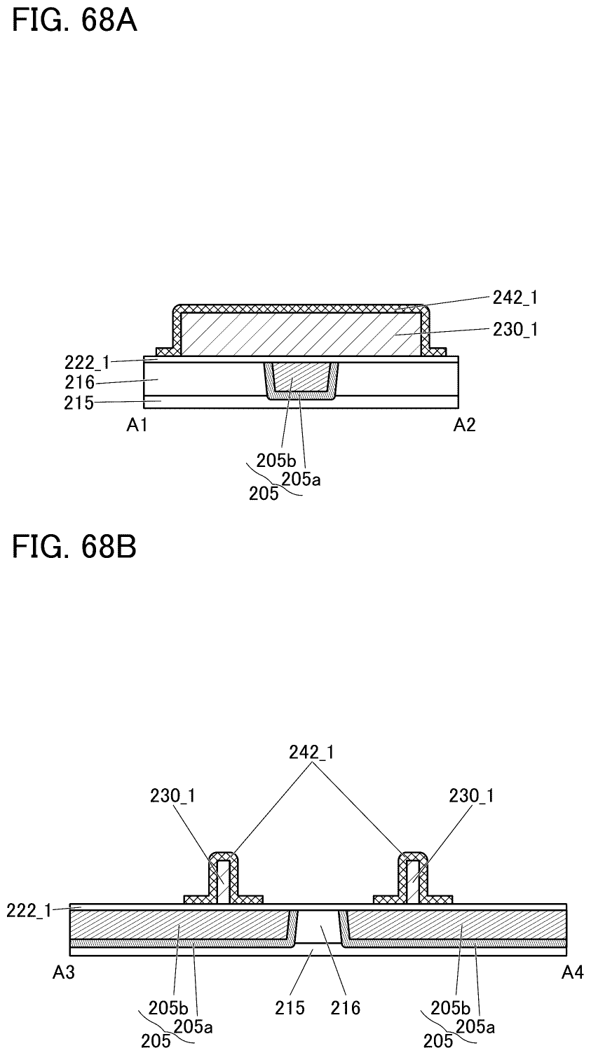

Then, the conductive film 242F1 is processed by a lithography method, whereby the island-shaped conductor 242_1 is formed in a region overlapping the oxide 230_1 (FIG. 68A and FIG. 68B). The conductor 242_1 is formed to cover the island-shaped oxide 230_1. The conductor 242_1 includes a region in contact with the top surface and the side surface of the oxide 230_1 and the top surface of the insulator 222_1.

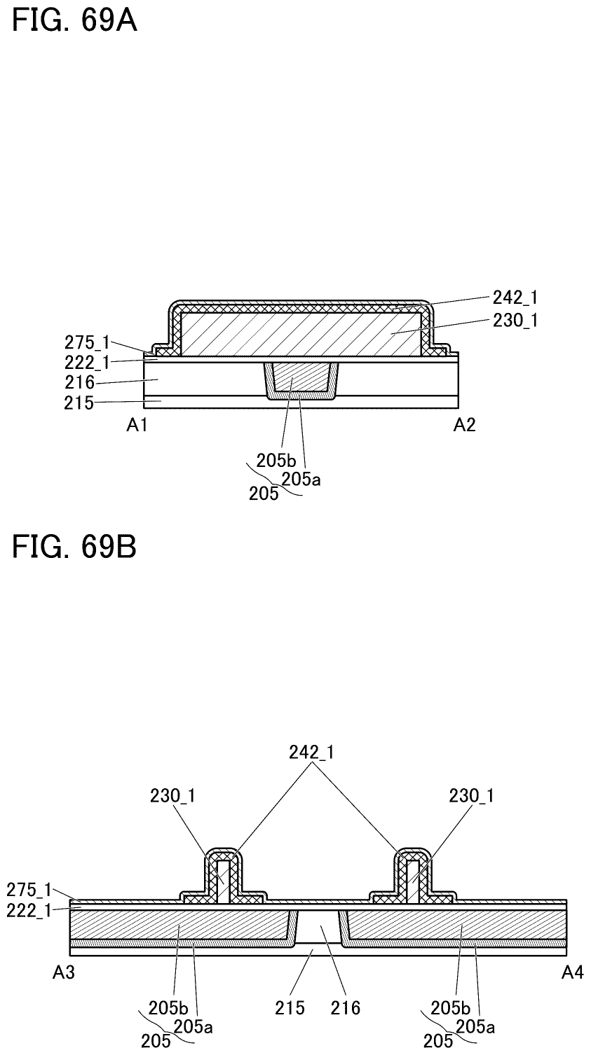

Next, the insulator 275_1 is deposited to cover the conductor 242_1 and the insulator 222_1 (FIG. 69A and FIG. 69B). The insulator 275_1 is preferably in contact with the top surface of the insulator 222_1.

The above description can be referred to for a material, a formation method, and the like that can be used for the insulator 275_1.

Then, the insulator 280_1 is deposited over the insulator 275_1. The above description can be referred to for a material, a formation method, and the like that can be used for the insulator 280_1.

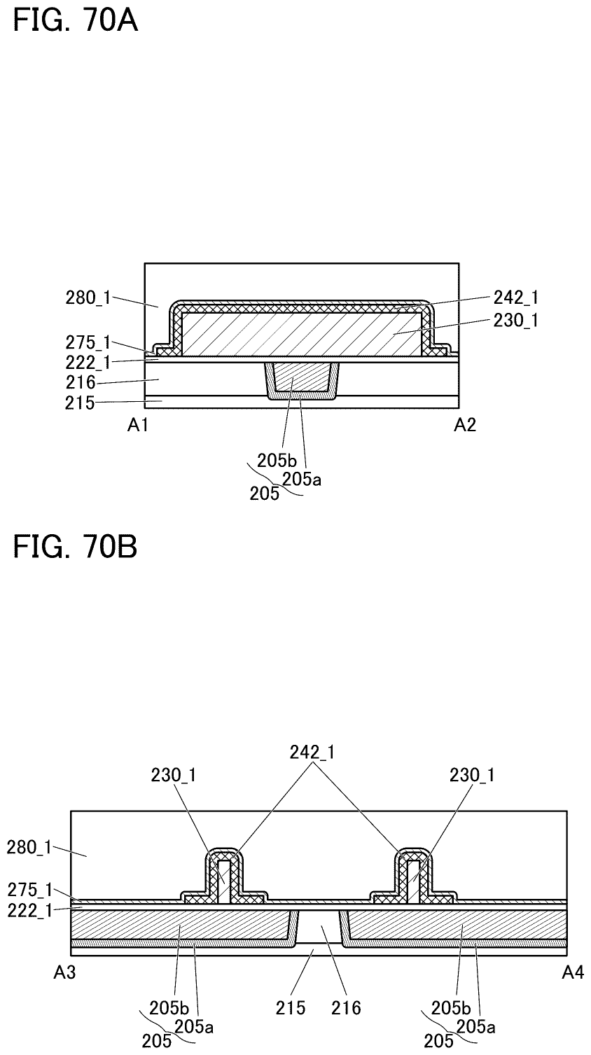

The top surface of the insulator 280_1 is preferably planarized by being subjected to CMP treatment after the deposition (FIG. 70A and FIG. 70B). Note that, for example, silicon nitride may be deposited over the insulator 280_1 by a sputtering method and CMP treatment may be performed on the silicon nitride until the insulator 280_1 is reached.

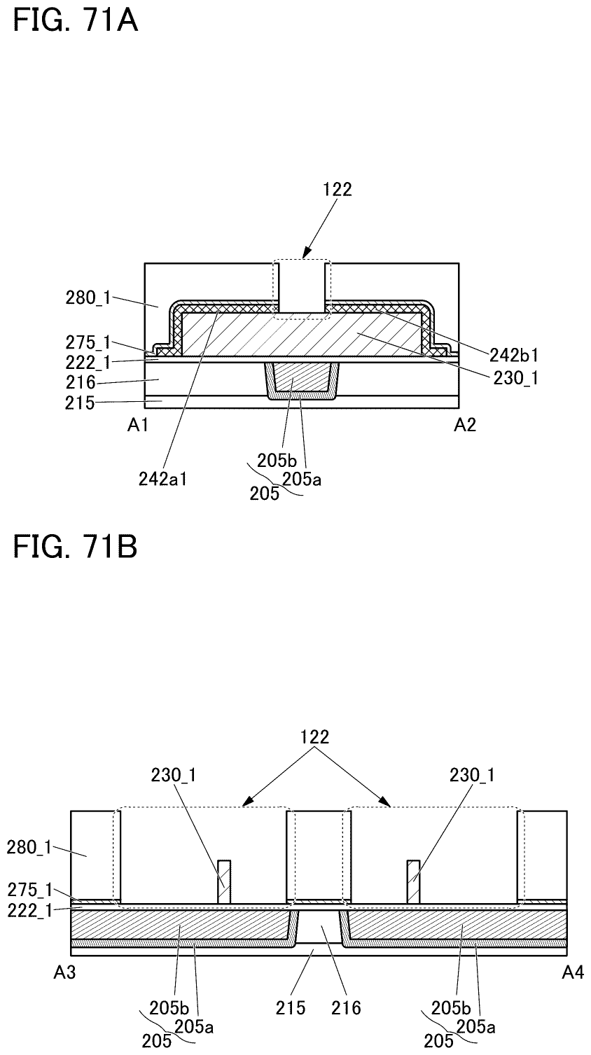

Subsequently, the conductor 242_1, the insulator 275_1, and the insulator 280_1 are processed by a lithography method, thereby forming two openings 122 reaching the oxides 230_1 (FIG. 71A and FIG. 71B). The openings 122 reaching the oxides 230_1 are provided in regions where the oxide 230_1 and the conductor 205 overlap each other.

The above description can be referred to for a method for forming the openings 122. By this processing, the conductor 242_1 is divided into the conductor 242a1 and the conductor 242b1 each having an island shape.

Next, an insulating film to be the insulator 250_1 is formed over the oxide 230_1 and the insulator 280_1. The insulating film is formed to be in contact with the sidewalls and the bottom surfaces of the openings 122. The above description can be referred to for a material, a formation method, and the like that can be used for the insulating film.

Then, it is preferable to perform microwave treatment in an oxygen-containing atmosphere. The above description can be referred to for the conditions of the microwave treatment.

Next, a conductive film to be the conductor 260a1 and a conductive film to be the conductor 260b1 are formed in this order. The above description can be referred to for materials, formation methods, and the like that can be used for the conductive film to be the conductor 260a1 and the conductive film to be the conductor 260b1.

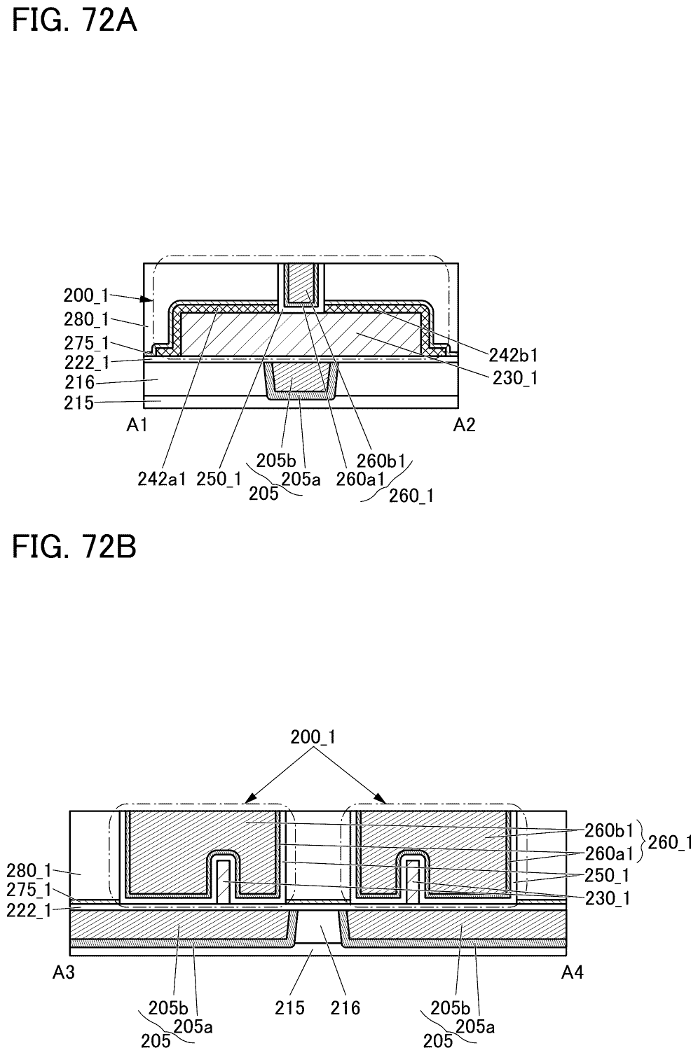

Then, the insulating film to be the insulator 250_1, the conductive film to be the conductor 260a1, and the conductive film to be the conductor 260b1 are polished by CMP treatment until the insulator 280_1 is exposed. That is, portions of the insulating film to be the insulator 250_1, the conductive film to be the conductor 260a1, and the conductive film to be the conductor 260b1 that are exposed from the openings 122 are removed. Thus, the insulator 250_1 and the conductor 260_1 (the conductor 260a1 and the conductor 260b1) are formed in the openings 122 overlapping the conductor 205 (FIG. 72A and FIG. 72B).

Accordingly, the insulator 250_1 is provided in contact with the sidewalls and the bottom surfaces of the openings 122. The conductor 260_1 is positioned to fill the openings 122 with the insulator 250_1 therebetween. In this manner, two transistors 200_1 that face each other in the channel width direction are formed.

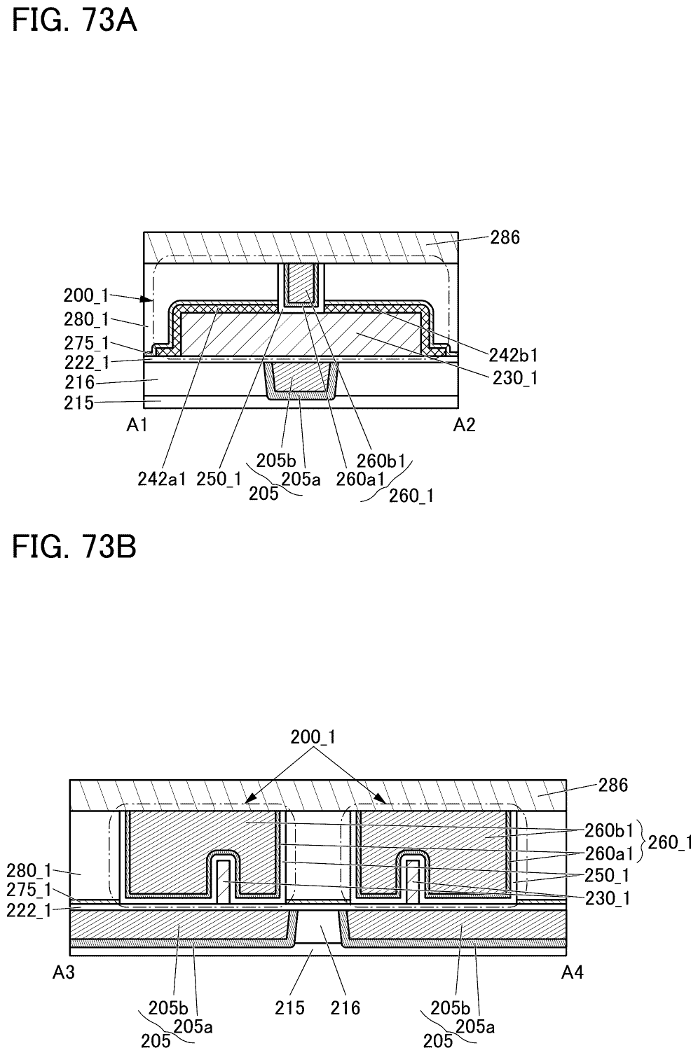

Next, the insulator 286 is formed over the insulator 250_1, the conductor 260_1, and the insulator 280_1 (FIG. 73A and FIG. 73B). The above description can be referred to for a material, a formation method, and the like that can be used for the insulator 286.

Subsequently, the insulator 286 is removed. A dry etching method, a wet etching method, or CMP can be used to remove the insulator 286. By the removal, the top surface of the insulator 250_1, the top surface of the conductor 260_1, and the top surface of the insulator 280_1 are exposed.

Then, the insulator 222_2 is formed in contact with the top surface of the insulator 250_1, the top surface of the conductor 260_1, and the top surface of the insulator 280_1. The above description of the insulator 222_1 can be referred to for a material, a formation method, and the like that can be used for the insulator 222_2.

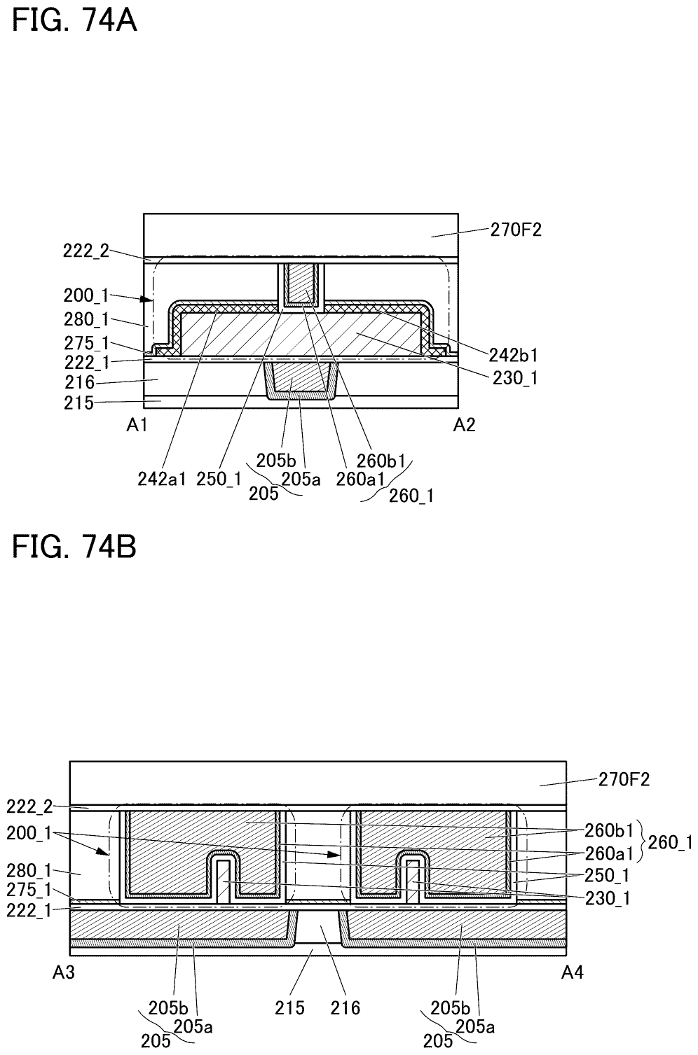

Next, an insulating film 270F2 is formed over the insulator 222_2 (FIG. 74A and FIG. 74B). The above description of the insulating film 270F1 can be referred to for a material, a formation method, and the like that can be used for the insulating film 270F2.

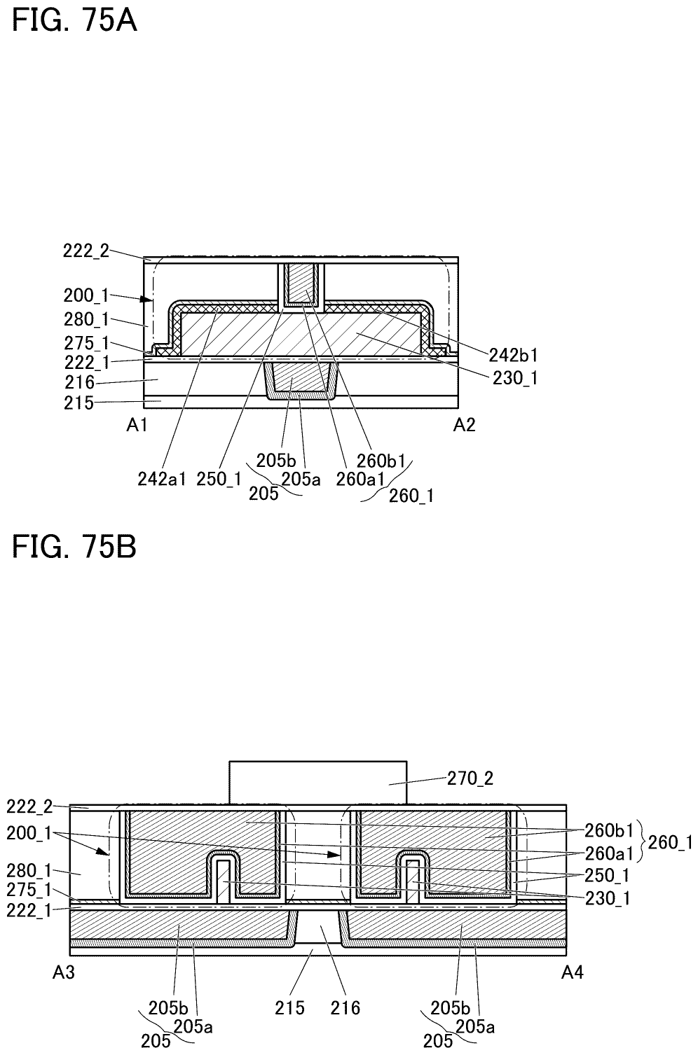

Then, the insulating film 270F2 is processed into an island shape by a lithography method, thereby forming an insulator 270_2 (FIG. 75A and FIG. 75B). The insulator 270_2 is formed to include regions overlapping the two opposite conductors 260_1 in the channel width direction of the transistor 200_1. The insulator 270_2 is preferably formed such that its side surface is perpendicular or substantially perpendicular to the top surface of the insulator 222_2. Accordingly, when an oxide film 230F2 to be formed later over the insulator 270_2 is processed by anisotropic etching, the oxide 230_2 in contact with the side surface of the insulator 270_2 can be formed with high accuracy. Moreover, in the case where a plurality of transistors are provided in the substrate plane, a small area and high density of the transistors can be achieved. By the processing, the insulating film 270F2 in a region where the oxide 230_2 is to be provided later is removed.

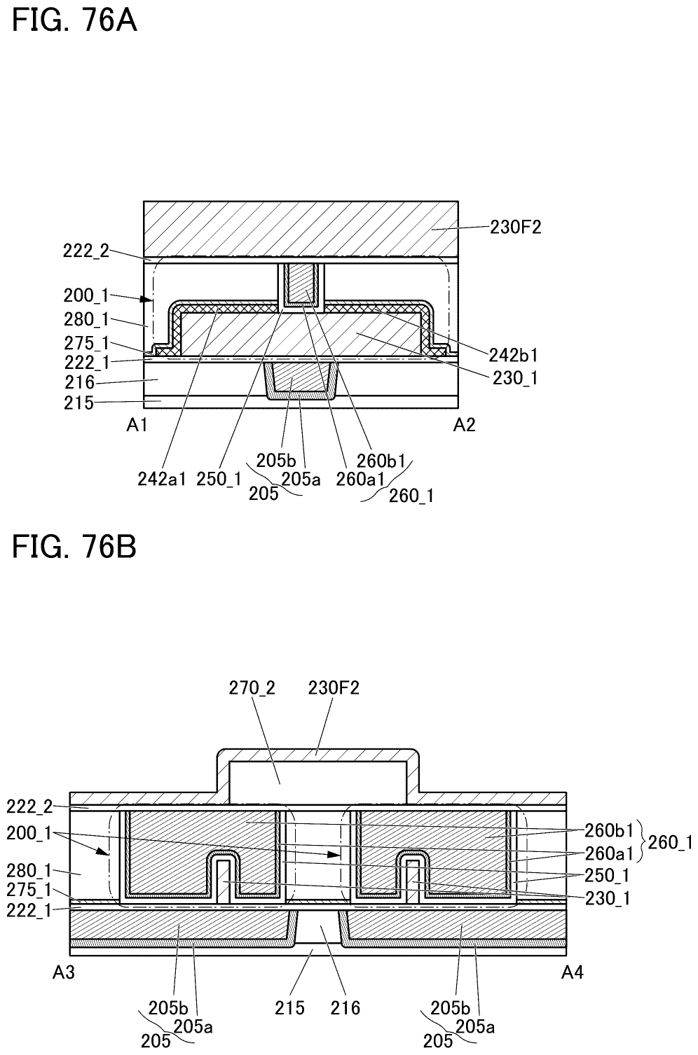

Next, the oxide film 230F2 is formed over the insulator 270_2 and the insulator 222_2 (FIG. 76A and FIG. 76B). The oxide film 230F2 includes a region in contact with the top surface and the side surface of the insulator 270_2 and the top surface of the insulator 222_2. The above description of the oxide film 230F1 can be referred to for a material, a formation method, and the like that can be used for the oxide film 230F2.

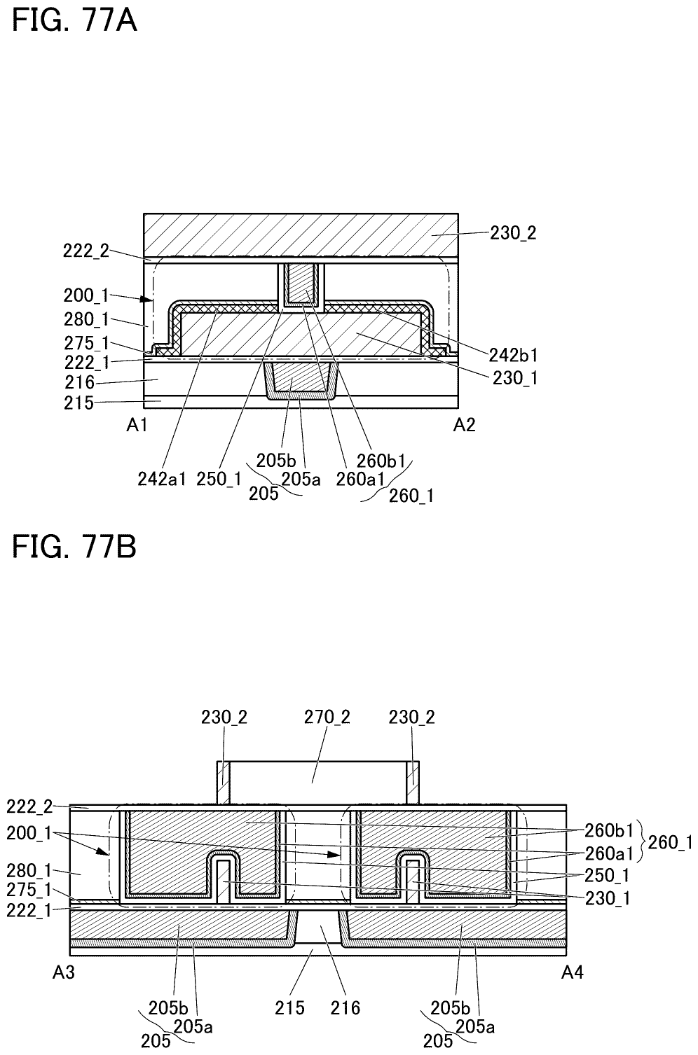

Then, the oxide film 230F2 is processed by anisotropic etching, thereby removing a region in contact with the top surface of the insulator 270_2 and a region in contact with the top surface of the insulator 222_2. Thus, the oxide 230_2 in contact with the side surface of the insulator 270_2 is formed (FIG. 77A and FIG. 77B).

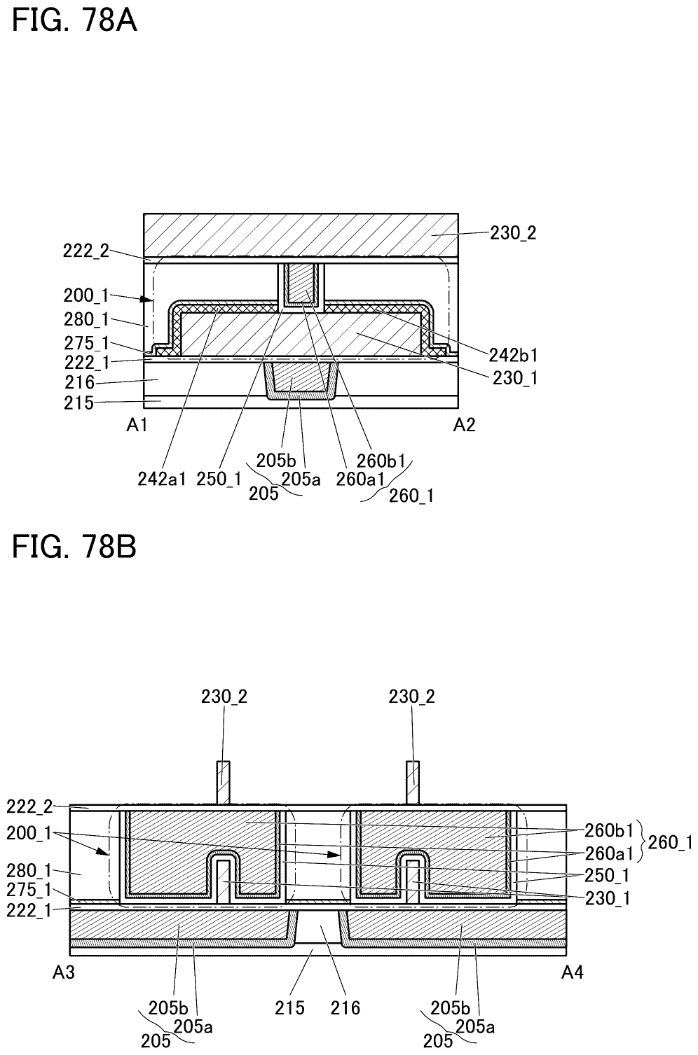

Next, the insulator 270_2 is removed (FIG. 78A and FIG. 78B). Thus, two island-shaped oxides 230_2 that face each other in the channel width direction of the transistor remain over the insulator 222_2 overlapping the conductor 260_1.

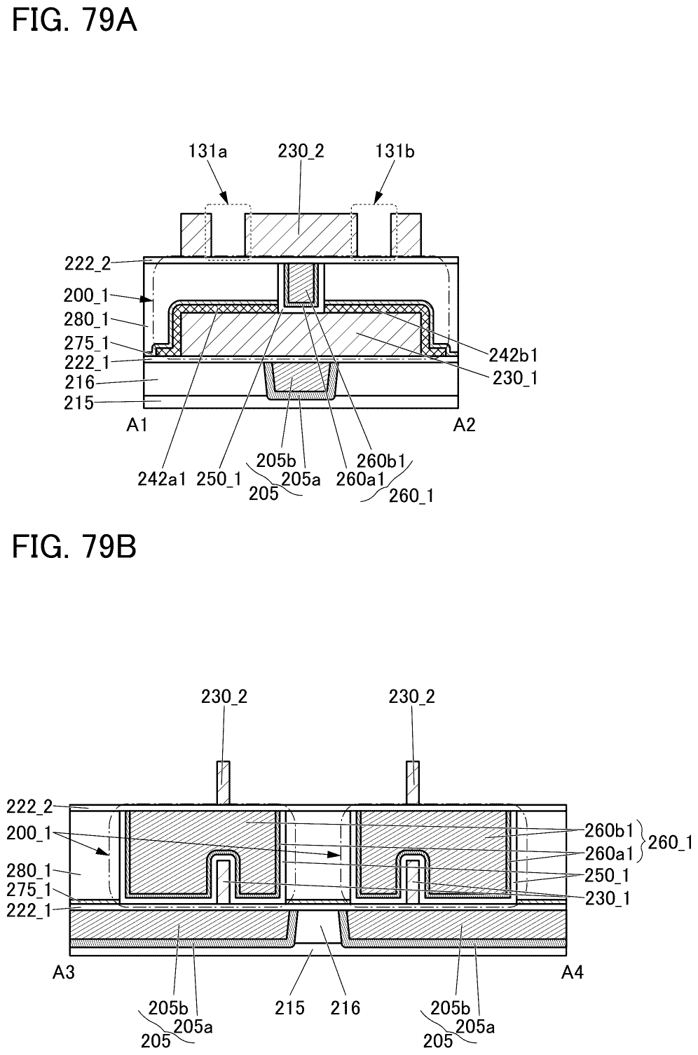

Subsequently, by a lithography method, the oxide 230_2 is processed into an island shape, and the opening 131a is formed in a region overlapping the conductor 242a1 and the opening 131b is formed in a region overlapping the conductor 242b1 (FIG. 79A and FIG. 79B). Note that in the case where the length of the oxide 230_2 in the A3-A4 direction is equal to or smaller than the width of the opening 131a, the oxide 230_2 is divided by the opening 131a and the opening 131b.

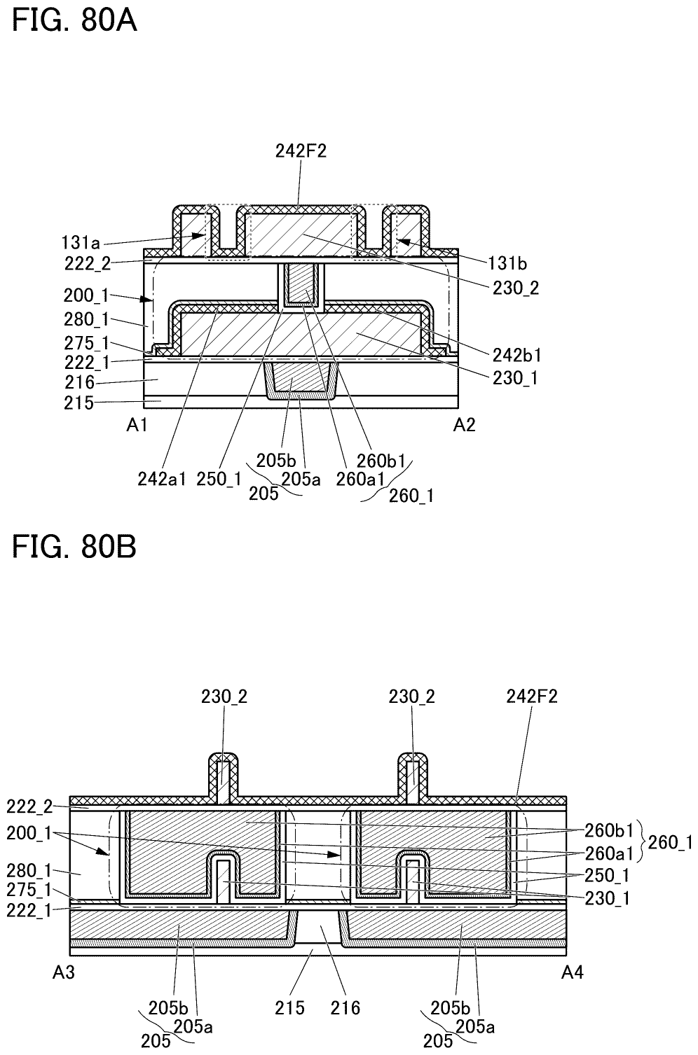

Then, the conductive film 242F2 is formed to cover the oxide 230_2 and the insulator 222_2 (FIG. 80A and FIG. 80B). The conductive film 242F2 includes a region in contact with the top surface and the side surface of the oxide 230_2 and the top surface of the insulator 222_2. The above description of the conductive film 242F1 can be referred to for a material, a formation method, and the like that can be used for the conductive film 242F2.

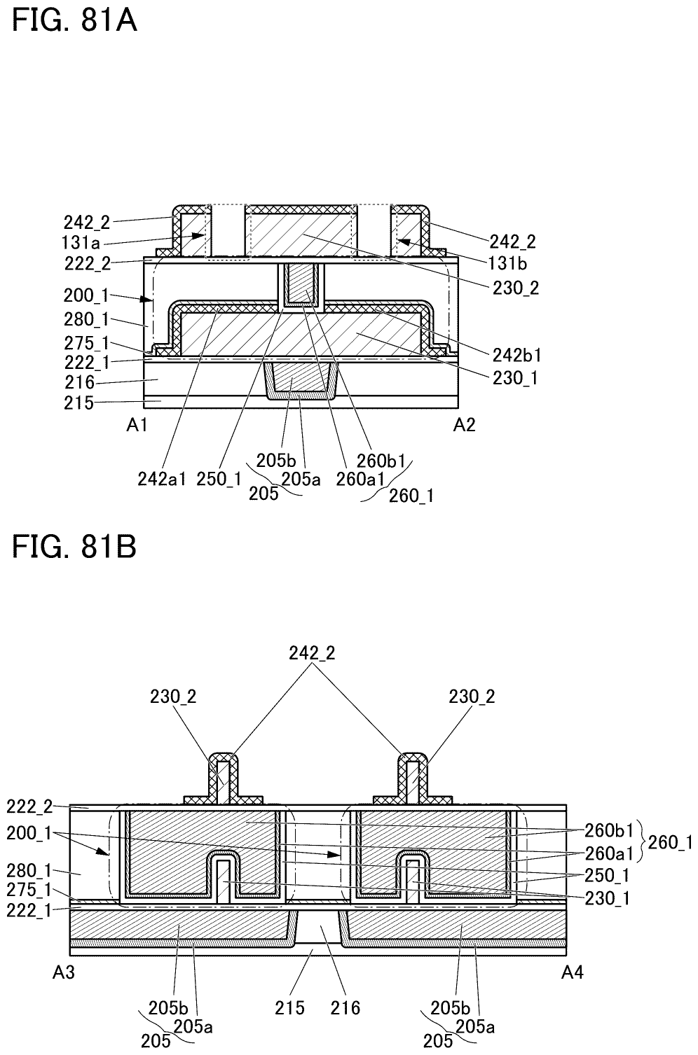

Next, the conductive film 242F2 is processed by a lithography method, whereby the island-shaped conductor 242_2 is formed in a region overlapping the oxide 230_2 (FIG. 81A and FIG. 81B). The conductor 242_2 is formed to cover the island-shaped oxide 230_2. The conductor 242_2 includes a region in contact with the top surface and the side surface of the oxide 230_2 and the top surface of the insulator 222_2. The oxide 230_2 and the conductor 242_2 are formed to at least partly overlap the conductor 260_1. The above description of the processing method and the like for conductive film 242F1 can be referred to for the processing method and the like for the oxide 230_2 and the conductive film 242F2. The insulator 222_2 is exposed in a region that is not overlapped by the oxide 230_2 or the conductor 242_2 (e.g., a region overlapped by the opening 131a or the opening 131b).

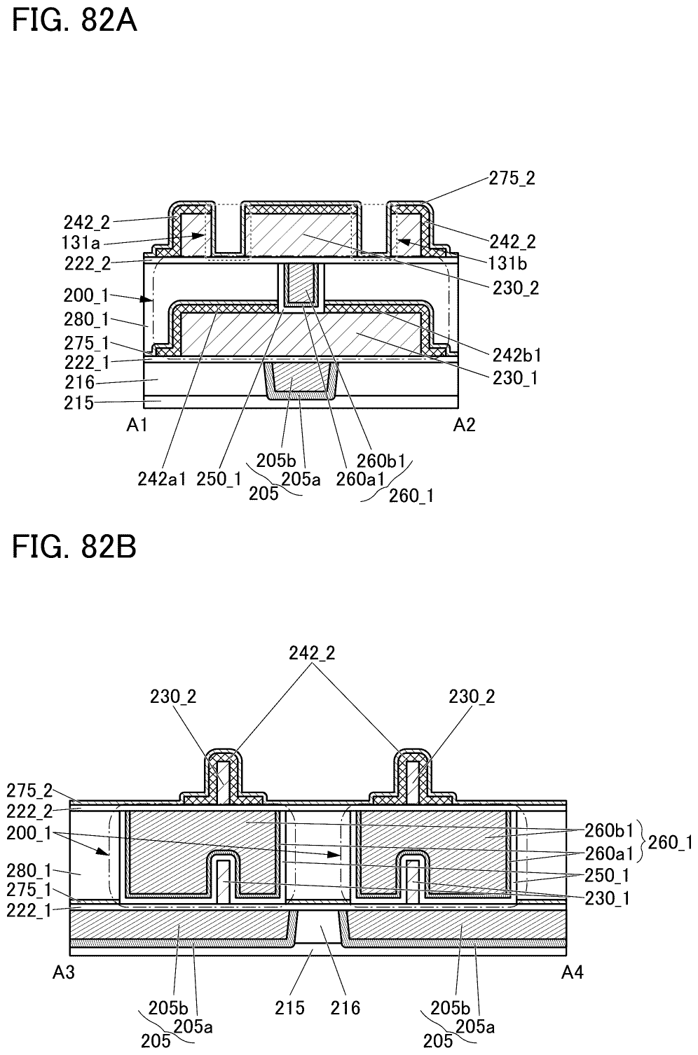

Then, the insulator 275_2 is deposited to cover the oxide 230_2 and the conductor 242_2 (FIG. 82A and FIG. 82B). The insulator 275_2 is provided in contact with the sidewalls and the bottom surfaces of the opening 131a and the opening 131b. The insulator 275_2 includes a region in contact with the side surface of the oxide 230_2, the side surface and the top surface of the conductor 242_2, and the top surface of the insulator 222_2. Note that the above description of the insulator 275_1 can be referred to for a material, deposition conditions, and the like that can be used for the insulator 275_2.

Next, the insulator 280_2 is deposited over the insulator 275_2. The above description of the insulator 280_1 can be referred to for a material, deposition conditions, and the like that can be used for the insulator 280_2.

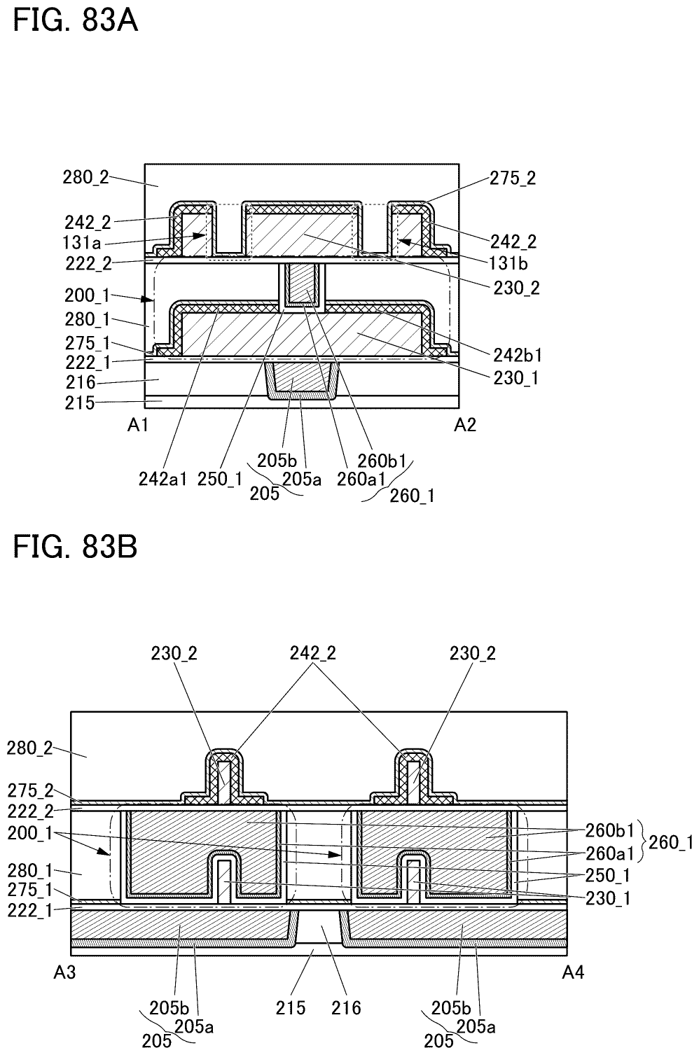

The top surface of the insulator 280_2 is preferably planarized by being subjected to CMP treatment after the deposition (FIG. 83A and FIG. 83B). Note that, for example, silicon nitride may be deposited over the insulator 280_2 by a sputtering method and CMP treatment may be performed on the silicon nitride until the insulator 280_2 is reached.

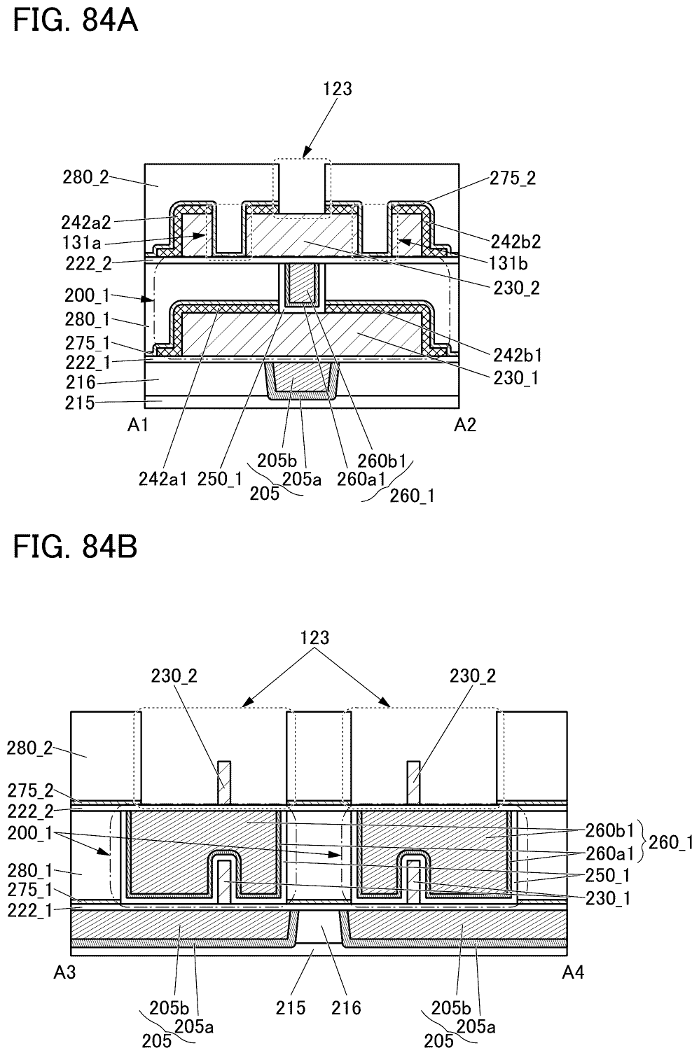

Subsequently, the conductor 242_2, the insulator 275_2, and the insulator 280_2 are processed by a lithography method, thereby forming two openings 123 reaching the oxides 230_2 (FIG. 84A and FIG. 84B). The opening 123 is provided in a region where the oxide 230_2 and the conductor 260_1 overlap each other. The above description of the formation method and the like for the opening 122 can be referred to for the formation method and the like for the opening 123.

By this processing, the conductor 242_2 is divided into the conductor 242a2 and the conductor 242b2 each having an island shape.

The width of the opening 123 and the width of the opening 122 are preferably substantially the same. This structure allows the transistor 200_1 and the transistor 200_2 to have the same channel length and thus can reduce variations in electrical characteristics of the semiconductor device 200.

Then, an insulating film to be the insulator 250_2 is formed over the oxide 230_2 and the insulator 280_2. The insulating film is formed to be in contact with the sidewall and the bottom surface of the opening 123. The above description of the material, the formation method, and the like that can be used for the insulating film to be the insulator 250_1 can be referred to for a material, a formation method, and the like that can be used for the insulating film to be the insulator 250_2.

Next, a conductive film to be the conductor 260a2 and a conductive film to be the conductor 260b2 are formed in this order. The above description of the materials, the formation methods, and the like that can be used for the conductive film to be the conductor 260a1 and the conductive film to be the conductor 260b1 can be referred to for materials, formation methods, and the like that can be used for the conductive film to be the conductor 260a2 and the conductive film to be the conductor 260b2.

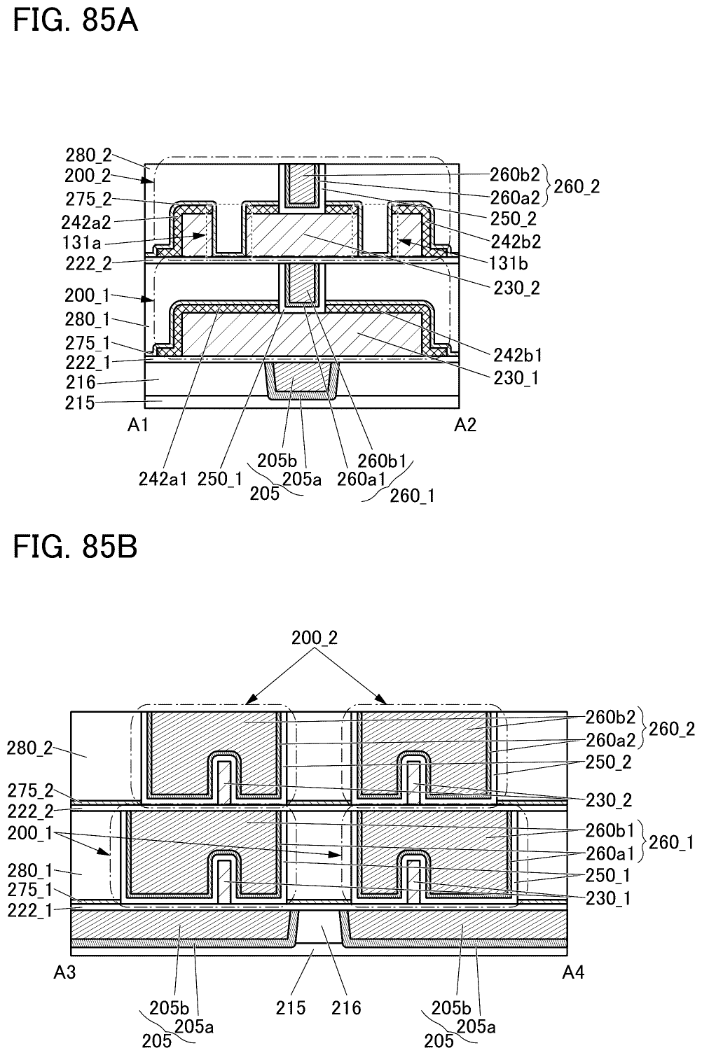

Then, the insulating film to be the insulator 250_2, the conductive film to be the conductor 260a2, and the conductive film to be the conductor 260b2 are polished by CMP treatment until the insulator 280_2 is exposed. That is, portions of the insulating film to be the insulator 250_2, the conductive film to be the conductor 260a2, and the conductive film to be the conductor 260b2 that are exposed from the opening 123 are removed. Thus, the insulator 250_2 and the conductor 260_2 (the conductor 260a2 and the conductor 260b2) are formed in the opening 123 overlapping the conductor 260_1 (FIG. 85A and FIG. 85B).

Accordingly, the insulator 250_2 is provided in contact with the sidewall and the bottom surface of the opening 123. The conductor 260_2 is positioned to fill the opening 123 with the insulator 250_2 therebetween. In this manner, two transistors 200_2 that face each other in the channel width direction are formed.

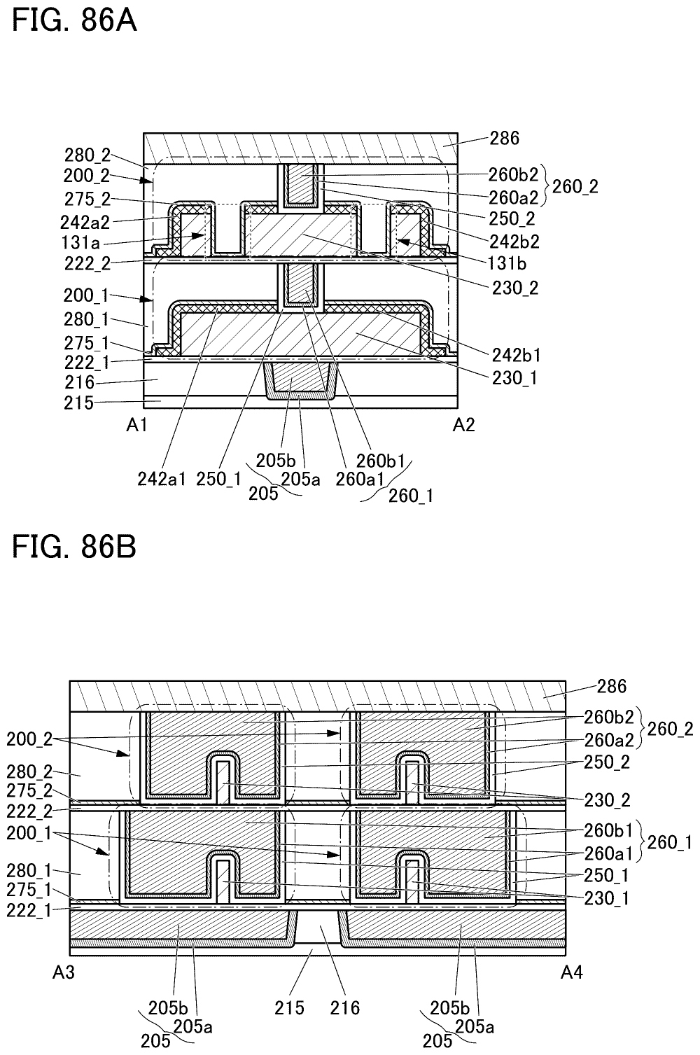

Next, the insulator 286 is formed over the insulator 250_2, the conductor 260_2, and the insulator 280_2 (FIG. 86A and FIG. 86B). The above description can be referred to for a material, a formation method, and the like that can be used for the insulator 286.

Subsequently, the insulator 286 is removed. A dry etching method, a wet etching method, or CMP can be used to remove the insulator 286. By the removal, the top surface of the insulator 250_2, the top surface of the conductor 260_2, and the top surface of the insulator 280_2 are exposed.

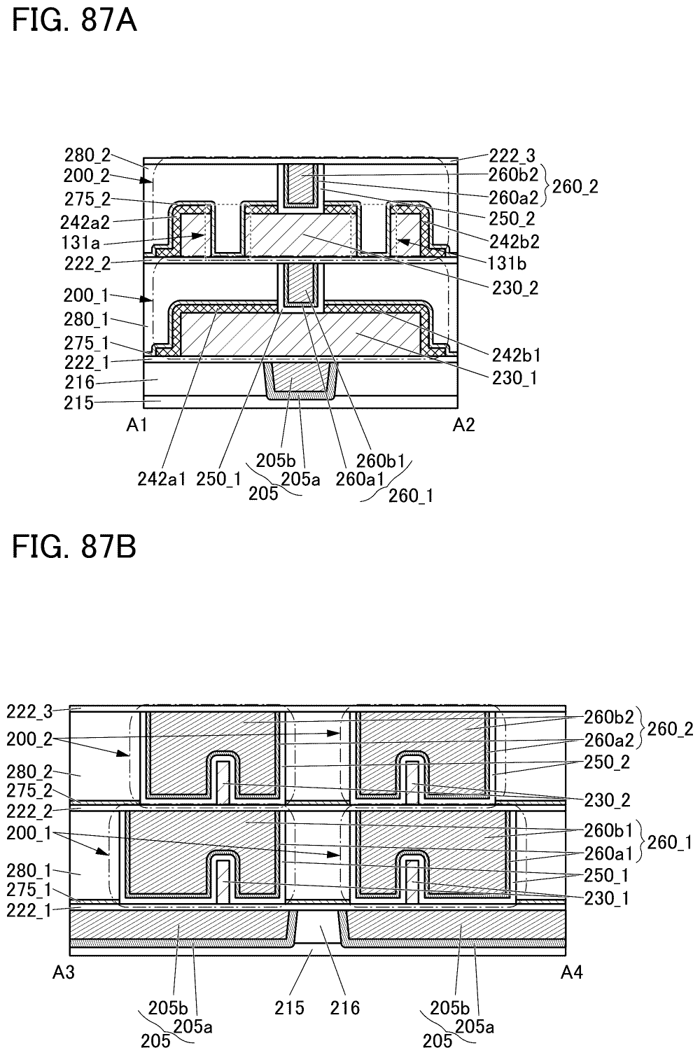

Next, the insulator 222_3 is formed in contact with the top surface of the insulator 250_2, the top surface of the conductor 260_2, and the top surface of the insulator 280_2 (FIG. 87A and FIG. 87B). The above description of the insulator 222_1 can be referred to for a material, a formation method, and the like that can be used for the insulator 222_3.

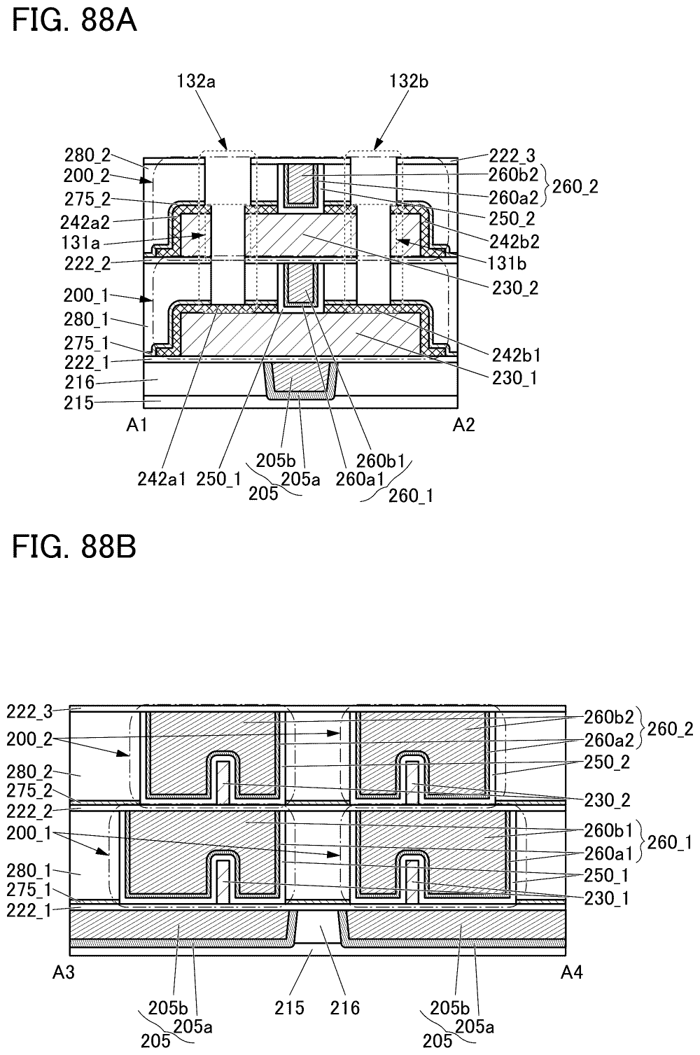

Then, the insulator 222_3, the insulator 280_2, the insulator 275_2, the insulator 222_2, the insulator 280_1, and the insulator 275_1 are processed by a lithography method, whereby the opening 132a reaching the conductor 242a1 is formed in a region overlapping the opening 131a and the opening 132b reaching the conductor 242b1 is formed in a region overlapping the opening 131b (FIG. 88A and FIG. 88B). A dry etching method or a wet etching method can be used for the processing. The processing removes a region of the insulator 275_2 that overlaps the opening 132a in a planar view and a region of the insulator 275_2 that overlaps the opening 132b in a planar view.

Next, a conductive film to be the conductor 243a1 and the conductor 243b1 is formed over the conductor 242a1, the conductor 242b1, and the insulator 222_3. The conductive film is formed to be in contact with the sidewalls and the bottom surfaces of the opening 132a and the opening 132b. The above description can be referred to for a material, a formation method, and the like that can be used for the conductive film to be the conductor 243a1 and the conductor 243b1.

Then, a conductive film to be the conductor 243a2 and the conductor 243b2 is formed over the conductive film to be the conductor 243a1 and the conductor 243b1. The above description can be referred to for a material, a formation method, and the like that can be used for the conductive film to be the conductor 243a2 and the conductor 243b2.

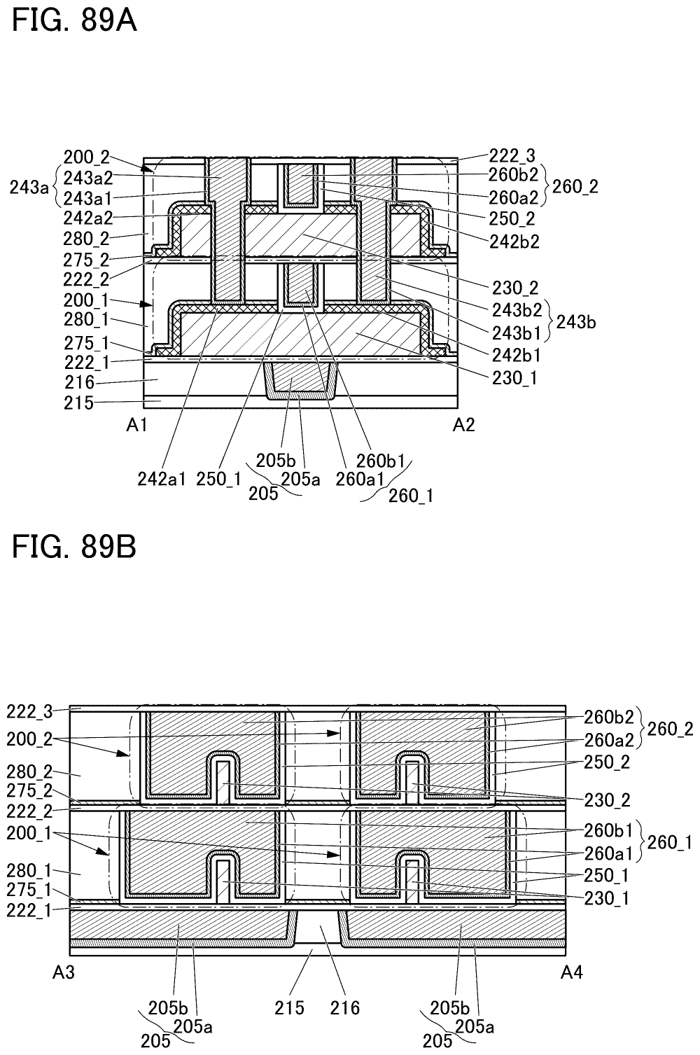

Subsequently, the conductive film to be the conductor 243a1 and the conductor 243b1 and the conductive film to be the conductor 243a2 and the conductor 243b2 are polished by CMP treatment until the insulator 222_3 is exposed. That is, portions of the conductive film to be the conductor 243a1 and the conductor 243b1 and the conductive film to be the conductor 243a2 and the conductor 243b2 that are exposed from the opening 132a and the opening 132b are removed. Thus, the conductor 243a (the conductor 243a1 and the conductor 243a2) is formed in the opening 132a. Moreover, the conductor 243b (the conductor 243b1 and the conductor 243b2) is formed in the opening 132b (FIG. 89A and FIG. 89B).

Accordingly, the conductor 242a1 and the conductor 242a2 are electrically connected to each other through the conductor 243a. The conductor 242b1 and the conductor 242b2 are electrically connected to each other through the conductor 243b.

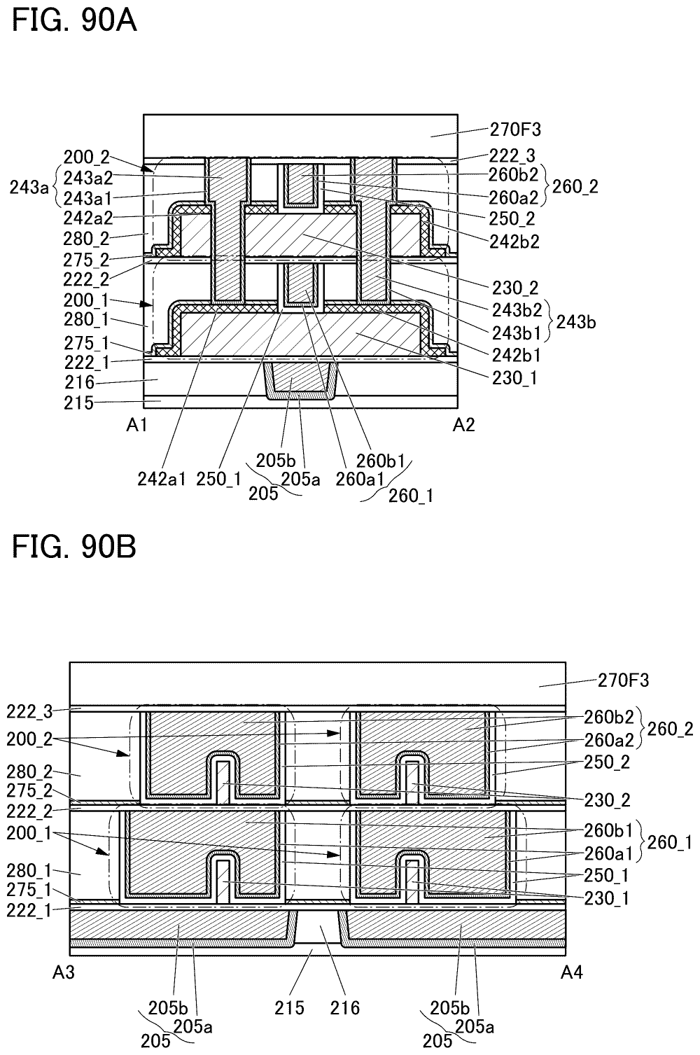

Next, an insulating film 270F3 is formed over the insulator 222_3 (FIG. 90A and FIG. 90B). The above description of the insulating film 270F1 can be referred to for a material, a formation method, and the like that can be used for the insulating film 270F3.

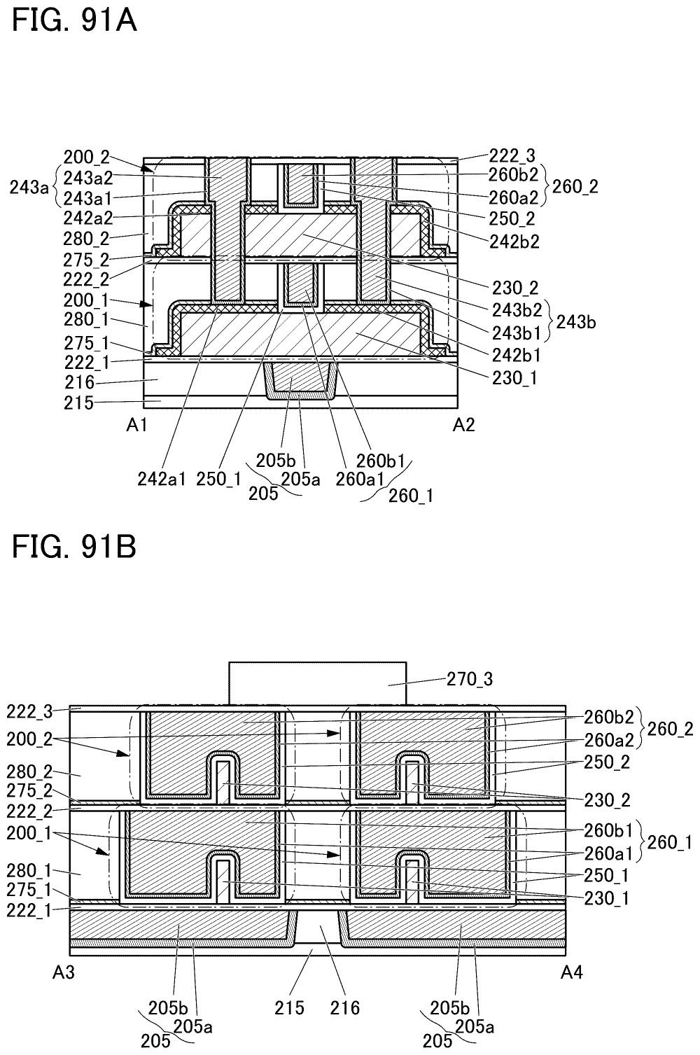

Then, the insulating film 270F3 is processed into an island shape by a lithography method, thereby forming an insulator 270_3 (FIG. 91A and FIG. 91B). The insulator 270_3 is formed to include regions overlapping the two opposite conductors 260_2 in the channel width direction of the transistor 200_2. The insulator 270_3 is preferably formed such that its side surface is perpendicular or substantially perpendicular to the top surface of the insulator 222_3. Accordingly, when an oxide film 230F3 to be formed later over the insulator 270_3 is processed by anisotropic etching, the oxide 230_3 in contact with the side surface of the insulator 270_3 can be formed with high accuracy. Moreover, in the case where a plurality of transistors are provided in the substrate plane, a small area and high density of the transistors can be achieved. By the processing, the insulating film 270F3 in a region where the oxide 230_3 is to be provided later is removed.

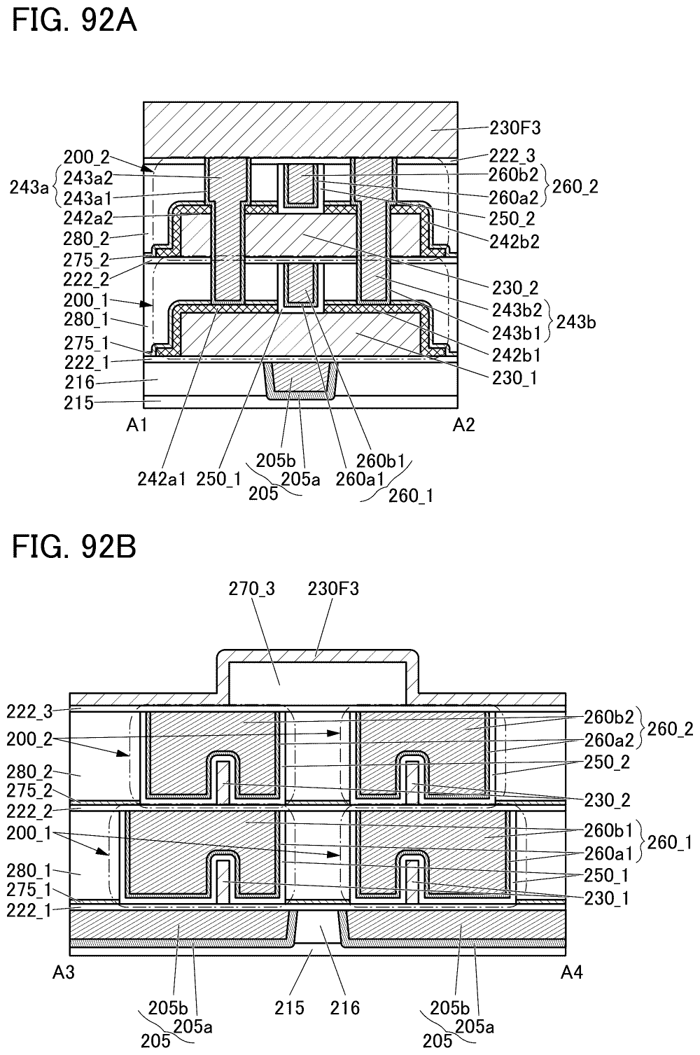

Then, the oxide film 230F3 is formed over the insulator 270_3 and the insulator 222_3 (FIG. 92A and FIG. 92B). The oxide film 230F3 includes a region in contact with the top surface and the side surface of the insulator 270_3 and the top surface of the insulator 222_3. The above description of the oxide film 230F1 can be referred to for a material, a formation method, and the like that can be used for the oxide film 230F3.

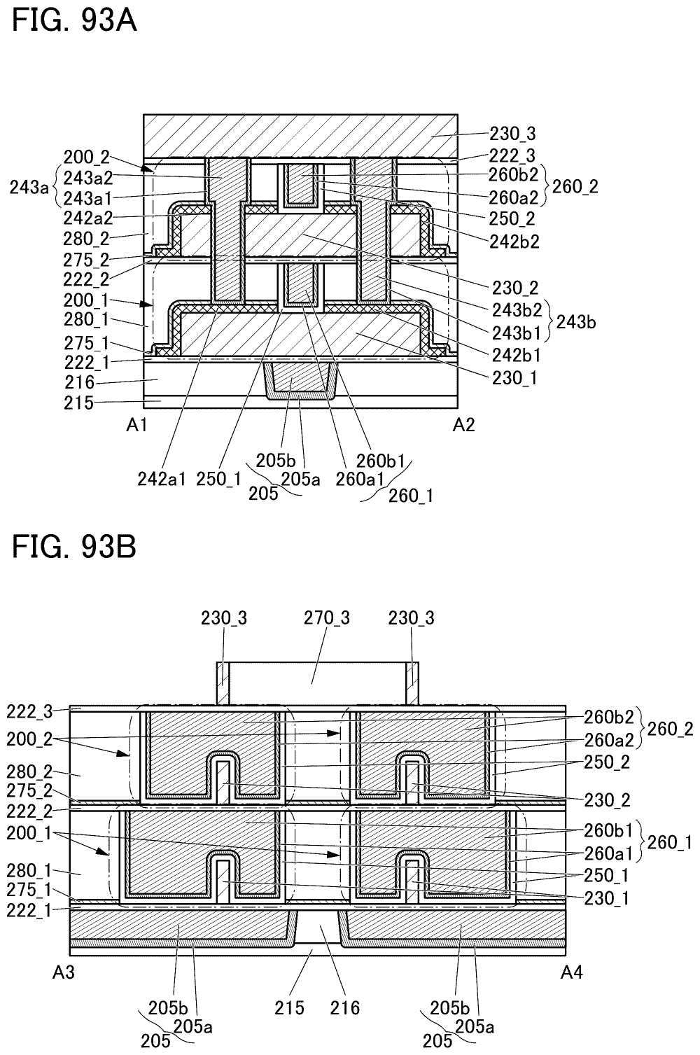

Next, the oxide film 230F3 is processed by anisotropic etching, thereby removing a region in contact with the top surface of the insulator 270_3 and a region in contact with the top surface of the insulator 222_3. Thus, the oxide 230_3 in contact with the side surface of the insulator 270_3 is formed (FIG. 93A and FIG. 93B).

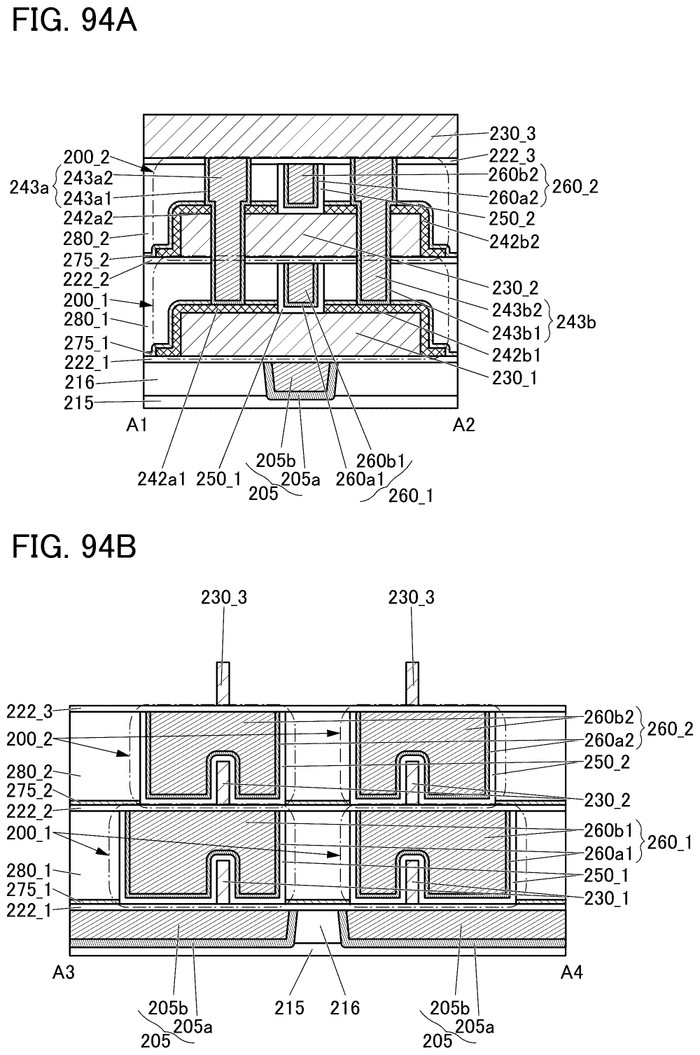

Then, the insulator 270_3 is removed (FIG. 94A and FIG. 94B). Thus, two island-shaped oxides 230_3 that face each other in the channel width direction of the transistors remain over the insulator 222_3 overlapping the conductor 260_2.

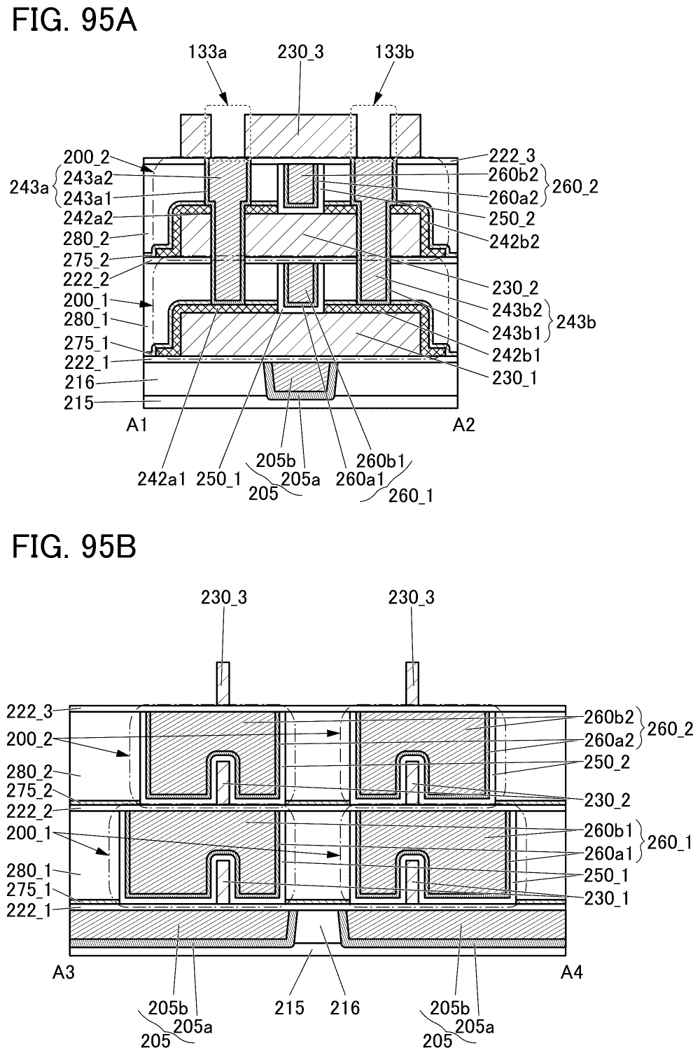

Next, by a lithography method, the oxide 230_3 is processed into an island shape, and the opening 133a is formed in a region overlapping the conductor 243a and the opening 133b is formed in a region overlapping the conductor 243b (FIG. 95A and FIG. 95B).

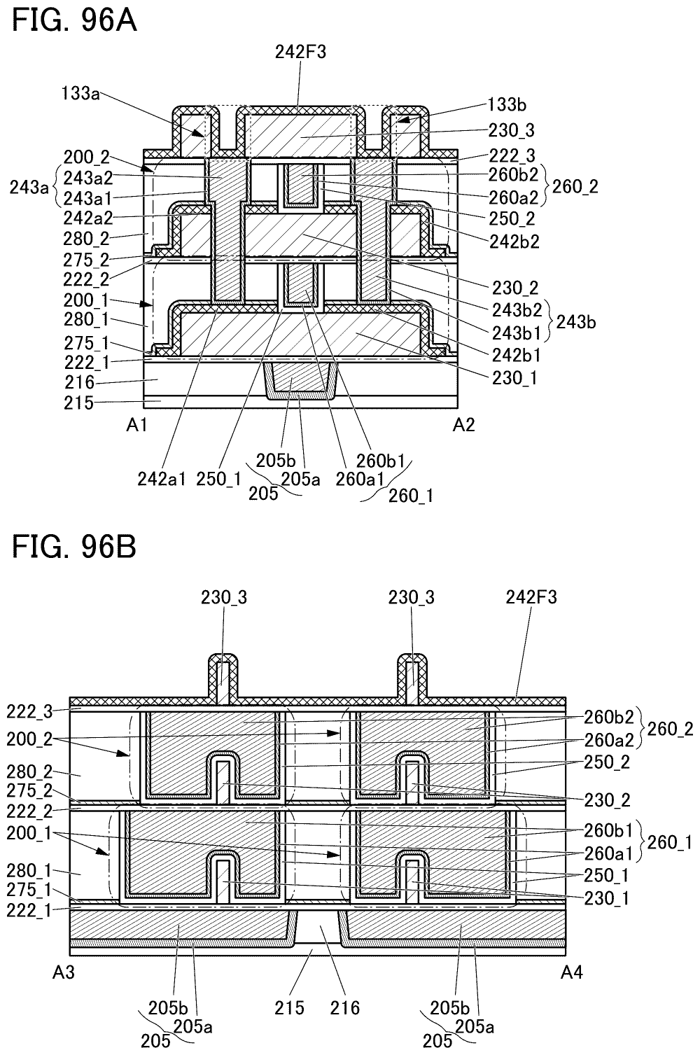

Subsequently, the conductive film 242F3 is formed to cover the oxide 230_3 and the insulator 222_3 (FIG. 96A and FIG. 96B). The conductive film 242F3 includes a region in contact with the top surface and the side surface of the oxide 230_3 and the top surface of the insulator 222_3. The above description of the conductive film 242F1 can be referred to for a material, a formation method, and the like that can be used for the conductive film 242F3.

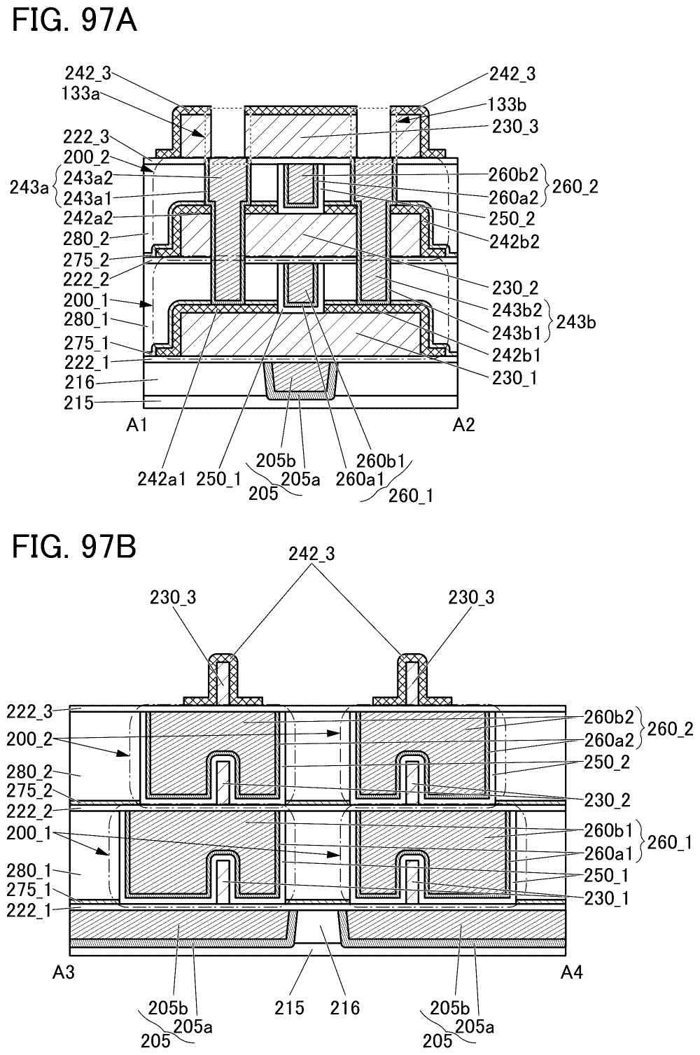

Next, the conductive film 242F3 is processed by a lithography method, whereby the island-shaped conductor 242_3 is formed in a region overlapping the oxide 230_3 (FIG. 97A and FIG. 97B). The conductor 242_3 is formed to cover the island-shaped oxide 230_3. The conductor 242_3 includes a region in contact with the top surface and the side surface of the oxide 230_3 and the top surface of the insulator 222_3. The oxide 230_3 and the conductor 242_3 are formed to at least partly overlap the conductor 260_1. The above description of the processing method and the like for conductive film 242F1 can be referred to for the processing method and the like for the oxide 230_3 and the conductive film 242F3. The conductor 243a, the conductor 243b, and the insulator 222_3 are exposed in a region that is not overlapped by the oxide 230_3 or the conductor 242_3 (e.g., a region overlapped by the opening 133a or the opening 133b).

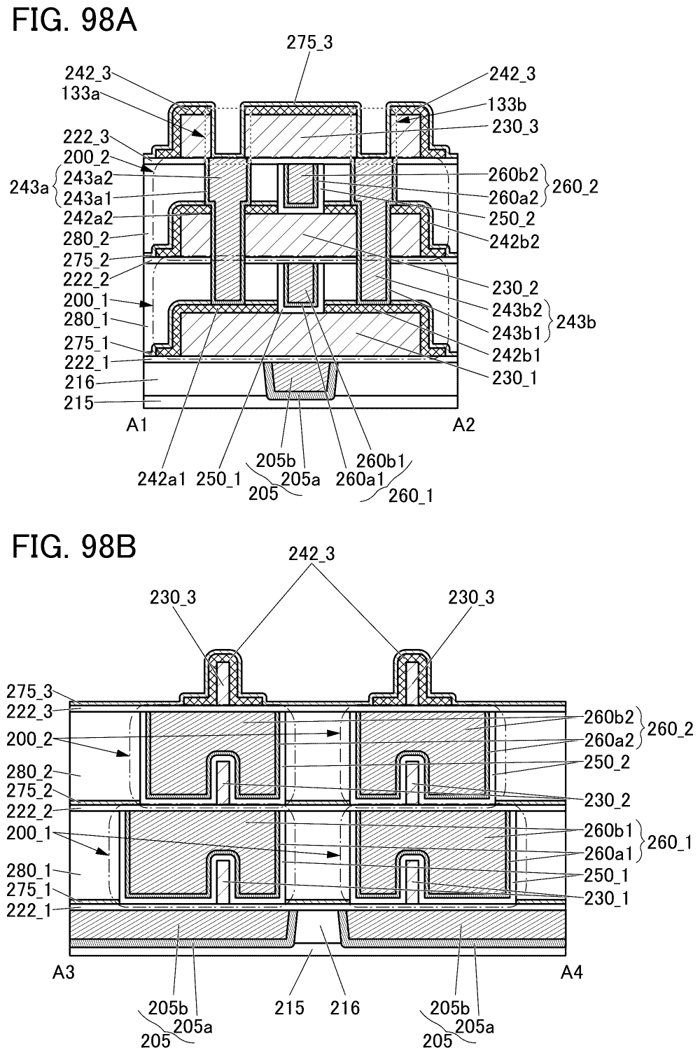

Then, the insulator 275_3 is deposited to cover the oxide 230_3 and the conductor 242_3 (FIG. 98A and FIG. 98B). The insulator 275_3 is provided in contact with the sidewalls and the bottom surfaces of the opening 133a and the opening 133b. The insulator 275_3 includes a region in contact with the side surface of the oxide 230_3, the side surface and the top surface of the conductor 242_3, and the top surface of the insulator 222_3. Note that the above description of the insulator 275_1 can be referred to for a material, deposition conditions, and the like that can be used for the insulator 275_3.

Next, the insulator 280_3 is deposited over the insulator 275_3. The above description of the insulator 280_1 can be referred to for a material, deposition conditions, and the like that can be used for the insulator 280_3.

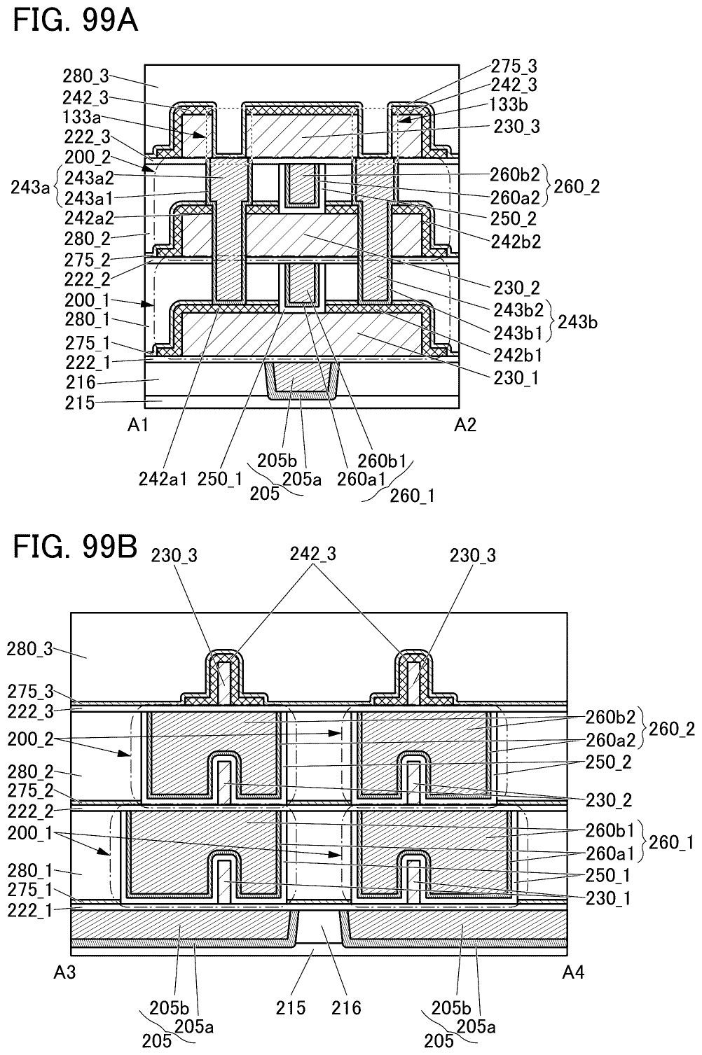

The top surface of the insulator 280_3 is preferably planarized by being subjected to CMP treatment after the deposition (FIG. 99A and FIG. 99B). Note that, for example, silicon nitride may be deposited over the insulator 280_3 by a sputtering method and CMP treatment may be performed on the silicon nitride until the insulator 280_3 is reached.

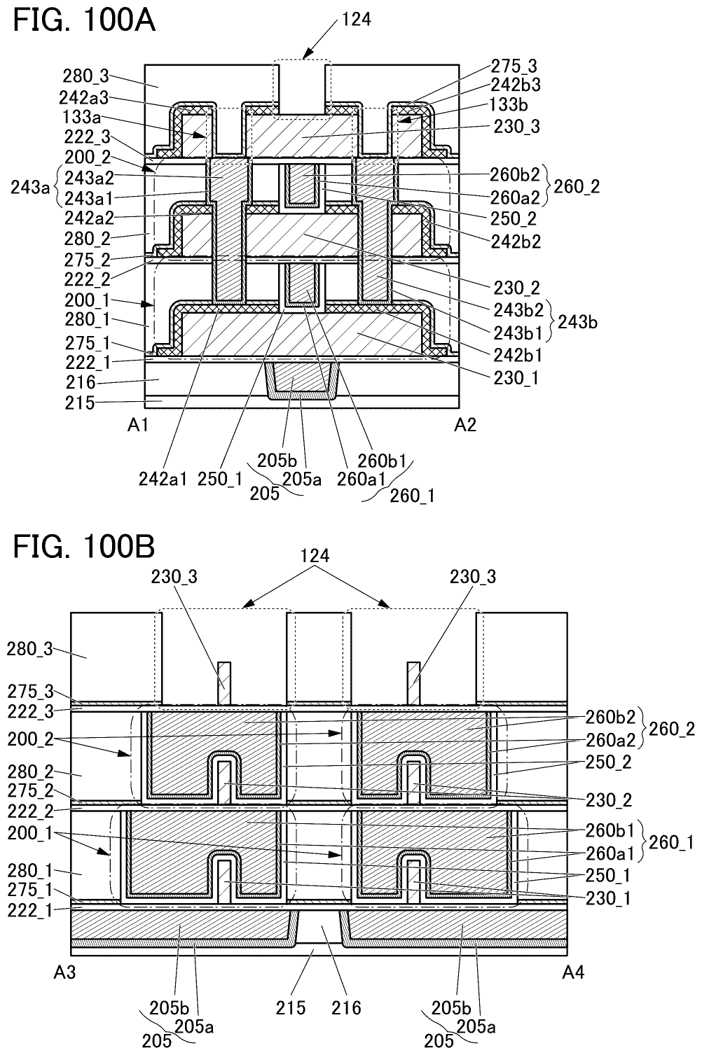

Then, the conductor 242_3, the insulator 275_3, and the insulator 280_3 are processed by a lithography method, thereby forming two openings 124 reaching the oxides 230_3 (FIG. 100A and FIG. 100B). The openings 124 are provided in regions where the oxide 230_3 and the conductor 260_2 overlap each other. The above description of the formation method and the like for the opening 122 can be referred to for the formation method and the like for the opening 124.

By this processing, the conductor 242_3 is divided into the conductor 242a3 and the conductor 242b3 each having an island shape.

The width of the opening 124, the width of the opening 123, and the width of the opening 122 are preferably substantially the same. This structure allows the transistor 200_1 to the transistor 200_3 to have the same channel length and thus can reduce variations of electrical characteristics in the semiconductor device 200.

Then, an insulating film to be the insulator 250_3 is formed over the oxide 230_3 and the insulator 280_3. The insulating film is formed to be in contact with the sidewall and the bottom surface of the opening 124. The above description of the material, the formation method, and the like that can be used for the insulating film to be the insulator 250_1 can be referred to for a material, a formation method, and the like that can be used for the insulating film to be the insulator 250_3.

Next, a conductive film to be the conductor 260a3 and a conductive film to be the conductor 260b3 are formed in this order. The above description of the materials, the formation methods, and the like that can be used for the conductive film to be the conductor 260a1 and the conductive film to be the conductor 260b1 can be referred to for materials, formation methods, and the like that can be used for the conductive film to be the conductor 260a3 and the conductive film to be the conductor 260b3.

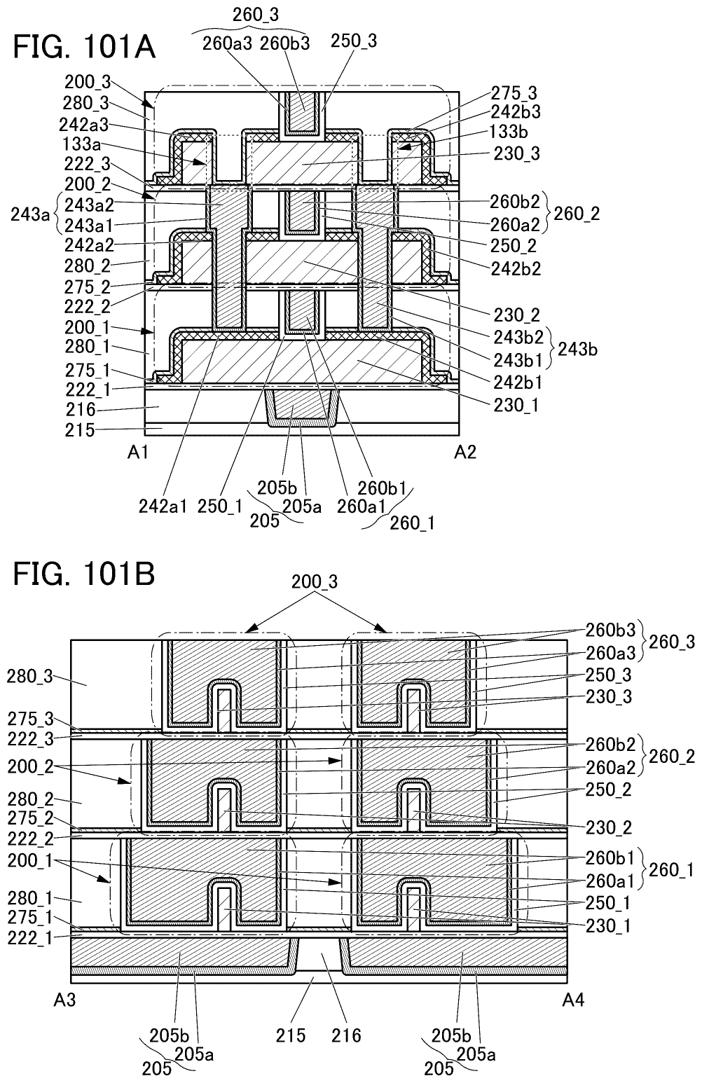

Then, the insulating film to be the insulator 250_3, the conductive film to be the conductor 260a3, and the conductive film to be the conductor 260b3 are polished by CMP treatment until the insulator 280_3 is exposed. That is, portions of the insulating film to be the insulator 250_3, the conductive film to be the conductor 260a3, and the conductive film to be the conductor 260b3 that are exposed from the opening 124 are removed. Thus, the insulator 250_3 and the conductor 260_3 (the conductor 260a3 and the conductor 260b3) are formed in the opening 124 overlapping the conductor 260_2 (FIG. 101A and FIG. 101B).

Accordingly, the insulator 250_3 is provided in contact with the sidewall and the bottom surface of the opening 124. The conductor 260_3 is positioned to fill the opening 124 with the insulator 250_3 therebetween. In this manner, two transistors 200_3 that face each other in the channel width direction are formed.

Next, the insulator 286 is formed over the insulator 250_3, the conductor 260_3, and the insulator 280_3. The above description can be referred to for a material, a formation method, and the like that can be used for the insulator 286.

Subsequently the insulator 283 is formed over the insulator 286. The above description can be referred to for a material, a formation method, and the like that can be used for the insulator 283.

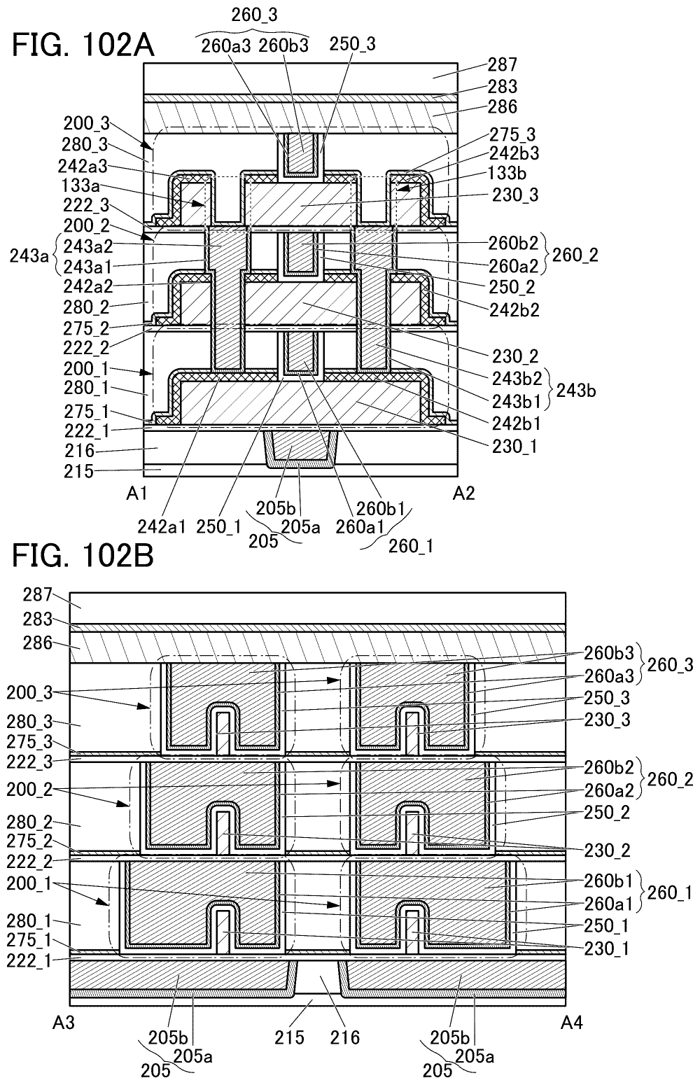

Next, the insulator 287 is formed over the insulator 283 (FIG. 102A and FIG. 102B). The above description can be referred to for a material, a formation method, and the like that can be used for the insulator 287.

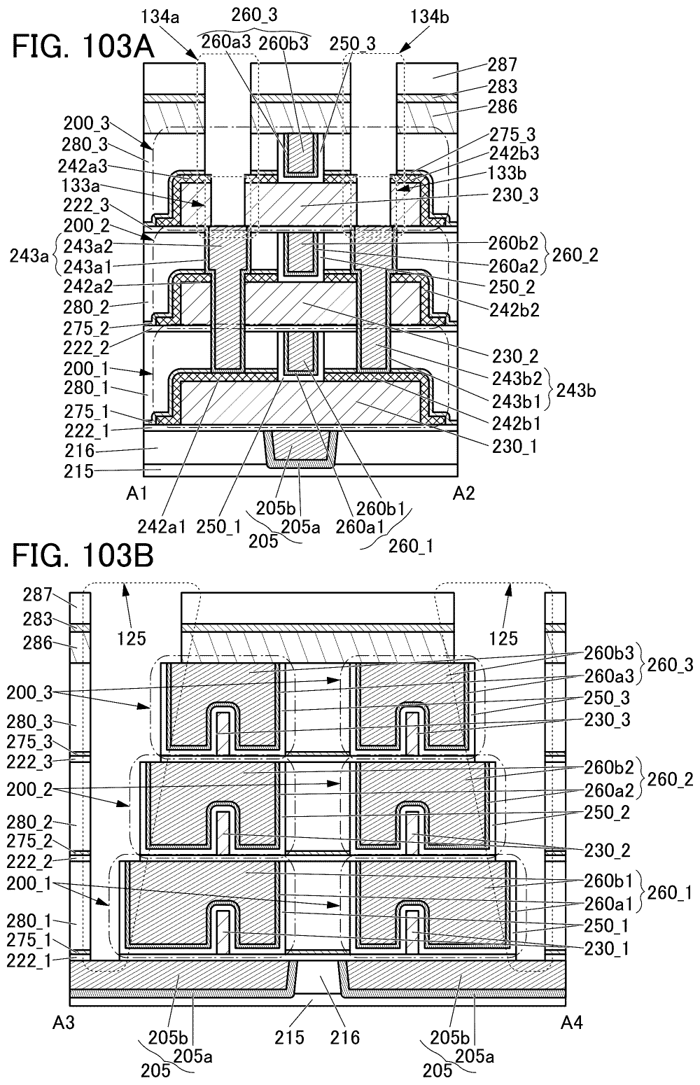

Then, the insulator 287, the insulator 283, the insulator 286, the insulator 280_3, and the insulator 275_3 are processed by a lithography method, whereby the opening 134a reaching the conductor 243a is formed in a region overlapping the opening 133a and the opening 134b reaching the conductor 243b is formed in a region overlapping the opening 133b (FIG. 103A).

A dry etching method or a wet etching method can be used for the processing. The processing removes a region of the insulator 275_3 that overlaps the opening 134a in a planar view and a region of the insulator 275_3 that overlaps the opening 134b in a planar view.

Next, a conductive film to be the conductor 244a1 and the conductor 244b1 is formed over the conductor 243a, the conductor 243b, the conductor 242a3, the conductor 242b3, and the insulator 287. The conductive film is formed to be in contact with the sidewalls and the bottom surfaces of the opening 134a and the opening 134b. Thus, the conductor 244a1 is in contact with the top surface of the conductor 243a and the top surface of the conductor 242a3. The conductor 244b1 is in contact with the top surface of the conductor 243b and the top surface of the conductor 242b3. The above description can be referred to for a material, a formation method, and the like that can be used for the conductive film to be the conductor 244a1 and the conductor 244b1.

Then, a conductive film to be the conductor 244b2 to be the conductor 244a2 is formed over the conductive film to be the conductor 244a1 and the conductor 244b1. The above description can be referred to for a material, a formation method, and the like that can be used for the conductive film to be the conductor 244a2 and the conductor 244b2.

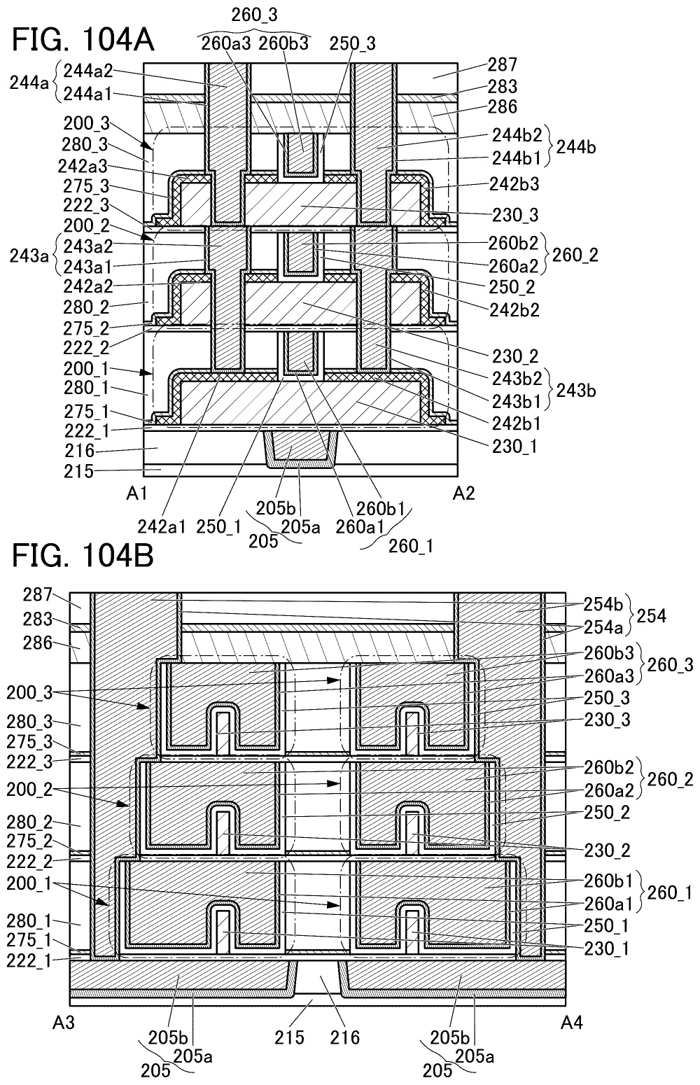

Subsequently, the conductive film to be the conductor 244a1 and the conductor 244b1 and the conductive film to be the conductor 244a2 and the conductor 244b2 are polished by CMP treatment until the insulator 287 is exposed. That is, portions of the conductive film to be the conductor 244a1 and the conductor 244b1 and the conductive film to be the conductor 244a2 and the conductor 244b2 that are exposed from the opening 134a and the opening 134b are removed. Thus, the conductor 244a (the conductor 244a1 and the conductor 244a2) is formed in the opening 134a reaching the conductor 243a. Moreover, the conductor 244b (the conductor 244b1 and the conductor 244b2) is formed in the opening 134b reaching the conductor 243b (FIG. 104A).

Accordingly, the conductor 244a electrically connects the conductor 242a3 and the conductor 243a. The conductor 244b electrically connects the conductor 242b3 and the conductor 243b. That is, the conductor 243a and the conductor 244a electrically connect the conductors functioning as either the source electrodes or the drain electrodes (the conductor 242a1 to the conductor 242a3) of the transistor 200_1 to the transistor 200_3. The conductor 243b and the conductor 244b electrically connect the conductors functioning as the others of the source electrodes and the drain electrodes (the conductor 242b1 to the conductor 242b3) of the transistor 200_1 to the transistor 200_3.

Subsequently, the insulator 287, the insulator 283, the insulator 286, the insulator 280_3, the insulator 275_3, the insulator 222_3, the insulator 280_2, the insulator 275_2, the insulator 222_2, the insulator 280_1, the insulator 275_1, and the insulator 222_1 are processed by a lithography method, whereby two openings 125 reaching the conductors 205 are formed (FIG. 103B). The opening 125 includes a region overlapping the top surface of the conductor 205, the top surface of the conductor 260_1, the top surface of the conductor 260_2, and the top surface of the conductor 260_3 in a planar view.

A dry etching method or a wet etching method can be used for the processing. By the processing, part of the top surface of the conductor 205, part of the top surface of the conductor 260_1, part of the top surface of the conductor 260_2, and part of the top surface of the conductor 260_3 are exposed in the opening 125.

Next, a conductive film to be the conductor 254a is formed over the conductor 205, the conductor 260_1, the conductor 260_2, the conductor 260_3, and the insulator 287. The conductive film is formed to be in contact with the sidewall and the bottom surface of the opening 125. Thus, the conductive film is in contact with the top surface of the conductor 205, the top surface of the conductor 260_1, the top surface of the conductor 260_2, and the top surface of the conductor 260_3. The above description can be referred to for a material, a formation method, and the like that can be used for the conductive film to be the conductor 254a.

Subsequently, a conductive film to be the conductor 254b is formed over the conductive film to be the conductor 254a. The above description can be referred to for a material, a formation method, and the like that can be used for the conductive film to be the conductor 254b.

Then, the conductive film to be the conductor 254a and the conductive film to be the conductor 254b are polished by CMP treatment until the insulator 287 is exposed. That is, portions of the conductive film to be the conductor 254a and the conductive film to be the conductor 254b that are exposed from the openings 125 are removed. Thus, the conductor 254 (the conductor 254a and the conductor 254b) is formed in each of the two openings 125 reaching the conductors 205 (FIG. 104B).

Accordingly, the conductor 254 electrically connects the conductor 260_1 to the conductor 260_3 and the conductor 205. That is, the conductor 254 electrically connects the conductor 205 and the conductors functioning as the gate electrodes (the conductor 260_1 to the conductor 260_3) of the transistor 200_1 to the transistor 200_3.

Although an example of a method in which the conductors 244a and 244b and the conductor 254 are formed in different steps is described above, one embodiment of the present invention is not limited thereto. For example, the conductor 244a, the conductor 244b, and two conductors 254 may be formed at the same time in the following manner: the openings 134a and 134b and the two openings 125 are formed at the same time, a first conductive film and a second conductive film are formed in this order, and CMP treatment is performed until the top surface of the insulator 287 is exposed.

Next, a conductive film to be the conductor 245a, the conductor 245b, and the conductor 255 is formed over the conductor 244a, the conductor 244b, the two conductors 254, and the insulator 287. The above description can be referred to for a material, a formation method, and the like that can be used for the conductive film.

Then, by a lithography method, the conductor 245a is formed to include a region overlapping the conductor 244a, the conductor 245b is formed to include a region overlapping the conductor 244b, and two conductors 255 are formed to include regions overlapping the two respective conductors 254.

Through the above steps, the semiconductor device 200 illustrated in FIG. 15 to FIG. 17 can be manufactured.

### Example 4 of Method for Manufacturing Semiconductor Device

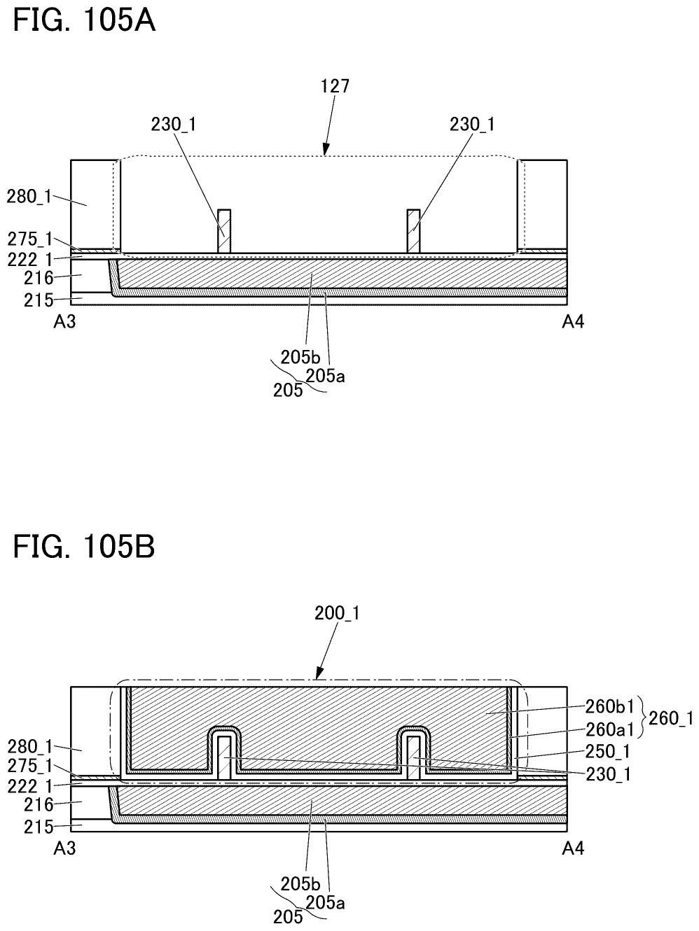

An example of a method for manufacturing the semiconductor device 200 illustrated in FIG. 20 and FIG. 21 will be described with reference to FIG. 105A and FIG. 105B.

Note that only part of the method for manufacturing the semiconductor device 200 illustrated in FIG. 20 and FIG. 21 is described below.

FIG. 105A and FIG. 105B are cross-sectional views along the dashed-dotted line A3-A4 in FIG. 20.

First, the steps up to FIG. 70B described in <Example 3 of method for manufacturing semiconductor device> are performed. Note that unlike in the description of <Example 3 of method for manufacturing semiconductor device>, only one conductor 205 is formed in the channel width direction of the transistors included in the semiconductor device 200; the description of <Example 3 of method for manufacturing semiconductor device> can be referred to for the other points (e.g., a material and a formation method that can be used for the conductor 205).

Next, the conductor 242_1, the insulator 275_1, and the insulator 280_1 are processed by a lithography method, thereby forming an opening 127 reaching the insulator 222_1 (FIG. 105A). The opening 127 reaching the insulator 222_1 is provided in a region where the oxides 230_1 and the conductor 205 overlap each other.

Unlike in <Example 3 of method for manufacturing semiconductor device> in which the two openings 122 are formed in the channel width direction of the transistors by the processing of the conductor 242_1, the insulator 275_1, and the insulator 280_1 by a lithography method (FIG. 71B), one opening 127 is formed in the channel width direction in FIG. 105A. The opening 127 is provided in a region where the two oxides 230_1 and the conductor 205 overlap each other.

Then, an insulating film to be the insulator 250_1 is formed over the oxides 230_1 and the insulator 280_1. The insulating film is formed to be in contact with the sidewall and the bottom surface of the opening 127. The above description can be referred to for a material, a formation method, and the like that can be used for the insulating film to be the insulator 250_1.

Next, a conductive film to be the conductor 260a1 and a conductive film to be the conductor 260b1 are formed in this order. The above description can be referred to for the materials, formation methods, and the like that can be used for the conductive film to be the conductor 260a1 and the conductive film to be the conductor 260b1.

Then, the insulating film to be the insulator 250_1, the conductive film to be the conductor 260a1, and the conductive film to be the conductor 260b1 are polished by CMP treatment until the insulator 280_1 is exposed. That is, portions of the insulating film to be the insulator 250_1, the conductive film to be the conductor 260a1, and the conductive film to be the conductor 260b1 that are exposed from the opening 127 are removed. Thus, the insulator 250_1 and the conductor 260_1 (the conductor 260a1 and the conductor 260b1) are formed in the opening 127 overlapping the conductor 205 (FIG. 105B).

Accordingly, the insulator 250_1 is provided in contact with the sidewall and the bottom surface of the opening 127. The conductor 260_1 is positioned to fill the opening 127 with the insulator 250_1 therebetween. In this manner, the transistors 200_1 are formed in which the two oxides 230_1 are provided in the channel width direction and share one insulator 250_1 and one conductor 260_1.

Next, the steps described with reference to FIG. 73A to FIG. 83B are performed.

Then, the steps described with reference to FIG. 105A and FIG. 105B are performed, thereby forming the transistors 200_2 in which the two oxides 230_2 are provided in the channel width direction and share one insulator 250_2 and one conductor 260_2.

Subsequently, the steps described with reference to FIG. 86A to FIG. 99B are performed.

Then, the steps described with reference to FIG. 105A and FIG. 105B are performed, thereby forming the transistors 200_3 in which the two oxides 230_3 are provided in the channel width direction and share one insulator 250_3 and one conductor 260_3.

Next, the steps described with reference to FIG. 102A to FIG. 104B are performed. Note that unlike in the description of <Example 3 of method for manufacturing semiconductor device>, only one conductor 254 is formed on the A4 side in the channel width direction of the transistors included in the semiconductor device 200; the description of <Example 3 of method for manufacturing semiconductor device> can be referred to for the other points (e.g., a material and a formation method that can be used for the conductor 254).

Through the above steps, the semiconductor device 200 illustrated in FIG. 20 and FIG. 21 can be manufactured.

As described above, the use of the manufacturing method of one embodiment of the present invention enables manufacture of the semiconductor device 200 that is minute and has a high degree of integration.

The semiconductor device of this embodiment includes an OS transistor. Since the off-state current of the OS transistors is low, a semiconductor device with low power consumption can be obtained. Since the OS transistors have excellent frequency characteristics, a semiconductor device with a high operating speed can be obtained. The use of the OS transistors makes it possible to obtain a semiconductor device having favorable electrical characteristics, a semiconductor device with a small variation in electrical characteristics of transistors, a semiconductor device with a high on-state current, or a highly reliable semiconductor device.

This embodiment can be combined with the other embodiments as appropriate. In the case where a plurality of structure examples are shown in one embodiment in this specification, the structure examples can be combined as appropriate.

### Embodiment 2

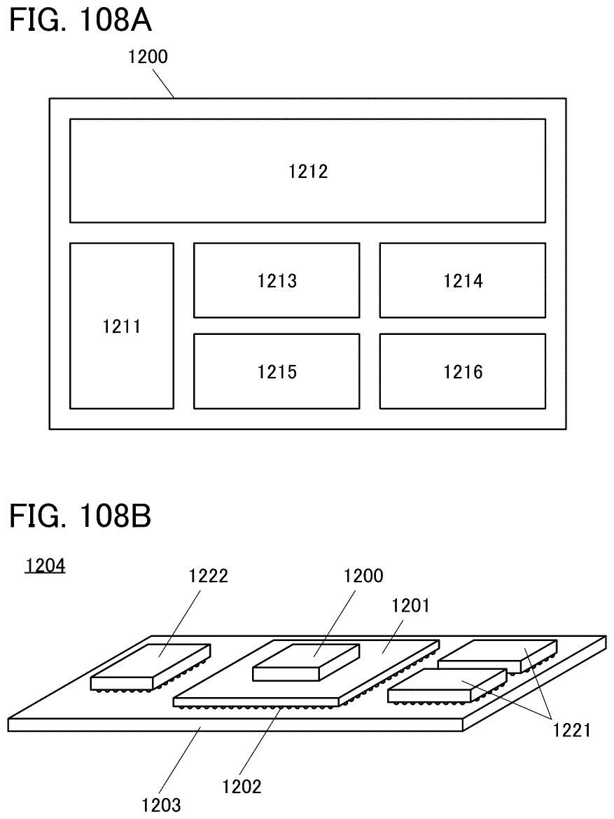

In this embodiment, an example of a chip on which the semiconductor device of one embodiment of the present invention is mounted will be described with reference to FIG. 108A and FIG. 108B.

A plurality of circuits (systems) are mounted on a chip 1200 illustrated in FIG. 108A and FIG. 108B. A technique for integrating a plurality of circuits (systems) into one chip is referred to as system on chip (SoC) in some cases.

As illustrated in FIG. 108A, the chip 1200 includes a CPU 1211, a GPU 1212, one or more analog arithmetic units 1213, one or more memory controllers 1214, one or more interfaces 1215, one or more network circuits 1216, and the like.

The chip 1200 is provided with a bump (not illustrated) and is connected to a first surface of a package substrate 1201 as illustrated in FIG. 108B. A plurality of bumps 1202 are provided on the rear side of the first surface of the package substrate 1201, and the package substrate 1201 is connected to a motherboard 1203.

Memory devices such as a DRAM 1221 and a flash memory 1222 may be provided over the motherboard 1203. For example, the OS transistors described in the foregoing embodiment can be used as transistors included in the DRAM 1221. This can make the DRAM 1221 have low power consumption, operate at high speed, and have a large capacity.

The CPU 1211 preferably includes a plurality of CPU cores. The GPU 1212 preferably includes a plurality of GPU cores. The CPU 1211 and the GPU 1212 may each include a memory for temporarily storing data. Alternatively, a common memory for the CPU 1211 and the GPU 1212 may be provided in the chip 1200. The aforementioned OS transistor can be used as transistors included in the memory. The GPU 1212 is suitable for parallel computation of a large number of pieces of data and thus can be used for image processing or product-sum operation. When an image processing circuit or a product-sum operation circuit using the OS transistor described in the foregoing embodiment is provided in the GPU 1212, image processing or product-sum operation can be performed with low power consumption.

Since the CPU 1211 and the GPU 1212 are provided in the same chip, a wiring between the CPU 1211 and the GPU 1212 can be shortened; accordingly, data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit with an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit for a LAN (Local Area Network) or the like. The network circuit 1216 may also include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic appliance such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 3

In this embodiment, application examples of the semiconductor device of one embodiment of the present invention will be described.

The semiconductor device of one embodiment of the present invention can be used as memory devices of a variety of electronic appliances (e.g., information terminals, computers, smartphones, e-book readers, digital still cameras, video cameras, video recording/reproducing devices, navigation systems, and game machines). In addition, the semiconductor device can also be used for image sensors, IoT (Internet of Things), healthcare-related devices, and the like. This enables electronic appliances to achieve low power consumption. When the OS transistor described in the foregoing embodiment is used in an integrated circuit such as a CPU or a GPU of the electronic appliances, power consumption can be further reduced. Note that here, computers refer not only to tablet computers, laptop computers, and desktop computers, but also to large computers such as server systems.

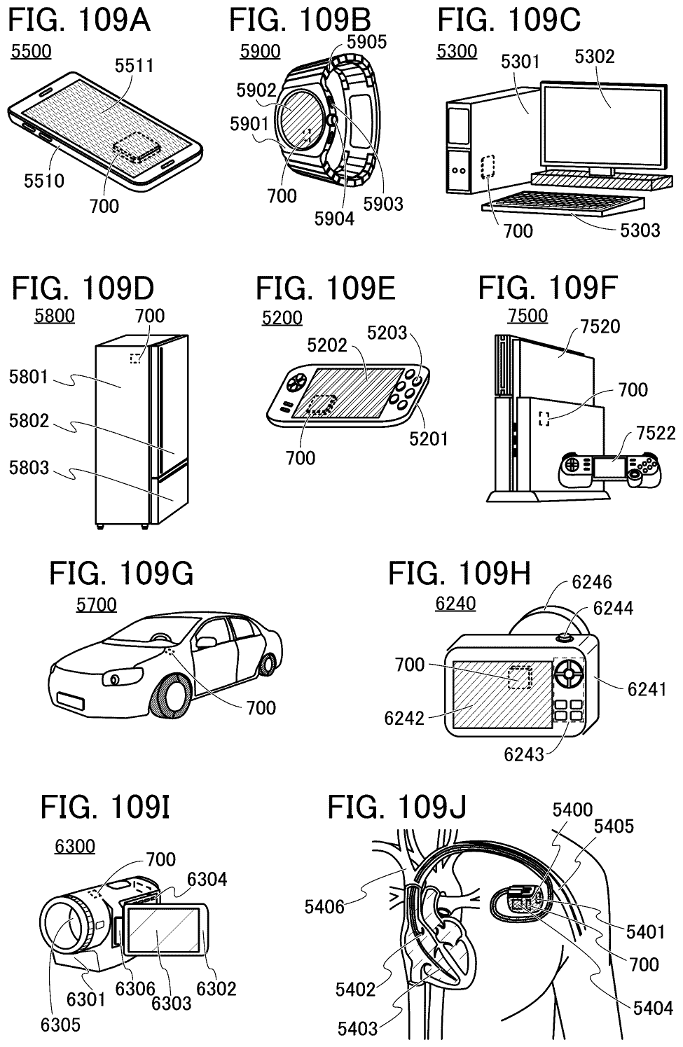

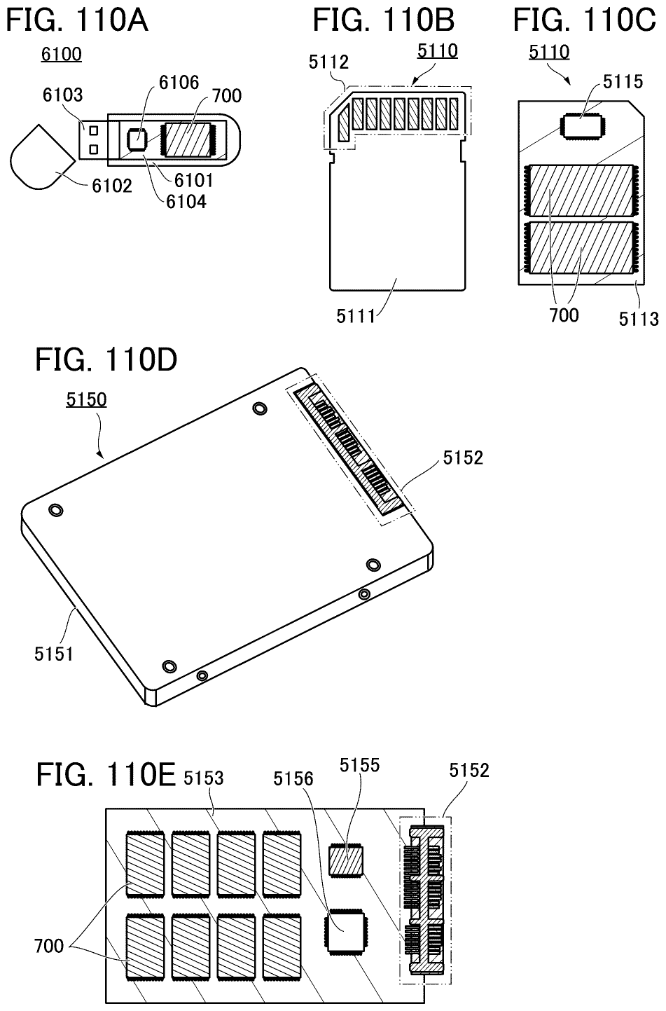

Examples of electronic appliances including the semiconductor device of one embodiment of the present invention will be described. Note that FIG. 109A to FIG. 109J and FIG. 110A to FIG. 110E each illustrate a state where the electronic component 700, which is described in the foregoing embodiment and includes the semiconductor device, is included in an electronic appliance.

### Mobile Phone

An information terminal 5500 illustrated in FIG. 109A is a mobile phone (smartphone), which is a type of information terminal. The information terminal 5500 includes a housing 5510 and a display portion 5511. As input interfaces, a touch panel is provided in the display portion 5511 and a button is provided in the housing 5510.

By using the semiconductor device of one embodiment of the present invention, the information terminal 5500 can retain a temporary file generated at the time of executing an application (e.g., a web browser's cache or the like).

### Wearable Terminal

FIG. 109B illustrates an information terminal 5900 as an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by using the semiconductor device of one embodiment of the present invention.

### Information Terminal

FIG. 109C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by using the semiconductor device of one embodiment of the present invention.

FIG. 109A to FIG. 109C illustrate the smartphone, the wearable terminal, and the desktop information terminal as electronic appliances; other examples of information terminals include a PDA (Personal Digital Assistant), a laptop information terminal, and a workstation.

### Household Appliance

FIG. 109D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is compatible with IT.

The semiconductor device of one embodiment of the present invention can be used in the electric refrigerator-freezer 5800. The electric refrigerator-freezer 5800 can transmit and receive information on food stored in the electric refrigerator-freezer 5800 and food expiration dates, for example, to and from an information terminal or the like via the Internet or the like. In the electric refrigerator-freezer 5800, the semiconductor device of one embodiment of the present invention can retain a temporary file generated at the time of transmitting the information.

FIG. 109D illustrates the electric refrigerator-freezer as a household appliance; other examples of household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### Game Machines

FIG. 109E illustrates a portable game machine 5200 as an example of a game machine. The portable game machine 5200 includes a housing 5201, a display portion 5202, a button 5203, and the like.

FIG. 109F illustrates a stationary game machine 7500 as an example of a game machine. The stationary game machine 7500 can be especially referred to as a home-use stationary game machine. The stationary game machine 7500 includes a main body 7520 and a controller 7522. Note that the controller 7522 can be connected to the main body 7520 with or without a wire. Although not illustrated in FIG. 109F, the controller 7522 can include a display portion that displays a game image, and an input interface besides a button, such as a touch panel, a stick, a rotating knob, or a sliding knob. The shape of the controller 7522 is not limited to that illustrated in FIG. 109F, and can be changed variously in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include one or more of a camera, a depth sensor, and a microphone so that the game player can play a game using a gesture or a voice instead of a controller.

In addition, videos displayed on the game machine can be output with a display device such as a television device, a personal computer display, a game display, or a head-mounted display.

By using the semiconductor device of one embodiment of the present invention, the portable game machine 5200 or the stationary game machine 7500 can achieve low power consumption. Moreover, heat generation from a circuit can be reduced owing to low power consumption; thus, the influence of heat generation on the circuit itself, a peripheral circuit, and a module can be reduced.

Moreover, by using the semiconductor device of one embodiment of the present invention, the portable game machine 5200 or the stationary game machine 7500 can retain a temporary file necessary for arithmetic operation that occurs during game play.

FIG. 109E and FIG. 109F illustrate the portable game machine and the home-use stationary game machine as examples of game machines; other examples of game machines include an arcade game machine installed in an entertainment facility (e.g., a game center and an amusement park) and a throwing machine for batting practice, installed in sports facilities.

### Moving Vehicle

The semiconductor device of one embodiment of the present invention can be used in an automobile, which is a moving vehicle, and the periphery of a driver's seat in the automobile.

FIG. 109G illustrates an automobile 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the automobile 5700. In addition, a memory device showing the above information may be provided around the driver's seat.

In particular, the display device can compensate for the view obstructed by the pillar or the like, the blind areas for the driver's seat, and the like by displaying a video taken by an imaging device (not illustrated) provided for the automobile 5700, thereby providing a high level of safety. That is, displaying an image taken by the imaging device provided on the exterior of the automobile 5700 can compensate for blind areas and improve safety.

The semiconductor device of one embodiment of the present invention can temporarily retain information; thus, the semiconductor device can be used to retain temporary information necessary in a system conducting automatic driving, navigation, and risk prediction for the automobile 5700, for example. The display device may be configured to display temporary information regarding navigation, risk prediction, or the like. Moreover, the semiconductor device may be configured to retain a video of a driving recorder provided in the automobile 5700.

Although the automobile is described above as an example of a moving vehicle, the moving vehicle is not limited to the automobile. Other examples of the moving vehicle include a train, a monorail train, a ship, and a flying object (a helicopter, an unmanned aircraft (drone), an airplane, and a rocket).

### Camera

The semiconductor device of one embodiment of the present invention can be used in a camera.

FIG. 109H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that the digital camera 6240 is configured here such that the lens 6246 is detachable from the housing 6241 for replacement; alternatively, the lens 6246 may be integrated with the housing 6241. In addition, the digital camera 6240 may be configured to be additionally equipped with a stroboscope, a viewfinder, or the like.

By using the semiconductor device of one embodiment of the present invention, the digital camera 6240 can have low power consumption. Moreover, heat generation from a circuit can be reduced owing to low power consumption; thus, the influence of heat generation on the circuit itself, a peripheral circuit, and a module can be reduced.

### Video Camera

The semiconductor device of one embodiment of the present invention can be used in a video camera.

FIG. 109I illustrates a video camera 6300 as an example of an imaging device. The video camera 6300 includes a first housing 6301, a second housing 6302, a display portion 6303, operation switches 6304, a lens 6305, a connection portion 6306, and the like. The operation switch 6304 and the lens 6305 are provided in the first housing 6301, and the display portion 6303 is provided in the second housing 6302. The first housing 6301 and the second housing 6302 are connected to each other with the connection portion 6306, and the angle between the first housing 6301 and the second housing 6302 can be changed with the connection portion 6306. Videos displayed on the display portion 6303 may be switched in accordance with the angle at the connection portion 6306 between the first housing 6301 and the second housing 6302.

When videos taken by the video camera 6300 are recorded, the videos need to be encoded in accordance with a data recording format. With the use of the semiconductor device of one embodiment of the present invention, the video camera 6300 can retain a temporary file generated at the time of encoding.

### ICD

The semiconductor device of one embodiment of the present invention can be used in an implantable cardioverter-defibrillator (ICD).

FIG. 109J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with the end of one of the wires placed in the right ventricle and the end of the other wire placed in the right atrium.

The ICD main unit 5400 functions as a pacemaker and paces the heart when the heart rate is not within a predetermined range. When the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In addition, in the ICD main unit 5400, data on the heart rate obtained by the sensor or the like, the number of times the treatment with pacing is performed, and the time taken for the treatment, for example, can be stored in the electronic component 700.

The antenna 5404 can receive electric power, and the battery 5401 is charged with the electric power. When the ICD main unit 5400 includes a plurality of batteries, the safety can be improved. Specifically, even when some of the batteries in the ICD main unit 5400 are dead, the other batteries can work properly; hence, the batteries also function as an auxiliary power source.

In addition to the antenna 5404 capable of receiving electric power, an antenna that can transmit physiological signals may be included to construct, for example, a system that monitors cardiac activity so that physiological signals such as a pulse, a respiratory rate, a heart rate, and body temperature can be checked with an external monitoring device.

### Expansion Device for PC

The semiconductor device of one embodiment of the present invention can be used in a computer such as a PC (Personal Computer) and an expansion device for an information terminal.

FIG. 110A illustrates, as an example of the extension device, a portable extension device 6100 that includes a chip capable of retaining information and is externally provided on a PC. The expansion device 6100 can store information using the chip when connected to a PC with a USB, for example. Note that although FIG. 110A illustrates the portable expansion device 6100, the expansion device of one embodiment of the present invention is not limited thereto and may be a comparatively large expansion device including a cooling fan or the like, for example.

The expansion device 6100 includes a housing 6101, a cap 6102, a USB connector 6103, and a substrate 6104. The substrate 6104 is held in the housing 6101. The substrate 6104 is provided with a circuit for driving the semiconductor device of one embodiment of the present invention or the like. For example, the electronic component 700 and a controller chip 6106 are attached to the substrate 6104. The USB connector 6103 functions as an interface for connection to an external device.

### SD Card

The semiconductor device of one embodiment of the present invention can be used in an SD card that can be attached to an electronic appliance such as an information terminal or a digital camera.

FIG. 110B is a schematic external view of an SD card, and FIG. 110C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, the electronic components 700 and a controller chip 5115 are attached to the substrate 5113. Note that the circuit configurations of the electronic component 700 and the controller chip 5115 are not limited to those described above, and the circuit configurations may be changed as appropriate depending on circumstances. For example, a write circuit, a row driver, a read circuit, and the like that are provided in an electronic component may be incorporated into the controller chip 5115 instead of the electronic component 700.

When the electronic component 700 is also provided on the rear surface side of the substrate 5113, the capacity of the SD card 5110 can be increased. In addition, a wireless chip with a wireless communication function may be provided on the substrate 5113. This enables wireless communication between an external device and the SD card 5110, making it possible to write and read data to/from the electronic component 700.

### SSD

The semiconductor device of one embodiment of the present invention can be used in an SSD (Solid State Drive) that can be attached to an electronic appliance such as an information terminal.

FIG. 110D is a schematic external view of an SSD, and FIG. 110E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the electronic components 700, a memory chip 5155, and a controller chip 5156 are attached to the substrate 5153. When the electronic component 700 is also provided on the rear surface side of the substrate 5153, the capacity of the SSD 5150 can be increased. A work memory is incorporated into the memory chip 5155. For example, a DRAM chip can be used as the memory chip 5155. A processor, an ECC (Error Check and Correct) circuit, and the like are incorporated into the controller chip 5156. Note that the circuit configurations of the electronic component 700, the memory chip 5155, and the controller chip 5115 are not limited to those described above, and the circuit configurations may be changed as appropriate depending on circumstances. For example, a memory functioning as a work memory may also be provided in the controller chip 5156.

### Computer

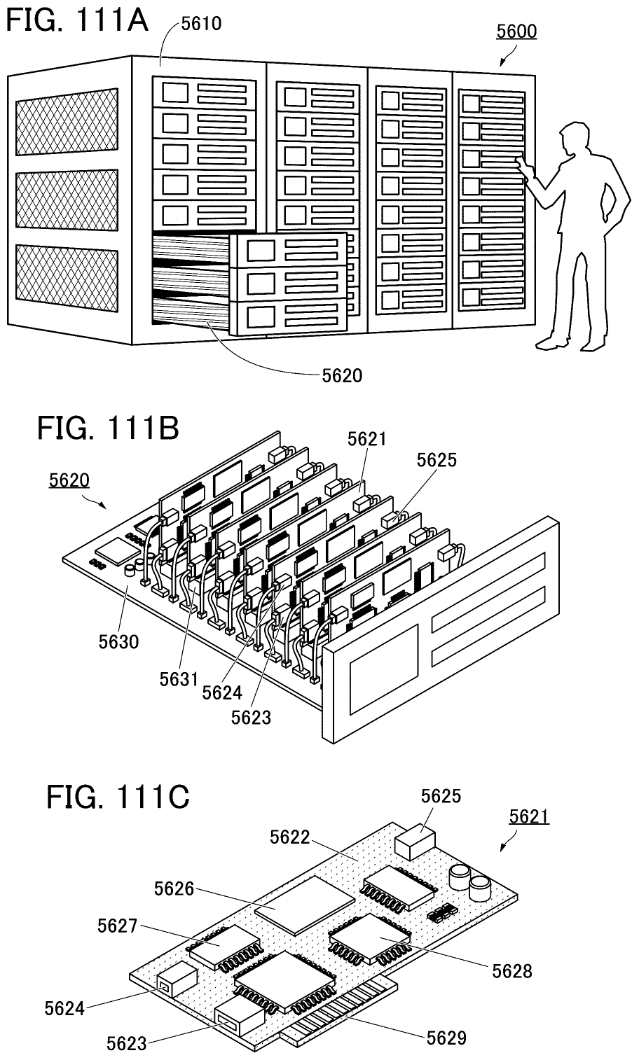

A computer 5600 illustrated in FIG. 111A is an example of a large computer. In the computer 5600, a plurality of rack mount computers 5620 are stored in a rack 5610.

The computer 5620 can have a structure in a perspective view illustrated in FIG. 111B, for example. In FIG. 111B, the computer 5620 includes a motherboard 5630, and the motherboard 5630 includes a plurality of slots 5631 and a plurality of connection terminals. A PC card 5621 is inserted in the slot 5631. The PC card 5621 includes a connection terminal 5623, a connection terminal 5624, and a connection terminal 5625, each of which is connected to the motherboard 5630.

The PC card 5621 illustrated in FIG. 111C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 111C also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal computed by the PC card 5621. Examples of the standard for each of the connection terminal 5623, the connection terminal 5624, and the connection terminal 5625 include USB, SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU. As the semiconductor device 5627, the electronic component 700 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The semiconductor device of one embodiment of the present invention is used in a variety of electronic appliances or the like described above, whereby a reduction in size and a reduction in power consumption of the electronic appliances can be achieved. In addition, since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention can achieve an electronic appliance that operates stably even in a high-temperature environment. Thus, the reliability of the electronic appliance can be increased.

This embodiment can be combined with the other embodiments as appropriate.

### Embodiment 4

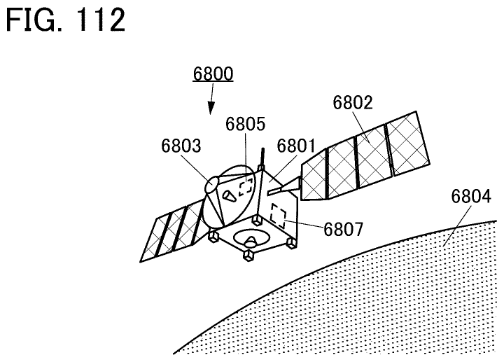

In this embodiment, a specific example of the case where the semiconductor device of one embodiment of the present invention is used in space equipment will be described with reference to FIG. 112.

The semiconductor device of one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, the OS transistor can be suitably used in outer space. Specifically, the OS transistor can be used as a transistor included in a semiconductor device provided in a space shuttle, an artificial satellite, or a space probe. Examples of radiation include X-rays and neutron beams. Note that outer space refers to, for example, space at an altitude greater than or equal to 100 km, and outer space in this specification may also include one or more of the thermosphere, mesosphere, and stratosphere.

FIG. 112 illustrates an artificial satellite 6800 as an example of space equipment. The artificial satellite 6800 includes a body 6801, a solar panel 6802, an antenna 6803, a secondary battery 6805, and a control device 6807. Note that in FIG. 112, a planet 6804 in outer space is illustrated as an example.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in the situation where the solar panel is not irradiated with sunlight or the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used in the control device 6807. A change in electrical characteristics due to exposure to radiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of space equipment in this embodiment, one embodiment of the present invention is not limited thereto. The semiconductor device of one embodiment of the present invention can be suitably used for space equipment, such as a spacecraft, a space capsule, or a space probe, for example.

Alternatively, for example, OS transistors can be used as transistors included in semiconductor devices provided in working robots in a nuclear power plant and a treatment plant or a disposal plant for radioactive wastes. In particular, OS transistors can be suitably used as transistors included in semiconductor devices provided in remote control robots that are controlled remotely in demolishment of a reactor facility, taking out of a nuclear fuel or a fuel debris, a field investigation on a space with a large amount of radioactive substance, and the like.

This embodiment can be combined with the other embodiments as appropriate.

### Reference Numerals

121: opening, 122: opening, 123: opening, 124: opening, 125: opening, 126: opening, 127: opening, 131a: opening, 131b: opening, 132a: opening, 132b: opening, 133a: opening, 133b: opening, 134a: opening, 134b: opening, 200_1: transistor, 200_2: transistor, 200_3: transistor, 200: semiconductor device, 205a: conductor, 205b: conductor, 205: conductor, 215: insulator, 216: insulator, 222_1: insulator, 222_2: insulator, 222_3: insulator, 222: insulator, 230_1: oxide, 230_2: oxide, 230_3: oxide, 230a1: oxide, 230a2: oxide, 230a3: oxide, 230a: oxide, 230A1: oxide film, 230A2: oxide film, 230A3: oxide film, 230b1: oxide, 230b2: oxide, 230b3: oxide, 230ba: region, 230bb: region, 230bc: region, 230b: oxide, 230B1: oxide film, 230B2: oxide film, 230B3: oxide film, 230F1: oxide film, 230F2: oxide film, 230F3: oxide film, 230: oxide, 242_1: conductor, 242_2: conductor, 242_3: conductor, 242a1: conductor, 242a2: conductor, 242a3: conductor, 242a: conductor, 242b1: conductor, 242b2: conductor, 242b3: conductor, 242b: conductor, 242F1: conductive film, 242F2: conductive film, 242F3: conductive film, 243a1: conductor, 243a2: conductor, 243a: conductor, 243b1: conductor, 243b2: conductor, 243b: conductor, 244a1: conductor, 244a2: conductor, 244a: conductor, 244b1: conductor, 244b2: conductor, 244b: conductor, 245a: conductor, 245b: conductor, 246a: conductor, 246b: conductor, 250_1: insulator, 250_2: insulator, 250_3: insulator, 250a: insulator, 250b: insulator, 250c: insulator, 250d: insulator, 250F: insulating film, 250: insulator, 253a: conductor, 253b: conductor, 253: conductor, 254a: conductor, 254b: conductor, 254: conductor, 255: conductor, 256: insulator, 260_1: conductor, 260_2: conductor, 260_3: conductor, 260a1: conductor, 260a2: conductor, 260a3: conductor, 260a: conductor, 260b1: conductor, 260b2: conductor, 260b3: conductor, 260b: conductor, 260: conductor, 270_1: insulator, 270_2: insulator, 270_3: insulator, 270F1: insulating film, 270F2: insulating film, 270F3: insulating film, 271a1: insulator, 271a2: insulator, 271a: insulator, 271b1: insulator, 271b2: insulator, 271b: insulator, 275_1: insulator, 275_2: insulator, 275_3: insulator, 275: insulator, 280_1: insulator, 280_2: insulator, 280_3: insulator, 280: insulator, 283: insulator, 286: insulator, 287: insulator, 300: semiconductor device, 700: electronic component, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: extension device, 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: first housing, 6302: second housing, 6303: display portion, 6304: operation switch, 6305: lens, 6306: connection portion, 6800: artificial satellite, 6801: body, 6802: solar panel, 6803: antenna, 6804: planet, 6805: secondary battery, 6807: control device, 7500: stationary game machine, 7520: main body, 7522: controller

1. A semiconductor device comprising:
a first transistor;
a second transistor;
a first insulator;
a first conductor;
a second conductor; and
a third conductor,
wherein the first transistor comprises:
a first gate electrode;
a first gate insulator over the first gate electrode;
a first semiconductor layer over the first gate insulator;
a first source electrode over the first semiconductor layer;
a first drain electrode over the first semiconductor layer;
a second gate insulator over the first semiconductor layer; and
a second gate electrode over the second gate insulator,
wherein the second transistor comprises:
a second semiconductor layer over the first insulator;
a second source electrode over the second semiconductor layer;
a second drain electrode over the second semiconductor layer;
a third gate insulator over the second semiconductor layer; and
a third gate electrode over the third gate insulator,
wherein the first semiconductor layer comprises a region overlapping the first gate electrode,
wherein the second gate electrode comprises a region overlapping the first gate electrode,
wherein the second gate electrode is positioned between the first source electrode and the first drain electrode in a planar view,
wherein the first insulator is provided over the second gate electrode,
wherein the second semiconductor layer comprises a region overlapping the first semiconductor layer,
wherein the third gate electrode comprises a region overlapping the second gate electrode,
wherein the third gate electrode is positioned between the second source electrode and the second drain electrode in the planar view,
wherein the first conductor penetrates the second source electrode and the second semiconductor layer and comprises a region in contact with the first source electrode,
wherein the second conductor penetrates the second drain electrode and the second semiconductor layer and comprises a region in contact with the first drain electrode, and
wherein the third conductor comprises a region in contact with the first gate electrode, the second gate electrode, and the third gate electrode.

2. The semiconductor device according to claim 1,
wherein the first transistor and the second transistor each comprise a metal oxide in a semiconductor layer.

3. The semiconductor device according to claim 1, further comprising:
a second insulator covering the first transistor; and
a third insulator covering the second transistor,
wherein the third insulator, the second source electrode, the second semiconductor layer, and the second insulator comprise a first opening reaching the first source electrode,
wherein the third insulator, the second drain electrode, the second semiconductor layer, and the second insulator comprise a second opening reaching the first drain electrode,
wherein the second conductor is in contact with a sidewall and a bottom surface of the first opening, and
wherein the third conductor is in contact with a sidewall and a bottom surface of the second opening.

4. The semiconductor device according to claim 1,
wherein a length of the third gate electrode in a channel width direction is smaller than a length of the second gate electrode in the channel width direction.

5. The semiconductor device according to claim 1,
wherein a width between the first source electrode and the first drain electrode and a width between the second source electrode and the second drain electrode are each less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm.

6. The semiconductor device according to claim 1, further comprising:
a second insulator covering the first transistor; and
a third insulator covering the second transistor,
wherein between the first source electrode and the first drain electrode, the second insulator comprises a first opening reaching the first semiconductor layer,
wherein between the second source electrode and the second drain electrode, the third insulator comprises a second opening reaching the second semiconductor layer,
wherein the second gate insulator is provided in contact with a sidewall and a bottom surface of the first opening,
wherein the second gate electrode is provided over the second gate insulator to fill the first opening,
wherein the third gate insulator is provided in contact with a sidewall and a bottom surface of the second opening,
wherein the third gate electrode is provided over the third gate insulator to fill the second opening,
wherein an uppermost surface of the second gate insulator is substantially level with a top surface of the second gate electrode, and
wherein an uppermost surface of the third gate insulator is substantially level with a top surface of the third gate electrode.

7. The semiconductor device according to claim 1,
wherein a side surface of each of the first source electrode and the first drain electrode is substantially aligned with side surfaces of the first semiconductor layer opposite the second gate electrode, and
wherein a side surface of each of the second source electrode and the second drain electrode is substantially aligned with side surfaces of the second semiconductor layer opposite the second gate electrode.

8. (canceled)

9. A semiconductor device comprising:
a first transistor;
a second transistor;
a first insulator;
a first conductor; and
a second conductor,
wherein the first transistor comprises:
a first gate electrode;
a first gate insulator over the first gate electrode;
a first semiconductor layer over the first gate insulator;
a first source electrode over the first semiconductor layer;
a first drain electrode over the first semiconductor layer;
a second gate insulator over the first semiconductor layer; and
a second gate electrode over the second gate insulator,
wherein the second transistor comprises:
a second semiconductor layer over the first insulator;
a second source electrode over the second semiconductor layer;
a second drain electrode over the second semiconductor layer;
a third gate insulator over the second semiconductor layer; and
a third gate electrode over the third gate insulator,
wherein the first semiconductor layer comprises a region overlapping the first gate electrode,
wherein the second gate electrode comprises a region overlapping the first gate electrode and a region in contact with a top surface of the first gate electrode through an opening in the first gate insulator and the second gate insulator,
wherein the second gate electrode is positioned between the first source electrode and the first drain electrode in a planar view,
wherein the first insulator is provided over the second gate electrode,
wherein the second semiconductor layer comprises a region overlapping the first semiconductor layer,
wherein the third gate electrode comprises a region overlapping the second gate electrode and a region in contact with a top surface of the second gate electrode through an opening in the first insulator and the third gate insulator,
wherein the third gate electrode is positioned between the second source electrode and the second drain electrode in the planar view,
wherein the first conductor penetrates the second source electrode and the second semiconductor layer and comprises a region in contact with the first source electrode, and
wherein the second conductor penetrates the second drain electrode and the second semiconductor layer and comprises a region in contact with the first drain electrode.

10. The semiconductor device according to claim 9,
wherein an end portion of the second gate electrode and an end portion of the third gate electrode are substantially aligned with each other in the planar view.

11. A semiconductor device comprising:
a first conductor;
a first insulator over the first conductor;
a first oxide over the first insulator;
a second insulator, a second conductor, and a third conductor over the first oxide;
a fourth conductor over the second insulator;
a third insulator over the second insulator and the fourth conductor;
a second oxide over the third insulator;
a fourth insulator, a fifth conductor, and a sixth conductor over the second oxide;
a seventh conductor over the fourth insulator;
an eighth conductor that penetrates the fifth conductor and the second oxide and is in contact with the second conductor;
a ninth conductor penetrates the sixth conductor and the second oxide and is in contact with the third conductor; and
a tenth conductor in contact with a top surface of the first conductor, a top surface of the fourth conductor, and a top surface of the seventh conductor,
wherein the first conductor is overlapped with the fourth conductor with the first oxide therebetween,
wherein the fourth conductor is overlapped with the seventh conductor with the second oxide therebetween,
wherein the second conductor and the fifth conductor are electrically connected to each other,
wherein the third conductor and the sixth conductor are electrically connected to each other,
wherein the first conductor, the fourth conductor, and the seventh conductor are electrically connected to each other, and
wherein the third insulator comprises a region in contact with a top surface of the second insulator and the top surface of the fourth conductor.

12. The semiconductor device according to claim 11,
wherein an uppermost surface of the second insulator and the top surface of the fourth conductor are substantially level with each other, and
wherein an uppermost surface of the fourth insulator and the top surface of the seventh conductor are substantially level with each other.

13. The semiconductor device according to claim 11,
wherein a side surface of each of the second conductor and the third conductor is substantially aligned with side surfaces of the first oxide opposite the fourth conductor, and
wherein a side surface of each of the fifth conductor and the sixth conductor is substantially aligned with side surface surfaces of the second oxide opposite the seventh conductor.
